(19) United States
(12) Patent Application Publication
(10) Pub. No.: US 2013/0071789 A1
(43) Pub. Date: Mar. 21, 2013

(54) RESIST COMPOSITION AND METHOD OF FORMING RESIST PATTERN

(71) Applicants: Jun IWASHITA, Kawasaki-shi (JP); Kenri KONNO, Kawasaki-shi (JP)

(72) Inventors: Jun IWASHITA, Kawasaki-shi (JP); Kenri KONNO, Kawasaki-shi (JP)

(73) Assignee: Tokyo Ohka Kogyo Co., Ltd., Kawasaki-shi (JP)

(21) Appl. No.: 13/617,697

(22) Filed: Sep. 14, 2012

(30) Foreign Application Priority Data
Sep. 20, 2011 (JP) 2011-204956

(51) Int. Cl. G03F 7/004; G03F 7/20

(52) U.S. Cl. 430/285.1; 430/270.1; 430/325; 430/296

(57) ABSTRACT

A resist composition for use with EUV or EB including:
a resin component (C) containing at least one type of atom selected from the group consisting of a fluorine atom and a silicon atom, an aromatic group, and a polarity conversion group that decomposes by action of base to increase the polarity; and
a resin component (A) that generates acid upon exposure and exhibits changed solubility in a developing solution under action of acid (excluding the aforementioned resin component (C)),
wherein an amount of a structural unit having the aforementioned aromatic group in the aforementioned resin component (C) is at least 20 mol %.

### BACKGROUND OF THE INVENTION

1. Field of the Invention

The present invention relates to a resist composition which generates acid upon exposure and exhibits changed solubility in a developing solution under the action of acid, and also relates to a method of forming a resist pattern using the resist composition.

Priority is claimed on Japanese Patent Application No. 2011-204956, filed Sep. 20, 2011, the content of which is incorporated herein by reference.

2. Description of Related Art

In lithography techniques, for example, a resist film composed of a resist material is formed on a substrate, and the resist film is subjected to selective exposure followed by development, thereby forming a resist pattern having a predetermined shape on the resist film. A resist material in which the exposed portions of the resist film become soluble in a developing solution is called a positive-type, and a resist material in which the exposed portions become insoluble in a developing solution is called a negative-type.

In recent years, in the production of semiconductor elements and liquid crystal display elements, advances in lithography techniques have led to rapid progress in the field of pattern miniaturization.

Typically, these pattern miniaturization techniques involve shortening the wavelength (and increasing the energy) of the exposure light source. Conventionally, ultraviolet radiation typified by g-line and i-line radiation has been used, but nowadays KrF excimer lasers and ArF excimer lasers are starting to be introduced in the mass production of semiconductor elements. Furthermore, research is also being conducted into lithography techniques that use an exposure light source having a shorter wavelength (and a higher energy level) than these excimer lasers, such as extreme ultraviolet radiation (EUV), electron beam (EB), and X-ray.

Resist materials for use with these types of exposure light sources require lithography properties such as a high resolution capable of reproducing patterns of minute dimensions, and a high level of sensitivity to these types of exposure light sources.

As a resist material that satisfies these conditions, conventionally a chemically amplified resist composition has been used, which includes a base component that exhibits changed solubility in a developing solution under the action of acid, and an acid generator component that generates acid upon exposure. For example, in the case where the developing solution is an alkali developing solution (namely, an alkali developing process), a positive-type chemically amplified resist composition is typically used, which contains a resin component (base resin) that exhibits increased solubility in an alkali developing solution under the action of acid, and an acid generator component. If the resist film formed using this resist composition is selectively exposed during formation of a resist pattern, then within the exposed portions, acid is generated from the acid generator component, and the action of this acid causes an increase in the solubility of the base resin in an alkali developing solution, making the exposed portions soluble in the alkali developing solution. As a result, by performing alkali developing, the unexposed portions remain as a pattern, resulting in the formation of a positive-type pattern.

The base resin uses a resin for which the polarity increases under the action of acid, resulting in an increase in the solubility of the resin in an alkali developing solution, but a decrease in the solubility of the resin within organic solvents. Accordingly, if a solvent developing process that uses a developing solution containing an organic solvent (an organic developing solution) is employed instead of the alkali developing process, then within the exposed portions of the resist film, the solubility in the organic developing solution decreases relatively, meaning that during the solvent developing process, the unexposed portions of the resist film are dissolved in the organic developing solution and removed, whereas the exposed portions remain as a pattern, resulting in the formation of a negative-type resist pattern. This type of solvent developing process that results in the formation of a negative-type resist pattern is sometimes referred to as a negative-type developing process (for example, see Patent Document 1).

Currently, resins that contain structural units derived from (meth)acrylate esters within the main chain (acrylic resins) are widely used as base resins for chemically amplified resist compositions that use ArF excimer laser lithography or the like, as they exhibit excellent transparency in the vicinity of 193 nm (for example, see Patent Document 2). Here, the term “(meth)acrylate ester” is a generic term that includes either or both of the acrylate ester having a hydrogen atom bonded to the α-position and the methacrylate ester having a methyl group bonded to the α-position. The term “(meth)acrylate” is a generic term that includes either or both of the acrylate having a hydrogen atom bonded to the α-position and the methacrylate having a methyl group bonded to the α-position. The term “(meth)acrylic acid” is a generic term that includes either or both of acrylic acid having a hydrogen atom bonded to the α-position and methacrylic acid having a methyl group bonded to the α-position.

In recent years, resins having an acid generating group that generates acid upon exposure have been proposed as base resins. For example, resin components have been proposed that have both an acid generating group that generates acid upon exposure and an acid decomposable group that exhibits changed polarity under the action of acid within the same structure (for example, see Patent Documents 3 to 5). These resin components combine the function of an acid generator and the function of a base component, and enable a chemically amplified resist composition to be prepared using only a single component. In other words, when this type of resin component is subjected to exposure, acid is generated from the acid generating group within the structure, and the action of that acid causes decomposition of the acid decomposable group, thereby forming a polar group such as a carboxyl group that causes an increase in the polarity. As a result, when a resin film (resist film) formed using such a resin component is subjected to selective exposure, the polarity of the exposed portions increases, and by performing developing using an alkali developing solution, the exposed portions can be dissolved and removed, thus forming a positive-type resist pattern.

As a technique for further improving the resolution, a lithography method called liquid immersion lithography (hereafter, frequently referred to as “immersion exposure”) is known in which exposure (immersion exposure) is conducted in a state where the region between the objective lens of the exposure apparatus and the sample is filled with a solvent (an immersion medium) that has a larger refractive index than the refractive index of air. According to this type of immersion exposure, it is considered that higher resolutions equivalent to those obtained using a shorter wavelength light source or a larger NA lens can be obtained using the same exposure light source wavelength, with no lowering of the depth of focus. Furthermore, immersion exposure can be conducted using a conventional exposure apparatus. As a result, immersion exposure is preferably used in recent years because it enables the formation of resist patterns of higher resolution and superior depth of focus at lower costs. Immersion exposure is effective in forming patterns having various shapes. Further, immersion exposure is expected to be capable of being used in combination with super-resolution techniques, such as phase shift methods and modified illumination methods. Currently, as the immersion exposure technique, technique using an ArF excimer laser as an exposure source is being actively studied, and water is mainly used as the immersion medium.

The addition of a compound containing a fluorine atom or silicon atom to these resist compositions used in the immersion exposure has been proposed. For example, in Patent Document 6, a resist composition to which a polymeric compound containing an aromatic cyclic group having a fluorine atom in the side chain was added has been disclosed. In Patent Document 7, a resist composition to which a fluorine-containing compound having a group represented by a specific general formula was added has been disclosed.

### DOCUMENTS OF RELATED ART

### Patent Document

[Patent Document 1] Japanese Unexamined Patent Application, First Publication No. 2009-025723
[Patent Document 2] Japanese Unexamined Patent Application, First Publication No. 2003-241385
[Patent Document 3] Japanese Unexamined Patent Application, First Publication No. Hei 10-221852
[Patent Document 4] Japanese Unexamined Patent Application, First Publication No. 2006-045311
[Patent Document 5] Japanese Unexamined Patent Application, First Publication No. 2010-095643
[Patent Document 6] Japanese Unexamined Patent Application, First Publication No. 2008-309938
[Patent Document 7] Japanese Unexamined Patent Application, First Publication No. 2009-139909

### SUMMARY OF THE INVENTION

Resist materials for use in EUV lithography or EB lithography require specific lithography properties, including sensitivity to EUV or EB, and a high resolution capable of forming the targeted very fine resist pattern.

Currently, chemically amplified resists that have been proposed for use with KrF excimer lasers or ArF excimer lasers are generally used as the resist materials for EUV lithography and EB lithography due to their superior lithography properties.

Chemically amplified resists containing an acrylic resin as the base resin are particularly common due to their superior lithography properties.

However, a problem exists in that when a chemically amplified resist that has been proposed for use with a KrF excimer laser or an ArF excimer laser is used for EUV lithography or EB lithography, the shape of the formed resist pattern is often unsatisfactory.

For example, in the case of EUV lithography, so-called “Out of Band” (OoB) light, which is incorporated within the light generated by the light source of the EUV exposure apparatus but is of a wavelength outside the EUV region, can cause problems. OoB light enters the unexposed portions of the resist film together with a flare that is generated at the same time (thus impairing the selectivity of the exposure region during the EUV light irradiation), and therefore the acid generator component decomposes and generates acid even within the unexposed portions, which can cause problems such as a decrease in the resist pattern contrast, thickness loss, and roughness (surface roughness in the upper surface and the side walls of the pattern). Roughness can cause inferior resist pattern shape. For example, roughness in the side wall surfaces of a pattern can cause shape defects typified by non-uniformity in the line width of a line and space pattern or distortion around the hole periphery in a hole pattern.

These shape defect problems caused by OoB light tend to be particularly marked when chemically amplified resists for lithography processes in which exposure is carried out using light having a wavelength in the DUV region such as ArF excimer laser light are used. In other words, in these types of chemically amplified resists, generally, irradiation of light having a wavelength in the DUV region results in the generation of acid and a change in solubility within the developing solution. OoB light includes light having a wavelength in the EUV region around 13.5 nm, the DUV region from 150 to 300 nm and in the infrared region. Onium salt-based acid generators that are widely used conventionally tend to absorb light having a wavelength in the DUV region to generate acid. For this reason, when an EUV exposure is performed, those portions that are intended as unexposed portions also exhibit photosensitivity, causing a decrease in the contrast, pattern thickness loss, or the like.

In EB lithography, electrons may be diffused (scattered) across the surface of the resist film depending on the electron beam irradiation conditions such as the accelerating voltage, and therefore the same type of problem as that observed with the OoB light in EUV lithography can occur.

Unsatisfactory resist pattern shape can adversely affect the formation of very fine semiconductor elements. Accordingly, resist materials for use in EUV lithography and EB lithography require improved lithography properties and an improved pattern shape.

The present invention takes the above circumstances into consideration, and has an object of providing a resist composition that is useful for use with EUV and EB, as well as providing a method of forming a resist pattern that uses the resist composition.

As a result of intensive investigation, the inventors of the present invention discovered that the above object can be achieved by adding, as an additive, a specific resin component to a resist composition where structures which generate an acid upon exposure have been distributed uniformly to some extent (namely, a resist composition containing a resin where structures which generate an acid upon exposure have been introduced as a base resin, or a resist composition containing at least a certain amount of an acid generator component relative to the base resin), and they were therefore able to complete the present invention.

Specifically, a first aspect of the present invention is a resist composition for use with EUV or EB which includes a resin component (C) containing at least one type of atom selected from the group consisting of a fluorine atom and a silicon atom, an aromatic group, and a polarity conversion group that decomposes by the action of a base to increase the polarity; and a resin component (A) that generates acid upon exposure and exhibits changed solubility in a developing solution under the action of acid (excluding the aforementioned resin component (C)),

wherein the amount of a structural unit having the aforementioned aromatic group in the aforementioned resin component (C) is equal to or greater than 20 mol %.

A second aspect of the present invention is a resist composition for use with EUV or EB which includes a resin component (C) containing at least one type of atom selected from the group consisting of a fluorine atom and a silicon atom, an aromatic group, and a polarity conversion group that decomposes by the action of a base to increase the polarity; a resin component (A) that exhibits changed solubility in a developing solution under the action of acid (excluding the aforementioned component (C)); and an acid generator component (B) that generates acid upon exposure,

wherein the amount of a structural unit having the aforementioned aromatic group in the aforementioned resin component (C) is equal to or greater than 20 mol %, and

the amount of the aforementioned acid generator component (B) is 15 parts by weight or more, relative to 100 parts by weight of the aforementioned resin component (A).

A third aspect of the present invention is a method of forming a resist pattern, the method including: forming a resist film on a substrate using the resist composition for use with EUV or EB according to the first or second aspect; exposing the resist film with EUV or EB; and developing the resist film to form a resist pattern.

In the present description and claims, the expression “for use with EUV or EB” indicates that formation of a resist pattern using the resist composition is performed by exposure using extreme ultraviolet radiation (EUV) or an electron beam (EB) as the exposure light source (radiation source).

The term “exposure” is used as a general concept that includes irradiation with any form of radiation.

The term “aliphatic” is a relative concept used in relation to the term “aromatic”, and defines a group or compound that has no aromaticity.

The term “alkyl group” includes linear, branched or cyclic, monovalent saturated hydrocarbon, unless otherwise specified. The same applies for the alkyl group within an alkoxy group.

The term “alkylene group” includes linear, branched or cyclic divalent saturated hydrocarbon, unless otherwise specified.

A “halogenated alkyl group” is a group in which part or all of the hydrogen atoms of an alkyl group have each been substituted with a halogen atom. A “halogenated alkylene group” is a group in which part or all of the hydrogen atoms of an alkylene group have each been substituted with a halogen atom. Examples of the halogen atom include a fluorine atom, a chlorine atom, a bromine atom and an iodine atom.

A “fluorinated alkyl group” is a group in which part or all of the hydrogen atoms of an alkyl group have each been substituted with a fluorine atom. A “fluorinated alkylene group” is a group in which part or all of the hydrogen atoms of an alkylene group have each been substituted with a fluorine atom.

The term “structural unit” refers to a monomer unit that contributes to the formation of a resin (polymeric compound, polymer, copolymer).

The present invention is able to provide a resist composition that is useful for use with EUV or EB, as well as providing a method of forming a resist pattern that uses the resist composition.

### DETAILED DESCRIPTION OF THE INVENTION

### <<Resist Composition According to First Aspect>>

A resist composition according to a first aspect of the present invention includes a resin component (C) containing at least one type of atom selected from the group consisting of a fluorine atom and a silicon atom, an aromatic group, and a polarity conversion group that decomposes by the action of a base to increase the polarity (hereafter, referred to as component (C)); and a resin component (A) that generates acid upon exposure and exhibits changed solubility in a developing solution under the action of acid (provided that the resin component (A) excludes the aforementioned component (C)) (hereafter, referred to as component (A)).

The resist composition of the present aspect includes the component (A), and thus exhibits changed solubility in a developing solution upon exposure. When a resist film is formed using the resist composition and that resist film is then subjected to selective exposure, acid is generated from the component (A) in the exposed portions, and the generated acid causes a change in the solubility of the component (A) in a developing solution. As a result, the solubility of the exposed portions in the developing solution changes, whereas in the unexposed portions, the solubility of the component (A) in the developing solution does not change, meaning that when the resist film is subjected to developing, either a positive-type resist pattern is formed by dissolving and removing the exposed portions in the case of a positive-type resist composition, or a negative-type resist pattern is formed by dissolving and removing the unexposed portions in the case of a negative-type resist composition.

In the present description, a resist composition in which the exposed portions are dissolved and removed to form a positive-type resist pattern is referred to as a “positive-type resist composition”, whereas a resist composition in which the unexposed portions are dissolved and removed to form a negative-type resist pattern is referred to as a “negative-type resist composition”. The resist composition of the present aspect may be either a positive-type resist composition or a negative-type resist composition. Further, the resist composition of the present aspect may be used for either an alkali developing process in which an alkali developing solution is used for the developing treatment during formation of the resist pattern, or a solvent developing process in which a developing solution containing an organic solvent (an organic developing solution) is used for the developing treatment. The resist composition of the present aspect is preferably used for forming a positive-type resist pattern in an alkali developing process, and in this case, as the component (A), a resin component which exhibits increased solubility in an alkali developing solution by the action of acid is used.

### <Component (C)>

The component (C) is a resin component containing at least one type of atom selected from the group consisting of a fluorine atom and a silicon atom, an aromatic group, and a polarity conversion group that decomposes by the action of a base to increase the polarity.

In the present description, the term “resin component” describes an organic compound capable of forming a film, which exists as a polymer. A polymeric compound having a molecular weight of 500 or more, and preferably 1,000 or more, is typically used as the resin component, as such polymeric compounds facilitate the formation of nano level resist patterns. For a resin component, the “molecular weight” refers to the polystyrene-equivalent weight average molecular weight determined by gel permeation chromatography (GPC).

### [Aromatic Group]

An aromatic group is a group obtained by removing one or more hydrogen atoms from an aromatic compound. An aromatic group contributes to an absorption of OoB light having a wavelength in the DUV region, thereby reducing the adverse effects thereof.

Aromatic compounds are compounds having aromaticity and contain an aromatic ring which may have a substituent. The aromatic ring preferably has 5 to 30 carbon atoms, more preferably 5 to 20 carbon atoms, still more preferably 6 to 15 carbon atoms, and most preferably 6 to 12 carbon atoms. The number of carbon atoms does not include any carbon atoms within any substituents. Specific examples of the aromatic ring include aromatic hydrocarbon rings such as benzene, biphenyl, fluorene, naphthalene, anthracene and phenanthrene, and aromatic heterocyclic rings in which part of the carbon atoms that constitute one of the above aromatic hydrocarbon rings have been substituted with a hetero atom. Examples of the hetero atom in the aromatic heterocyclic rings include an oxygen atom, a sulfur atom and a nitrogen atom. The aromatic ring may have a substituent bonded thereto. As the aromatic ring, an aromatic hydrocarbon ring is preferred, and benzene or naphthalene is particularly desirable.

Examples of the substituent which may be bonded to the aforementioned aromatic ring include an alkyl group, an alkoxy group, a halogen atom, a halogenated alkyl group, a hydroxyl group, an oxo group (═O), and a polarity conversion group that decomposes by the action of an acid or base to increase the polarity.

The alkyl group for the substituent is preferably an alkyl group of 1 to 5 carbon atoms, and examples thereof include a methyl group, an ethyl group, a propyl group, an n-butyl group and a tert-butyl group.

The alkoxy group for the substituent is preferably an alkoxy group of 1 to 5 carbon atoms, and examples thereof include a methoxy group, an ethoxy group, an n-propoxy group, an iso-propoxy group, an n-butoxy group and a tert-butoxy group.

Examples of the halogen atom for the substituent include a fluorine atom, a chlorine atom, a bromine atom and an iodine atom, and a fluorine atom is preferred.

Examples of the halogenated alkyl group for the substituent include groups in which part or all of the hydrogen atoms of an aforementioned alkyl group have each been substituted with an aforementioned halogen atom.

Among the polarity conversion groups for the substituent, examples of the polarity conversion group that decomposes by the action of an acid to increase the polarity include the same acid decomposable groups as those described later in connection with the structural unit (c2). Examples of the polarity conversion group that decomposes by the action of a base to increase the polarity include the same groups as those shown below.

Of the various possibilities described above, as the substituent which may be bonded to the aromatic group, a fluorine atom, an alkyl group of 1 to 5 carbon atoms or an alkoxy group of 1 to 5 carbon atoms is preferred, and a fluorine atom, a methyl group or a methoxy group is particularly desirable.

[Polarity Conversion Group that Decomposes by the Action of a Base to Increase the Polarity]

A polarity conversion group that decomposes by the action of a base to increase the polarity (hereafter, sometimes referred to as a base decomposable polarity conversion group) may be decomposed (hydrolyzed) by the action of an alkali developing solution (preferably a 2.38% by weight aqueous solution of tetramethylammonium hydroxide (TMAH) at 23° C.). Therefore, since the component (C) changes from hydrophobic to hydrophilic by the alkali development, when a resist pattern is formed using a resist composition containing the component (C), the surface of the resist pattern changes from hydrophobic to hydrophilic by the alkali development. As a result, the occurrence of defects is suppressed, and a resist pattern having a satisfactory shape with a small line width roughness (LWR) can be formed.

Examples of base decomposable polarity conversion groups include groups which decompose by the action of a base to form a polar group. Examples of the polar group include a carboxyl group, a hydroxyl group and an amino group.

Specific examples of the polarity conversion groups include polar group-containing groups having at least one polar group in which at least one of the polar group is protected with a base dissociable group. The polar group-containing group may be composed only of a polar group, or may be a group in which n polar group(s) [n represents an integer of 1 or more] is bonded to a linking group having a valency of (n+1).

A “base dissociable group” is a group exhibiting base dissociability in which at least a bond between the base dissociable group and the atom adjacent to the base dissociable group may be cleaved by the action of a base, and examples of the base include an alkali developing solution (such as a 2.38% by weight aqueous solution of tetramethylammonium hydroxide (TMAH) of 23° C.). It is necessary that the base dissociable group that constitutes the polarity conversion group is a group of lower polarity than the polar group generated by the dissociation of the base dissociable group. Thus, when the base dissociable group dissociates under the action of a base, a polar group exhibiting a higher polarity than that of the base dissociable group is generated, resulting in an increase in the polarity. As a result, the polarity of the entire component (C) increases. Various base dissociable groups which have been proposed so far as base dissociable groups can be employed without particular limitations.

As the base decomposable polarity conversion group, a group represented by general formulas (I-1) to (I-4) shown below or the like is preferable. Among these, a group represented by general formula (I-1) or (I-2) is preferred, and a group represented by general formula (I-2) is particularly preferred.

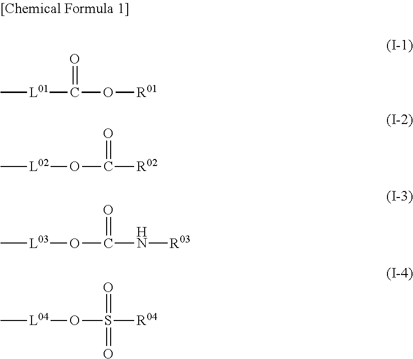

In the formula, R⁰¹ represents an alkyl group of 1 to 2 carbon atoms or a fluorinated alkyl group of 1 to 10 carbon atoms; L⁰¹ represents a single bond or a divalent linking group; R⁰² represents an organic group which may have a fluorine atom; L⁰² represents a single bond or a divalent linking group; R⁰³ represents an organic group which may have a fluorine atom; L⁰³ represents a single bond or a divalent linking group; R⁰⁴ represents an organic group which may have a fluorine atom, and L⁰⁴ represents a single bond or a divalent linking group.

In formula (I-1), the fluorinated alkyl group for R⁰¹ is preferably linear or branched, and more preferably linear. The fluorination ratio (percentage of the hydrogen atoms within an unsubstituted alkyl group substituted with fluorine atoms) is preferably 30% or more, and more preferably 50% or more.

There are no particular limitations on the upper limit for the fluorination ratio and may even be 100%.

In particular, the fluorinated alkyl group is preferably a group represented by the formula: —(CH₂)ᵥ—R^{f} [v represents an integer of 0 to 4, and R^{f} represents a fluorinated alkyl group of 1 to 8 carbon atoms]. v is preferably an integer of 1 to 3. R^{f} preferably has 1 to 2 carbon atoms. Further, if v is an integer equal to or greater than 1, R^{f} is preferably a perfluoroalkyl group.

Specific examples of R⁰¹ include —CH₃, —CH₂—CH₃, —CF₃, —CH₂—CF₃, —CH₂—CF₂—CF₃, —CH(CF₃)₂, —(CH₂)₂—(CF₂)₂—CF₃, —(CH₂)₂—(CF₂)₃—CF₃, —(CH₂)₂—(CF₂)₄—CF₃, —(CH₂)₂—(CF₂)₇—CF₃, —(CH₂)₃—CF₃, —(CH₂)₃—CF₂—CF₃, —(CH₂)₄—CF₃ and —(CH₂)₄—CF₂—CF₃.

In formula (I-1), although there are no particular limitations on the divalent linking group for L⁰¹, preferred examples include divalent hydrocarbon groups which may have a substituent, and divalent linking groups containing a hetero atom.

(Divalent Hydrocarbon Group which May have a Substituent)

The hydrocarbon group for the divalent linking group may be an aliphatic hydrocarbon group or an aromatic group (hereafter, sometimes referred to as an aromatic hydrocarbon group.).

An “aliphatic hydrocarbon group” refers to a hydrocarbon group that has no aromaticity. The aliphatic hydrocarbon group may be saturated or unsaturated. In general, the aliphatic hydrocarbon group is preferably saturated.

Specific examples of the aliphatic hydrocarbon group include a linear or branched aliphatic hydrocarbon group, and an aliphatic hydrocarbon group that includes a ring within the structure thereof.

The linear or branched aliphatic hydrocarbon group preferably has 1 to 10 carbon atoms, more preferably 1 to 8 carbon atoms, and still more preferably 1 to 5 carbon atoms. As the linear aliphatic hydrocarbon group, a linear alkylene group is preferable.

Specific examples thereof include a methylene group [—CH₂—], an ethylene group [—(CH₂)₂—], a trimethylene group [—(CH₂)₃—], a tetramethylene group [—(CH₂)₄—] and a pentamethylene group [—(CH₂)₅—].

As the branched aliphatic hydrocarbon group, a branched alkylene group is preferred, and specific examples include various alkylalkylene groups, including alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂— and —C(CH₂CH₃)₂—CH₂—; alkyltrimethylene groups such as —CH(CH₃)CH₂CH₂— and —CH₂CH(CH₃)CH₂—; and allyltetramethylene groups such as —CH(CH₃)CH₂CH₂CH₂— and —CH₂CH(CH₃)CH₂CH₂—. As the alkyl group within the alkylalkylene group, a linear alkyl group of 1 to 5 carbon atoms is preferable.

The linear or branched aliphatic hydrocarbon group may or may not have a substituent (groups or atoms other than hydrogen atom) that substitutes a hydrogen atom. Examples of this substituent include a fluorine atom, a fluorinated alkyl group of 1 to 5 carbon atoms and an oxo group (═O).

Examples of the aliphatic hydrocarbon group that includes a ring within the structure thereof include a cyclic aliphatic hydrocarbon group (a group in which two hydrogen atoms have been removed from an aliphatic hydrocarbon ring) which may contain a hetero atom-containing substituent in the ring structure thereof, a group in which the aforementioned cyclic aliphatic hydrocarbon group is bonded to the terminal of a linear or branched aliphatic hydrocarbon group, and a group in which the aforementioned cyclic aliphatic hydrocarbon group is interposed within the chain of a linear or branched aliphatic hydrocarbon group. Examples of the linear or branched aliphatic hydrocarbon group include the same groups as those mentioned above.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic aliphatic hydrocarbon group, a group in which two hydrogen atoms have been removed from a monocycloalkane is preferred. The monocycloalkane preferably contains 3 to 6 carbon atoms, and specific examples include cyclopentane and cyclohexane. As the polycyclic aliphatic hydrocarbon group, a group in which two hydrogen atoms have been removed from a polycycloalkane is preferable, and the polycycloalkane preferably contains 7 to 12 carbon atoms. Specific examples of the polycycloalkane include adamantane, norbornane, isobornane, tricyclodecane and tetracyclododecane.

The cyclic aliphatic hydrocarbon group may or may not have a substituent (groups or atoms other than hydrogen atom) that substitutes a hydrogen atom. Examples of the substituent include an alkyl group, an alkoxy group, a halogen atom, a halogenated alkyl group, a hydroxyl group and an oxo group (═O).

The alkyl group for the substituent is preferably an alkyl group of 1 to 5 carbon atoms, and is most preferably a methyl group, an ethyl group, a propyl group, an n-butyl group or a tert-butyl group.

The alkoxy group for the substituent is preferably an alkoxy group of 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom for the substituent include a fluorine atom, a chlorine atom, a bromine atom and an iodine atom, and a fluorine atom is preferred.

Examples of the halogenated alkyl group for the substituent include groups in which part or all of the hydrogen atoms of an aforementioned alkyl group have each been substituted with an aforementioned halogen atom.

In the cyclic aliphatic hydrocarbon group, part of the carbon atoms that constitute the cyclic structure thereof may be substituted with a substituent containing a hetero atom. The hetero atom-containing substituent is preferably —O—, —C(═O)—O—, —S—, —S(═O)₂— or —S(═O)₂—O—.

The aromatic group as the divalent hydrocarbon group is a divalent hydrocarbon group having an aromatic ring, and may also have a substituent.

The aromatic ring preferably has 5 to 30 carbon atoms, more preferably 5 to 20 carbon atoms, still more preferably 6 to 15 carbon atoms, and most preferably 6 to 12 carbon atoms. Here, the number of carbon atoms does not include any carbon atoms within any substituent(s). Specific examples of the aromatic ring include aromatic hydrocarbon rings such as benzene, biphenyl, fluorene, naphthalene, anthracene and phenanthrene, and aromatic heterocyclic rings in which part of the carbon atoms that constitute one of the above aromatic hydrocarbon rings have been substituted with a hetero atom. Examples of the hetero atom in the aromatic heterocyclic rings include an oxygen atom, a sulfur atom and a nitrogen atom.

Specific examples of the aromatic group as the divalent hydrocarbon group include groups in which two hydrogen atoms have been removed from an aforementioned aromatic hydrocarbon ring or aromatic heterocyclic ring (namely, arylene groups or heteroarylene groups); and groups in which one of the hydrogen atoms of a group having one hydrogen atom removed from an aforementioned aromatic hydrocarbon ring or aromatic heterocyclic ring (namely, aryl groups or heteroaryl groups) has been substituted with an alkylene group (for example, groups in which one hydrogen atom has been further removed from the aryl group within an arylalkyl group, such as a benzyl group, a phenethyl group, a 1-naphthylmethyl group, a 2-naphthylmethyl group, a 1-naphthylethyl group or a 2-naphthylethyl group). The alkylene group bonded to the aryl group or heteroaryl group preferably has 1 to 4 carbon atoms, more preferably 1 or 2 carbon atoms, and most preferably 1 carbon atom.

The aromatic group may or may not have a substituent. For example, a hydrogen atom bonded to the aromatic ring within the aromatic group may be substituted with a substituent. Examples of the substituent include an alkyl group, an alkoxy group, a halogen atom, a halogenated alkyl group, a hydroxyl group and an oxo group (═O).

The alkyl group for the substituent is preferably an alkyl group of 1 to 5 carbon atoms, and is most preferably a methyl group, an ethyl group, a propyl group, an n-butyl group or a tert-butyl group.

The alkoxy group for the substituent is preferably an alkoxy group of 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom for the substituent include a fluorine atom, a chlorine atom, a bromine atom and an iodine atom, and a fluorine atom is preferred.

Examples of the halogenated alkyl group for the substituent include groups in which part or all of the hydrogen atoms of an aforementioned alkyl group have each been substituted with an aforementioned halogen atom.

### (Divalent Linking Group Containing a Hetero Atom)

Examples of the hetero atom in the divalent linking group containing a hetero atom include atoms other than a carbon atom or hydrogen atom, and specific examples include an oxygen atom, a nitrogen atom, a sulfur atom, a halogen atom and a silicon atom.

Specific examples of the divalent linking group containing a hetero atom include non-hydrocarbon-based linking groups such as —O—, —C(═O)—, —C(═O)—O—, —O—C(═O)—O—, —S—, —S(═O)₂—, —S(═O)₂—O—, —NH—, —NH—C(═O)—, —NH—C(═NH)—, ═N— and —SiH₂—O—; and a combination of at least one of these non-hydrocarbon-based linking groups with a divalent hydrocarbon group. Examples of the divalent hydrocarbon group include the same groups as those described above for the divalent hydrocarbon group which may have a substituent, although a linear or branched aliphatic hydrocarbon group is preferable.

Of the various possibilities described above, each of the —NH— in —C(═O)—NH— and the H in —NH—, —NH—C(═NH)— and —SiH₂—O— may be substituted with a substituent such as an alkyl group or acyl group. The substituent preferably has 1 to 10 carbon atoms, more preferably 1 to 8 carbon atoms, and most preferably 1 to 5 carbon atoms.

Further, examples of the divalent linking group which is a combination of a non-hydrocarbon-based linking group with a divalent hydrocarbon group include —Y²¹—O—Y²²—, —[Y²¹—C(═O)—O]_{m′}—Y²²—, —Y²¹—O—C(═O)—Y²²— (with the provision that each of Y²¹ and Y²² independently represents a divalent hydrocarbon group which may have a substituent, O represents an oxygen atom and m′ represents an integer of 0 to 3) and —[Y²³—O]_{n′}— (with the provision that Y²³ represents an alkylene group, O represents an oxygen atom and n′ represents an integer of 1 or more).

In the above formulas —Y²¹—O—Y²²—, —[Y²¹—C(═O)—O]_{m′}—Y²²— and —Y²¹—O—C(═O)—Y²²—, each of Y²¹ and Y²² independently represents a divalent hydrocarbon group which may have a substituent. Examples of this divalent hydrocarbon group include the same groups as those described above for the “divalent hydrocarbon group which may have a substituent”.

Y²¹ is preferably a linear aliphatic hydrocarbon group, more preferably a linear alkylene group, still more preferably a linear alkylene group of 1 to 5 carbon atoms, and most preferably a methylene group or an ethylene group.

Y²² is preferably a linear or branched aliphatic hydrocarbon group, and is more preferably a methylene group, an ethylene group or an alkylmethylene group. The alkyl group within the alkylmethylene group is preferably a linear alkyl group of 1 to 5 carbon atoms, more preferably a linear alkyl group of 1 to 3 carbon atoms, and most preferably a methyl group.

In the group represented by formula —[Y²¹—C(═O)—O]_{m′}—Y²²—, m′ represents an integer of 0 to 3, and is preferably an integer of 0 to 2, more preferably 0 or 1, and most preferably 1.

In other words, the group represented by formula —[Y²¹—C(═O)—O]_{m′}—Y²²— is most preferably a group represented by a formula —Y²¹—C(═O)—O—Y²²—. Among such groups, groups represented by the formula —(CH₂)_{a′}—C(═O)—O—(CH₂)_{b′}— are particularly preferred. In this formula, a′ represents an integer of 1 to 10, preferably an integer of 1 to 8, more preferably an integer of 1 to 5, still more preferably 1 or 2, and most preferably 1. b′ represents an integer of 1 to 10, preferably an integer of 1 to 8, more preferably an integer of 1 to 5, still more preferably 1 or 2, and most preferably 1.

The alkylene group for Y²³ in the above formula —[Y²³—O]_{n′}— is preferably an alkylene group of 1 to 4 carbon atoms.

In formula (I-1), as the divalent linking group for L⁰¹, a linear or branched alkylene group, a divalent aliphatic cyclic group or a divalent linking group containing a hetero atom is preferable, a linear or branched alkylene group is more preferable, and a linear alkylene group is still more preferable.

In formula (I-2), the organic group for R⁰² may be an organic group having a fluorine atom or may be an organic group having no fluorine atom, although an organic group having a fluorine atom is preferred. Here, an “organic group having a fluorine atom” refers to an organic group in which part or all of the hydrogen atoms have been substituted with a fluorine atom. As the organic group, a monovalent hydrocarbon group which may have a substituent is preferred. The hydrocarbon group may be an aliphatic hydrocarbon group or an aromatic group.

The aliphatic hydrocarbon group as the monovalent hydrocarbon group may be saturated or unsaturated. In general, the aliphatic hydrocarbon group is preferably saturated.

Specific examples of the aliphatic hydrocarbon group include a linear or branched aliphatic hydrocarbon group, and an aliphatic hydrocarbon group that includes a ring within the structure thereof.

The linear or branched aliphatic hydrocarbon group preferably has 1 to 10 carbon atoms, more preferably 1 to 8 carbon atoms, and still more preferably 1 to 5 carbon atoms. The linear or branched aliphatic hydrocarbon group is preferably an alkyl group.

The linear or branched aliphatic hydrocarbon group may or may not have a substituent (groups or atoms other than hydrogen atom) that substitutes a hydrogen atom. Examples of this substituent include a fluorine atom, a fluorinated alkyl group of 1 to 5 carbon atoms and an oxo group (═O).

Examples of the aliphatic hydrocarbon group that includes a ring within the structure thereof include a monovalent cyclic aliphatic hydrocarbon group (a group in which one hydrogen atom has been removed from an aliphatic hydrocarbon ring), a group in which a monovalent cyclic aliphatic hydrocarbon group is bonded to the terminal of a linear or branched aliphatic hydrocarbon group, and a group in which a cyclic aliphatic hydrocarbon group is interposed within the chain of a monovalent linear or branched aliphatic hydrocarbon group. Examples of the monovalent linear or branched aliphatic hydrocarbon group include the same groups as those mentioned above.

The cyclic aliphatic hydrocarbon group preferably has 3 to 20 carbon atoms, and more preferably 3 to 12 carbon atoms.

The cyclic aliphatic hydrocarbon group may be either a polycyclic group or a monocyclic group. As the monocyclic aliphatic hydrocarbon group, a group in which one or more hydrogen atoms have been removed from a monocycloalkane is preferred. The monocycloalkane preferably contains 3 to 6 carbon atoms, and specific examples thereof include cyclopentane and cyclohexane. As the polycyclic aliphatic hydrocarbon group, a group in which one or more hydrogen atoms have been removed from a polycycloalkane is preferable, and the polycycloalkane preferably contains 7 to 12 carbon atoms. Specific examples of the polycycloalkane include adamantane, norbornane, isobornane, tricyclodecane and tetracyclododecane.

The cyclic aliphatic hydrocarbon group may or may not have a substituent (groups or atoms other than hydrogen atom) that substitutes a hydrogen atom. Examples of the substituent include an alkyl group of 1 to 5 carbon atoms, a fluorine atom, a fluorinated alkyl group of 1 to 5 carbon atoms, and an oxo group (═O).

In the cyclic aliphatic hydrocarbon group, part of the carbon atoms that constitute the cyclic structure thereof may be substituted with a substituent containing a hetero atom. The hetero atom-containing substituent is preferably —O—, —C(═O)—O—, —S—, —S(═O)₂— or —S(═O)₂—O—.

The aromatic group as the monovalent hydrocarbon group is a monovalent hydrocarbon group having an aromatic ring, and may also have a substituent.

The aromatic ring preferably has 5 to 30 carbon atoms, more preferably 5 to 20 carbon atoms, still more preferably 6 to 15 carbon atoms, and most preferably 6 to 12 carbon atoms. Here, the number of carbon atoms does not include any carbon atoms within any substituent(s). Specific examples of the aromatic ring include aromatic hydrocarbon rings such as benzene, biphenyl, fluorene, naphthalene, anthracene and phenanthrene, and aromatic heterocyclic rings in which part of the carbon atoms that constitute one of the above aromatic hydrocarbon rings have been substituted with a hetero atom. Examples of the hetero atom in the aromatic heterocyclic rings include an oxygen atom, a sulfur atom and a nitrogen atom.

Specific examples of the aromatic group as the monovalent hydrocarbon group include groups in which one hydrogen atom has been removed from an aforementioned aromatic hydrocarbon ring or aromatic heterocyclic ring (namely, aryl groups or heteroaryl groups); and groups in which one of the hydrogen atoms of an aforementioned aromatic hydrocarbon ring or aromatic heterocyclic ring has been substituted with an alkylene group (namely, arylalkyl groups or heteroarylalkyl groups). The alkyl group within the aforementioned arylalkyl group or heteroarylalkyl group preferably contains 1 to 4 carbon atoms, more preferably 1 or 2 carbon atoms, and most preferably 1 carbon atom. Specific examples of the aforementioned arylalkyl group or heteroarylalkyl group include a benzyl group, a phenethyl group, a 1-naphthylmethyl group, a 2-naphthylmethyl group, a 1-naphthylethyl group and a 2-naphthylethyl group.

The aromatic group may or may not have a substituent. For example, a hydrogen atom bonded to the aromatic ring within the aromatic group may be substituted with a substituent. Examples of the substituent include an alkyl group, an alkoxy group, a halogen atom, a halogenated alkyl group, a hydroxyl group and an oxo group (═O).

The alkyl group for the substituent is preferably an alkyl group of 1 to 5 carbon atoms, and is most preferably a methyl group, an ethyl group, a propyl group, an n-butyl group or a tert-butyl group.

The alkoxy group for the substituent is preferably an alkoxy group of 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom for the substituent include a fluorine atom, a chlorine atom, a bromine atom and an iodine atom, and a fluorine atom is preferred.

Examples of the halogenated alkyl group for the substituent include groups in which part or all of the hydrogen atoms of an aforementioned alkyl group have each been substituted with an aforementioned halogen atom.

Of the various possibilities described above, R⁰² is preferably a linear or branched aliphatic hydrocarbon group substituted with a fluorine atom, and more preferably a linear or branched fluorinated alkyl group.

The fluorination ratio of the fluorinated alkyl group (percentage of the hydrogen atoms within an unsubstituted alkyl group substituted with fluorine atoms) is preferably 30% or more, and more preferably 50% or more. There are no particular limitations on the upper limit for the fluorination ratio and may even be 100%.

In formula (I-2), examples of the divalent linking group for L⁰² include the same groups as those described above as the divalent linking group for L⁰¹ in formula (I-1).

Of these, as L⁰², a linear or branched alkylene group, a divalent aliphatic cyclic group or a divalent linking group containing a hetero atom is preferable, a linear or branched alkylene group is more preferable, and a linear alkylene group is still more preferable.

In formula (I-3), as R⁰³ and L⁰³, the same groups as those described above for R⁰² and L⁰² in formula (I-2), respectively, can be used.

In formula (I-4), as R⁰⁴ and L⁰⁴, the same groups as those described above for R⁰² and L⁰² in formula (I-2), respectively, can be used.

In the component (C), at least one type of atom selected from a fluorine atom and a silicon atom, an aromatic group, and a polarity conversion group that decomposes by the action of a base to increase the polarity may be included in the same structural unit or may be included in different structural units.

Here, the structural unit constituting the component (C) is not particularly limited, although it is preferably a structural unit derived from a compound having an ethylenic double bond.

A “structural unit derived from a compound having an ethylenic double bond” refers to a structural unit having a structure in which the ethylenic double bond in the compound having an ethylenic double bond is cleaved to form a single bond.

Examples of the compound having an ethylenic double bond include an acrylic acid in which the hydrogen atom bonded to the carbon atom on the α-position may be substituted with a substituent, or the esters thereof; an acrylamide in which the hydrogen atom bonded to the carbon atom on the α-position may be substituted with a substituent, or the derivatives thereof; vinyl aromatic compounds in which the hydrogen atom bonded to the carbon atom on the α-position may be substituted with a substituent; cycloolefin or the derivatives thereof, and esters of vinyl sulfonic acid.

Of these, an acrylic acid in which the hydrogen atom bonded to the carbon atom on the α-position may be substituted with a substituent, or the esters thereof, an acrylamide in which the hydrogen atom bonded to the carbon atom on the α-position may be substituted with a substituent, or the derivatives thereof, or vinyl aromatic compounds in which the hydrogen atom bonded to the carbon atom on the α-position may be substituted with a substituent are preferred.

An “acrylate ester” refers to a compound in which the terminal hydrogen atom of the carboxyl group of acrylic acid (CH₂═CH—COON) has been substituted with an organic group.

In the present description, an acrylic acid and acrylate ester in which the hydrogen atom bonded to the carbon atom on the α-position has been substituted with a substituent may also be termed an “α-substituted acrylic acid” and “α-substituted acrylate ester”, respectively. Further, the generic term “(α-substituted) acrylic acid” may be used to describe both the acrylic acid and the α-substituted acrylic acid, and the generic term “(α-substituted) acrylate ester” may be used to describe both the acrylate ester and the α-substituted acrylate ester.

Examples of the substituent bonded to the carbon atom on the α-position of an α-substituted acrylic acid or the esters thereof include a halogen atom, an alkyl group of 1 to 5 carbon atoms, a halogenated alkyl group of 1 to 5 carbon atoms, and a hydroxyalkyl group. With respect to the “structural unit derived from an acrylate ester”, the “α-position (the carbon atom on the α-position)” refers to the carbon atom having the carbonyl group bonded thereto, unless specified otherwise.

Examples of the halogen atom for the α-position substituent include a fluorine atom, a chlorine atom, a bromine atom and an iodine atom.

Specific examples of the alkyl group of 1 to 5 carbon atoms for the α-position substituent include linear or branched alkyl groups such as a methyl group, an ethyl group, a propyl group, an isopropyl group, an n-butyl group, an isobutyl group, a tert-butyl group, a pentyl group, an isopentyl group and a neopentyl group.

Specific examples of the halogenated alkyl group of 1 to 5 carbon atoms for the α-position substituent include groups in which part or all of the hydrogen atoms of an aforementioned alkyl group of 1 to 5 carbon atoms are each substituted with a halogen atom. Examples of the halogen atom include a fluorine atom, a chlorine atom, a bromine atom and an iodine atom, and a fluorine atom is particularly desirable.

Further, hydroxyalkyl groups of 1 to 5 carbon atoms are preferred as the hydroxyalkyl group for the α-position substituent, and specific examples thereof include groups in which part or all of the hydrogen atoms of an aforementioned alkyl group of 1 to 5 carbon atoms are each substituted with a hydroxyl group.

In the present invention, it is preferable that a hydrogen atom, an alkyl group of 1 to 5 carbon atoms or a halogenated alkyl group of 1 to 5 carbon atoms is bonded to the carbon atom on the α-position of the (α-substituted) acrylic acid or the esters thereof, and of these, a hydrogen atom, an alkyl group of 1 to 5 carbon atoms or a fluorinated alkyl group of 1 to 5 carbon atoms is more preferable, and in terms of industrial availability, a hydrogen atom or a methyl group is the most desirable.

An “organic group” refers to a group containing a carbon atom, and may include atoms other than carbon atoms (such as a hydrogen atom, an oxygen atom, a nitrogen atom, a sulfur atom, or a halogen atom (such as a fluorine atom and a chlorine atom) and the like).

The organic group included in (α-substituted) acrylate esters is not particularly limited, although examples thereof include characteristic groups such as the aforementioned aromatic groups and polarity conversion groups, and the acid decomposable groups which will be described later, and characteristic group-containing groups that include these characteristic group within the structure thereof. Examples of the characteristic group-containing groups include a group in which a divalent linking group is bonded to the characteristic group. Examples of the divalent linking group include the same groups as those described above as the divalent linking group for L⁰¹ in formula (I-1).

Examples of the “acrylamide or the derivatives thereof” include an acrylamide in which the hydrogen atom bonded to the carbon atom on the α-position may be substituted with a substituent (hereafter, sometimes referred to as “(α-substituted) acrylamide”) and a compound in which one or both of the hydrogen atoms at the amino group terminal of α-substituted) acrylamide have been substituted with a substituent.

Examples of the substituent which may be bonded to the carbon atom on the α-position in an acrylamide or the derivatives thereof include the same substituents as those mentioned above for the substituent bonded to the carbon atom on the α-position of an α-substituted acrylate ester.

As the substituent that substitutes one or both of the hydrogen atoms at the amino group terminal of (α-substituted) acrylamide, an organic group is preferred. The organic group is not particularly limited, and examples thereof include the same organic groups as those described which the aforementioned (α-substituted) acrylate ester has.

Examples of the compound in which one or both of the hydrogen atoms at the amino group terminal of (α-substituted) acrylamide have been substituted with a substituent include a compound in which —C(═O)—O— bonded to the carbon atom on the α-position in the aforementioned (α-substituted) acrylate ester has been substituted with —C(═O)—N(R^{b})— (in the formula, R^{b}) represents a hydrogen atom or an alkyl group of 1 to 5 carbon atoms].

In the formula, the alkyl group for R^{b} is preferably a linear or branched group.

A “vinyl aromatic compound” is a compound having an aromatic ring and one vinyl group bonded to this aromatic ring, and examples thereof include styrene or the derivatives thereof and vinyl naphthalene or the derivatives thereof.

Examples of the substituent which may be bonded to the carbon atom on the α-position in a vinyl aromatic compound (namely, the carbon atom bonded to the aromatic ring among the carbon atoms in the vinyl group) include the same substituents as those mentioned above for the substituent bonded to the carbon atom on the α-position of an α-substituted acrylate ester.

Hereafter, a vinyl aromatic compound in which the hydrogen atom bonded to the carbon atom on the α-position has been substituted with a substituent may be referred to as an “(α-substituted) vinyl aromatic compound”.

Examples of “styrene or the derivatives thereof” include a styrene in which the hydrogen atom bonded to the carbon atom on the α-position may be substituted with a substituent and the hydrogen atom bonded to the benzene ring may be substituted with a substituent other than a hydroxyl group (hereafter, sometimes referred to as “(α-substituted) styrene”); a hydroxystyrene in which the hydrogen atom bonded to the carbon atom on the α-position may be substituted with a substituent and the hydrogen atom bonded to the benzene ring may be substituted with a substituent other than a hydroxyl group (hereafter, sometimes referred to as “(α-substituted) hydroxystyrene”); a compound in which the hydrogen atom of the hydroxyl group of (α-substituted) hydroxystyrene has been substituted with an organic group; a vinylbenzoic acid in which the hydrogen atom bonded to the carbon atom on the α-position may be substituted with a substituent and the hydrogen atom bonded to the benzene ring may be substituted with a substituent other than a hydroxyl group and carboxyl group (hereafter, sometimes referred to as “(α-substituted) vinylbenzoic acid”); and a compound in which the hydrogen atom of the carboxyl group of (α-substituted) vinylbenzoic acid has been substituted with an organic group.

A hydroxystyrene is a compound having one vinyl group and at least one hydroxyl group bonded to a benzene ring. The number of hydroxyl groups bonded to the benzene ring is preferably from 1 to 3, and is most preferably 1. There are no particular limitations on the bonding position of the hydroxyl group on the benzene ring. When there is only one hydroxyl group, the hydroxyl group is preferably bonded to the para-4 position relative to the vinyl group. When the number of hydroxyl groups is an integer of 2 or more, any arbitrary combination of bonding positions may be used.

A vinylbenzoic acid is a compound having one vinyl group bonded to a benzene ring of benzoic acid.

There are no particular limitations on the bonding position of the vinyl group on the benzene ring.

There are no particular limitations on the substituent other than a hydroxyl group and carboxyl group that may be bonded to the benzene ring of a styrene or the derivatives thereof, and examples include a halogen atom, an alkyl group of 1 to 5 carbon atoms, and a halogenated alkyl group of 1 to 5 carbon atoms. Specific examples of the halogen atom include a fluorine atom, a chlorine atom, a bromine atom and an iodine atom, and a fluorine atom is particularly desirable.

The organic group in a compound in which the hydrogen atom of the hydroxyl group of (α-substituted) hydroxystyrene has been substituted with an organic group is not particularly limited, and examples thereof include the same organic groups as those described which the aforementioned (α-substituted) acrylate ester has.

The organic group in a compound in which the hydrogen atom of the carboxyl group of (α-substituted) vinylbenzoic acid has been substituted with an organic group is not particularly limited, and examples thereof include the same organic groups as those described which the aforementioned (α-substituted) acrylate ester has.

Examples of “vinylnaphthalene or the derivatives thereof” include a vinylnaphthalene in which the hydrogen atom bonded to the carbon atom on the α-position may be substituted with a substituent and the hydrogen atom bonded to the naphthalene ring may be substituted with a substituent other than a hydroxyl group (hereafter, sometimes referred to as “α-substituted) vinylnaphthalene”); a vinyl(hydroxynaphthalene) in which the hydrogen atom bonded to the carbon atom on the α-position may be substituted with a substituent and the hydrogen atom bonded to the naphthalene ring may be substituted with a substituent other than a hydroxyl group (hereafter, sometimes referred to as “(α-substituted) vinyl(hydroxynaphthalene)”); and a compound in which the hydrogen atom of the hydroxyl group of (α-substituted) vinyl(hydroxynaphthalene) has been substituted with an organic groups.

A vinyl(hydroxynaphthalene) is a compound having one vinyl group and at least one hydroxyl group bonded to a naphthalene ring. The vinyl group may be bonded to the 1st position or the 2nd position of the naphthalene ring. The number of hydroxyl groups bonded to the naphthalene ring is preferably from 1 to 3, and is most preferably 1. There are no particular limitations on the bonding position of the hydroxyl group on the naphthalene ring. When the vinyl group is bonded to the 1st position or the 2nd position of the naphthalene ring, the hydroxyl group(s) are preferably bonded to any of the 5th to 8th positions of the naphthalene ring. Particularly in those cases where there is only a single hydroxyl group, the hydroxyl group is preferably bonded to one of the 5th to 7th positions of the naphthalene ring, and is more preferably bonded to the 5th or 6th position. When the number of hydroxyl groups is an integer of 2 or more, any arbitrary combination of bonding positions may be used.

Examples of the substituent that may be bonded to the naphthalene ring of the vinylnaphthalene or the derivatives thereof include the same substituents as those mentioned above as the substituent that may be bonded to the benzene ring of the (α-substituted) hydroxystyrene.

The organic group in a compound in which the hydrogen atom of the hydroxyl group of (α-substituted) vinyl(hydroxynaphthalene) has been substituted with an organic group is not particularly limited, and examples thereof include the same organic groups as those described which the aforementioned (α-substituted) acrylate ester has.

Specific examples of the structural units derived from an (α-substituted) acrylic acid or esters thereof include structural units represented by general formula (U-1) shown below.

Specific examples of the structural units derived from an (α-substituted) acrylamide or derivatives thereof include structural units represented by general formula (U-2) shown below.

Of the (α-substituted) vinyl aromatic compounds, specific examples of the structural units derived from an (α-substituted) styrene or derivatives thereof include structural units represented by general formula (U-3) shown below. Further, specific examples of the structural units derived from an (α-substituted) vinylnaphthalene or derivatives thereof include structural units represented by general formula (U-4) shown below.

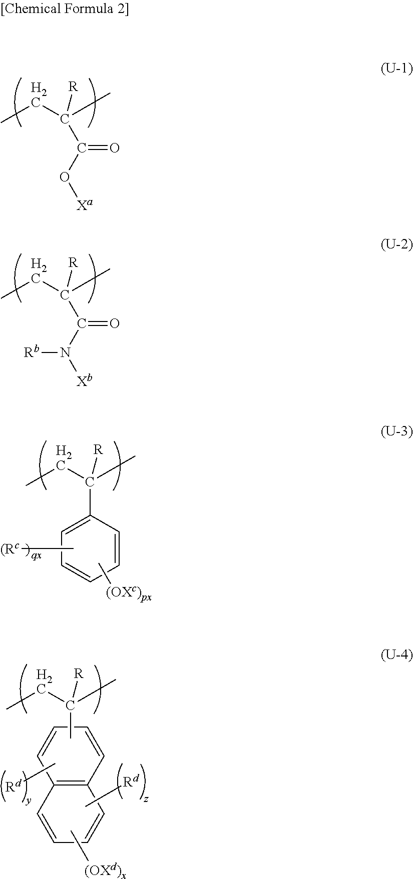

In the formulas, R represents a hydrogen atom, an alkyl group of 1 to 5 carbon atoms or a halogenated alkyl group of 1 to 5 carbon atoms. Each of X^{a} to X^{d} independently represents a hydrogen atom or an organic group. R^{b} represents a hydrogen atom or an alkyl group of 1 to 5 carbon atoms. Each of R^{c} and R^{d} independently represents a halogen atom, —COOX^{e} (wherein X^{e} represents a hydrogen atom or an organic group), an alkyl group of 1 to 5 carbon atoms or a halogenated alkyl group of 1 to 5 carbon atoms. px represents an integer of 0 to 3, qx represents an integer of 0 to 5, with the provision that px+qx is 0 to 5. In those cases where qx is an integer of 2 or more, the plurality of R^{c} groups may be the same or different from each other. x represents an integer of 0 to 3, y represents an integer of 0 to 3 and z represents an integer of 0 to 4, with the provision that x+y+z is 0 to 7. In those cases where y+z is an integer of 2 or more, the plurality of R^{d} groups may be the same or different from each other.

The component (C) includes at least a structural unit containing a fluorine atom or a silicon atom (hereafter, referred to as structural unit (c0)).

Although the structural unit (c0) is not particularly limited as long as it contains a fluorine atom or a silicon atom, it is preferably a structural unit derived from a compound having an ethylenic double bond, and a structural unit represented by general formula (c-0) shown below is particularly desirable.

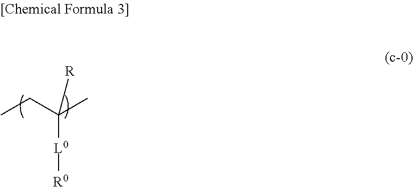

In the formula, R represents a hydrogen atom, an alkyl group of 1 to 5 carbon atoms or a halogenated alkyl group of 1 to 5 carbon atoms; L⁰ represents a divalent linking which may have a fluorine atom or a silicon atom, or a single bond; and R⁰ represents a monovalent organic group which may have a fluorine atom or a silicon atom, with the provision that at least one of L⁰ and R⁰ has a fluorine atom or a silicon atom.

In formula (c-0), the alkyl group and the halogenated alkyl group for R are respectively the same as defined for the alkyl group and the halogenated alkyl group for the substituent bonded to the carbon atom on the α-position of the aforementioned α-substituted acrylic acid or esters thereof.

Examples of the divalent linking group for L⁰ include the same groups as those described above as the divalent linking group for L⁰¹ in the formula (I-1). Of the various possibilities, groups represented by —C(═O)—O-L¹⁰-, —C(═O)—N(R^{N})-L¹⁰- or —R^{ar}-L¹⁰- are preferred.

L¹⁰ represents a single bond or a divalent linking group. Examples of the divalent linking group include the same divalent linking groups as those described above for L⁰¹ in the general formula (I-1).

R^{N} represents a hydrogen atom or an alkyl group of 1 to 5 carbon atoms. The alkyl group is preferably a linear alkyl group or a branched alkyl group. As R^{N}, a hydrogen atom or a methyl group is particularly desirable.

R^{ar} represents a divalent aromatic group which may have a substituent. Examples of the divalent aromatic group include the same aromatic groups as those described above as the divalent hydrocarbon group within the description of the divalent linking group for L⁰¹ in the general formula (I-1). Among these, a phenylene group which may have a substituent or a naphthylene group which may have a substituent is preferred.

There are no particular limitations on the organic group for R⁰, and the organic group including a characteristic group in accordance with the desired properties of the component (C) can be appropriately selected from among known organic groups. Examples thereof include characteristic groups (such as base decomposable polarity conversion groups, acid decomposable groups and polar group-containing hydrocarbon groups) that are incorporated within the side chains of structural units (c1) to (c6) which will be described later.

Specific examples of the structural units constituting the component (C) include the following structural units (c1) to (c5).

Structural unit (c1): a fluorine-containing structural unit including a base decomposable polarity conversion group;

Structural unit (c2): a structural unit containing an acid decomposable group that decomposes by the action of an acid to increase the polarity;

Structural unit (c3): a structural unit containing a polar group;

Structural unit (c4): a fluorine-containing structural unit containing a ring structure and does not fall under the category of the structural units (c1) to (c3);

Structural unit (c5): a silicon-containing structural unit that includes an organic group having a trialkylsilyl group or a siloxane bond (Si—O—Si).

[Structural Unit (c1)]

A base decomposable polarity conversion group in the structural unit of (c1) is the same base decomposable polarity conversion groups as those described above.

Examples of the structural unit (c1) include those in which R⁰ in the general formula (c-0) is a base decomposable polarity conversion group, and preferred examples thereof include structural units represented by general formula (c1-10) or (c1-20) shown below.

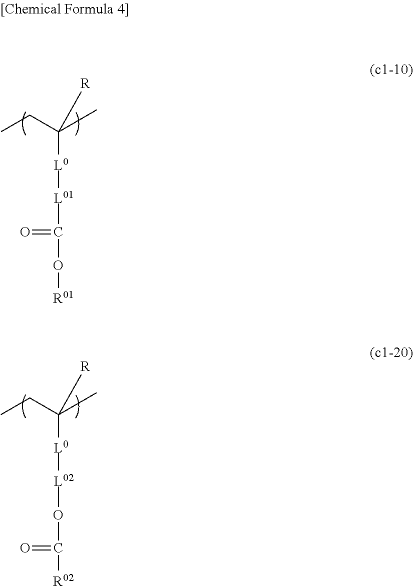

In formula (c1-10), R, L⁰, L⁰¹ and R⁰¹ are each the same as defined above, with the provision that at least one of L⁰, L⁰¹ and R⁰¹ has a fluorine atom. In formula (c1-20), R, L⁰, L⁰² and R⁰² are each the same as defined above, with the provision that at least one of L⁰, L⁰² and R⁰² has a fluorine atom.

In the formulas, R and L⁰ are each the same as defined above for R and L⁰ in the aforementioned formula (c-0).

L⁰¹ and R⁰¹ are each the same as defined above for L⁰¹ and R⁰¹ in the aforementioned general formula (I-1).

L⁰² and R⁰² are each the same as defined above for L⁰² and R⁰² in the aforementioned general formula (I-2).

Preferred examples of the structural units represented by the aforementioned general formula (c1-10) or (c1-20) include structural units represented by general formulas (c1-11) to (c1-15) and (c1-21) to (c1-25).

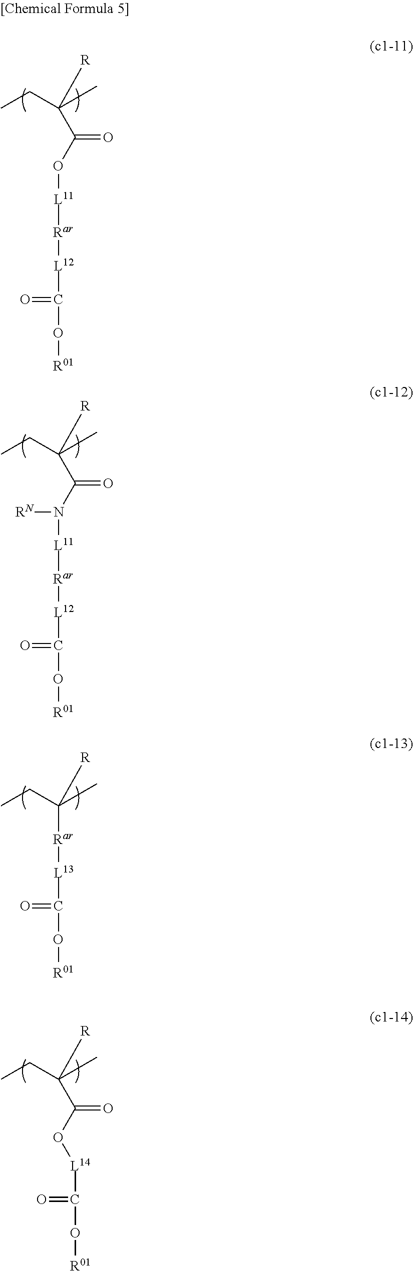

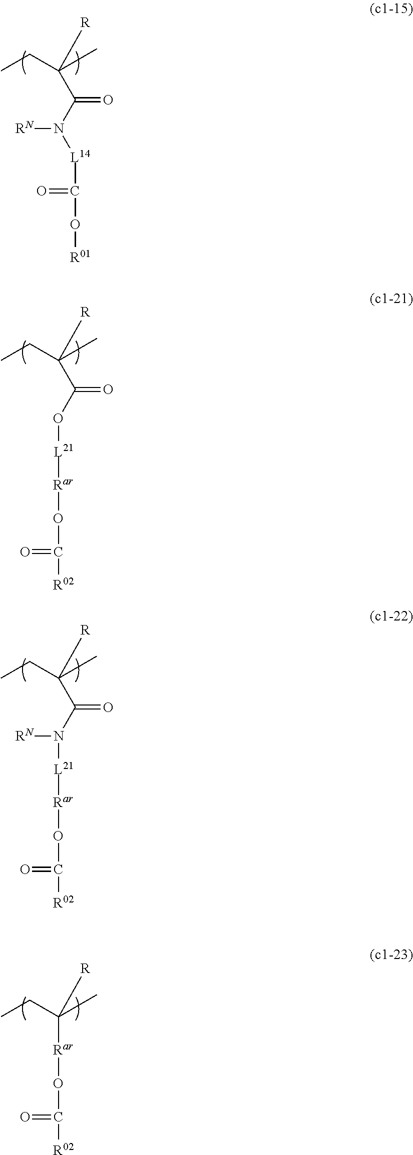

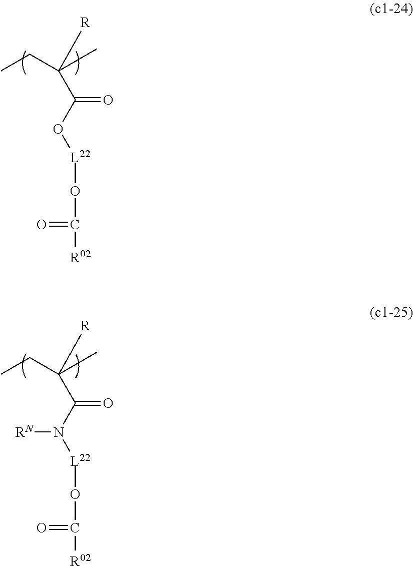

In formulas (c1-11) to (c1-12), R and R⁰¹ are each the same as defined above; L¹¹ represents a single bond or a divalent linking group; R^{ar} represents a divalent aromatic group which may have a substituent; L¹² represents a single bond or a divalent linking group; and R^{N} represents a hydrogen atom or an alkyl group of 1 to 5 carbon atoms, with the provision that at least one of L¹¹, R^{ar}, L¹² and R⁰¹ has a fluorine atom.

In formula (c1-13), R, R^{ar} and R⁰¹ are each the same as defined above; and L¹³ represents a single bond or a divalent linking group, with the provision that at least one of R^{ar} L¹³ and R⁰¹ has a fluorine atom.

In formulas (c1-14) to (c1-15), R, R⁰¹ and R^{N} are each the same as defined above; and L¹⁴ represents a divalent linking group that does not contain an aromatic group, with the provision that at least one of L¹⁴ and R⁰¹ has a fluorine atom.

In formulas (c1-21) to (c1-22), R, R^{ar}, R⁰² and R^{N} are each the same as defined above; and L²¹ represents a single bond or a divalent linking group, with the provision that at least one of L²¹, R^{ar} and R⁰² has a fluorine atom.

In formula (c1-23), R, R^{ar} and R⁰² are each the same as defined above, with the provision that at least one of R^{ar} and R⁰² has a fluorine atom.

In formulas (c1-24) to (c1-25), R, R⁰² and R^{N} are each the same as defined above; and L²² represents a divalent linking group that does not contain an aromatic group, with the provision that at least one of L²² and R⁰² has a fluorine atom.

In the formulas, R is the same as defined above for R in the aforementioned formula (c-0).

R⁰¹ is the same as defined above for R⁰¹ in general formula (I-1) described in connection with the base decomposable polarity conversion group, and R⁰² is the same as defined above for R⁰² in general formula (I-2).

R^{ar} is the same as defined for R^{ar} in —R^{ar}-L¹⁰- mentioned above within the description of the divalent linking group for L⁰¹ in the aforementioned formula (I-1).

R^{N} is the same as defined for R^{N} in —C(═O)—N(R^{N})-L¹⁰- mentioned above within the description of the divalent linking group for L⁰¹ in the aforementioned formula (I-1).

Examples of the divalent linking group for L⁰¹ and L²¹ include the same divalent linking groups as those described above for L⁰¹ in the general formula (I-1). Among the above possibilities, a linear or branched alkylene group is preferred, and a linear alkylene group is more preferred. Among these, a methylene group is particularly desirable.

Examples of the divalent linking group for L¹² and L¹³ include the same divalent linking groups as those described above for L⁰¹ in the general formula (I-1). Among these, those containing an ether bond or an ester bond are preferred, —O—(CH₂)ₐ₁—, —O—C(═O)—(CH₂)ₐ₁—, —(CH₂)ₐ₂—O—(CH₂)ₐ₁— or —(CH₂)ₐ₂—O—C(═O)—(CH₂)ₐ₁— is more preferred, and —O—(CH₂)ₐ₁— is particularly preferred. In the formulas, a1 represents an integer of 1 to 5, and a2 represents an integer of 1 to 5.

Examples of the divalent linking group for L¹⁴ and L²² include the same divalent linking groups as those described above for L⁰¹ in the general formula (I-1) (excluding those containing an aromatic group). Of these, a linear or branched alkylene group which may have a fluorine atom, a divalent aliphatic cyclic group or a divalent linking group containing a hetero atom is preferable, and a linear or branched alkylene group which may have a fluorine atom is more preferable. Among these, a linear alkylene group or a branched alkylene group in which a fluorine atom or a fluorinated alkyl group is bonded to a carbon atom adjacent to the carbonyl group is preferred, and —CH₂—, —CH₂—CH₂—, —CH(CH₃)—CF₂—, —CH(CH₂CH₃)—CF₂— or —CH(CH₂CH₃)—CF(CH₃)— is particularly desirable.

Of the above possibilities, as the structural unit (c1), structural units represented by general formulas (c1-11), (c1-12), (c1-14), (c1-15) and (c1-23) are preferred.

Specific examples of preferred forms of these structural units include the structural units shown below. In the formulas, R^{β} represents a hydrogen atom or a methyl group.

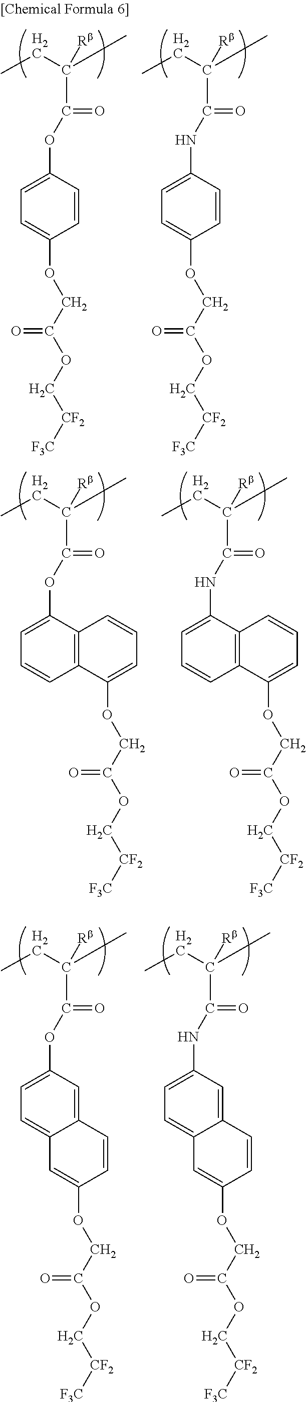

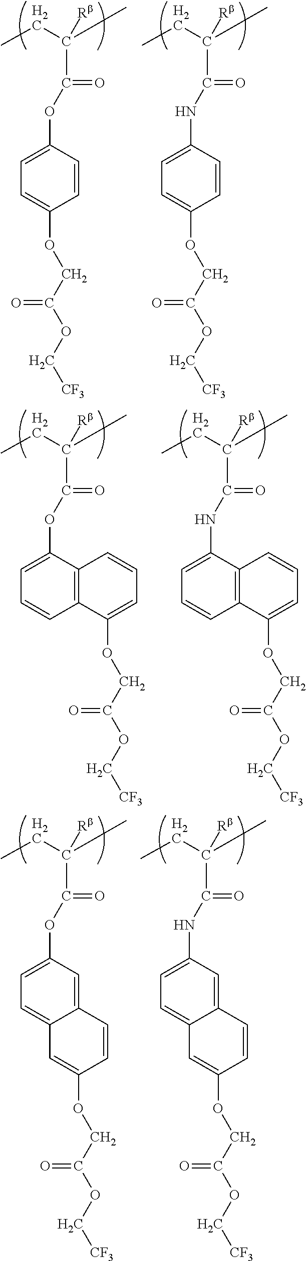

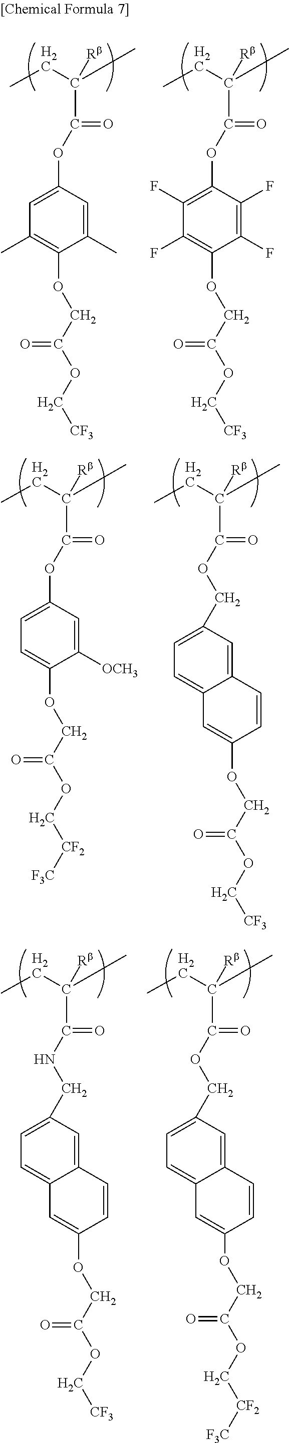

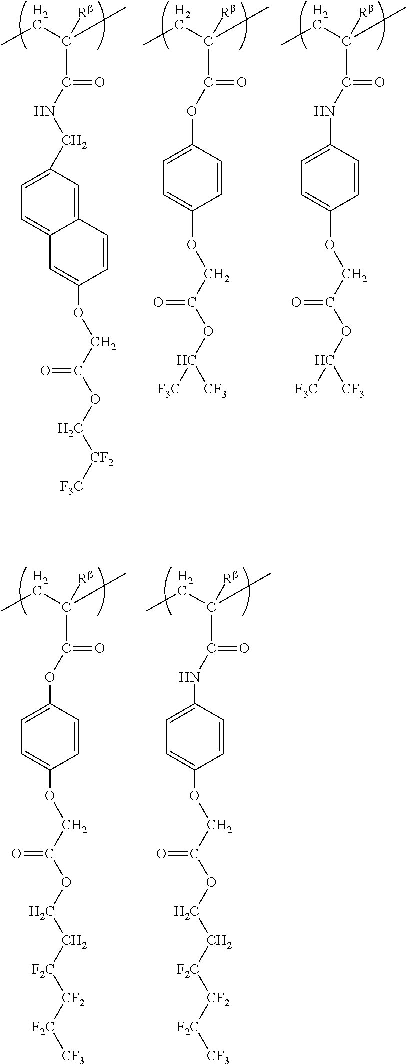

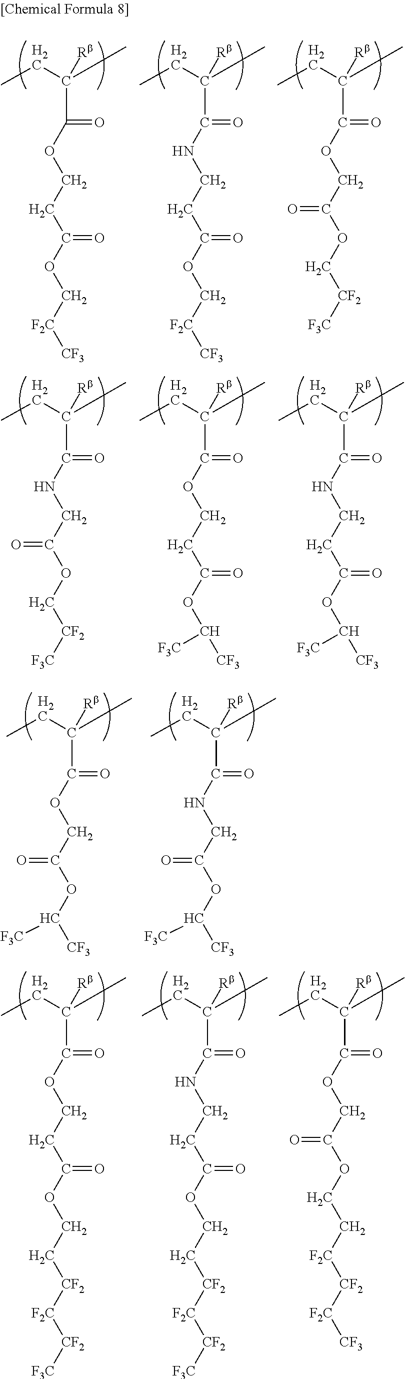

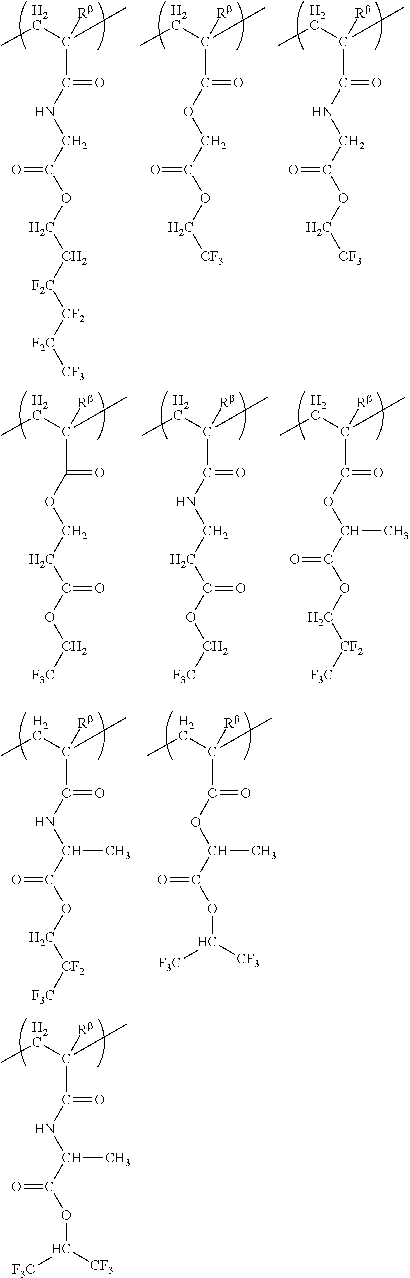

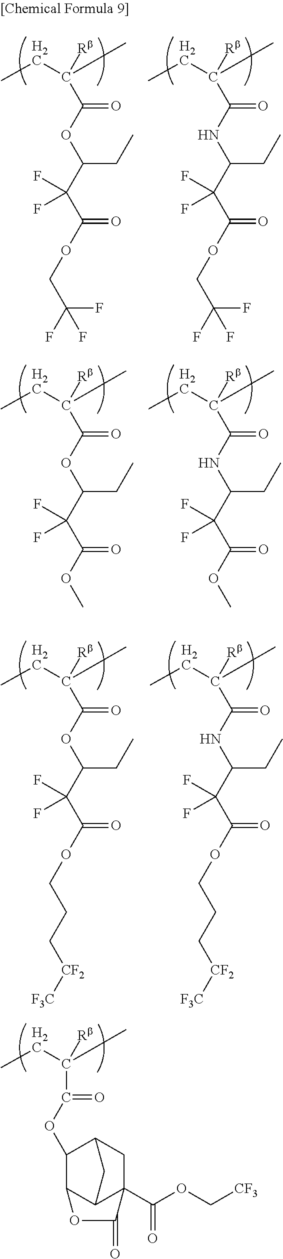

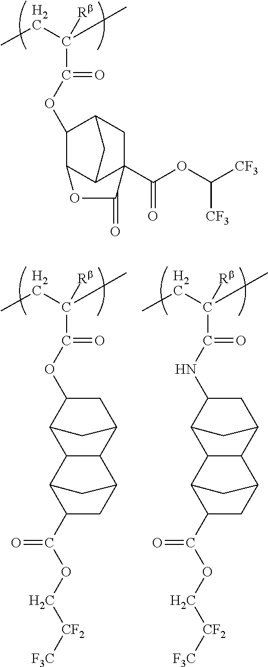

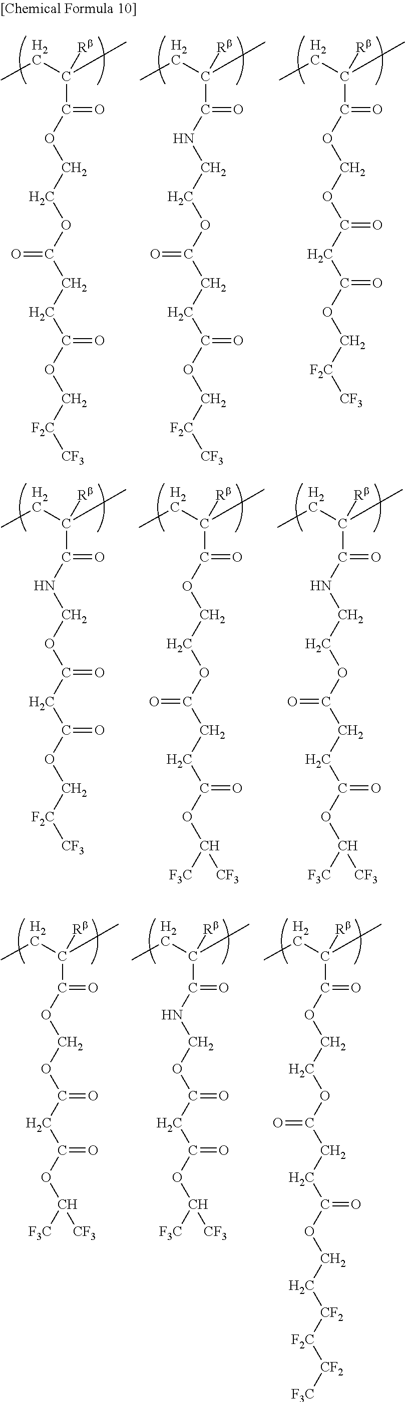

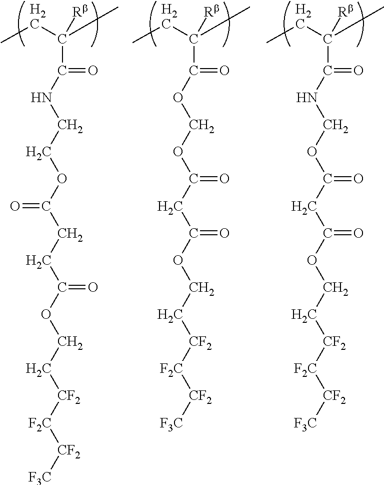

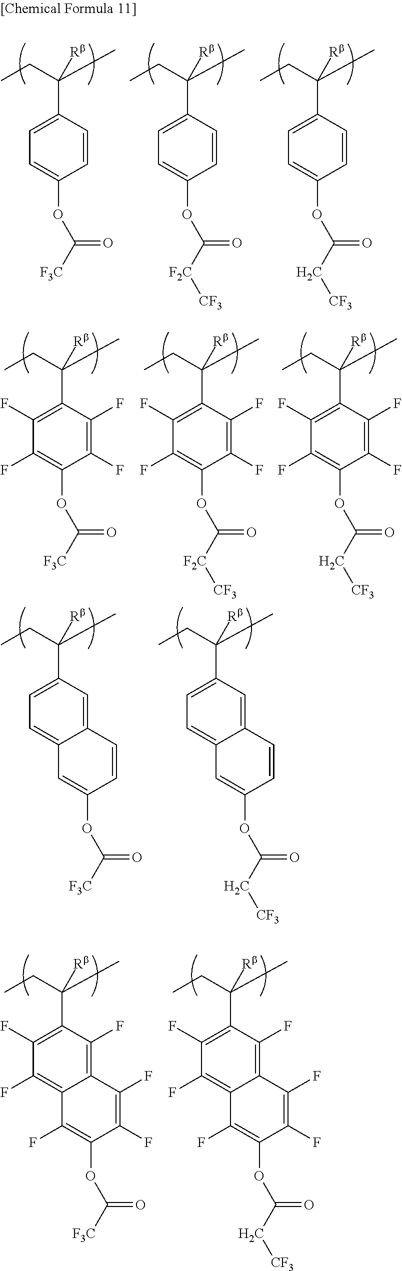

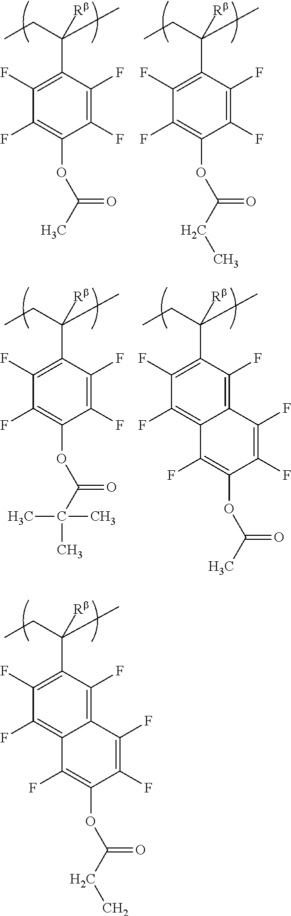

When the component (C) contains the structural unit (c1), the structural unit (c1) contained within the component (C) may be either a single type of structural unit or a combination of two or more types of structural units.

In the component (C), the amount of the structural unit (c1) based on the combined total of all structural units constituting the component (C) is preferably 40 to 90 mol %, more preferably 50 to 85 mol %, and still more preferably 50 to 80 mol %. When the amount of the structural unit (c1) is at least as large as the lower limit of the above-mentioned range, the surface segregation effects can be enhanced, the solubility in an alkali developing solution improves, and lithography properties can also be improved. On the other hand, when the amount of the structural unit (c1) is not more than the upper limit of the above range, a good balance can be achieved with the other structural units.

When the structural unit (c1) contains an aromatic group, the amount of the structural unit (c1) based on the combined total of all structural units constituting the component (C) is preferably 20 to 85 mol %, and more preferably 25 to 80 mol %. By ensuring that the amount of the structural unit (c1) is within the aforementioned range, the surface segregation effects can be enhanced, and the effect of reducing the influence of OoB light can be improved. In the case of applying an alkali developing process, the solubility in an alkali developing solution improves.

When the structural unit (c1) contains no aromatic group, the amount of the structural unit (c1) is preferably 0 to 45 mol %, and more preferably 5 to 40 mol %.

[Structural Unit (c2)]

The structural unit (c2) is a structural unit containing an acid decomposable group that decomposes by the action of an acid (acid decomposable polarity conversion group).

The term “acid decomposable group” refers to a group exhibiting acid decomposability in which at least a part of the bond within the structure of this acid decomposable group may be cleaved by the action of acid generated from the component (A) or the acid generator component (B) that is optionally added upon exposure.

Examples of acid decomposable groups which exhibit increased polarity by the action of an acid include groups which are decomposed by the action of an acid to form a polar group.

Examples of the polar group that constitutes the acid decomposable group include a carboxyl group, a hydroxyl group, an amino group and a sulfo group (—SO₃H). Among these groups, a carboxyl group or a hydroxyl group is more preferred, and a carboxyl group is particularly desirable.

Specific examples of the acid decomposable groups include groups in which the aforementioned polar group is protected with an acid dissociable group (such as groups in which the hydrogen atom of the aforementioned polar group is protected with an acid dissociable group).

An “acid dissociable group” is a group exhibiting acid dissociability in which at least the bond between the acid dissociable group and the atom adjacent to this acid dissociable group may be cleaved by the action of acid generated from the component (A) or the acid generator component (B) that is optionally added upon exposure. It is necessary that the acid dissociable group that constitutes the acid decomposable group is a group which exhibits a lower polarity than the polar group generated by the dissociation of the acid dissociable group. Thus, when the acid dissociable group is dissociated by the action of acid, a polar group exhibiting a higher polarity than that of the acid dissociable group is generated, resulting in an increase in the polarity of the component (C).

Because the polarity of the component (C) increases at the time of exposure, in the case of an alkali developing process, the solubility of the exposed portions in an alkali developing solution improves.

The acid dissociable group is not particularly limited, and any of the groups that have been conventionally proposed as acid dissociable groups for the base resins of chemically amplified resists can be used. Generally, groups that form either a cyclic or chain-like tertiary alkyl ester with the carboxyl group of the (meth)acrylic acid, and acetal-type acid dissociable groups such as alkoxyalkyl groups are widely known.

Here, a tertiary alkyl ester describes a structure in which an ester is formed by substituting the hydrogen atom of a carboxyl group with a chain-like or cyclic tertiary alkyl group, and a tertiary carbon atom within the chain-like or cyclic tertiary alkyl group is bonded to the oxygen atom at the terminal of the carbonyloxy group (—C(═O)—O—). In this tertiary alkyl ester, the action of acid causes cleavage of the bond between the oxygen atom and the tertiary carbon atom, thereby forming a carboxyl group.

The chain-like or cyclic alkyl group may have a substituent.

Hereafter, for the sake of simplicity, groups that exhibit acid dissociability as a result of the formation of a tertiary alkyl ester with a carboxyl group are referred to as “tertiary alkyl ester-type acid dissociable groups”.

Examples of tertiary alkyl ester-type acid dissociable groups include aliphatic branched, acid dissociable groups and acid dissociable groups containing an aliphatic cyclic group.

Here, the term “aliphatic branched” refers to a branched structure having no aromaticity. The structure of the “aliphatic branched acid dissociable group” is not limited to groups constituted of only carbon atoms and hydrogen atoms (not limited to hydrocarbon groups), but is preferably a hydrocarbon group. Further, the “hydrocarbon group” may be either saturated or unsaturated, but is preferably saturated.

Examples of the aliphatic branched, acid dissociable group include groups represented by the formula —C(R⁷¹)(R⁷²)(R⁷³). In this formula, each of R⁷¹ to R⁷³ independently represents a linear alkyl group of 1 to 5 carbon atoms. The group represented by the formula —C(R⁷¹)(R⁷²)(R⁷³) preferably has 4 to 8 carbon atoms, and specific examples include a tert-butyl group, a 2-methyl-2-butyl group, a 2-methyl-2-pentyl group and a 3-methyl-3-pentyl group.

Among these, a tert-butyl group is particularly desirable.

In the aliphatic branched, acid dissociable group used in the structural unit (c2), part of the hydrogen atoms may be substituted with fluorine atoms. In this case, it is preferable that one of R⁷¹, R⁷² and R⁷³ in the aforementioned group represented by the formula —C(R⁷¹)(R⁷²)(R⁷³) is a fluorinated alkyl group and two of them are alkyl groups. As the fluorinated alkyl group, a group represented by the formula —(CH₂)_{w}—CF₃ is preferred. w represents an integer of 0 to 3.

The term “aliphatic cyclic group” refers to a monocyclic group or polycyclic group that has no aromaticity.

The aliphatic cyclic group within the “acid dissociable groups containing an aliphatic cyclic group” may or may not have a substituent. Examples of the substituent include an alkyl group of 1 to 5 carbon atoms, an alkoxy group of 1 to 5 carbon atoms, a fluorine atom, a fluorinated alkyl group of 1 to 5 carbon atoms, and an oxygen atom (═O).

The basic ring structure of the “aliphatic cyclic group” excluding substituents is not limited to structures constituted of only carbon and hydrogen (not limited to hydrocarbon groups), but is preferably a hydrocarbon group. Further, the hydrocarbon group may be either saturated or unsaturated, but in most cases, is preferably saturated.

The aliphatic cyclic group may be either a monocyclic group or a polycyclic group.

The aliphatic cyclic group preferably contains 3 to 30 carbon atoms, more preferably 5 to 30 carbon atoms, still more preferably 5 to 20 carbon atoms, still more preferably 6 to 15 carbon atoms, and most preferably 6 to 12 carbon atoms. As the monocyclic aliphatic cyclic group, a group in which one or more hydrogen atoms have been removed from a monocycloalkane is preferred. The monocycloalkane preferably contains 3 to 6 carbon atoms, and specific examples thereof include cyclobutane, cyclopentane and cyclohexane. As the polycyclic aliphatic cyclic group, a group in which one or more hydrogen atoms have been removed from a polycycloalkane is preferable, and the polycycloalkane preferably contains 7 to 12 carbon atoms. Specific examples of the polycycloalkane include adamantane, norbornane, isobornane, tricyclodecane and tetracyclododecane. Further, in these aliphatic cyclic groups, part of the carbon atoms constituting the ring may be replaced with an ether group (—O—).

Examples of acid dissociable groups containing an aliphatic cyclic group include

(i) a group which forms a tertiary carbon atom on the ring structure of a monovalent aliphatic cyclic group in which a substituent (a group or an atom other than hydrogen) is bonded to the carbon atom to which an atom adjacent to the acid dissociable group (e.g., “—O—” within “—C(═O)—O— group”) is bonded; and

(ii) a group which have a monovalent aliphatic cyclic group, and a branched alkylene group containing a tertiary carbon atom that is bonded to the monovalent aliphatic cyclic group.

In a group of type (i) described above, as the substituent bonded to the carbon atom to which an atom adjacent to the acid dissociable group is bonded on the ring skeleton of the aliphatic cyclic group, an alkyl group can be mentioned. Examples of these alkyl groups include the same groups as those described below for R^{N} in formulas (1-1) to (1-9) shown below.

Specific examples of groups of type (i) include groups represented by general formulas (1-1) to (1-9) shown below.

Specific examples of groups of type (ii) include groups represented by general formulas (2-1) to (2-6) shown below.

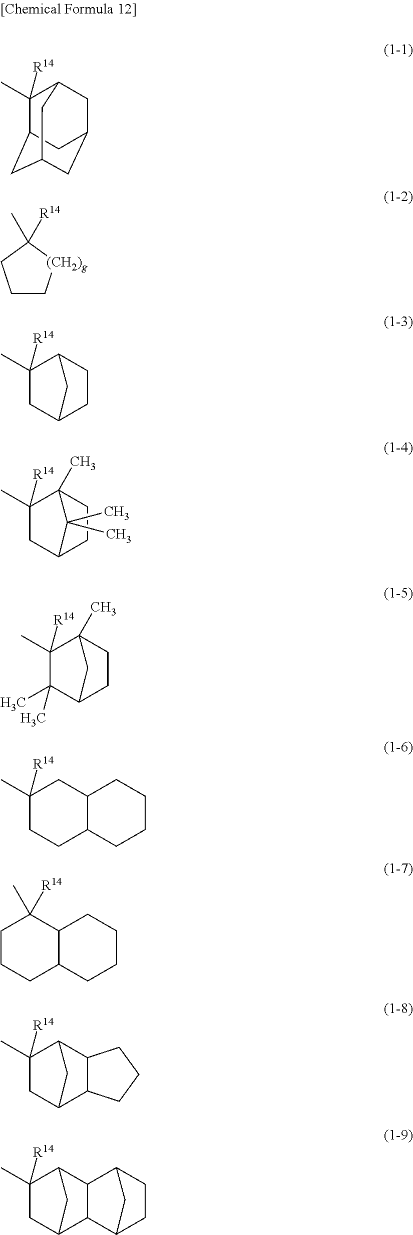

In the formulas above, R¹⁴ represents an alkyl group, and g represents an integer of 0 to 8.

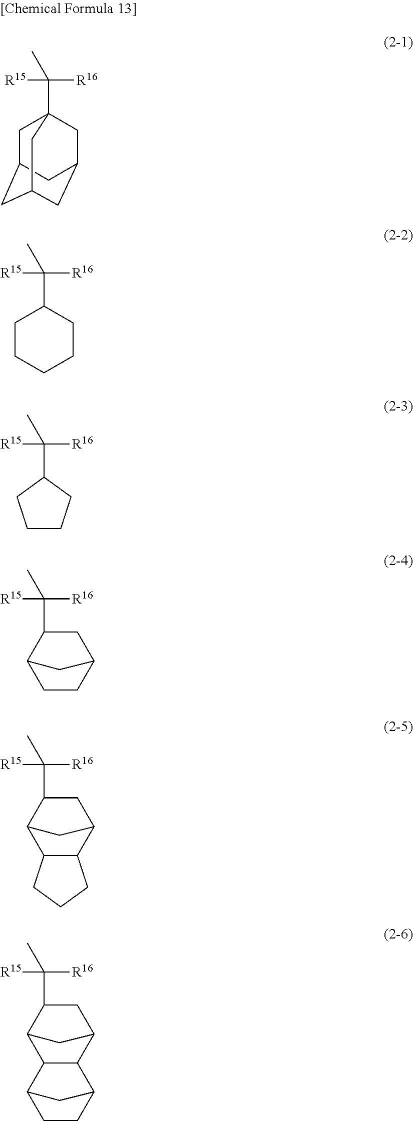

In the formulas above, each of R¹⁵ and R¹⁶ independently represents an alkyl group.

In formulas (1-1) to (1-9), the alkyl group represented by R¹⁴ may be a linear, branched or cyclic group, and is preferably a linear or branched alkyl group.

The linear alkyl group preferably has 1 to 5 carbon atoms, more preferably 1 to 4 carbon atoms, and still more preferably 1 or 2 carbon atoms. Specific examples include a methyl group, an ethyl group, an n-propyl group, an n-butyl group and an n-pentyl group. Among these, a methyl group, an ethyl group or an n-butyl group is preferable, and a methyl group or an ethyl group is more preferable.

The branched alkyl group preferably has 3 to 10 carbon atoms, and more preferably 3 to 5 carbon atoms. Specific examples of such branched alkyl groups include an isopropyl group, an isobutyl group, a tert-butyl group, an isopentyl group and a neopentyl group, and an isopropyl group is particularly desirable.

g is preferably an integer of 0 to 3, more preferably an integer of 1 to 3, and still more preferably 1 or 2.

In formulas (2-1) to (2-6), examples of the alkyl group for R¹⁵ and R¹⁶ include the same alkyl groups as those described above for R¹⁴.

In formulas (1-1) to (1-9) and formulas (2-1) to (2-6), a portion of the carbon atoms that constitute the ring(s) may be replaced with an ethereal oxygen atom (—O—).

Further, in formulas (1-1) to (1-9) and formulas (2-1) to (2-6), one or more of the hydrogen atoms bonded to the carbon atoms that constitute the ring(s) may be substituted with a substituent. Examples of the substituent include an alkyl group of 1 to 5 carbon atoms, a fluorine atom and a fluorinated alkyl group.

An “acetal-type acid dissociable group” generally substitutes a hydrogen atom at the terminal of an OH-containing polar group such as a carboxyl group or hydroxyl group, so as to be bonded with an oxygen atom. When acid is generated upon exposure, the generated acid acts to break the bond between the acetal-type acid dissociable group and the oxygen atom to which the acetal-type, acid dissociable group is bonded, thereby forming an OH-containing polar group such as a carboxyl group or a hydroxyl group.

Examples of acetal-type acid dissociable groups include groups represented by general formula (p1) shown below.

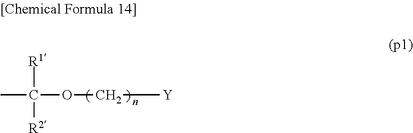

In the formula, each of R¹′ and R²′ independently represents a hydrogen atom or an alkyl group of 1 to 5 carbon atoms; n represents an integer of 0 to 3; and Y represents an alkyl group of 1 to 5 carbon atoms or an aliphatic cyclic group.

In general formula (p1), n is preferably an integer of 0 to 2, more preferably 0 or 1, and most preferably 0.

As the alkyl group for R¹′ and R²′, the same alkyl groups as those described above as the substituent which may be bonded to the carbon atom on the α-position of the aforementioned α-substituted acrylate ester can be used, although a methyl group or ethyl group is preferable, and a methyl group is particularly desirable.

In the present invention, it is preferable that at least one of R¹′ and R²′ be a hydrogen atom. That is, it is preferable that the acid dissociable group (p1) is a group represented by general formula (p1-1) shown below.

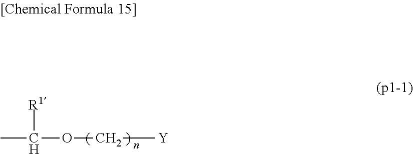

In the formula, R¹′, n and Y are the same as defined above.

As the alkyl group for Y, the same alkyl groups as those described above as the substituent which may be bonded to the carbon atom on the α-position of the aforementioned α-substituted acrylate ester can be used.

As the aliphatic cyclic group for Y, any of the monocyclic or polycyclic aliphatic cyclic groups which have been proposed for conventional ArF resists and the like can be selected and used as appropriate. For example, the same groups as those described above for the aliphatic cyclic group of the “acid dissociable group containing an aliphatic cyclic group” can be used.

Further, as the acetal-type, acid dissociable group, groups represented by general formula (p2) shown below can also be used.

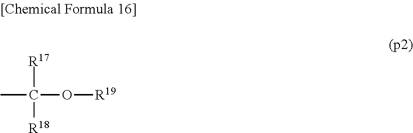

In the formula, each of R¹⁷ and R¹⁸ independently represents a linear or branched alkyl group or a hydrogen atom; and R¹⁹ represents a linear, branched or cyclic alkyl group; or alternatively, each of R¹⁷ and R¹⁹ may independently represent a linear or branched alkylene group, wherein R¹⁷ and R¹⁹ are bonded to each other to form a ring.

The alkyl group for R¹⁷ and R¹⁸ preferably has 1 to 15 carbon atoms, and may be either linear or branched. As the alkyl group, an ethyl group or a methyl group is preferable, and a methyl group is most preferable.

It is particularly desirable that either one of R¹⁷ and R¹⁸ be a hydrogen atom, and the other be a methyl group.

R¹⁹ represents a linear, branched or cyclic alkyl group which preferably has 1 to 15 carbon atoms, and may be any of linear, branched or cyclic.

When R¹⁹ represents a linear or branched alkyl group, it is preferably an alkyl group of 1 to 5 carbon atoms, more preferably an ethyl group or methyl group, and most preferably an ethyl group.

When R¹⁹ represents a cyclic alkyl group, it preferably has 4 to 15 carbon atoms, more preferably 4 to 12 carbon atoms, and most preferably 5 to 10 carbon atoms. Specific examples of the cyclic alkyl group include the same groups as those described above as “aliphatic cyclic groups”, including groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group. Among these, a group in which one or more hydrogen atoms have been removed from adamantane is preferable.

Further, in the above formula (p2), each of R¹⁷ and R¹⁹ may independently represent a linear or branched alkylene group (preferably an alkylene group of 1 to 5 carbon atoms), wherein R¹⁹ and R¹⁷ are bonded to each other.

In such a case, a cyclic group is formed by R¹⁷, R¹⁹, the oxygen atom having R¹⁹ bonded thereto, and the carbon atom having the oxygen atom and R¹⁷ bonded thereto. Such a cyclic group is preferably a 4- to 7-membered ring, and more preferably a 4- to 6-membered ring. Specific examples of the cyclic group include a tetrahydropyranyl group and a tetrahydrofuranyl group.

Examples of the structural unit (c2) include the same groups as those described below for the structural unit (a1). The structural unit (c2) may or may not have a fluorine atom or a silicon atom. Examples of the structural unit (c2) having a fluorine atom or a silicon atom include those in which R⁰ in the aforementioned general formula (c-0) represents an acid decomposable group, and those in which L⁰¹ in formula (c-0) represents —C(═O)—O-L¹⁰-, —C(═O)—N(R^{N})-L¹⁰- or —R^{ar}-L¹⁰- are particularly desirable.

Specific examples of the structural unit (c2) include structural units represented by general formulas (c2-11) to (c2-15) shown below.

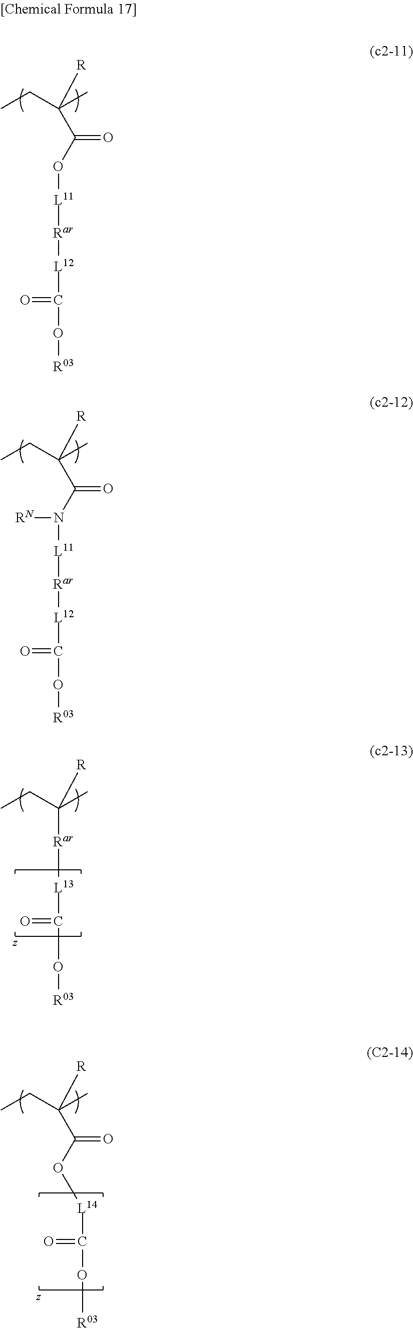

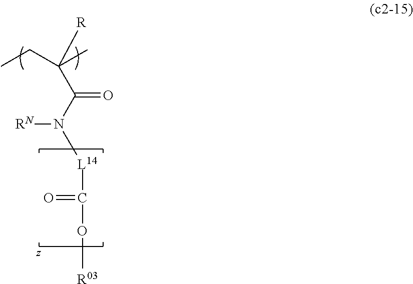

In formulas (c2-11) to (c2-12), R, L¹¹, R^{ar}, L¹² and R^{N} are each the same as defined above, and R⁰³ represents an acid dissociable group. In formula (c2-13), R, R^{ar}, L¹³ and R⁰³ are each the same as defined above, and z represents 0 or 1. In formulas (c2-14) to (c2-15), R, L¹⁴, R⁰³, R^{N} and z are each the same as defined above.

In formulas (c2-11) to (c2-15), R, L¹¹ to L¹⁴, R^{ar} and R^{N} are each the same as defined above for R, L⁰¹ to L¹⁴, R^{ar} and R^{N} in general formula (c1-11) to (c1-15) mentioned within the description of the structural unit (c1). However, the structural units represented by general formulas (c2-11) to (c2-15) do not necessarily have a fluorine atom or a silicon atom.

Examples of the acid dissociable group for R⁰³ include the same groups as those mentioned above. Of these, a tertiary alkyl ester-type acid dissociable group is preferred, and an acid dissociable group containing an aliphatic cyclic group is particularly desirable.

When the component (C) contains the structural unit (c2), the structural unit (c2) contained within the component (C) may be either a single type of structural unit or a combination of two or more types of structural units.

In the component (C), the amount of the structural unit (c2) based on the combined total of all structural units constituting the component (C) is preferably 0 to 45 mol %, more preferably 5 to 40 mol %, and still more preferably 10 to 40 mol %. When the amount of the structural unit (c2) is not more than the upper limit of the above range, a good balance can be achieved with the other structural units.

Further, when the amount of the structural unit (c2) is equal to or more than 5 mol %, the solubility in a developing solution improves in the exposed regions in the case of an alkali developing process and in the unexposed regions in the case of a solvent developing process.

When the structural unit (c2) contains an aromatic group, the amount of the structural unit (c2) based on the combined total of all structural units constituting the component (C) is preferably 5 to 30 mol %, and more preferably 10 to 20 mol. By ensuring that the amount of the structural unit (c2) is within the aforementioned range, the effect of reducing the influence of OoB light can be improved, and the solubility in a developing solution improves in the exposed regions in the case of an alkali developing process and in the unexposed regions in the case of a solvent developing process.

When the structural unit (c2) contains no aromatic group, the amount of the structural unit (c2) based on the combined total of all structural units constituting the component (C) is preferably 0 to 45 mol %, and more preferably 0 to 40 mol %.

[Structural Unit (c3)]

The structural unit (c3) is a structural unit containing a polar group. Including the structural unit (c3) within the component (C) further increases the polarity of the component (C) following exposure. This increase in polarity contributes to reducing defects. Further, this increase in polarity also contributes to improved resolution and the like, particularly in the case of an alkali developing process.

Examples of polar groups include —OH, —COOH, —CN, —SO₂NH₂ and —CONH₂. An —OH group may be a phenolic hydroxyl group or an alcoholic hydroxyl group.

The structural unit (c3) is preferably a structural unit containing a hydrocarbon group in which some of the hydrogen atoms have been substituted with a polar group or an organic group containing a polar group.

Examples of organic groups containing a polar group include a hydroxyalkyl group, a hydroxyalkyloxy group, a fluorinated alcohol group (a hydroxyalkyl group in which part or all of the hydrogen atoms bonded to carbon atoms are each substituted with a fluorine atom) and a hydroxyaryl group. Of these, the carbon skeleton of the hydroxyalkyl group, hydroxyalkyloxy group and fluorinated alcohol group may be linear, branched, cyclic, or a combination thereof. In the case of a linear or branched skeleton, the carbon skeleton preferably contains 1 to 12 carbon atoms. In the case of a cyclic skeleton, the carbon skeleton preferably contains 3 to 30 carbon atoms. Examples of the aryl group within the hydroxyaryl group include groups in which one hydrogen atom has been removed from an aromatic ring mentioned above in the description of the aromatic group, and a phenyl group or a naphthyl group is preferable.

The hydrocarbon group in which the hydrogen atoms have been substituted with a polar group or an organic group containing a polar group may be either an aliphatic hydrocarbon group or an aromatic hydrocarbon group. Among these, the hydrocarbon group in the structural unit (c3) is more preferably an aromatic hydrocarbon group.

Examples of the aliphatic hydrocarbon group and aromatic hydrocarbon group for the hydrocarbon group include the same aliphatic hydrocarbon groups and aromatic hydrocarbon groups as those described above as the divalent hydrocarbon groups in connection with the divalent linking groups for L⁰¹ in the general formula (I-1).

The hydrocarbon group may have a substituent other than a polar group. Examples of the substituent include an alkyl group of 1 to 5 carbon atoms, a fluorine atom, a fluorinated alkyl group of 1 to 5 carbon atoms, and an oxo group (═O).

As the structural unit (c3), structural units derived from (α-substituted) acrylic acid, or structural units containing a polar group that are structural units derived from (α-substituted) acrylate esters are preferred. The structural units derived from (α-substituted) acrylic acid and the structural units derived from (α-substituted) acrylate esters refer to the structural units having a structure in which the ethylenic double bond of (α-substituted) acrylic acid is cleaved to form a single bond, and the structural units having a structure in which the ethylenic double bond of (α-substituted) acrylate esters is cleaved to form a single bond, respectively.

Examples of the structural units derived from (α-substituted) acrylate esters and containing a polar group include a structural unit (a3-11) which will be described later.

The structural unit (c3) may or may not have a fluorine atom or a silicon atom. Examples of the structural unit (c3) having a fluorine atom or a silicon atom include those in which R⁰ in the aforementioned general formula (c-0) represents a hydrocarbon group containing a polar group.

As the structural unit (c3), those containing a fluorine atom in addition to the polar group are preferred, and those in which R⁰ in the general formula (c-0) represents either an aromatic cyclic group to which a hydroxyl group and a fluorine atom are bonded or an aliphatic cyclic group to which a fluorinated alcohol group is bonded are more preferred.

In particular, those in which L⁰¹ in the formula (c-0) represents a single bond, —C(═O)—O-L¹⁰- or —C(═O)—N(R^{N})-L¹⁰- are preferred.

Specific examples of preferred forms of the structural unit (c3) are shown below.

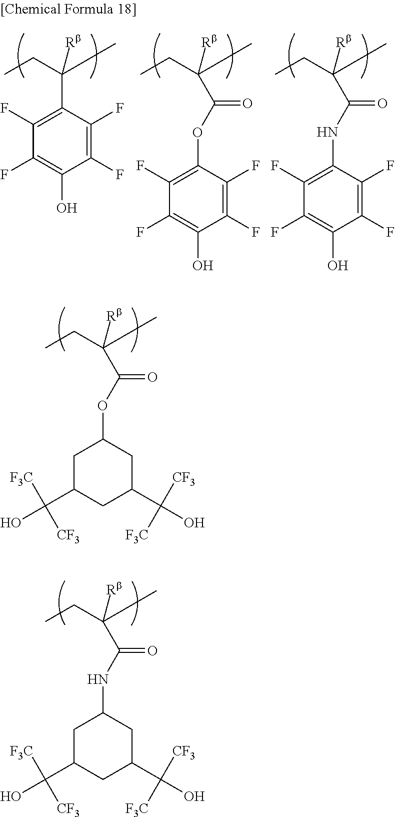

When the component (C) contains the structural unit (c3), the structural unit (c3) contained within the component (C) may be either a single type of structural unit or a combination of two or more types of structural units.

In the component (C), the amount of the structural unit (c3) based on the combined total of all structural units constituting the component (C) is preferably 0 to 50 mol %, and more preferably 5 to 45 mol %. When the amount of the structural unit (c3) is not more than the upper limit of the above range, a good balance can be achieved with the other structural units. When the amount of the structural unit (c3) is at least 5 mol %, the effects achieved by including the structural unit (c3) can be satisfactorily obtained, regardless of the structural unit (c3) having an aromatic group or not. When the structural unit (c3) has an aromatic group, the effect of reducing the influence of OoB light can be further improved.

[Structural Unit (c4)]

The structural unit (c4) is a fluorine-containing structural unit containing a cyclic group and does not fall under the category of the structural units (c1) to (c3). Including the structural unit (c4) improves the dry etching resistance of the formed resist pattern. Further, the hydrophobicity of the component (C) is also enhanced. An improvement in the hydrophobicity contributes to improvements in the resolution and the resist pattern shape and the like, particularly in the case of an organic solvent developing process.

The cyclic group in the structural unit (c4) may be an aromatic cyclic group or a aliphatic cyclic group.

Examples of the aromatic cyclic group include those in which one or more hydrogen atoms have been removed from an aromatic ring mentioned above in the description of the aromatic group.

The aliphatic cyclic group may be saturated or unsaturated. In general, the aliphatic cyclic group is preferably saturated. The aliphatic cyclic group may be either a monocyclic group or a polycyclic group. As the monocyclic aliphatic cyclic group, a group in which one or more hydrogen atoms have been removed from a monocycloalkane is preferred. The monocycloalkane preferably contains 3 to 6 carbon atoms, and specific examples thereof include cyclopentane and cyclohexane. As the polycyclic aliphatic cyclic group, a group in which one or more hydrogen atoms have been removed from a polycycloalkane is preferable, and the polycycloalkane preferably contains 7 to 12 carbon atoms. Specific examples of the polycycloalkane include adamantane, norbornane, isobornane, tricyclodecane and tetracyclododecane.

The cyclic group may have a substituent bonded thereto. Examples of the substituent include an alkyl group of 1 to 5 carbon atoms, a fluorine atom, a fluorinated alkyl group of 1 to 5 carbon atoms, and an oxo group (═O).

Of these, examples of the alkyl group, alkoxy group, halogen atom and halogenated alkyl group include the same substituents as those described above as the substituent which may be bonded to the aromatic ring within the description of the aromatic group.

Examples of the polar group as the substituent include a hydroxyl group, a carboxyl group, an amino group, a sulfo group, a cyano group, a hydroxyalkyl group, a hydroxyalkyloxy group and a fluorinated alcohol group (namely, a hydroxyalkyl group in which some or all of the hydrogen atoms bonded to the carbon atoms have been substituted with fluorine atoms). Of these, the carbon skeleton of the hydroxyalkyl group, hydroxyalkyloxy group and fluorinated alcohol group may be linear, branched, cyclic, or a combination thereof. In the case of a linear or branched skeleton, the carbon skeleton preferably contains 1 to 12 carbon atoms. In the case of a cyclic skeleton, the carbon skeleton preferably contains 3 to 30 carbon atoms.

As the structural unit (c4), those in which R⁰ in the aforementioned general formula (c-0) represents a fluorine-containing cyclic group are preferred, and in particular, those in which L⁰¹ in the formula (c-0) represents a single bond, —C(═O)—O-L¹⁰- or —C(═O)—N(R^{N})-L¹⁰- are preferred.

Specific examples of preferred forms of the structural unit (c4) are shown below.

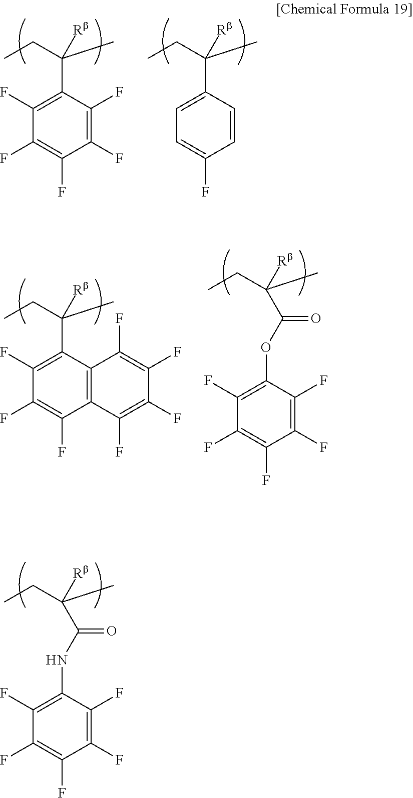

When the component (C) contains the structural unit (c4), the structural unit (c4) contained within the component (C) may be either a single type of structural unit or a combination of two or more types of structural units.

In the component (C), the amount of the structural unit (c4) based on the combined total of all structural units constituting the component (C) is preferably 0 to 30 mol %, and more preferably 1 to 20 mol %. When the amount of the structural unit (c4) is not more than the upper limit of the above range, a good balance can be achieved with the other structural units. When the amount of the structural unit (c4) is at least 1 mol %, the effects achieved by including the structural unit (c4) can be satisfactorily obtained.

[Structural Unit (c5)]

The structural unit (c5) is a silicon-containing structural unit that includes an organic group having a trialkylsilyl group or a siloxane bond.

Examples of the trialkylsilyl group include groups represented by the formula —Si(R⁷⁴)(R⁷⁵)(R⁷⁶). In the formula, each of R⁷⁴ to R⁷⁶ independently represents a linear or branched alkyl group. The alkyl group preferably has 1 to 10 carbon atoms, more preferably 1 to 8 carbon atoms, and still more preferably 1 to 5 carbon atoms. As the alkyl group, a methyl group, an ethyl group, an isopropyl group, a t-butyl group or the like is preferred, and a methyl group is particularly desirable.

Specific examples of the trialkylsilyl group include a trimethylsilyl group, a triethylsilyl group, a triisopropylsilyl group and a t-butyldimethylsilyl group.

The organic group containing a trialkylsilyl group may be composed only of a trialkylsilyl group, or may be a group in which n trialkylsilyl group(s) (n represents an integer of 1 or more) is bonded to a linking group having a valency of (n+1). Among the linking groups having a valency of (n+1), examples of linking groups when n is 1 (namely, divalent linking groups) include the same groups as those described above within the description of the divalent linking groups for L⁰¹ in the general formula (I-1), and linear or branched alkylene groups in which an ether bond or an ester bond may be inserted are preferred. Examples of linking groups when n is 2 or more include a group in which (n−1) hydrogen atom(s) has been further removed from the linking group.

Examples of the organic group containing a siloxane bond (Si—O—Si) include a cyclic siloxane in which a hydrocarbon group is bonded to a silicon atom, a cage-type silsesquioxane in which a hydrocarbon group is bonded to a silicon atom, and a group in which part of the carbon chain of a chain-like or cyclic alkyl group has been substituted with —Si—O—Si—. The hydrocarbon group bonded to the silicon atom of the cyclic siloxane or cage-type silsesquioxane may be either an aliphatic hydrocarbon group or an aromatic group, is preferably an aliphatic group, and more preferably an alkyl group of 1 to 5 carbon atoms.

Examples of the structural unit (c5) include those in which R⁰ in the aforementioned general formula (c-0) represents an organic group containing a trialkylsilyl group or a siloxane structure, and those in which L⁰¹ in formula (c-0) represents —C(═O)—O-L¹⁰- or a single bond are particularly desirable.

When the component (C) contains the structural unit (c5), the structural unit (c5) contained within the component (C) may be either a single type of structural unit or a combination of two or more types of structural units.

In the component (C), the amount of the structural unit (c5) based on the combined total of all structural units constituting the component (C) is preferably 0 to 60 mol %, more preferably 1 to 50 mol %, and still more preferably 5 to 40 mol %. By virtue of the above-mentioned range, the surface segregation effects, the applicability and the like can be improved, and a good balance can be achieved with the other structural units.

The component (C) may further contain a structural unit (hereafter, referred to as “structural unit (c6)”) other than the structural units (c1) to (c5).

The structural unit (c6) is not particularly limited as long as it is capable of forming a copolymer with the structural units (c1) to (c5). For example, any of the multitude of conventional structural units used within resist resins for ArF excimer lasers, KrF excimer lasers, EB and EUV can be used. Examples of such structural units include the structural units (a0), (a2) and (a4) mentioned within the description of the component (A) which will be described later, and can be selected appropriately from among them.

The structural units that constitute the component (C) may be either a single type of structural unit or a combination of two or more types of structural units.

When the component (C) is constituted of a single type of structural unit, as the structural unit, those having a base decomposable polarity conversion group and an aromatic group as well as a fluorine atom or a silicon atom are used. Examples of such structural units include structural units represented by the aforementioned general formulas (c1-11) to (c1-13) and (c1-21) to (c1-23).

In the component (C), it is necessary that the amount of a structural unit having the aforementioned aromatic group is at least 20 mol %. When this amount is at least 20 mol %, the influence of OoB light can be reduced. The amount of the structural unit having an aromatic group within the component (C) based on the combined total of all structural units constituting the component (C) is preferably 20 to 100 mol %, and more preferably 25 to 100 mol %.

The structural unit having an aromatic group may correspond to any one of the structural units (c1) to (c6).

Further, in terms of achieving superior effects for the present invention, the amount of the structural unit containing at least one type of atom selected from a fluorine atom and a silicon atom (and preferably a fluorine atom) within the component (C), based on the combined total of all structural units constituting the component (C) is preferably at least 70 mol %, and more preferably at least 80 mol %. The upper limit is not particularly limited and may even be 100 mol %.

Furthermore, the component (C) preferably contains a structural unit having at least one type of atom selected from a fluorine atom and a silicon atom (and preferably a fluorine atom) and also having an aromatic group so that the amount of the structural unit based on the combined total of all structural units constituting the component (C) is 20 to 100 mol %, and more preferably 25 to 100 mol %.

In the component (C), a preferred amount for the structural unit containing a polarity conversion group that decomposes by the action of a base to increase the polarity is the same as the preferred amount for the aforementioned structural unit (c1).

Further, the amount of the structural unit containing at least one type of atom selected from a fluorine atom and a silicon atom (and preferably a fluorine atom) within the component (C), based on the amount of the structural unit having an aromatic group, is preferably 40 to 500 mol %, and more preferably 50 to 400 mol %. By ensuring that the amount is within the aforementioned range, the surface segregation effects can be enhanced, and the effect of reducing the influence of OoB light can be improved.

The amount of the structural unit containing a polarity conversion group that decomposes by the action of a base to increase the polarity within the component (C), based on the amount of the structural unit having an aromatic group, is preferably 50 to 250 mol %, and more preferably 55 to 200 mol %. By ensuring that the amount is within the aforementioned range, the effect of reducing the influence of OoB light can be improved, and the solubility in an alkali developing solution also improves.

The component (C) is preferably a polymer containing the structural unit (c1), and more preferably a copolymer containing the structural unit (c1) and at least one type of structural unit selected from the structural unit (c2) and the structural unit (c3).

As the structural unit (c1), at least one type of structural unit selected from the group consisting of structural units represented by the aforementioned general formulas (c1-11) to (c1-15) and (c1-21) to (c1-25) is preferred, and at least one type of structural unit selected from the group consisting of structural units represented by general formulas (c1-11), (c1-12), (c1-14), (c1-15) and (c1-23) is more preferred.

As the structural unit (c2), at least one type of structural unit selected from the group consisting of structural units represented by the aforementioned general formulas (c2-11) to (c2-15) is preferred, and at least one type of structural unit selected from the group consisting of structural units represented by general formulas (c2-11), (c2-12) and (c2-14) is more preferred.

As the structural unit (c3), structural units derived from (α-substituted) acrylic acid, structural units containing an aromatic cyclic group to which a fluorine atom and a hydroxyl group are bonded, or structural units containing an aliphatic cyclic group to which a fluorinated alcohol group is bonded are preferred, and structural units having a hydroxyphenyl group in which the hydrogen atom has been substituted with a fluorine atom or structural units having a cyclohexyl group to which a fluorinated alcohol group is bonded are more preferred.

The weight average molecular weight (Mw) (the polystyrene equivalent value determined by gel permeation chromatography (GPC)) of the component (C) is not particularly limited, but is preferably from 1,000 to 80,000, more preferably from 5,000 to 60,000, and most preferably from 10,000 to 50,000. When the weight average molecular weight is no more than the upper limit of the above-mentioned range, the resist composition exhibits a satisfactory solubility in a resist solvent. On the other hand, when the weight average molecular weight is at least as large as the lower limit of the above-mentioned range, dry etching resistance and the cross-sectional shape of the resist pattern becomes satisfactory.

Further, although there are no particular limitations on the dispersity (Mw/Mn), the dispersity is preferably from 1.0 to 5.0, more preferably from 1.0 to 3.0, and most preferably from 1.0 to 2.5. Here, Mn is the number average molecular weight.

The component (C) can be obtained, for example, by a conventional radical polymerization or the like of the monomers corresponding with the structural units to be included, using a radical polymerization initiator such as azobisisobutyronitrile (AIBN).

Furthermore, in the component (C), by using a chain transfer agent such as HS—CH₂—CH₂—CH₂—C(CF₃)₂—OH during the aforementioned polymerization, a —C(CF₃)₂—OH group can be introduced at the terminals of the component (C). Such a copolymer having introduced a hydroxyalkyl group in which some of the hydrogen atoms of the alkyl group have been substituted with fluorine atoms is effective in reducing developing defects and LER (line edge roughness: unevenness of the side walls of a line pattern).

The monomers used for forming each of the structural units may be synthesized using conventional methods. For example, the monomer corresponding with the structural unit (a0) can be synthesized using the method disclosed in Japanese Unexamined Patent Application, First Publication No. 2006-045311 or Japanese Unexamined Patent Application, First Publication No. 2010-095643. In the case of conventional monomers, commercially available products may also be used.

As the component (C), one type of component may be used alone, or two or more types may be used in combination.

In the resist composition of the present aspect, the amount of the component (C) is preferably from 1 to 15 parts by weight, more preferably from 2 to 14 parts by weight, and still more preferably from 3 to 12 parts by weight, relative to 100 parts by weight of the component (A). Provided the amount is at least 1 part by weight, the pattern shape and resolution limit and the like are improved for a resist pattern formed by EUV exposure or EB exposure. When the amount is not more than 15 parts by weight, a good balance can be achieved with the component (A), and the lithography properties such as the shape and resolution are improved.

### <Component (A)>

The component (A) used in the resist composition of the present aspect is a resin component which generates acid upon exposure and also exhibits changed solubility in a developing solution under the action of acid.

The component (A) may exhibit increased solubility in the developing solution under the action of acid, or decreased solubility in the developing solution under the action of acid.

The component (A) may contain a region that generates an acid upon exposure (acid generating region) within the side chain or at the terminal of the main chain. If the acid generating region is present within the side chain, a structural unit (a0) which will be described later is included.

In those cases where the resist composition of the present aspect is a resist composition which forms a negative-type resist pattern in an alkali developing process (or forms a positive-type resist pattern in a solvent developing process), a resin component which generates acid upon exposure and is also soluble in an alkali developing solution (hereinafter, sometimes referred to as “component (A2)”) is preferably used as the component (A), and a cross-linking agent is further added to the composition. In this resist composition, when acid is generated from the component (A2) upon exposure, the action of the acid causes cross-linking between the component (A2) and the cross-linking agent, and as a result, the solubility in an alkali developing solution decreases (whereas the solubility in an organic developing solution increases). Accordingly, during resist pattern formation, by conducting selective exposure of a resist film formed by applying the resist composition onto a substrate, the exposed portions change to a state that is substantially insoluble in an alkali developing solution (but soluble in an organic developing solution), while the unexposed portions remain soluble in an alkali developing solution (but substantially insoluble in an organic developing solution), meaning developing with an alkali developing solution can be used to form a negative-type resist pattern. Further, if an organic developing solution is used as the developing solution, then a positive-type resist pattern can be formed.

Examples of the component (A2) include conventional resins that are soluble in an alkali developing solution (hereinafter referred to as “alkali-soluble resins”) into which an acid generating region (for example, the anion moiety that generates an acid upon exposure) that generates acid upon exposure has been introduced.

Examples of the alkali-soluble resin (prior to introduction of the acid generating region) include a resin having a structural unit derived from at least one of an α-(hydroxyalkyl)acrylic acid and an alkyl ester of α-(hydroxyalkyl)acrylic acid (preferably an alkyl ester having 1 to 5 carbon atoms), as disclosed in Japanese Unexamined Patent Application, First Publication No. 2000-206694; an acrylic resin or polycycloolefin resin having a sulfonamide group, and in which an atom other than a hydrogen atom or a substituent may be bonded to the carbon atom on the α-position, as disclosed in U.S. Pat. No. 6,949,325; an acrylic resin containing a fluorinated alcohol, and in which an atom other than a hydrogen atom or a substituent may be bonded to the carbon atom on the α-position, as disclosed in U.S. Pat. No. 6,949,325, Japanese Unexamined Patent Application, First Publication No. 2005-336452 or Japanese Unexamined Patent Application, First Publication No. 2006-317803; and a polycycloolefin resin having a fluorinated alcohol, as disclosed in Japanese Unexamined Patent Application, First Publication No. 2006-259582. These resins are preferable in that a resist pattern can be formed with minimal swelling.

The term “α-(hydroxyalkyl)acrylic acid” refers to one or both of acrylic acid in which a hydrogen atom is bonded to the carbon atom on the α-position having the carboxyl group bonded thereto, and α-hydroxyalkylacrylic acid in which a hydroxyalkyl group (and preferably a hydroxyalkyl group of 1 to 5 carbon atoms) is bonded to the carbon atom on the α-position.

As the acid generating region, those having the same structure as that of the acid generating region included in the compound known as an acid generator for a resist composition can be employed.

The position for introducing the acid generating region may be at the terminal of the main chain or within the side chain moiety. The acid generating region can be introduced into the main chain terminal, for example, by using a polymerization initiator having an acid generating region as a polymerization initiator in the production of alkali-soluble resins. The introduction into the side chain moiety can be carried out, when producing the alkali-soluble resin, by polymerizing a monomer having an alkali-soluble group (for example, monomers for deriving structural units having an alkali-soluble group such as a hydroxyl group or a carboxyl group as the polar group, among structural units (a3) described later) or a precursor thereof (for example, an alkali-soluble group which is protected with a protective group) with a monomer having an acid generating region (for example, monomers for deriving structural units (a0) described later.

As the cross-linking agent, usually, an amino-based cross-linking agent such as a glycoluril having a methylol group or alkoxymethyl group, or a melamine-based cross-linking agent is preferable, as it enables formation of a resist pattern with minimal swelling. The amount of the cross-linking agent added is preferably within a range from 1 to 50 parts by weight, relative to 100 parts by weight of the alkali-soluble resin.

In those cases where the resist composition of the present aspect is a resist composition which forms a positive-type resist pattern in an alkali developing process, and forms a negative-type resist pattern in a solvent developing process, a resin component which exhibits increased polarity under the action of acid (hereinafter, sometimes referred to as “component (A1)”) is preferably used as the component (A). Because the polarity of the component (A1) changes upon exposure, by using the component (A1), favorable developing contrast can be achieved, not only in an alkali developing process, but also in a solvent developing process.

In other words, in those cases where an alkali developing process is employed, the component (A1)) is substantially insoluble in an alkali developing solution prior to exposure, but when acid is generated from the component (A1) upon exposure, the action of this acid causes an increase in the polarity that increases the solubility in the alkali developing solution. Accordingly, during resist pattern formation, by conducting selective exposure of a resist film formed by applying the resist composition onto a substrate, the exposed portions change from being substantially insoluble in the alkali developing solution to being soluble, while the unexposed portions remain substantially insoluble in the alkali developing solution, meaning alkali developing can be used to form a positive-type resist pattern. On the other hand, when a solvent developing process is employed, the component (A1) exhibits high solubility in an organic developing solution prior to exposure, but when acid is generated from the component (A1) upon exposure, the action of the acid causes an increase in the polarity that reduces the solubility in the organic developing solution. Accordingly, during resist pattern formation, by conducting selective exposure of a resist film formed by applying the resist composition onto a substrate, the exposed portions change from being soluble in the organic developing solution to being substantially insoluble, while the unexposed portions remain soluble in the organic developing solution, meaning developing with the organic developing solution can be used to achieve contrast between the exposed portions and the unexposed portions, enabling formation of a negative-type resist pattern.

In the present aspect, the component (A) is preferably the component (A1).

(Structural Unit (a0))

The structural unit (a0) is a structural unit that generates acid upon exposure.

The structural unit (a0) is not particularly limited as long as it has a structure that generates an acid upon exposure, although it preferably has an onium salt structure that generates an acid upon exposure. Here, examples of the onium salt structure include the same structure as those of the functional sites of the onium salt-based acid generators that are commonly used in chemically amplified resist compositions. The strength of the generated acid is not particularly limited, and the acid may be strong acids as those generally used as the acid generated by the acid generators in the resist compositions or may be other weak acids.

Specific examples of the structural unit (a0) include structural units having a group represented by general formula (a0-1) or (a0-2) shown below.

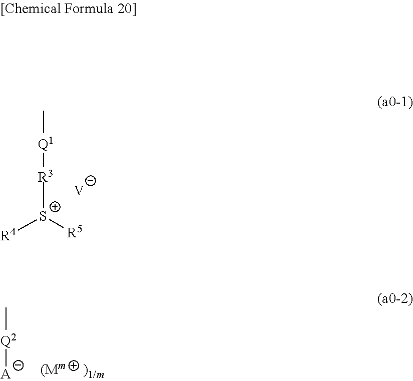

In the formulas, each of Q¹ and Q² independently represents a single bond or a divalent linking group; each of R³, R⁴ and R⁵ independently represents an organic group, wherein R⁴ and R⁵ may be bonded to each other to form a ring together with the sulfur atom in the formula; V⁻ represents a counter anion; A⁻ represents an organic group containing an anion; M^{m+} represents a counter cation; and m represents an integer of 1 to 3.
(Structural Unit Having a Group Represented by Formula (a0-1))

In formula (a0-1), Q¹ represents a single bond or a divalent linking group.

Examples of the divalent linking group for Q¹ include the same groups as those described above as the divalent linking group for L⁰¹ in the formula (I-1). In particular, as Q¹ in the present invention, a single bond, an ester bond [—C(═O)—O−], an ether bond (—O—), an alkylene group, or a combination thereof is preferred.

In formula (a0-1), each of R³ to R⁵ independently represents an organic group.

The organic group for R³ to R⁵ refers to a group containing a carbon atom, and may include atoms other than carbon atoms (such as a hydrogen atom, an oxygen atom, a nitrogen atom, a sulfur atom, or a halogen atom (such as a fluorine atom and a chlorine atom) and the like).

As the organic group for R³, an arylene group or an alkylene group which may have a substituent is preferred.

Examples of the arylene group for R³ which may have a substituent include unsubstituted arylene groups of 6 to 20 carbon atoms, and substituted arylene groups in which part or all of the hydrogen atoms of an aforementioned unsubstituted arylene group have each been substituted with a substituent.

The unsubstituted arylene group is preferably an arylene group of 6 to 10 carbon atoms because it can be synthesized at a low cost. Specific examples thereof include a phenylene group and a naphthylene group.

Examples of the substituent within the substituted arylene group include an alkyl group, an alkoxy group, a halogen atom, a hydroxyl group, an oxo group (═O), an aryl group, an alkoxyalkyloxy group, an alkoxycarbonylalkyloxy group, —C(═O)—O—R⁶″, —O—C(═O)—R⁷″ and —O—R⁸″. Each of R⁶″, R⁷ and R⁸″ independently represents a hydrogen atom, a saturated hydrocarbon group or an aliphatic unsaturated hydrocarbon group.

The alkyl group for the substituent is preferably an alkyl group of 1 to 5 carbon atoms, and is most preferably a methyl group, an ethyl group, a propyl group, an n-butyl group or a tert-butyl group.

The alkoxy group for the substituent is preferably an alkoxy group of 1 to 5 carbon atoms, and is most preferably a methoxy group, an ethoxy group, an n-propoxy group, an iso-propoxy group, an n-butoxy group or a tert-butoxy group.

The halogen atom for the substituent is preferably a fluorine atom.

Examples of the aryl group for the substituent include the same aryl groups as those described above for R⁴″ to R⁵″, and of these, aryl groups of 6 to 20 carbon atoms are preferred, aryl groups of 6 to 10 carbon atoms are more preferred, and a phenyl group or a naphthyl group is particularly desirable.

Examples of the alkoxyalkyloxy group for the substituent include groups represented by a general formula: —O—C(R⁴⁷)(R⁴⁸)—O—R⁴⁹ [wherein each of R⁴⁷ and R⁴⁸ independently represents a hydrogen atom or a linear or branched alkyl group; and R⁴⁹ represents an alkyl group].

The alkyl group for R⁴⁷ and R⁴⁸ preferably has 1 to 5 carbon atoms, and may be either linear or branched. As the alkyl group, an ethyl group or a methyl group is preferable, and a methyl group is most preferable.

It is preferable that at least one of R⁴⁷ and R⁴⁸ be a hydrogen atom. It is particularly desirable that either one of R⁴⁷ and R⁴⁸ be a hydrogen atom, and the other be a hydrogen atom or a methyl group.

The alkyl group for R⁴⁹ preferably has 1 to 15 carbon atoms, and may be linear, branched or cyclic.

The linear or branched alkyl group for R⁴⁹ preferably has 1 to 5 carbon atoms. Examples thereof include a methyl group, an ethyl group, a propyl group, an n-butyl group and a tert-butyl group.

The cyclic alkyl group for R⁴⁹ preferably has 4 to 15 carbon atoms, more preferably 4 to 12 carbon atoms, and most preferably 5 to 10 carbon atoms. Specific examples thereof include groups in which one or more hydrogen atoms have been removed from a monocycloalkane or a polycycloalkane such as a bicycloalkane, tricycloalkane or tetracycloalkane, and which may or may not be substituted with an alkyl group of 1 to 5 carbon atoms, a fluorine atom or a fluorinated alkyl group. Examples of the monocycloalkane include cyclopentane and cyclohexane. Examples of the polycycloalkane include adamantane, norbornane, isobornane, tricyclodecane and tetracyclododecane. Among these, a group in which one or more hydrogen atoms have been removed from adamantane is preferable.

Examples of the alkoxycarbonylalkyloxy group for the substituent include groups represented by a general formula: —O—R⁵⁰—C(═O)—O—R⁵⁶ [wherein R⁵⁰ represents a linear or branched alkylene group; and R⁵⁶ represents a tertiary alkyl group].

The linear or branched alkylene group for R⁵⁰ preferably has 1 to 5 carbon atoms, and examples thereof include a methylene group, an ethylene group, a trimethylene group, a tetramethylene group and a 1,1-dimethylethylene group.

Examples of the tertiary alkyl group for R⁵⁶ include a 2-methyl-2-adamantyl group, a 2-(2-propyl)-2-adamantyl group, a 2-ethyl-2-adamantyl group, a 1-methyl-1-cyclopentyl group, a 1-ethyl-1-cyclopentyl group, a 1-methyl-1-cyclohexyl group, a 1-ethyl-1-cyclohexyl group, a 1-(1-adamantyl)-1-methylethyl group, a 1-(1-adamantyl)-1-methylpropyl group, a 1-(1-adamantyl)-1-methylbutyl group, a 1-(1-adamantyl)-1-methylpentyl group, a 1-(1-cyclopentyl)-1-methylethyl group, a 1-(1-cyclopentyl)-1-methylpropyl group, a 1-(1-cyclopentyl)-1-methylbutyl group, a 1-(1-cyclopentyl)-1-methylpentyl group, a 1-(1-cyclohexyl)-1-methylethyl group, a 1-(1-cyclohexyl)-1-methylpropyl group, a 1-(1-cyclohexyl)-1-methylbutyl group, a 1-(1-cyclohexyl)-1-methylpentyl group, a tert-butyl group, a tert-pentyl group and a tert-hexyl group.

Moreover, groups in which R⁵⁶ in the general formula —O—R⁵⁰—C(═O)—O—R⁵⁶ has been substituted with R⁵⁶′ may also be used. R⁵⁶′ represents a hydrogen atom, an alkyl group, a fluorinated alkyl group, or an aliphatic cyclic group which may contain a hetero atom.

Examples of the alkyl group for R⁵⁶′ include the same groups as those described above for the alkyl group for R⁴⁹.

Examples of the fluorinated alkyl group for R⁵⁶′ include groups in which part or all of the hydrogen atoms within an aforementioned alkyl group for R⁴⁹ have each been substituted with a fluorine atom.

Examples of the aliphatic cyclic group which may contain a hetero atom for R⁵⁶′ include aliphatic cyclic groups that do not contain a hetero atom, aliphatic cyclic groups containing a hetero atom within the ring structure, and groups in which a hydrogen atom within an aliphatic cyclic group has been substituted with a hetero atom.

As the aliphatic cyclic groups for R⁵⁶′ that do not contain a hetero atom, groups in which one or more hydrogen atoms have been removed from a monocycloalkane or a polycycloalkane such as a bicycloalkane, tricycloalkane or tetracycloalkane can be mentioned. Examples of the monocycloalkane include cyclopentane and cyclohexane. Examples of the polycycloalkane include adamantane, norbornane, isobornane, tricyclodecane and tetracyclododecane. Among these, a group in which one or more hydrogen atoms have been removed from adamantane is preferable.

For R⁵⁶″, specific examples of the aliphatic cyclic groups containing a hetero atom within the ring structure include groups represented by formulas (L1) to (L6) and (S1) to (S4) shown below.

For R⁵⁶′, specific examples of the groups in which a hydrogen atom within the aliphatic cyclic group has been substituted with a hetero atom include groups in which a hydrogen atom within an aliphatic cyclic group has been substituted with an oxo group (═O).

Each of R⁶″, R⁷″ and R⁸″ in the formulas —C(═O)—O—R⁶″, —O—C(═O)—R⁷″ and —O—R⁸″ independently represents a hydrogen atom, a saturated hydrocarbon group, or an aliphatic unsaturated hydrocarbon group.

The saturated hydrocarbon group may be linear, branched or cyclic, or may be a combination of any of these structures.

The linear or branched saturated hydrocarbon group preferably contains 1 to 25 carbon atoms, more preferably 1 to 15 carbon atoms, and still more preferably 4 to 10 carbon atoms.

Examples of the linear saturated hydrocarbon group include a methyl group, an ethyl group, a propyl group, a butyl group, a pentyl group, a hexyl group, a heptyl group, an octyl group, a nonyl group and a decyl group.

Examples of the branched saturated hydrocarbon group include the tertiary alkyl groups mentioned above within the description of R⁵⁶. Further, other examples of the branched saturated hydrocarbon group, excluding tertiary alkyl groups, include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The linear or branched saturated hydrocarbon group may have a substituent. Examples of the substituent include an alkoxy group, a halogen atom, a halogenated alkyl group, a hydroxyl group, an oxo group (═O), a cyano group and a carboxyl group.

The alkoxy group as the substituent for the linear or branched saturated hydrocarbon group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent for the linear or branched saturated hydrocarbon group include a fluorine atom, a chlorine atom, a bromine atom and an iodine atom, and a fluorine atom is preferable.

Examples of the halogenated alkyl group as the substituent for the linear or branched saturated hydrocarbon group include groups in which part or all of the hydrogen atoms within an aforementioned linear or branched saturated hydrocarbon group have each been substituted with an aforementioned halogen atom.

The cyclic saturated hydrocarbon group for R⁶″, R⁷″ and R⁸″ preferably contains 3 to 20 carbon atoms. The cyclic saturated hydrocarbon group may be either a polycyclic group or a monocyclic group. Examples include groups in which one hydrogen atom has been removed from a monocycloalkane, and groups in which one hydrogen atom has been removed from a polycycloalkane such as a bicycloalkane, tricycloalkane or tetracycloalkane. More specific examples include groups in which one hydrogen atom has been removed from a monocycloalkane such as cyclopentane, cyclohexane, cycloheptane or cyclooctane, and groups in which one hydrogen atom has been removed from a polycycloalkane such as adamantane, norbornane, isobornane, tricyclodecane or tetracyclododecane.

The cyclic saturated hydrocarbon group may have a substituent. For example, part of the carbon atoms constituting the ring within the cyclic alkyl group may be substituted with a hetero atom, or a hydrogen atom bonded to the ring within the cyclic alkyl group may be substituted with a substituent.

Examples of the former case include groups in which one or more hydrogen atoms have been removed from a heterocycloalkane in which a portion of the carbon atoms that constitute the ring(s) of an aforementioned monocycloalkane or polycycloalkane have been substituted with a hetero atom such as an oxygen atom, a sulfur atom or a nitrogen atom. Further, the ring structure may contain an ester bond (—C(═O)—O—). More specific examples include a lactone-containing monocyclic group, such as a group in which one hydrogen atom has been removed from γ-butyrolactone; and a lactone-containing polycyclic group, such as a group in which one hydrogen atom has been removed from a bicycloalkane, tricycloalkane or tetracycloalkane containing a lactone ring.

In the latter case, examples of the substituent include the same substituents as those described above for the linear or branched saturated hydrocarbon group, and an alkyl group of 1 to 5 carbon atoms.

Further, the saturated hydrocarbon group for R⁶″, R⁷″ and R⁸″ may be a combination of a linear or branched saturated hydrocarbon group and a cyclic saturated hydrocarbon group.

Examples of combinations of a linear or branched saturated hydrocarbon group and a cyclic saturated hydrocarbon group include groups in which a cyclic saturated hydrocarbon group is bonded as a substituent to a linear or branched saturated hydrocarbon group (such as a 1-(1-adamantyl)methyl group), and groups in which a linear or branched saturated hydrocarbon group is bonded as a substituent to a cyclic saturated hydrocarbon group.

The aliphatic unsaturated hydrocarbon group for R⁶″, R⁷″ and R⁸″ is preferably a linear or branched group. Examples of the linear aliphatic unsaturated hydrocarbon group include a vinyl group, a propenyl group (allyl group) and a butynyl group. Examples of the branched aliphatic unsaturated hydrocarbon group include a 1-methylpropenyl group and 2-methylpropenyl group. The linear or branched aliphatic unsaturated hydrocarbon group may have a substituent. Examples of the substituent include the same substituents as those described above which the aforementioned linear or branched alkyl group may have.

Of the various possibilities described above, each of R⁶″, R⁷″ and R⁸″ is preferably a hydrogen atom, a linear or branched saturated hydrocarbon group of 1 to 15 carbon atoms, or a cyclic saturated hydrocarbon group of 3 to 20 carbon atoms, as such groups yield superior lithography properties and resist pattern shape.

The organic group for R⁴ and R⁵ is not particularly limited, and examples thereof include an aryl group which may have a substituent, an alkyl group which may have a substituent, and an alkenyl group which may have a substituent. Among these, an aryl group or alkyl group which may have a substituent is preferred.

Examples of the aryl group which may have a substituent include unsubstituted aryl groups of 6 to 20 carbon atoms, and substituted aryl groups in which part or all of the hydrogen atoms of an aforementioned unsubstituted aryl group have each been substituted with a substituent.

The unsubstituted aryl group is preferably an aryl group having 6 to 10 carbon atoms because it can be synthesized at a low cost. Specific examples thereof include a phenyl group and a naphthyl group.

Examples of the substituent within the substituted aryl group include an alkyl group, an alkoxy group, a halogen atom, a hydroxyl group, an oxo group (═O), an aryl group, an alkoxyalkyloxy group, an alkoxycarbonylalkyloxy group, —C(═O)—O—R⁶′, —O—C(═O)—R⁷′ and —O—R⁸′. Examples of these substituents include the same substituents as those described above as the substituent for the substituted arylene group.

As the aryl group for R⁴ and R⁵, a phenyl group or a naphthyl group is preferred.

Examples of the alkyl group for R⁴ and R⁵ include unsubstituted alkyl groups, and substituted alkyl groups in which part or all of the hydrogen atoms of an aforementioned unsubstituted alkyl group have each been substituted with a substituent.

As the unsubstituted alkyl group, in terms of achieving excellent resolution, an alkyl group of 1 to 5 carbon atoms is preferred. Specific examples include a methyl group, an ethyl group, an n-propyl group, an isopropyl group, an n-butyl group, an isobutyl group, an n-pentyl group, a cyclopentyl group, a hexyl group, a cyclohexyl group, a nonyl group and a decyl group.

Examples of the alkenyl group for R⁴ and R⁵ include unsubstituted alkenyl groups, and substituted alkenyl groups in which part or all of the hydrogen atoms of an aforementioned unsubstituted alkenyl group have each been substituted with a substituent.

The unsubstituted alkenyl group preferably has 2 to 10 carbon atoms, more preferably 2 to 5 carbon atoms, and still more preferably 2 to 4 carbon atoms. Specific examples thereof include a vinyl group, a propenyl group (an allyl group), a butynyl group, a 1-methylpropenyl group and a 2-methylpropenyl group.

Examples of the substituent within the substituted alkyl group and substituted alkenyl group include the same substituents as those mentioned above for the substituent of the aforementioned substituted arylene group.

R⁴ and R⁵ may be bonded to each other to form a ring together with the sulfur atom in the formula. The formed ring may be saturated or unsaturated. Further, the ring may be either monocyclic or polycyclic. For example, if one or both of the R⁴ and R⁵ groups that form the ring are cyclic groups (such as a cyclic alkyl group or aryl group), then a polycyclic ring structure (condensed ring structure) is formed when these groups are bonded to each other.

The ring to be formed that includes the sulfur atom from the formula within the ring structure is preferably a 3- to 10-membered ring, and more preferably a 5- to 7-membered ring, including the sulfur atom.

The atoms that constitute the ring structure of this ring may include another hetero atom besides the sulfur atom bonded to R⁴ and R⁵. Examples of this other hetero atom include a sulfur atom, an oxygen atom and a nitrogen atom.

Specific examples of the ring that is formed include a thiophene ring, thiazole ring, benzothiophene ring, thianthrene ring, dibenzothiophene ring, 9H-thioxanthene ring, thioxanthone ring, phenoxathiin ring, tetrahydrothiophenium ring and tetrahydrothiopyranium ring.

In formula (a0-1), V⁻ represents a counter anion.

The counter anion for V⁻ is not particularly limited, and, for example, any anion moiety can be appropriately used which is conventionally known as an anion moiety of an onium salt-based acid generator.

Examples of V⁻ include anions represented by general formula: R⁴″SO₃⁻.

In the aforementioned general formula: R⁴″SO₃⁻, R⁴″ represents a linear, branched or cyclic alkyl group, a halogenated alkyl group, an aryl group or an alkenyl group which may have a substituent.

The linear or branched alkyl group for R⁴″ preferably has 1 to 10 carbon atoms, more preferably 1 to 8 carbon atoms, and most preferably 1 to 4 carbon atoms.

The cyclic alkyl group for R⁴″ preferably has 4 to 15 carbon atoms, more preferably 4 to 10 carbon atoms, and most preferably 6 to 10 carbon atoms.

Examples of R⁴″SO₃⁻ when R⁴″ represents an alkyl group include an alkyl sulfonate such as methanesulfonate, n-propanesulfonate, n-butanesulfonate, n-octanesulfonate, 1-adamantanesulfonate, 2-norbornanesulfonate and d-camphor-10-sulfonate.

The halogenated alkyl group for R⁴″ is a group in which part or all of the hydrogen atoms in the alkyl group has been substituted with a halogen atom, and the alkyl group is preferably an alkyl group of 1 to 5 carbon atoms, more preferably a linear or branched alkyl group, and still more preferably a methyl group, an ethyl group, a propyl group, an isopropyl group, an n-butyl group, a tert-butyl group, a tert-pentyl group or an isopentyl group. Further, examples of the halogen atom that substitutes the hydrogen atoms include a fluorine atom, a chlorine atom, an iodine atom and a bromine atom.

In the halogenated alkyl group, it is preferable that 50 to 100% of the total number of hydrogen atoms of the alkyl group (alkyl group prior to halogenation) are substituted with halogen atoms, and it is more preferable that all of the hydrogen atoms are substituted with halogen atoms.

Here, the halogenated alkyl group is preferably a fluorinated alkyl group.

The fluorinated alkyl group preferably has 1 to 10 carbon atoms, more preferably 1 to 8 carbon atoms, and most preferably 1 to 4 carbon atoms.

Further, the fluorination ratio of the fluorinated alkyl group is preferably from 10 to 100%, more preferably from 50 to 100%, and it is particularly desirable that all hydrogen atoms are substituted with fluorine atoms because the acid strength increases.

Specific examples of preferred fluorinated alkyl groups include a trifluoromethyl group, a heptafluoro-n-propyl group and a nonafluoro-n-butyl group.

The aryl group for R⁴″ is preferably an aryl group of 6 to 20 carbon atoms.

The alkenyl group for R⁴″ is preferably an alkenyl group of 2 to 10 carbon atoms.

With respect to R⁴″, the expression “may have a substituent” means that part of or all of the hydrogen atoms within the aforementioned linear, branched or cyclic alkyl group, halogenated alkyl group, aryl group or alkenyl group may be substituted with substituents (atoms other than hydrogen atoms, or groups).

R⁴ may have one substituent, or two or more substituents.

Examples of the substituent include a halogen atom, a hetero atom, an alkyl group, and a group represented by the formula X³-Q′- (wherein Q′ represents a divalent linking group containing an oxygen atom, and X³ represents a hydrocarbon group of 3 to 30 carbon atoms which may have a substituent).

Examples of the halogen atom and alkyl group include the same halogen atoms and alkyl groups as those described above with respect to the halogenated alkyl group for R⁴″.

Examples of the hetero atom include an oxygen atom, a nitrogen atom, and a sulfur atom.

In the group represented by formula X³-Q′-, Q′ represents a divalent linking group containing an oxygen atom.

Q′ may contain an atom other than an oxygen atom. Examples of atoms other than an oxygen atom include a carbon atom, a hydrogen atom, a sulfur atom and a nitrogen atom.

Examples of the divalent linking groups containing an oxygen atom include non-hydrocarbon, oxygen atom-containing linking groups such as an oxygen atom (an ether bond; —O—), an ester bond (—C(═O)—O—), an amide bond (—C(═O)—NH—), a carbonyl group (—C(═O)—) and a carbonate bond (—O—C(═O)—O—); and combinations of the aforementioned non-hydrocarbon, oxygen atom-containing linking groups with an alkylene group. A sulfonyl group (—SO₂—) may be further connected to such combinations.

Specific examples of the combinations of the aforementioned non-hydrocarbon, hetero atom-containing linking groups and an alkylene group include —R⁹¹—O—, —R⁹²—O—C(═O)—, —C(═O)—O—R⁹³—O—C(═O)—, —SO₂—O—R⁹⁴—O—C(═O)—, —R⁹⁵—SO₂—O—R⁹⁴—O—C(═O)— (in the formulas, each of R⁹¹ to R⁹⁵ independently represents an alkylene group).

The alkylene group for R⁹¹ to R⁹⁵ is preferably a linear or branched alkylene group, and preferably has 1 to 12 carbon atoms, more preferably 1 to 5 carbon atoms, and most preferably 1 to 3 carbon atoms.

Specific examples of the alkylene group include a methylene group [—CH₂—], alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)— and —C(CH₂CH₃)₂—, an ethylene group [—CH₂CH₂—], alkylethylene groups such as —CH(CH₃)CH₂—, —CH(CH₃)CH(CH₃)—, —C(CH₃)₂CH₂— and —CH(CH₂CH₃)CH₂—, a trimethylene group (n-propylene group) [—CH₂CH₂CH₂—], alkyltrimethylene groups such as —CH(CH₃)CH₂CH₂— and —CH₂CH(CH₃)CH₂—, a tetramethylene group [—CH₂CH₂CH₂CH₂—], alkyltetramethylene groups such as —CH(CH₃)CH₂CH₂CH₂— and —CH₂CH(CH₃)CH₂CH₂—, and a pentamethylene group [—CH₂CH₂CH₂CH₂CH₂—].

Q′ is preferably a divalent linking group containing an ester bond or ether bond, and is more preferably a group represented by —R⁹¹—O—, —R⁹²—O—C(═O)— or —C(═O)—O—R⁹³—O—C(═O)—.

In the group represented by the formula X³-Q′-, the hydrocarbon group for X³ may be either an aromatic hydrocarbon group or an aliphatic hydrocarbon group.

The aromatic hydrocarbon group is a hydrocarbon group having an aromatic ring. The aromatic hydrocarbon group preferably has 5 to 30 carbon atoms, more preferably 5 to 20 carbon atoms, still more preferably 6 to 15 carbon atoms, and most preferably 6 to 12 carbon atoms. Here, the number of carbon atoms does not include any carbon atoms within any substituent(s).

Specific examples of aromatic hydrocarbon groups include an aryl group which is an aromatic hydrocarbon ring having one hydrogen atom removed therefrom, such as a phenyl group, a biphenyl group, a fluorenyl group, a naphthyl group, an anthryl group or a phenanthryl group; and an arylalkyl group such as a benzyl group, a phenethyl group, a 1-naphthylmethyl group, a 2-naphthylmethyl group, a 1-naphthylethyl group, or a 2-naphthylethyl group. The alkyl chain within the arylalkyl group preferably has 1 to 4 carbon atoms, more preferably 1 or 2 carbon atoms, and most preferably 1 carbon atom.

The aromatic hydrocarbon group may have a substituent. For example, a portion of the carbon atoms that constitute the aromatic ring within the aromatic hydrocarbon group may be substituted with a hetero atom, or a hydrogen atom bonded to the aromatic ring within the aromatic hydrocarbon group may be substituted with a substituent.

In the former example, a heteroaryl group in which part of the carbon atoms constituting the ring within the aforementioned aryl group has been substituted with a hetero atom such as an oxygen atom, a sulfur atom or a nitrogen atom, and a heteroarylalkyl group in which part of the carbon atoms constituting the aromatic hydrocarbon ring within the aforementioned arylalkyl group has been substituted with the aforementioned hetero atom can be used.

In the latter example, as the substituent for the aromatic hydrocarbon group, an alkyl group, an alkoxy group, a halogen atom, a halogenated alkyl group, a hydroxyl group, an oxygen atom (═O) or the like can be used.

The alkyl group as the substituent for the aromatic hydrocarbon group is preferably an alkyl group of 1 to 5 carbon atoms, and a methyl group, an ethyl group, a propyl group, an n-butyl group or a tert-butyl group is particularly desirable.

The alkoxy group as the substituent for the aromatic hydrocarbon group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the halogen atom as the substituent for the aromatic hydrocarbon group include a fluorine atom, a chlorine atom, a bromine atom and an iodine atom, and a fluorine atom is preferable.

Example of the halogenated alkyl group as the substituent for the aromatic hydrocarbon group includes a group in which part or all of the hydrogen atoms within the aforementioned alkyl group have been substituted with the aforementioned halogen atoms.

The aliphatic hydrocarbon group for X³ may be either a saturated aliphatic hydrocarbon group or an unsaturated aliphatic hydrocarbon group. Further, the aliphatic hydrocarbon group may be linear, branched or cyclic.

In the aliphatic hydrocarbon group for X³, a portion of the carbon atoms that constitute the aliphatic hydrocarbon group may be substituted with a substituent containing a hetero atom, or part or all of the hydrogen atoms that constitute the aliphatic hydrocarbon group may each be substituted with a substituent containing a hetero atom.

As the “hetero atom” for X³, there is no particular limitation as long as it is an atom other than a carbon atom and a hydrogen atom, and examples thereof include a halogen atom, an oxygen atom, a sulfur atom and a nitrogen atom.

Examples of the halogen atom include a fluorine atom, a chlorine atom, an iodine atom and a bromine atom.

The substituent containing a hetero atom may consist solely of the hetero atom, or may be a group that also contains a group or atom other than the hetero atom.

Specific examples of the substituent for substituting part of the carbon atoms include —O—, —C(═O)—O—, —C(═O)—, —O—C(═O)—O—, —C(═O)—NH—, —NH— (the H may be replaced with a substituent such as an alkyl group or an acyl group), —S—, —S(═O)₂— and —S(═O)₂—O—. When the aliphatic hydrocarbon group is cyclic, any of these substituents may be included within the ring structure of the aliphatic hydrocarbon group.

Specific examples of the substituent for substituting part or all of the hydrogen atoms include an alkoxy group, a halogen atom, a halogenated alkyl group, a hydroxyl group, an oxygen atom (═O) and a cyano group.

The aforementioned alkoxy group is preferably an alkoxy group having 1 to 5 carbon atoms, more preferably a methoxy group, an ethoxy group, an n-propoxy group, an iso-propoxy group, an n-butoxy group or a tert-butoxy group, and most preferably a methoxy group or an ethoxy group.

Examples of the aforementioned halogen atom include a fluorine atom, a chlorine atom, a bromine atom and an iodine atom, and a fluorine atom is preferable.

Example of the aforementioned halogenated alkyl group includes a group in which part or all of the hydrogen atoms within an alkyl group of 1 to 5 carbon atoms (e.g., a methyl group, an ethyl group, a propyl group, an n-butyl group or a tert-butyl group) has been substituted with the aforementioned halogen atoms.

As the aliphatic hydrocarbon group, a linear or branched saturated hydrocarbon group, a linear or branched monovalent unsaturated hydrocarbon group, or a cyclic aliphatic hydrocarbon group (aliphatic cyclic group) is preferable.

The linear saturated hydrocarbon group (alkyl group) preferably contains 1 to 20 carbon atoms, more preferably 1 to 15 carbon atoms, and most preferably 1 to 10 carbon atoms. Specific examples include a methyl group, an ethyl group, a propyl group, a butyl group, a pentyl group, a hexyl group, a heptyl group, an octyl group, a nonyl group, a decyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecyl group, an icosyl group, a henicosyl group and a docosyl group.

The branched saturated hydrocarbon group (alkyl group) preferably contains 3 to 20 carbon atoms, more preferably 3 to 15 carbon atoms, and most preferably 3 to 10 carbon atoms. Specific examples include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group and a 4-methylpentyl group.

The unsaturated hydrocarbon group preferably contains 2 to 10 carbon atoms, more preferably 2 to 5 carbon atoms, still more preferably 2 to 4 carbon atoms, and most preferably 3 carbon atoms. Examples of linear monovalent unsaturated hydrocarbon groups include a vinyl group, a propenyl group (an allyl group) and a butynyl group. Examples of branched monovalent unsaturated hydrocarbon groups include a 1-methylpropenyl group and a 2-methylpropenyl group.

Among the above-mentioned examples, as the unsaturated hydrocarbon group, a propenyl group is particularly desirable.

The aliphatic cyclic group may be either a monocyclic group or a polycyclic group. The aliphatic cyclic group preferably contains 3 to 30 carbon atoms, more preferably 5 to 30 carbon atoms, still more preferably 5 to 20 carbon atoms, still more preferably 6 to 15 carbon atoms, and most preferably 6 to 12 carbon atoms.

Examples of the aliphatic cyclic group include groups in which one or more hydrogen atoms have been removed from a monocycloalkane, or a polycycloalkane such as a bicycloalkane, tricycloalkane or tetracycloalkane. Specific examples include groups in which one or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

When the aliphatic cyclic group does not contain a hetero atom-containing substituent group in the ring structure thereof, the aliphatic cyclic group is preferably a polycyclic group, more preferably a group in which one or more hydrogen atoms have been removed from a polycycloalkane, and a group in which one or more hydrogen atoms have been removed from adamantane is particularly desirable.

When the aliphatic cyclic group contains a hetero atom-containing substituent group in the ring structure thereof, the hetero atom-containing substituent group is preferably —O—, —C(═O)—O—, —S—, —S(═O)₂— or —S(═O)₂—O—. Specific examples of such aliphatic cyclic groups include groups represented by formulas (L1) to (L6) and (S1) to (S4) shown below.

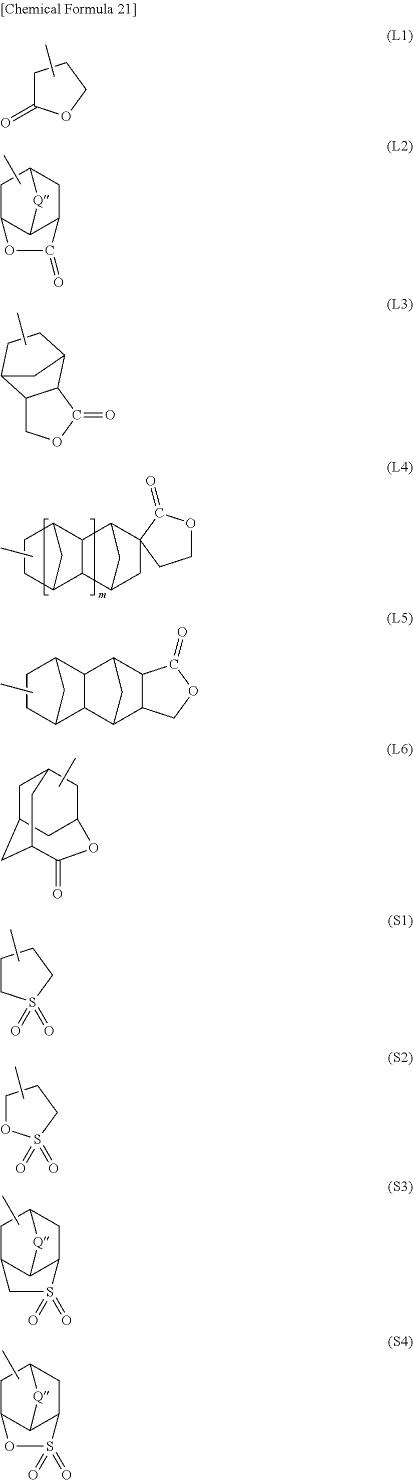

In the formulas, Q″ represents an alkylene group of 1 to 5 carbon atoms, —O—, —S—, —O—R⁹⁴′— or —S—R⁹⁵′— (wherein each of R⁹⁴′ and R⁹⁵′ independently represents an alkylene group of 1 to 5 carbon atoms); and m represents an integer of 0 or 1.

Examples of the alkylene groups for Q″, R⁹⁴′ and R⁹⁵′ include the same alkylene groups as those described above for R⁹¹ to R⁹⁵.

In these aliphatic cyclic groups, part of the hydrogen atoms bonded to the carbon atoms that constitute the ring structure may each be substituted with a substituent. Examples of the substituent include an alkyl group, an alkoxy group, a halogen atom, a halogenated alkyl group, a hydroxyl group and an oxygen atom (═O).

As the alkyl group, an alkyl group of 1 to 5 carbon atoms is preferable, and a methyl group, an ethyl group, a propyl group, an n-butyl group or a tert-butyl group is particularly desirable.

Examples of the alkoxy group, the halogen atom and halogenated alkyl group include the same groups and atoms as those listed above for the substituent used for substituting part or all of the aforementioned hydrogen atoms.

In the present invention, X³ is preferably a cyclic group which may have a substituent. This cyclic group may be either an aromatic hydrocarbon group which may have a substituent, or an aliphatic cyclic group which may have a substituent, although an aliphatic cyclic group which may have a substituent is preferable.

As the aromatic hydrocarbon group, a naphthyl group which may have a substituent or a phenyl group which may have a substituent is preferable.

As the aliphatic cyclic group which may have a substituent, a polycyclic aliphatic cyclic group which may have a substituent is preferable. As the aliphatic polycyclic group, the aforementioned group in which one or more hydrogen atoms have been removed from a polycycloalkane, and groups represented by the aforementioned formulas (L2) to (L6), (S3) and (S4) are preferable.

Of the various possibilities described above, R⁴″ is preferably a halogenated alkyl group or has a group represented by the formula X³-Q′- as a substituent.

When R⁴″ has X³-Q′- as a substituent, R⁴″ is preferably a group represented by the formula X³-Q′-Y³— (in the formula, Q′ and X³ are the same as defined above; and Y³ represents an alkylene group of 1 to 4 carbon atoms which may have a substituent, or a fluorinated alkylene group of 1 to 4 carbon atoms which may have a substituent).

In the group represented by the formula X³-Q′-Y³—, as the alkylene group for Y³, the same alkylene group as those described above for Q′ in which the number of carbon atoms is 1 to 4 can be used.

As the fluorinated alkylene group, the aforementioned alkylene group in which part or all of the hydrogen atoms has been substituted with fluorine atoms can be used.

Specific examples of Y³ include —CF₂—, —CF₂CF₂—, —CF₂CF₂CF₂—, —CF(CF₃)CF₂—, —CF(CF₂CF₃)—, —C(CF₃)₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CF(CF₂CF₂CF₃)—, —C(CF₃)(CF₂CF₃)—; —CHF—, —CH₂CF₂—, —CH₂CH₂CF₂—, —CH₂CF₂CF₂—, —CH(CF₃)CH₂—, —CH(CF₂CF₃)—, —C(CH₃)(CF₃)—, —CH₂CH₂CH₂CF₂—, —CH₂CH₂CF₂CF₂—, —CH(CF₃)CH₂CH₂—, —CH₂CH(CF₃)CH₂—, —CH(CF₃)CH(CF₃)—, —C(CF₃)₂CH₂—; —CH₂—, —CH₂CH₂—, —CH₂CH₂CH₂—, —CH(CH₃)CH₂—, —CH(CH₂CH₃)—, —C(CH₃)₂—, —CH₂CH₂CH₂CH₂—, —CH(CH₃)CH₂CH₂—, —CH₂CH(CH₃)CH₂—, —CH(CH₃)CH(CH₃)—, —C(CH₃)₂CH₂—, —CH(CH₂CH₃)CH₂—, —CH(CH₂CH₂CH₃)—, and —C(CH₃)(CH₂CH₃)—.

Y³ is preferably a fluorinated alkylene group, and particularly preferably a fluorinated alkylene group in which the carbon atom bonded to the adjacent sulfur atom is fluorinated. Examples of such fluorinated alkylene groups include —CF₂—, —CF₂CF₂—, —CF₂CF₂CF₂—, —CF(CF₃)CF₂—, —CF₂CF₂CF₂CF₂—, —CF(CF₃)CF₂CF₂—, —CF₂CF(CF₃)CF₂—, —CF(CF₃)CF(CF₃)—, —C(CF₃)₂CF₂—, —CF(CF₂CF₃)CF₂—, —CH₂CF₂—, —CH₂CH₂CF₂—, —CH₂CF₂CF₂—, —CH₂CH₂CH₂CF₂—, —CH₂CH₂CF₂CF₂— and —CH₂CF₂CF₂CF₂—.

Of these, —CF₂—, —CF₂CF₂—, —CF₂CF₂CF₂— or CH₂CF₂CF₂— is preferable, —CF₂—, —CF₂CF₂— or —CF₂CF₂CF₂— is more preferable, and —CF₂— is particularly desirable.

The alkylene group or fluorinated alkylene group may have a substituent. The expression that the alkylene group or fluorinated alkylene group “may have a substituent” means that part or all of the hydrogen atoms or fluorine atoms in the alkylene group or fluorinated alkylene group may each be substituted, either with an atom other than a hydrogen atom or fluorine atom, or with a group.

Examples of substituents which the alkylene group or fluorinated alkylene group may have include an alkyl group of 1 to 4 carbon atoms, an alkoxy group of 1 to 4 carbon atoms, and a hydroxyl group.

Specific examples of R⁴″—SO₃⁻ in which R⁴″ is a group represented by the formula X³-Q′-Y³— include anions represented by any one of formulas (b1) to (b9) shown below.

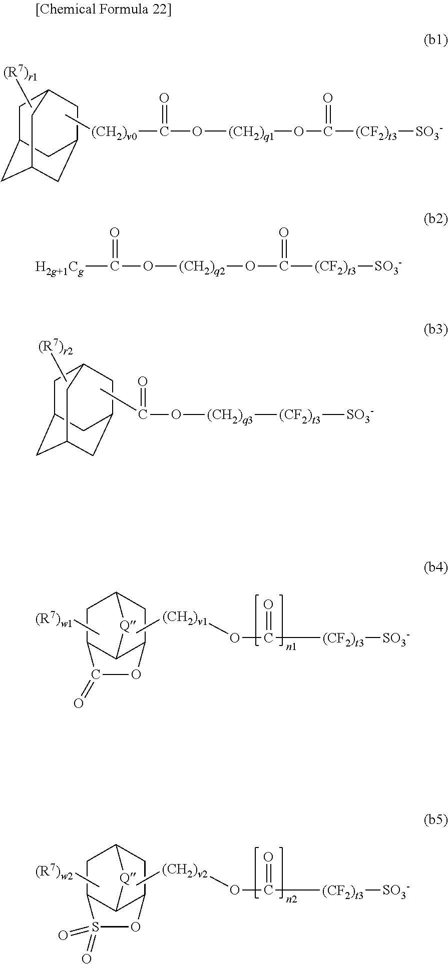

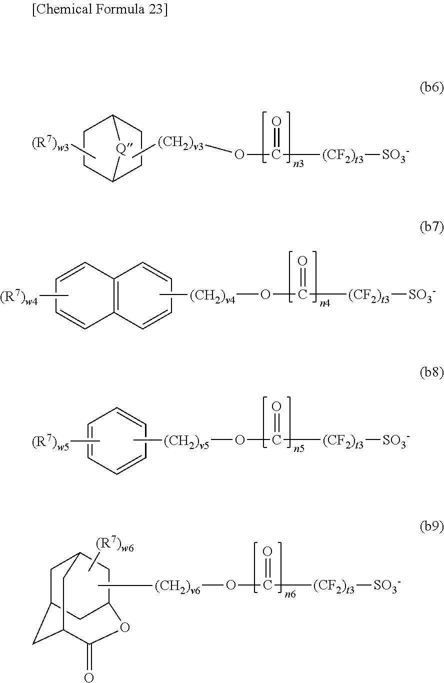

In the formulas, each of q1 and q2 independently represents an integer of 1 to 5; q3 represents an integer of 1 to 12; t3 represents an integer of 1 to 3; each of r1 and r2 independently represents an integer of 0 to 3; g represents an integer of 1 to 20; R⁷ represents a substituent; each of n1 to n6 independently represents 0 or 1; each of v0 to v6 independently represents an integer of 0 to 3; each of w1 to w6 independently represents an integer of 0 to 3; and Q″ is the same as defined above.

Examples of the substituent for R⁷ include the same substituents as those described above which may substitute part of the hydrogen atom bonded to the carbon atom constituting the ring structure of the aliphatic cyclic group, or those described above which may substitute the hydrogen atom bonded to the aromatic ring within the aromatic hydrocarbon group, with respect to X³.

If there are two or more of the R⁷ group, as indicated by the values r1, r2, and w1 to w6, then the two or more of the R⁷ groups may be the same or different from each other.

Further, in formula (a0-1), as V⁻, anions represented by general formula (b-3) shown below and anions represented by general formula (b-4) shown below may also be used.

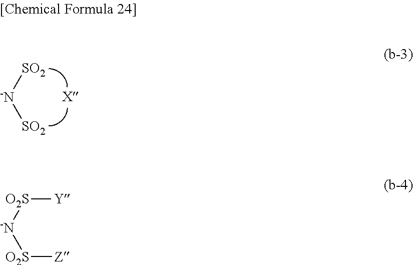

In the formulas, X″ represents an alkylene group of 2 to 6 carbon atoms in which at least one hydrogen atom has been substituted with a fluorine atom; and each of Y″ and Z″ independently represents an alkyl group of 1 to 10 carbon atoms in which at least one hydrogen atom has been substituted with a fluorine atom.

In formula (b-3), X″ represents a linear or branched alkylene group in which at least one hydrogen atom has been substituted with a fluorine atom, and the alkylene group preferably has 2 to 6 carbon atoms, more preferably 3 to 5 carbon atoms, and most preferably 3 carbon atoms.

In formula (b-4), each of Y″ and Z″ independently represents a linear or branched alkyl group in which at least one hydrogen atom has been substituted with a fluorine atom, and the alkyl group preferably has 1 to 10 carbon atoms, more preferably 1 to 7 carbon atoms, and most preferably 1 to 3 carbon atoms.

The smaller the number of carbon atoms of the alkylene group for X″ or those of the alkyl group for Y″ and Z″ within the above-mentioned range of the number of carbon atoms, the more the solubility in a resist solvent is improved.

Further, in the alkylene group for X″ or the alkyl group for Y″ and Z″, it is preferable that the number of hydrogen atoms substituted with fluorine atoms is as large as possible because the acid strength increases and the transparency to high energy radiation of 200 nm or less or electron beam is improved.

The fluorination ratio of the alkylene group or alkyl group is preferably from 70 to 100%, more preferably from 90 to 100%, and it is particularly desirable that the alkylene group or alkyl group be a perfluoroalkylene group or perfluoroalkyl group in which all hydrogen atoms are substituted with fluorine atoms.

In formula (a0-1), as V⁻, anions represented by general formula: R⁴″SO₃⁻ (in particular, anions represented by the above formulas (b1) to (b9) in which R⁴″ is a group represented by the formula X³-Q′-Y³—) are preferred.

Specific examples of groups represented by formula (a0-1) are shown below.

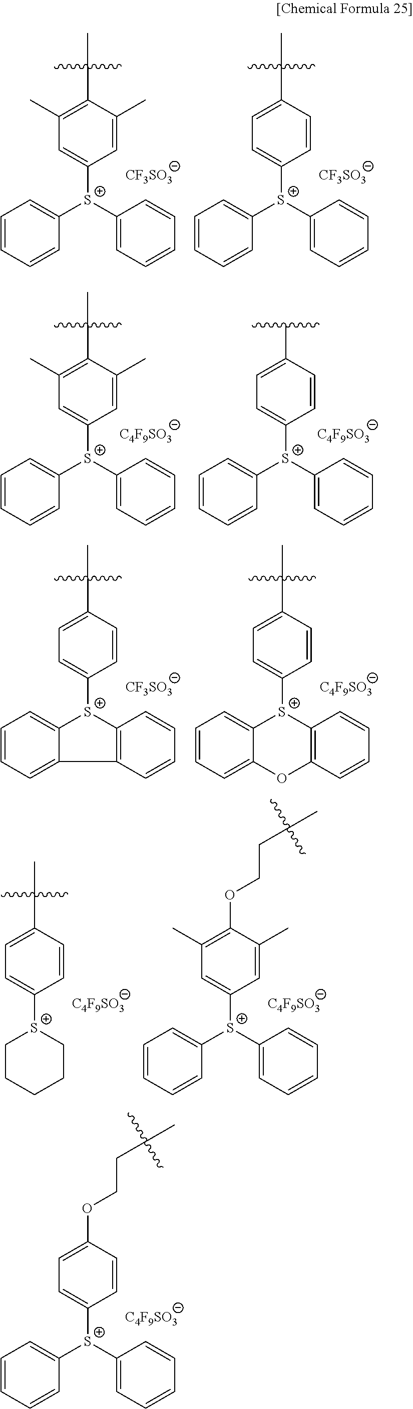

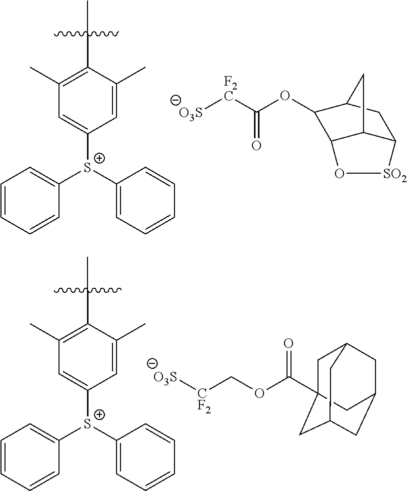

As the structural unit having a group represented by the above formula (a0-1) (hereafter, referred to as “structural unit (a0-1)”), structural units represented by formula (a0-11) shown below are preferred.

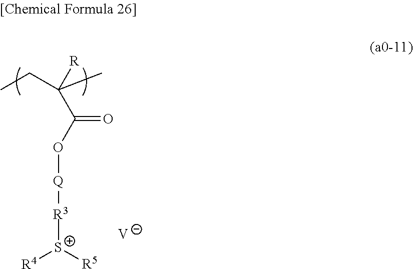

In the formula, R represents a hydrogen atom, an alkyl group of 1 to 5 carbon atoms or a halogenated alkyl group of 1 to 5 carbon atoms; and Q¹, R³ to R⁵ and V⁻ are the same as defined above.

In formula (a0-11), the alkyl group for R is preferably a linear or branched alkyl group, and specific examples thereof include a methyl group, an ethyl group, a propyl group, an isopropyl group, an n-butyl group, an isobutyl group, a tert-butyl group, a pentyl group, an isopentyl group and a neopentyl group.

Examples of the halogenated alkyl group for R include groups in which part or all of the hydrogen atoms within the aforementioned alkyl group for R has been substituted with a halogen atom. Examples of the halogen atom include a fluorine atom, a chlorine atom, a bromine atom and an iodine atom, and a fluorine atom is particularly desirable.

As R, a hydrogen atom, an alkyl group of 1 to 5 carbon atoms or a fluorinated alkyl group of 1 to 5 carbon atoms is preferable, and a hydrogen atom or a methyl group is particularly desirable.

In formula (a0-11), Q¹, R³ to R⁵ and V⁻ are the same as defined above.

(Structural Unit Having a Group Represented by Formula (a0-2))

In the above formula (a0-2), Q² represents a single bond or a divalent linking group. Examples of the divalent linking group for Q² include the same groups as those described above as the divalent linking group for L⁰¹ in the formula (I-1).

In particular, as Q² in the present invention, a single bond, a linear or branched alkylene group, an ester bond [—C(═O)—O—], or a combination thereof is preferred.

In formula (a0-2), A⁻ represents an organic group containing an anion.

A⁻ is not particularly limited as long as it includes a portion which is generated upon exposure to form an acid anion, although a group capable of generating a sulfonate anion, carbanion, carboxylate anion, sulfonylimide anion, bis(alkylsulfonyl)imide anion and tris(alkylsulfonyl)methide anion) is preferred.

In particular, as A⁻, groups represented by (a0-2-an1) to (a0-2-an5) shown below are preferred.

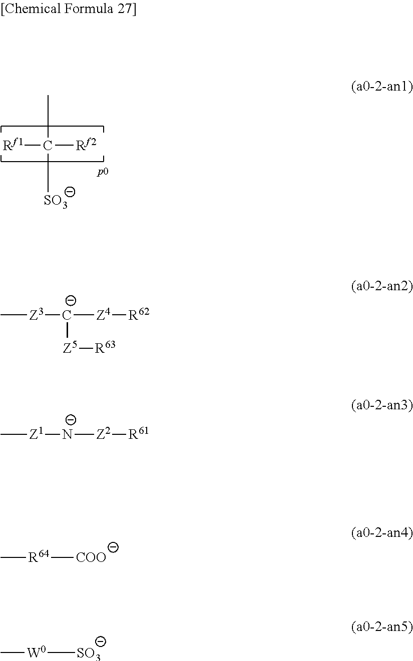

In the formulas, each of R^{f1} and R^{f2} independently represents a hydrogen atom, an alkyl group, a fluorine atom or a fluorinated alkyl group, provided that at least one of R^{f1} and R^{f2} represents a fluorine atom or a fluorinated alkyl group; p0 represents an integer of 1 to 8; Z³ represents —C(═O)—O—, —SO₂— or a hydrocarbon group which may have a substituent; each of Z⁴ and Z⁵ independently represents —C(═O)— or —SO₂—; each of R⁶² and R⁶³ independently represents a hydrocarbon group which may have a fluorine atom; Z¹ represents —C(═O)—, —SO₂—, —C(═O)—O— or a single bond; Z² represents —C(═O)— or —SO₂—; R⁶¹ represents a hydrocarbon group which may have a fluorine atom; R⁶⁴ represents a hydrocarbon group which may have a fluorine atom; W⁰ represents a hydrocarbon group of 1 to 30 carbon atoms which may have a substituent (with the provision that the carbon atom adjacent to S is not substituted with a fluorine atom).

In formula (a0-2-an1), each of R^{f1} and R^{f2} independently represents a hydrogen atom, an alkyl group, a fluorine atom or a fluorinated alkyl group, provided that at least one of R^{f1} and R^{f2} represents a fluorine atom or a fluorinated alkyl group.

The alkyl group for R^{f1} and R^{f2} is preferably an alkyl group of 1 to 5 carbon atoms, and specific examples thereof include a methyl group, an ethyl group, a propyl group, an isopropyl group, an n-butyl group, an isobutyl group, a tert-butyl group, a pentyl group, an isopentyl group and a neopentyl group.

The fluorinated alkyl group for R^{f1} and R^{f2} is preferably a group in which part or all of the hydrogen atoms within an aforementioned alkyl group for R^{f1} and R^{f2} have each been substituted with a fluorine atom.

As R^{f1} and R^{f2}, a fluorine atom or a fluorinated alkyl group is preferred.

In formula (a0-an1), p0 represents an integer of 1 to 8, preferably an integer of 1 to 4, and more preferably 1 or 2.

In formula (a0-2-an2), Z³ represents —C(═O)—O—, —SO₂— or a hydrocarbon group which may have a substituent. Examples of the hydrocarbon group for Z³ which may have a substituent include the same groups as those described above as the “divalent hydrocarbon group which may have a substituent” within the description of the divalent linking group for L⁰¹ in the formula (I-1). Of these, Z³ is preferably —SO₂—.

In formula (a0-2-an2), each of Z⁴ and Z⁵ independently represents —C(═O)— or —SO₂—. It is preferable that at least one of Z⁴ and Z⁵ represent —SO₂—, and it is more preferable that both of Z⁴ and Z⁵ represent —SO₂—.

Each of R⁶² and R⁶³ independently represents a hydrocarbon group which may have a fluorine atom, and examples thereof include the same groups as those hydrocarbon groups which may have a fluorine atom for R⁶¹ which will be described later.

In formula (a0-2-an3), Z¹ represents —C(═O)—, —SO₂—, —C(═O)—O— or a single bond. If Z¹ represents a single bond, it is preferable that N⁻ in the formula does not directly bind to —C(═O)— on the side (that is, the left end in the formula) opposite to the side on which Z² is bound.

In formula (a0-2-an3), Z² represents —C(═O)— or —SO₂—, and is preferably —SO₂—.

R⁶¹ represents a hydrocarbon group which may have a fluorine atom. Examples of the hydrocarbon group for R⁶¹ include an alkyl group, a monovalent alicyclic hydrocarbon group, an aryl group or an aralkyl group.

The alkyl group for R⁶¹ preferably has 1 to 8 carbon atoms, more preferably 1 to 6 carbon atoms, still more preferably 1 to 4 carbon atoms, and may be linear or branched. More specifically, preferred examples include a methyl group, an ethyl group, a propyl group, a butyl group, a hexyl group and an octyl group.

The monovalent alicyclic hydrocarbon group for R⁶¹ preferably has 3 to 20 carbon atoms, more preferably 3 to 12 carbon atoms, and may be a polycyclic group or a monocyclic group. As the monocyclic alicyclic hydrocarbon group, a group in which one or more hydrogen atoms have been removed from a monocycloalkane is preferred. The monocycloalkane preferably contains 3 to 6 carbon atoms, and specific examples thereof include cyclobutane, cyclopentane and cyclohexane. As the polycyclic alicyclic hydrocarbon group, a group in which one or more hydrogen atoms have been removed from a polycycloalkane is preferable, and the polycycloalkane preferably contains 7 to 12 carbon atoms. Specific examples of the polycycloalkane include adamantane, norbornane, isobornane, tricyclodecane and tetracyclododecane.

The aryl group for R⁶¹ preferably has 6 to 18 carbon atoms, more preferably 6 to 10 carbon atoms, and more specifically, a phenyl group is particularly desirable.

Preferred examples of the aralkyl groups for R⁶¹ include those in which an alkylene group of 1 to 8 carbon atoms and one of the “aryl groups for R⁶¹” described above are bonded. An aralkyl group in which an alkylene group of 1 to 6 carbon atoms and one of the “aryl groups for R⁶¹” described above are bonded is more preferred, and an aralkyl group in which an alkylene group of 1 to 4 carbon atoms and one of the “aryl groups for R⁶¹” described above are bonded is particularly desirable.

The hydrocarbon group for R⁶¹ is preferably a group in which part or all of the hydrogen atoms in the hydrocarbon group has been substituted with a fluorine atom, and more preferably a group in which 30 to 100% of the hydrogen atoms in the hydrocarbon group have been substituted with a fluorine atom. Among these examples, a perfluoroalkyl group in which all of the hydrogen atoms within the alkyl group described above have been substituted with a fluorine atom is particularly desirable.

In formula (a0-2-an4), R⁶⁴ represents a hydrocarbon group which may have a fluorine atom. Examples of the hydrocarbon group for R⁶⁴ include an alkylene group, a divalent alicyclic hydrocarbon group, a group in which one or more hydrogen atoms have been removed from an aryl group, and a group in which one or more hydrogen atoms have been removed from an aralkyl group.

Specific examples of the hydrocarbon group for R⁶⁴ include groups in which one or more hydrogen atoms have been removed from those listed above within the description of the hydrocarbon group for R⁶¹ (such as alkyl groups, monovalent alicyclic hydrocarbon groups, aryl groups and aralkyl groups).

The hydrocarbon group for R⁶⁴ is preferably a group in which part or all of the hydrogen atoms in the hydrocarbon group has been substituted with a fluorine atom, and more preferably a group in which 30 to 100% of the hydrogen atoms in the hydrocarbon group have been substituted with a fluorine atom.

In formula (a0-2-an5), W⁰ represents a hydrocarbon group of 1 to 30 carbon atoms which may have a substituent.

The hydrocarbon group of 1 to 30 carbon atoms for W⁰ which may have a substituent may be either an aliphatic hydrocarbon group or an aromatic hydrocarbon group, and the same aliphatic hydrocarbon groups and aromatic hydrocarbon groups as those described above within the description of the divalent linking group for L⁰¹ in the formula (I-1) can be used.

Among these, as the hydrocarbon group for W⁰ which may have a substituent, an aliphatic cyclic group which may have a substituent is preferable, and a group in which two or more hydrogen atoms have been removed from adamantane, norbornane, isobornane, tricyclodecane, tetracyclododecane or camphor (which may have a substituent) is more preferable.

If A⁻ includes a group represented by formulas (a0-2-an1) and (a0-2-an2) or a group represented by formula (a0-2-an3) in which Z¹ represents —C(═O)—O— or a single bond, it is possible to generate a relatively strong acid such as fluorinated alkylsulfonate anion and carbanion from the component (C) by exposure.

On the other hand, if A⁻ includes a group represented by formulas (a0-2-an4) and (a0-2-an5) or a group represented by formula (a0-2-an3) in which Z′ represents —C(═O)—O— or —SO₂—, it is possible to generate a relatively weak acid such as alkylsulfonate anion and carboxylate anion from the component (C) by exposure.

Because it is possible to generate an acid having a desired acid strength of the from the structural unit (a0) as described above, it is possible to appropriately determine the function of the acid generated from the structural unit (a0) in the resist composition, and A⁻ can also be selected in accordance with the desired function.

For example, if the structural unit (a0) is responsible for the role similar to that of an acid generator typically used in the resist composition, it is preferable to select A⁻ which generates a strong acid.

Further, for example, when the structural unit (a0) is responsible for the function similar to that of a quencher typically used in the resist composition (quenchers that trap a strong acid by means of salt exchange with the strong acid generated from an acid generator), it is preferable to select A⁻ which generates a weak acid.

The expressions “strong acid” and “weak acid” used herein are those determined in relation to the activation energy of an acid decomposable group that is decomposed by the action of an acid, such as those included in the structural unit (a1) which will be described later, or in relation to the acid strength of the acid generator to be used in combination. Therefore, the aforementioned “relatively weak acid” cannot always be used as a quencher.

In formula (a0-2), M^{m+} represents a counter cation, and m represents an integer of 1 to 3.

As the counter cation for M^{m+}, an organic cation is preferred. The organic cation is not particularly limited, and, for example, photodegradable bases conventionally used in the quenchers for resist compositions or organic cations known as a cation moiety in the onium-based acid generators for resist compositions can be used. As an organic cation, for example, cations represented by general formula (m-1) or (m-2) shown below can be used.

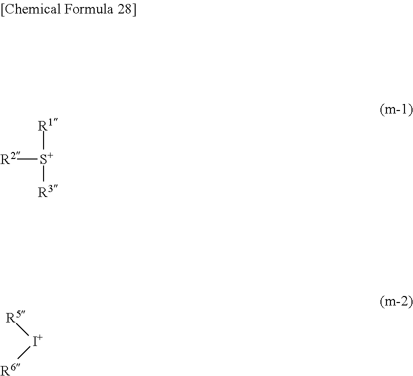

In the formulas, each of R¹″ to R³″ and R⁵″ and R⁶″ independently represents an aryl group, alkyl group or alkenyl group which may have a substituent. In formula (m-1), two of R¹″ to R³″ may be bonded to each other to form a ring with the sulfur atom in the formula.

In the aforementioned formula (m-1), examples of the aryl group which may have a substituent, the alkyl group which may have a substituent, and the alkenyl group which may have a substituent for R¹″ to R³″ include the same aryl groups, alkyl groups and alkenyl groups as those mentioned above within the description of R⁴ and R⁵ in the aforementioned general formula (a0-1).

When two of R¹″ to R³″ in formula (m-1) are bonded to each other to form a ring with the sulfur atom in the formula, examples of the ring to be formed include the same rings as those described above as the ring formed by the bonding of R⁴ and R⁵ in the aforementioned general formula (a0-1) with the sulfur atom in the formula.

Specific examples of preferred cation moieties for the compound represented by the above formula (m-1) include the cation moieties represented by formulas (m1-1-1) to (m1-1-33) shown below.

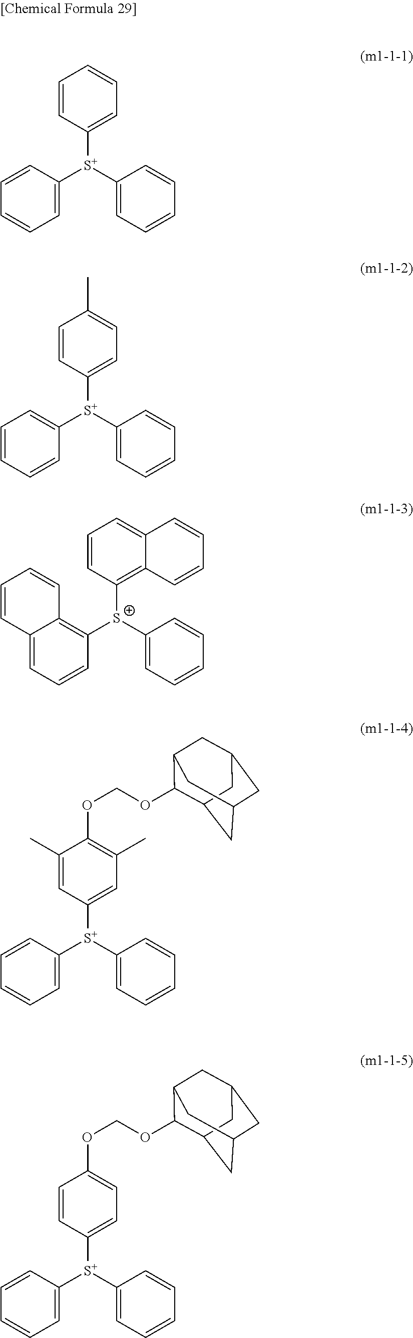

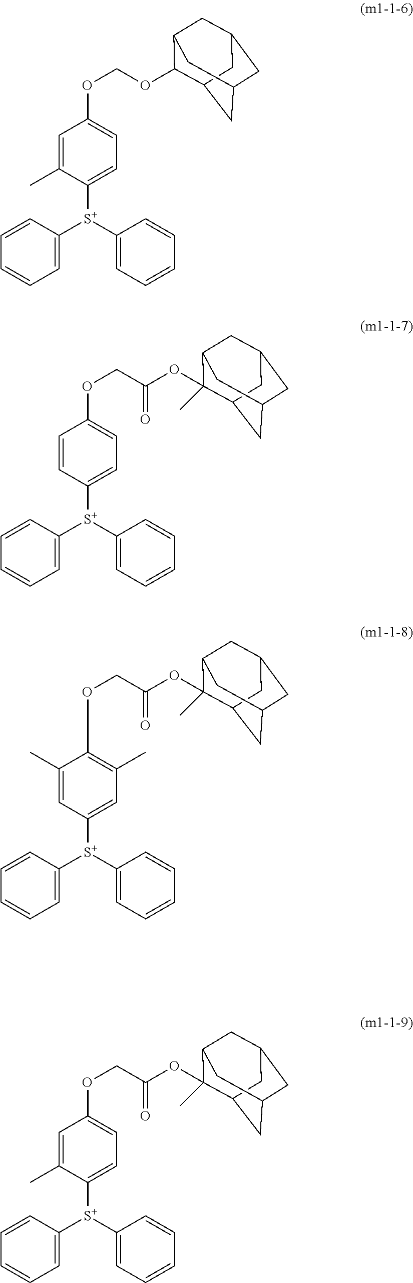

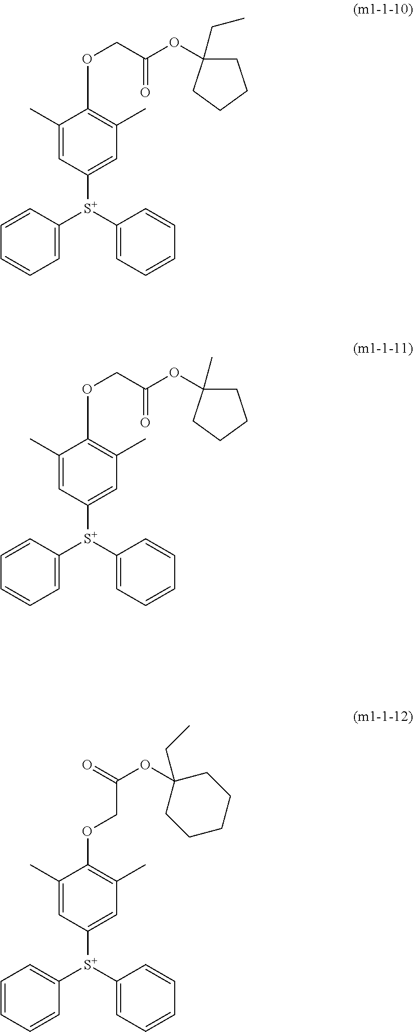

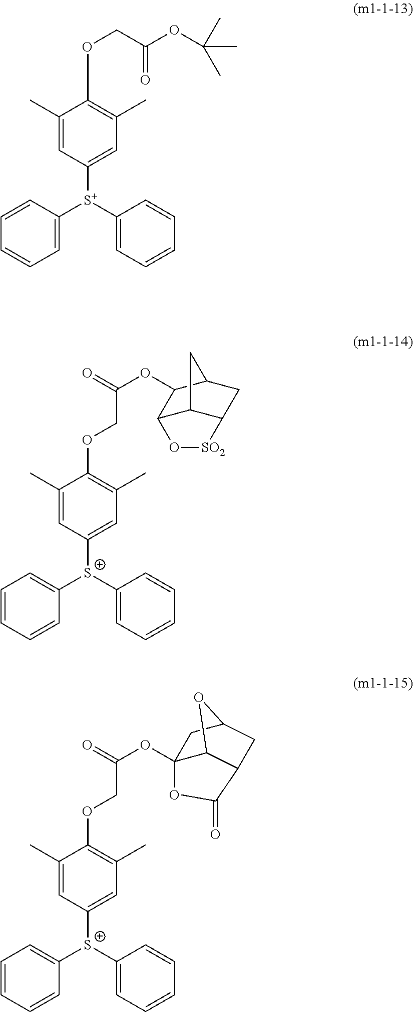

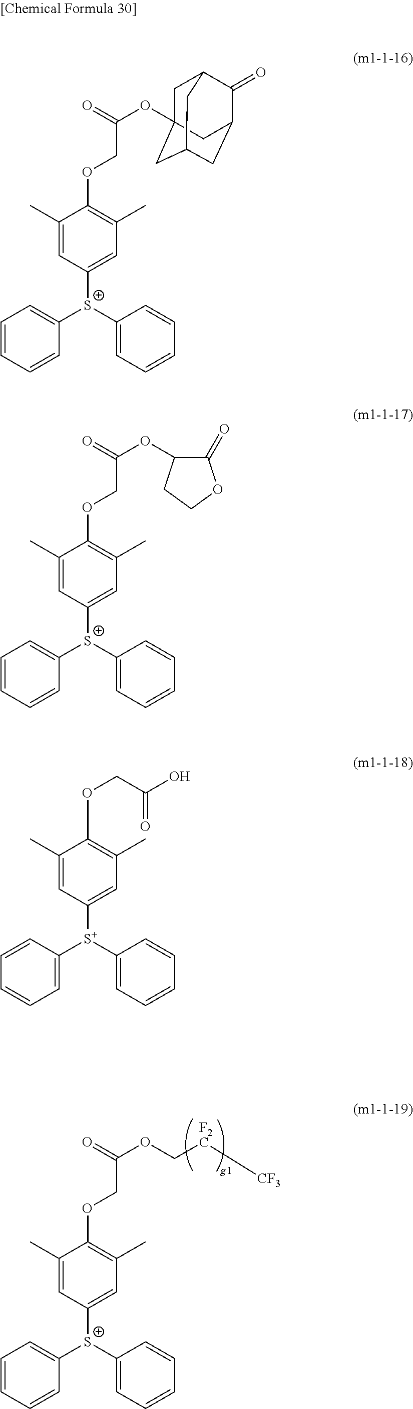

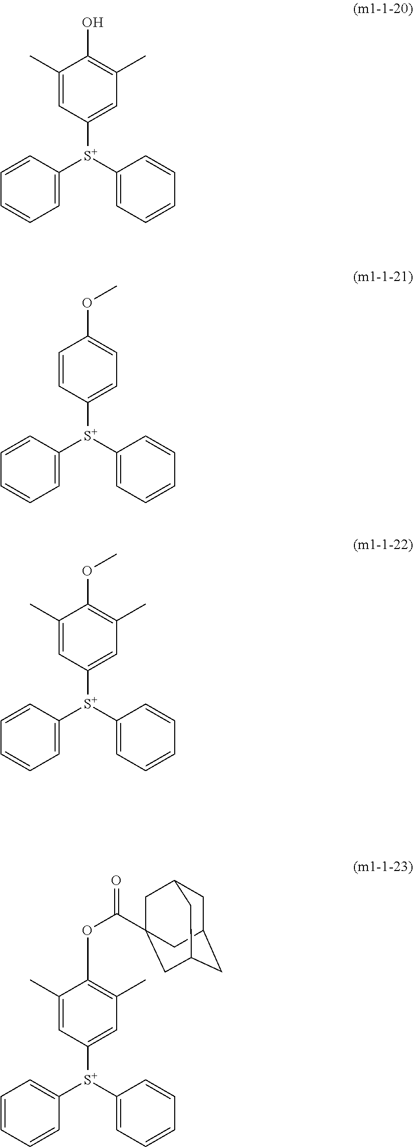

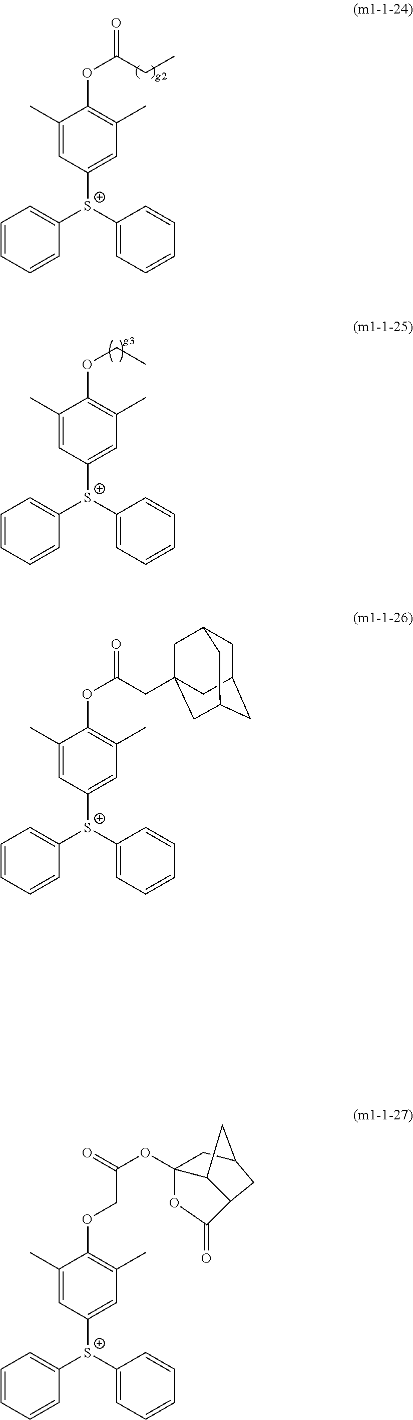

In the formulas, g1, g2 and g3 represent numbers of repeating units, wherein g1 is an integer of 1 to 5, g2 is an integer of 0 to 20, and g3 is an integer of 0 to 20.

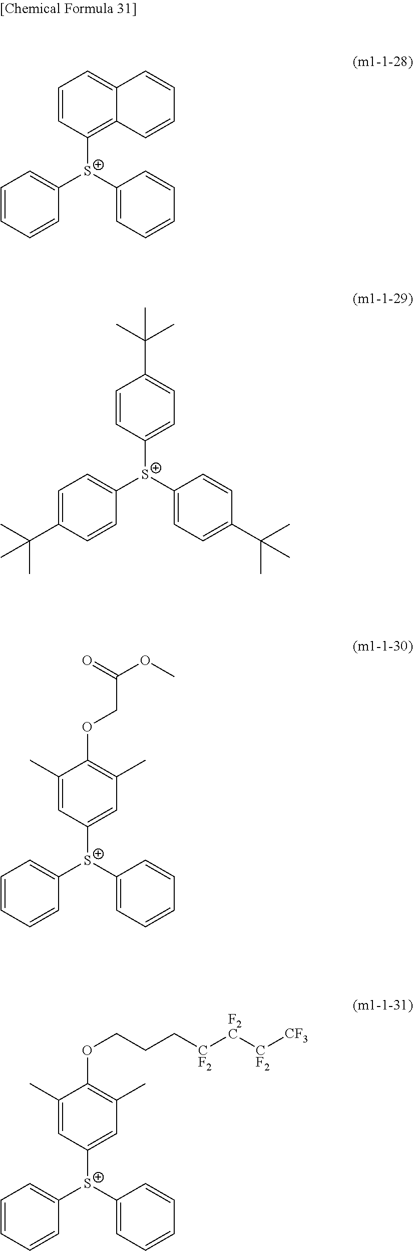

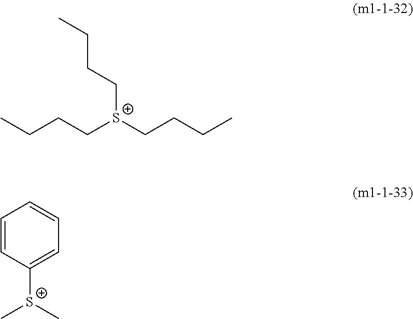

Further, in the cation moiety of the compound represented by the above formula (m-1), specific examples of preferred cations in the case where two of R¹″ to R³″ may be bonded to each other to form a ring together with the sulfur atom in the formula include the cation moieties represented by formulas (m1-2) to (m1-5) shown below.

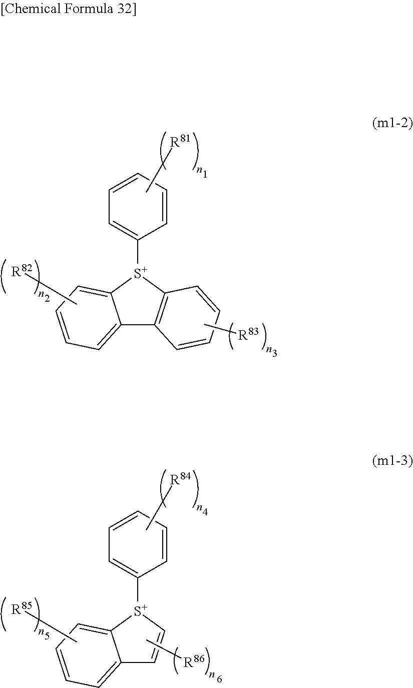

In the formulas, each of R⁸¹ to R⁸⁶ independently represents an alkyl group, an acetyl group, an alkoxy group, a carboxyl group, a hydroxyl group or a hydroxyalkyl group; each of n₁ to n₅ independently represents an integer of 0 to 3; and n₆ represents an integer of 0 to 2.

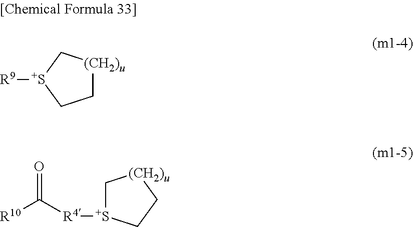

In the formulas, each of R⁹ and R¹⁰ independently represents a phenyl group or naphthyl group which may have a substituent, an alkyl group or alkoxy group of 1 to 5 carbon atoms, or a hydroxyl group, R⁴′ represents an alkylene group of 1 to 5 carbon atoms, and u represents an integer of 1 to 3.

In formulas (m1-2) and (m1-3), the alkyl group for R⁸¹ to R⁸⁶ is preferably an alkyl group of 1 to 5 carbon atoms, and among such groups, is more preferably a linear or branched alkyl group, and most preferably a methyl group, an ethyl group, a propyl group, an isopropyl group, an n-butyl group or a tert-butyl group.

The alkoxy group is preferably an alkoxy group of 1 to 5 carbon atoms, more preferably a linear or branched alkoxy group, and most preferably a methoxy group or an ethoxy group.

The hydroxyalkyl group is preferably the aforementioned alkyl group in which one or more hydrogen atoms have been substituted with hydroxy groups, and examples thereof include a hydroxymethyl group, a hydroxyethyl group and a hydroxypropyl group.

If there are two or more of an individual R⁸¹ to R⁸⁶ group, as indicated by the corresponding value of n₁ to n₆, then the two or more of the individual R⁸¹ to R⁸⁶ group may be the same or different from each other.

n₁ is preferably 0 to 2, more preferably 0 or 1, and still more preferably 0.

It is preferable that n₂ and n₃ each independently represent 0 or 1, and more preferably 0.

n₄ is preferably 0 to 2, and more preferably 0 or 1.

n₅ is preferably 0 or 1, and more preferably 0.

n₆ is preferably 0 or 1, and more preferably 1.

Specific examples of preferred cation moieties represented by the above formula (m1-2) or (m1-3) include the cations shown below.

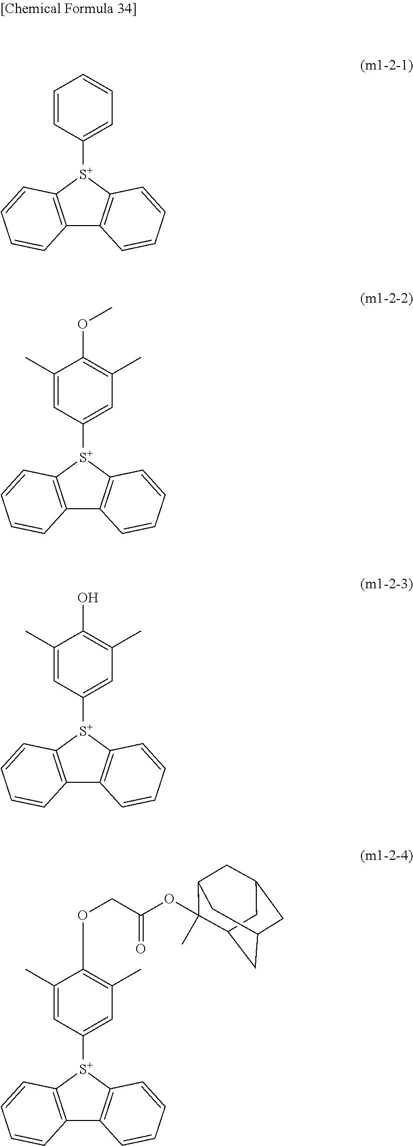 [SMILES: c1ccc(-[s+]2c3ccccc3c3ccccc32)cc1 ; COc1c(C)cc(-[s+]2c3ccccc3c3ccccc32)cc1C ; Cc1cc(-[s+]2c3ccccc3c3ccccc32)cc(C)c1O ; Cc1cc(-[s+]2c3ccccc3c3ccccc32)cc(C)c1OCC(=O)OC1(C)C2CC3CC(C2)CC1C3]

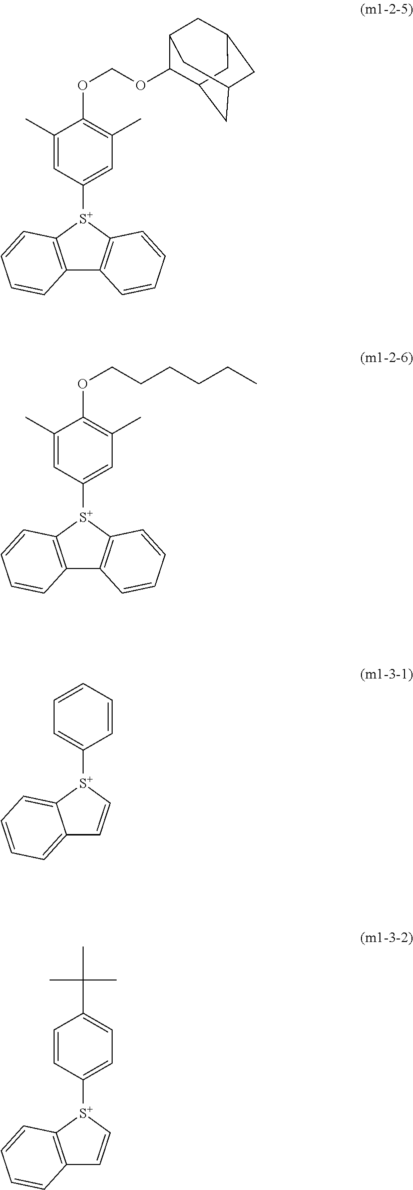 [SMILES: Cc1cc(-[s+]2c3ccccc3c3ccccc32)cc(C)c1OCOC1C2CC3CC(C2)CC1C3 ; CCCCCCOc1c(C)cc(-[s+]2c3ccccc3c3ccccc32)cc1C ; c1ccc(-[s+]2ccc3ccccc32)cc1 ; CC(C)(C)c1ccc(-[s+]2ccc3ccccc32)cc1]

In formulas (m1-4) and (m1-5), each of R⁹ and R¹⁰ independently represents a phenyl group or naphthyl group which may have a substituent, an alkyl group or alkoxy group of 1 to 5 carbon atoms, or a hydroxyl group. Examples of the substituent include the same groups as those described above for the substituent of the substituted alylene groups mentioned within the description relating to the organic groups of R³ (such as an alkyl group, alkoxy group, alkoxyalkyloxy group, alkoxycarbonylalkyloxy group, halogen atom, hydroxyl group, oxo group (═O), aryl group, —C(═O)—O—R⁶″, —O—C(═O)—R⁷″, —O—R⁸″, or a group represented by the above general formula —O—R⁵⁰—C(═O)—O—R⁵⁶ in which R⁵⁶ has been substituted with R⁵⁶′).

R⁴′ represents an alkylene group of 1 to 5 carbon atoms.

u represents an integer of 1 to 3, and is most preferably 1 or 2.

Specific examples of preferred cation moieties represented by formula (m1-4) or (m1-5) include the cations shown below.

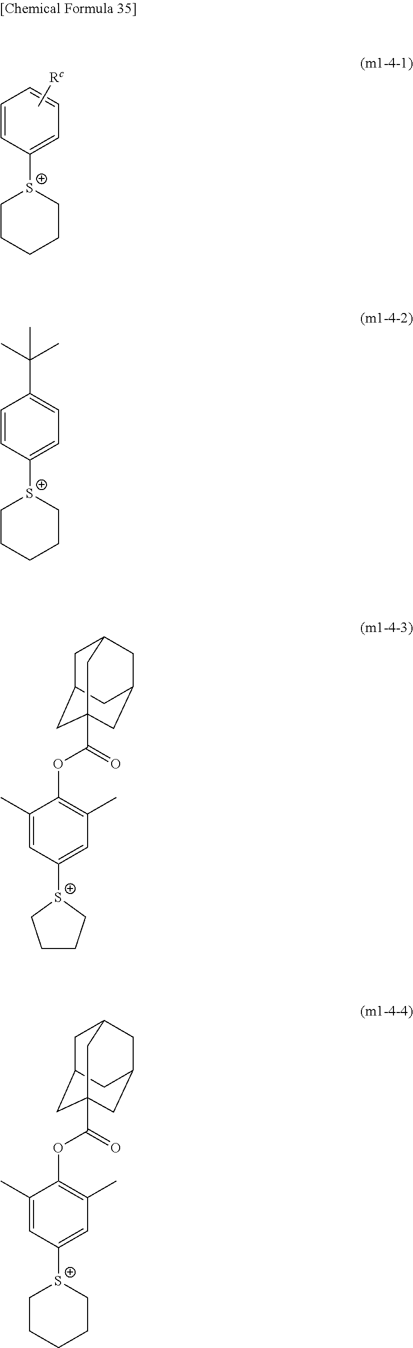

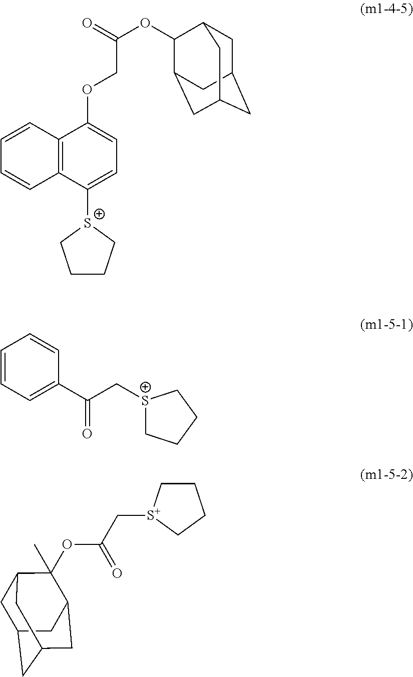

In formula (m1-4-1), R^{C} represents a substituent. Examples of the substituent include the same substituents as those described above within the description relating to the substituted alylene groups (such as an alkyl group, alkoxy group, alkoxyalkyloxy group, alkoxycarbonylalkyloxy group, halogen atom, hydroxyl group, oxo group (═O), aryl group, —C(═O)—O—R⁶″, —O—C(═O)—R⁷″ or —O—R⁸″).

As a structural unit having a group represented by formula (a0-2) (hereafter, referred to as “structural unit (a0-2)”), a structural unit selected from the group consisting of groups represented by formulas (a0-2-11) to (a0-2-13), (a0-2-21) to (a0-2-25), (a0-2-31) to (a0-2-32), (a0-2-41) to (a0-2-44), and (a0-2-51) to (a0-2-53) shown below is preferred.

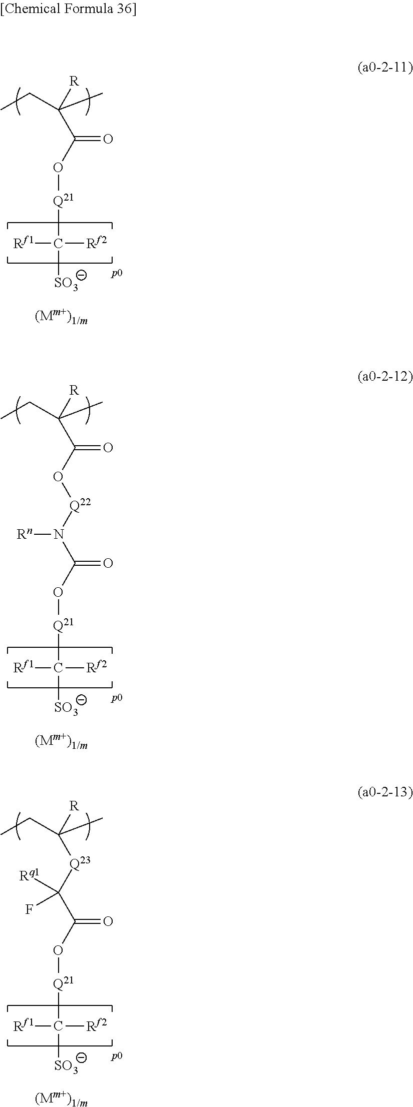

In the formulas, R, R^{f1}, R^{f2}, p0 and (M^{m+})_{1/m} are the same as defined above; each Q²¹ independently represents a single bond or a divalent linking group; Q²² represents a divalent linking group; Q²³ represents a group containing —O—, —CH₂—O— or —C(═O)—O—; R^{q1} represents a fluorine atom or a fluorinated alkyl group; and Rⁿ represents a hydrogen atom or an alkyl group of 1 to 5 carbon atoms.

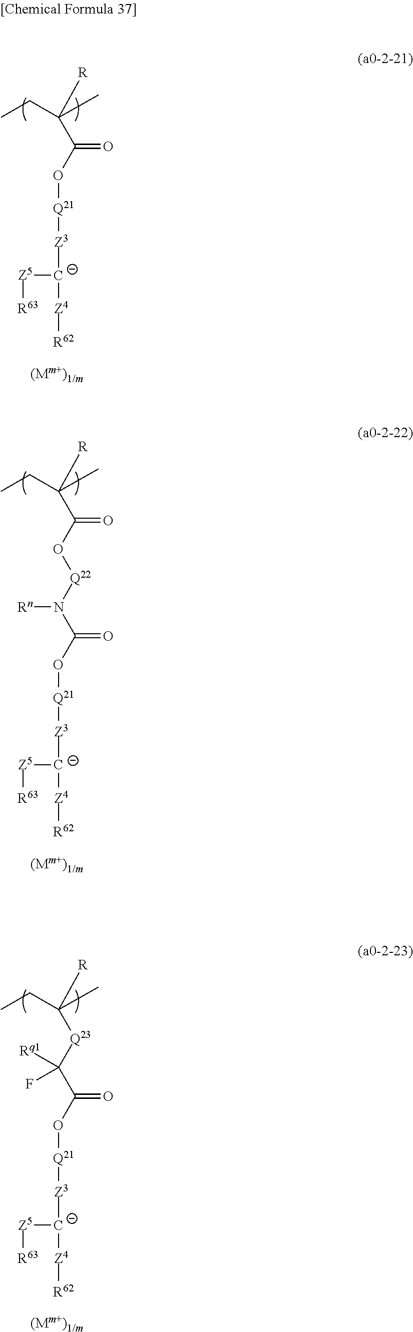

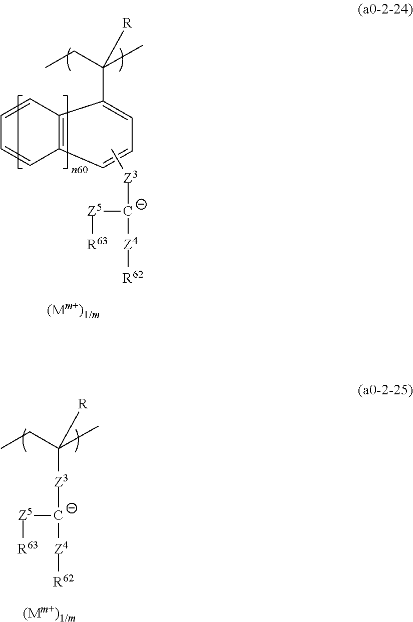

In the formulas, R, Q²¹ to Q²³, Z³ to Z⁵, R⁶² to R⁶³, Rⁿ, R^{q1} and (M^{m+})_{1/m} are the same as defined above; and n60 represents an integer of 0 to 3.

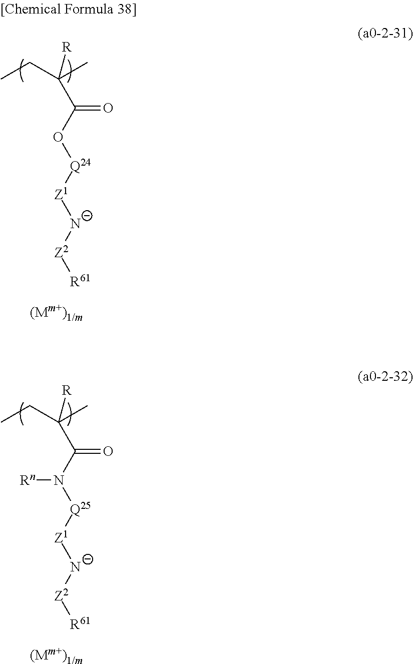

In the formulas, R, Z¹ and Z², Rⁿ and (M^{m+})_{1/m} are the same as defined above; and each of Q²⁴ and Q²⁵ independently represents a single bond or a divalent linking group.

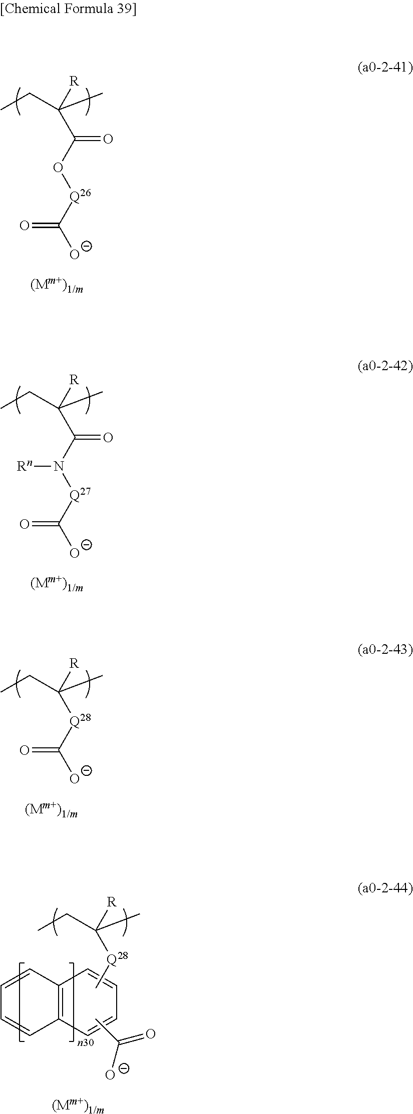

In the formulas, R, Rⁿ and (M^{m+})_{1/m} are the same as defined above; each of Q²⁶ to Q²⁸ independently represents a single bond or a divalent linking group; and n30 represents an integer of 0 to 3.

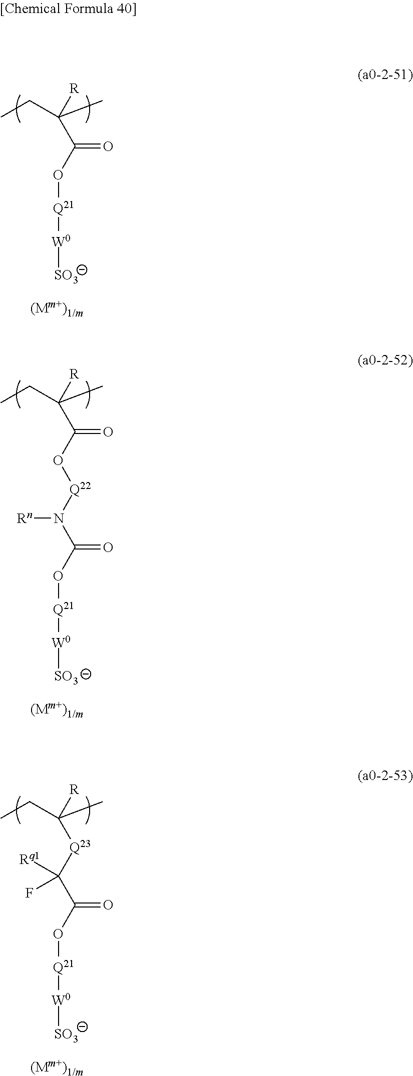

In the formulas, R, Q²¹ to Q²³, W⁰, R^{q1}, Rⁿ and (M^{m+})_{1/m} are the same as defined above.

In formulas (a0-2-11) to (a0-2-13), R, R^{f1}, R^{f2}, p0 and (M^{m+})_{1/m} are the same as defined above; and Q²¹ represents a single bond or a divalent linking group. Examples of the divalent linking group for Q²¹ include the same groups as those described above as the divalent linking group for L⁰¹ in formula (I-1). Among such groups, as Q²¹, linear or branched alkylene groups, cyclic aliphatic hydrocarbon groups, aromatic hydrocarbon groups or divalent linking groups containing a hetero atom are preferred; linear or branched alkylene groups, combinations of linear or branched alkylene groups with a divalent linking group containing a hetero atom, combinations of cyclic aliphatic hydrocarbon groups with a divalent linking group containing a hetero atom, combinations of aromatic hydrocarbon groups with a divalent linking group containing a hetero atom are more preferred; linear or branched alkylene groups, combinations of linear or branched alkylene groups with an ester bond [—C(═O)—O—] and combinations of divalent alicyclic hydrocarbon groups with an ester bond [—C(═O)—O—] are particularly preferred; and linear or branched alkylene groups, or combinations of linear or branched alkylene groups with an ester bond [—C(═O)—O—] are most preferred.

In formula (a0-2-12), Q²² represents a divalent linking group. Examples thereof include the same groups as those described above as the divalent linking group for L⁰¹ in the formula (I-1), and among such groups, the linear or branched alkylene groups, cyclic aliphatic hydrocarbon groups and divalent aromatic hydrocarbon groups are preferred, linear alkylene groups are particularly preferred, and a methylene group or an ethylene group is most preferred.

In formula (a0-2-12), Rⁿ represents a hydrogen atom or an alkyl group of 1 to 5 carbon atoms. As the alkyl group of 1 to 5 carbon atoms, the same alkyl groups of 1 to 5 carbon atoms as those described above for R can be used. In particular, as Rⁿ, a hydrogen atom or a methyl group is preferred.

In formula (a0-2-13), Q²³ represents a group containing —O—, —CH₂—O— or —C(═O)—O—.

Specific examples of Q²³ include a group composed of —O—, —CH₂—O— or —C(═O)—O—; and a group composed of —O—, —CH₂—O— or —C(═O)—O— and a divalent hydrocarbon group which may have a substituent.

Examples of the divalent hydrocarbon group which may have a substituent include the same groups as those described above as the “divalent hydrocarbon group which may have a substituent” within the description of the divalent linking group for L⁰¹ in the formula (I-1). Among these, as the “divalent hydrocarbon group” for Q¹, an aliphatic hydrocarbon group is preferable, and a linear or branched alkylene group is more preferable.

Q²³ is preferably a group composed of —C(═O)—O— and a divalent hydrocarbon group which may have a substituent, is more preferably a group composed of —C(═O)—O— and an aliphatic hydrocarbon group, and is still more preferably a group composed of —C(═O)—O— and a linear or branched alkylene group.

In particular, more specifically, preferred examples of Q²³ include groups represented by general formula (Q23-1) shown below.

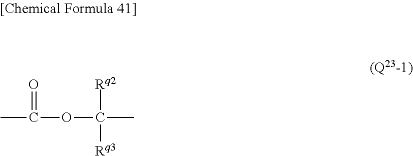

In formula (Q23-1), each of R^{q2} and R^{q3} independently represents a hydrogen atom, an alkyl group or a fluorinated alkyl group, and R^{q2} and R^{q3} may be bonded to each other to form a ring.

In the above formula (Q23-1), the alkyl group for R^{q2} and R^{q3} may be any of linear, branched or cyclic, but is preferably linear or branched.

If the alkyl group is linear or branched, it is preferably an alkyl group of 1 to 5 carbon atoms, more preferably an ethyl group or a methyl group, and particularly preferably an ethyl group.

If the alkyl group is a cyclic alkyl group, it preferably has 4 to 15 carbon atoms, more preferably 4 to 12 carbon atoms, and most preferably 5 to 10 carbon atoms. Specific examples thereof include groups in which one or more hydrogen atoms have been removed from a monocycloalkane, and groups in which one or more hydrogen atoms have been removed from a polycycloalkane such as a bicycloalkane, tricycloalkane or tetracycloalkane. More specific examples include groups in which one or more hydrogen atoms have been removed from a monocycloalkane such as cyclopentane and cyclohexane, and groups in which one or more hydrogen atoms have been removed from a polycycloalkane such as adamantane, norbornane, isobornane, tricyclodecane or tetracyclododecane. Among these, a group in which one or more hydrogen atoms have been removed from adamantane is preferable.

The fluorinated alkyl group for R^{q2} and R^{q3} is a group in which part or all of the hydrogen atoms within an alkyl group have each been substituted with a fluorine atom.

In the fluorinated alkyl group, an alkyl group which has not been substituted with a fluorine atom may be any of linear, branched or cyclic, and examples thereof include the same groups as those described above as the “alkyl group for R^{q2} and R^{q3}”.

R^{q2} and R^{q3} may be bonded to each other to form a ring. As a ring constituted R^{q2}, R^{q3} and the carbon atom to which they are bonded, the aforementioned cyclic alkyl group in which two hydrogen atoms have been removed from a monocycloalkane or polycycloalkane can be used, and the ring is preferably a 4- to 10-membered ring, and more preferably a 5- to 7-membered ring.

Of the various possibilities described above, R^{q2} and R^{q3} preferably represent a hydrogen atom or an alkyl group.

In formula (a0-2-13), R^{q1} represents a fluorine atom or a fluorinated alkyl group.

In the fluorinated alkyl group for R^{q1}, an alkyl group which has not been substituted with a fluorine atom may be any of linear, branched or cyclic.

If the alkyl group is a linear or branched alkyl group, it preferably has 1 to 5 carbon atoms, more preferably 1 to 3 carbon atoms, and particularly preferably 1 or 2 carbon atoms.

If the alkyl group is a cyclic alkyl group, it preferably has 4 to 15 carbon atoms, more preferably 4 to 12 carbon atoms, and still more preferably 5 to 10 carbon atoms. Specific examples thereof include groups in which one or more hydrogen atoms have been removed from a monocycloalkane, and groups in which one or more hydrogen atoms have been removed from a polycycloalkane such as a bicycloalkane, tricycloalkane or tetracycloalkane. More specific examples include groups in which one or more hydrogen atoms have been removed from a monocycloalkane such as cyclopentane and cyclohexane, and groups in which one or more hydrogen atoms have been removed from a polycycloalkane such as adamantane, norbornane, isobornane, tricyclodecane or tetracyclododecane.

In the fluorinated alkyl group, the percentage of the number of fluorine atoms, based on the total number of fluorine atoms and hydrogen atoms contained in the fluorinated alkyl group (namely, the fluorination ratio (%) is preferably from 30 to 100%, and more preferably from 50 to 100%. The higher the fluorination ratio, the higher the hydrophobicity of the resist film.

Of the various possibilities described above, R^{q1} is preferably a fluorine atom.

In formulas (a0-2-21) to (a0-2-25), R, Q²¹ to Q²³, Z³ to Z⁵, R⁶² to R⁶³, R^{q1} and (M^{m+})_{1/m} are the same as defined above.

In formula (a0-2-24), n60 represents an integer of 0 to 3, and is preferably 0 or 1.

In formulas (a0-2-31) and (a0-2-32), R, Z¹ and Z², Rⁿ and (M^{m+})_{1/m} are the same as defined above; and each of Q²⁴ and Q²⁵ independently represents a single bond or a divalent linking group.

Examples of the divalent linking group for Q²⁴ and Q²⁵ include the same groups as those described above as the divalent linking group for L⁰¹ in the formula (I-1). As described above, in those cases where Z¹ represents a single bond, it is preferable that the terminals of Q²⁴ and Q²⁵ bonded to Z¹ are not —C(═O)—. As the divalent linking group for Q²⁴ and Q²⁵, a linear or branched alkylene group, a cyclic aliphatic hydrocarbon group or a divalent linking group containing a hetero atom is particularly desirable. Of these, a linear or branched alkylene group or a cyclic aliphatic hydrocarbon group is preferred, and a linear alkylene group or a cyclic aliphatic hydrocarbon group is more preferred.

In formulas (a0-2-41) to (a0-2-44), R, Rⁿ and (M^{m+})_{1/m} are the same as defined above; and each of Q²⁶ to Q²⁸ independently represents a single bond or a divalent linking group. Q²⁶ to Q²⁸ are the same as defined above for Q²⁴ and Q²⁵.

In formula (a0-2-44), n30 represents an integer of 0 to 3, and is preferably 0 or 1.

In formulas (a0-2-51) to (a0-2-53), R, Q²¹ to Q²³, W⁰, R^{q1}, Rⁿ and (M^{m+})_{1/m} are the same as defined above.

Specific examples of the structural unit (a0-2) are shown below. In the formulas shown below, R^{α} represents a hydrogen atom, a methyl group or a trifluoromethyl group, and (M^{m+})_{1/m} is the same as defined above.

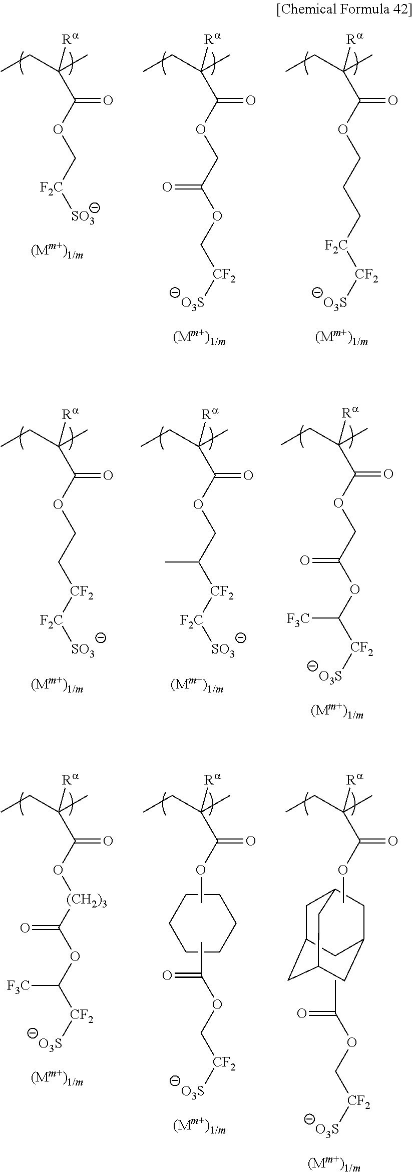

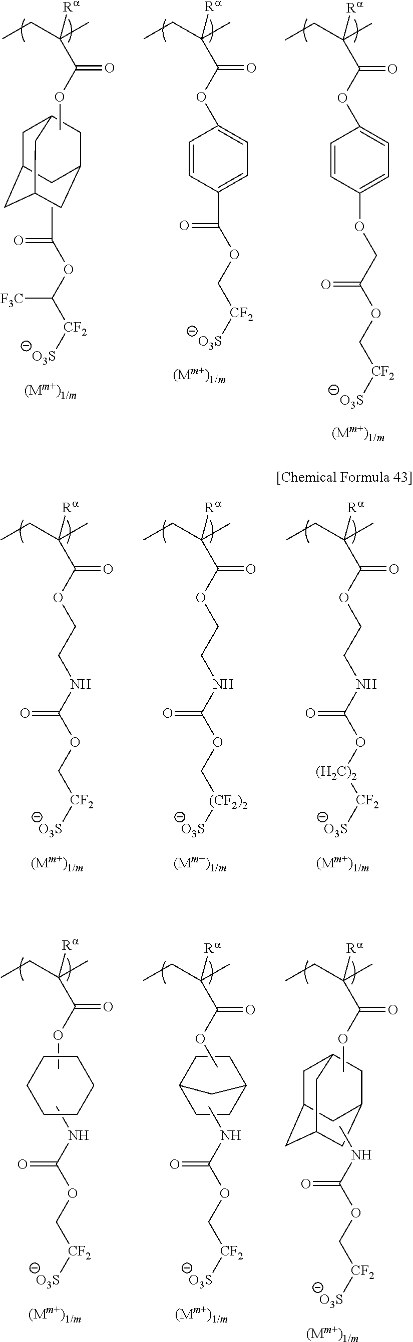

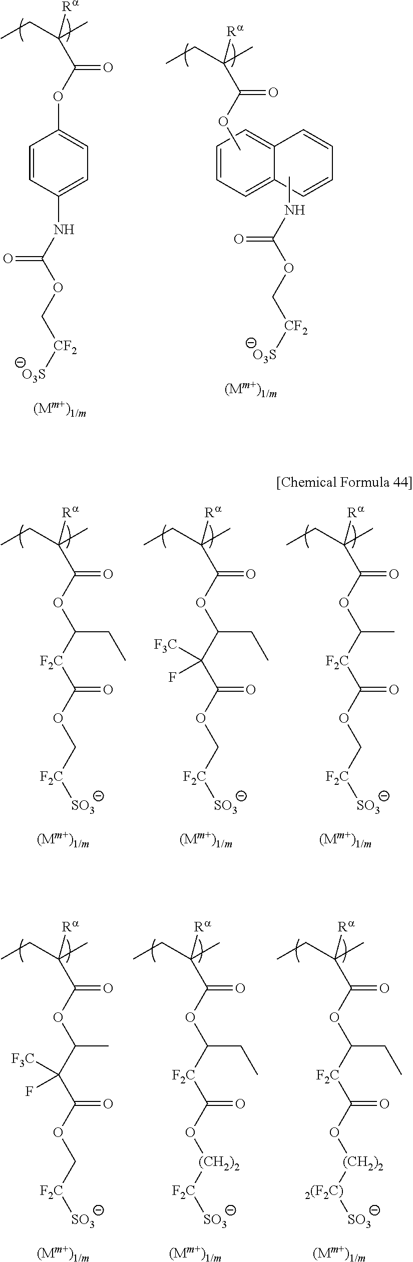

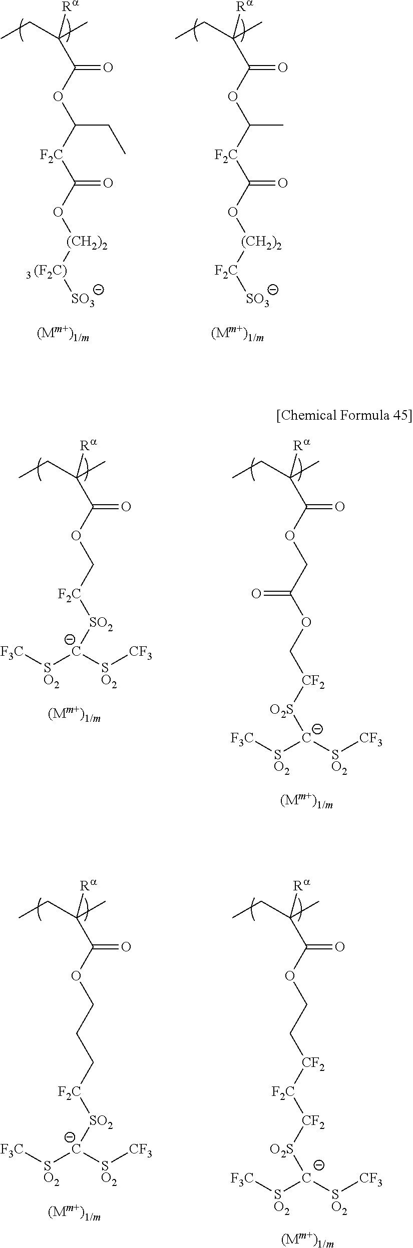

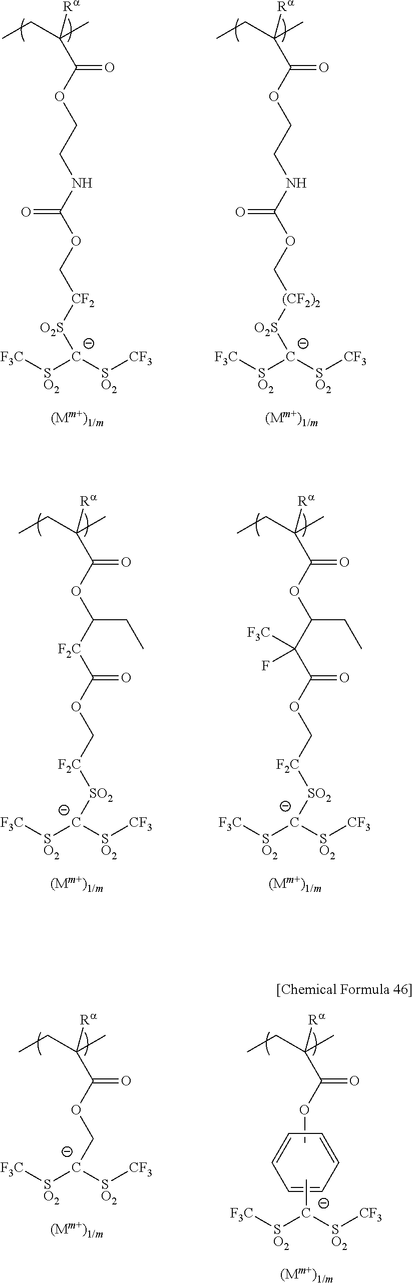

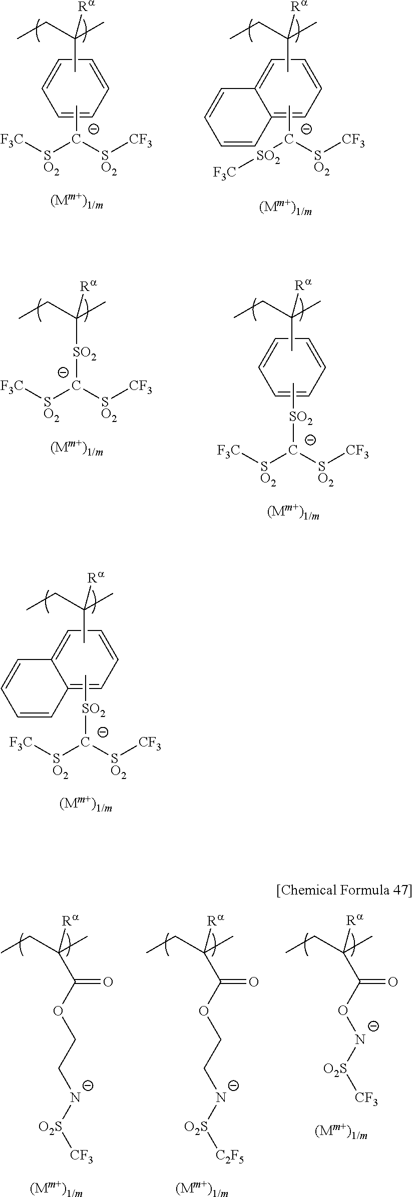

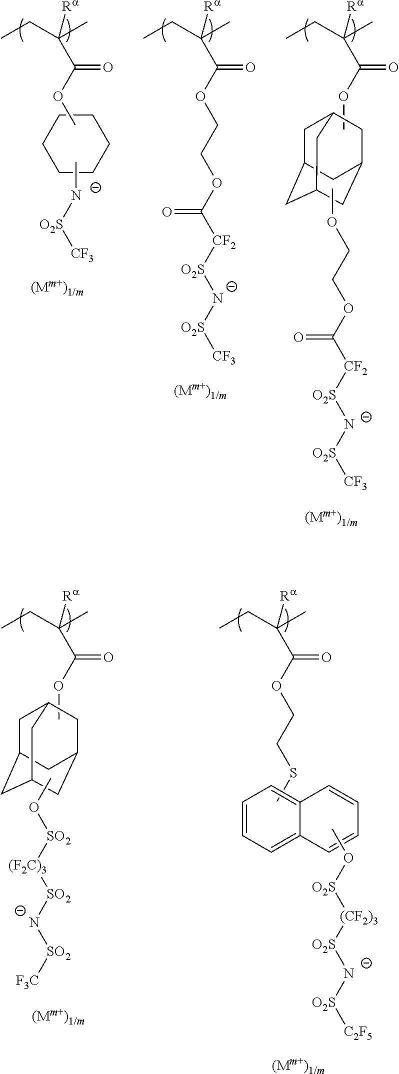

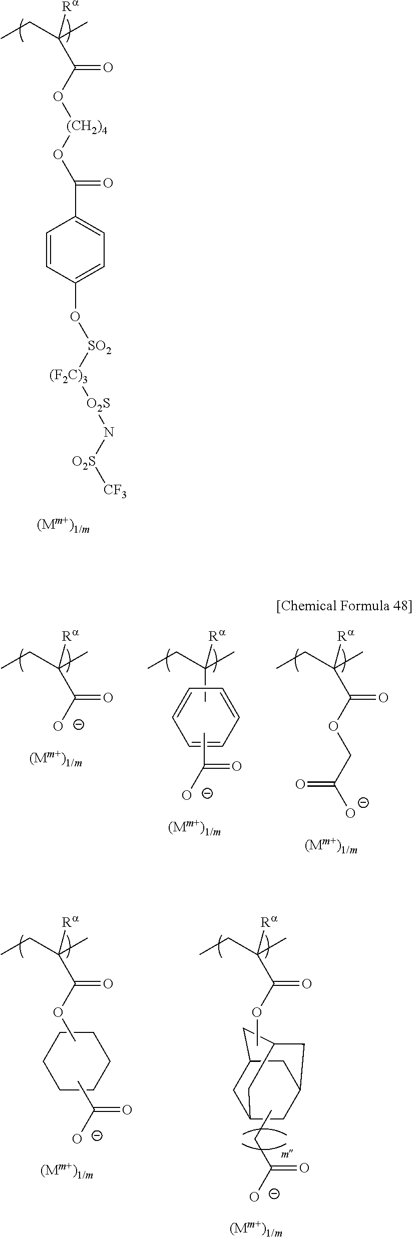

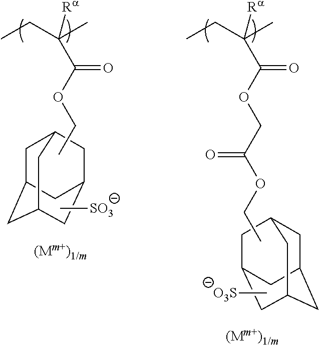

The component (A) may only have a single type of structural unit (a0) or may have a combination of two or more types thereof.

In the component (A), the amount of the structural unit (a0) based on the combined total of all structural units constituting the polymer is preferably 1 to 50 mol %, more preferably 1 to 45 mol %, still more preferably 3 to 40 mol %, and most preferably 5 to 35 mol %. When the amount of the structural unit (a0) is at least 1 mol %, the effect of improving various lithography properties such as the sensitivity and resolution can be satisfactorily achieved. On the other hand, when the amount of the structural unit (a0) is no more than the upper limit of the above-mentioned range, a good balance can be achieved with the other structural units. Further, satisfactory solubility within the resist solvent (a component (S) described below) can be ensured.

The component (A) may have a structural unit other than the structural unit (a0). As such a structural unit, any of the multitude of conventional structural units used within resist resins for ArF excimer lasers or KrF excimer lasers (and particularly for ArF excimer lasers) can be used, and examples thereof include:

the structural unit (a0) that generates an acid upon exposure;

a structural unit (a1) containing an acid decomposable group that exhibits increased polarity under the action of acid;

a structural unit (a2) containing a —SO₂— containing cyclic group or a lactone-containing cyclic group; a structural unit (a3) containing a polar group; and

a structural unit (a4) containing a non-acid dissociable cyclic group.

In those cases where the component (A) is a component (A2), the component (A2) preferably contains a polar group.

Examples of the polar group include the same polar groups as those mentioned for the structural unit (a3) described later, and an alkali-soluble group such as a hydroxyl group or a carboxyl group is preferred.

When the structural units (a0) contains a polar group, the component (A2) may be constituted only of the structural unit (a0), or may further include the structural unit (a3) containing a polar group.

In those cases where the structural unit (a0) does not include a polar group, the component (A2) must include the structural unit (a3) in addition to the structural unit (a0).

In those cases where the component (A) is a component (A1), the component (A1) preferably contains an acid decomposable group that exhibits increased polarity under the action of acid.

As described above for the structural unit (c1), the term “acid decomposable group” refers to a group exhibiting acid decomposability in which at least a part of the bonds within the structure of this acid decomposable group may be cleaved by the action of an acid (such as the acid generated from the structural unit (a0) upon exposure or the acid generated from the acid generator component (B) serving as an optional component described below).

In those cases where the structural unit (a0) includes an acid decomposable group, the component (A1)) may be composed solely of the structural unit (a0), or may also include a structural unit (a1) containing an acid decomposable group that exhibits increased polarity under the action of acid.

In those cases where the structural unit (a0) does not include an acid decomposable groups, the component (A1) must include the structural unit (a1) in addition to the structural unit (a0).

In the present invention, the component (A) is preferably the component (A1). That is, the component (A) is preferably a resin component which generates an acid upon exposure and also exhibits increased polarity by the action of the acid, and the resist composition of the present aspect is preferably a chemically amplified resist composition which becomes a positive type in the case of an alkali developing process, and a negative type in the case of a solvent developing process.

(Structural Unit (a1))

The structural unit (a1) is a structural unit containing an acid decomposable group that exhibits increased polarity under the action of acid.

Examples of the acid decomposable group include the same groups as those mentioned above within the description of the structural unit (c2).

As the structural unit (a1), as long as it contains an acid decomposable group, there are no particular limitations on the structure of other sites, and examples thereof include a structural unit (a11), which is derived from an acrylate ester in which the hydrogen atom bonded to the carbon atom on the α-position may be substituted with a substituent, and contains an acid decomposable group; a structural unit (a12), which is derived from a hydroxystyrene in which the hydrogen atom bonded to the carbon atom on the α-position may be substituted with a substituent and a hydrogen atom bonded to the benzene ring may be substituted with a substituent other than a hydroxyl group, and in which the hydrogen atom of the hydroxyl group is substituted with an acid dissociable group or a substituent containing an acid dissociable group; and a structural unit (a13), which is derived from a vinyl(hydroxynaphthalene) in which the hydrogen atom bonded to the carbon atom on the α-position may be substituted with a substituent and a hydrogen atom bonded to the naphthalene ring may be substituted with a substituent other than a hydroxyl group, and in which the hydrogen atom of the hydroxyl group is substituted with an acid dissociable group or a substituent containing an acid dissociable group. The structural unit (a11) is preferred in terms of improving line edge roughness, whereas the structural units (a12) and (a13) are preferred in terms of facilitating absorption of wavelengths in the EUV region, and further reducing the adverse effects of OoB light on the acid generator component.

{Structural Unit (a11)}

The structural unit (a11) is a structural unit derived from an acrylate ester in which the hydrogen atom bonded to the carbon atom on the α-position may be substituted with a substituent, and contains an acid decomposable group.

Specific examples of the structural unit (a11) include structural units represented by a general formula (a1-0-1) shown below and structural units represented by a general formula (a1-0-2) shown below.

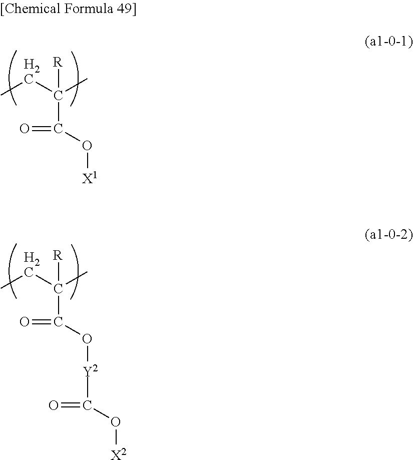

In the formulas, R represents a hydrogen atom, an alkyl group of 1 to 5 carbon atoms or a halogenated alkyl group of 1 to 5 carbon atoms, X¹ represents an acid dissociable group, Y² represents a divalent linking group, and X² represents an acid dissociable group.

In the general formula (a1-0-1), examples of the alkyl group and the halogenated alkyl group for R include the same alkyl groups and halogenated alkyl groups as those described above for the α-position substituent within the description relating to the α-substituted acrylate ester. R is preferably a hydrogen atom, an alkyl group of 1 to 5 carbon atoms or a fluorinated alkyl group of 1 to 5 carbon atoms, and is most preferably a hydrogen atom or a methyl group.

There are no particular limitations on X¹ as long as it is an acid dissociable group. Examples thereof include the aforementioned tertiary alkyl ester-type acid dissociable groups and acetal-type acid dissociable groups, and of these, a tertiary alkyl ester-type acid dissociable group is preferable.

In general formula (a1-0-2), R is the same as defined above.

X² is the same as defined for X¹ in formula (a1-0-1).

Although there are no particular limitations on the divalent linking group for Y², preferred examples include divalent hydrocarbon groups which may have a substituent, and divalent linking groups containing a hetero atom. Specific examples of these divalent hydrocarbon groups which may have a substituent, and divalent linking groups containing a hetero atom include the same divalent linking groups as those described above for L⁰¹ in the general formula (I-1) within the description relating to the component (C).

In particular, Y² is preferably a linear or branched alkylene group, a divalent alicyclic hydrocarbon group, or a divalent linking group containing a hetero atom.

When Y² is a linear or branched alkylene group, the alkylene group preferably contains 1 to 10 carbon atoms, more preferably 1 to 6 carbon atoms, still more preferably 1 to 4 carbon atoms, and most preferably 1 to 3 carbon atoms. Specific examples include the same linear alkylene groups and branched alkylene groups as those mentioned above for the linear or branched aliphatic hydrocarbon group within the description of the divalent linking group for R¹.

When Y² is a divalent alicyclic hydrocarbon group, examples of the alicyclic hydrocarbon group include the same alicyclic hydrocarbon groups as those mentioned above as the “aliphatic hydrocarbon group that includes a ring within the structure” within the description of the divalent linking group for L⁰.

Specific examples of the alicyclic hydrocarbon group include groups in which two or more hydrogen atoms have been removed from cyclopentane, cyclohexane, norbornane, isobornane, adamantane, tricyclodecane and tetracyclododecane.

When Y² is a divalent linking group containing a hetero atom, preferred examples of the divalent linking group include —O—, —C(═O)—O—, —C(═O)—, —O—C(═O)—O—, —C(═O)—NH—, —NH— (wherein H may be substituted with a substituent such as an alkyl group or acyl group), —S—, —S(═O)₂—, —S(═O)₂—O—, and groups represented by general formulas —Y²¹—O—Y²²—, —[Y²¹—C(═O)—O]_{m′}—Y²²— and —Y²¹—O—C(═O)—Y²²— [wherein each of Y²¹ and Y²² independently represents a divalent hydrocarbon group which may have a substituent, O represents an oxygen atom, and m′ represents an integer of 0 to 3].

When Y² represents —NH—, the H may be substituted with a substituent such as an alkyl group, an acyl group or the like. The substituent (an alkyl group, an acyl group or the like) preferably has 1 to 10 carbon atoms, more preferably 1 to 8 carbon atoms, and most preferably 1 to 5 carbon atoms.

In the formulas —Y²¹—O—Y²²—, —[Y²¹—C(═O)—O]_{m′}—Y²²— and —Y²¹—O—C(═O)—Y²²—, each of Y²¹ and Y²² independently represents a divalent hydrocarbon group which may have a substituent. Examples of this divalent hydrocarbon group include the same groups as those described above for the “divalent hydrocarbon group which may have a substituent” for Y².

Y²¹ is preferably a linear aliphatic hydrocarbon group, more preferably a linear alkylene group, still more preferably a linear alkylene group of 1 to 5 carbon atoms, and most preferably a methylene group or an ethylene group.

Y²² is preferably a linear or branched aliphatic hydrocarbon group, and is more preferably a methylene group, an ethylene group or an alkylmethylene group. The alkyl group within the alkylmethylene group is preferably a linear alkyl group of 1 to 5 carbon atoms, more preferably a linear alkyl group of 1 to 3 carbon atoms, and most preferably a methyl group.

In the group represented by formula —[Y²¹—C(═O)—O]_{m′}—Y²²—, m′ represents an integer of 0 to 3, and is preferably an integer of 0 to 2, more preferably 0 or 1, and most preferably 1. In other words, the group represented by formula —[Y²¹—C(═O)—O]_{m′}—Y²²— is most preferably a group represented by a formula —Y²¹—C(═O)—O—Y²²—. Among such groups, groups represented by formula —(CH₂)_{a′}—C(═O)—O—(CH₂)_{b′}— are particularly preferred. In this formula, a′ represents an integer of 1 to 10, preferably an integer of 1 to 8, more preferably an integer of 1 to 5, still more preferably 1 or 2, and most preferably 1. b′ represents an integer of 1 to 10, preferably an integer of 1 to 8, more preferably an integer of 1 to 5, still more preferably 1 or 2, and most preferably 1.

The divalent linking group containing a hetero atom for Y² is preferably an organic group composed of a combination of at least one non-hydrocarbon group and a divalent hydrocarbon group. Among such groups, linear groups containing an oxygen atom as the hetero atom, such as groups containing an ether bond or an ester bond, are preferred, a group represented by one of the above formulas —Y²¹—O—Y²²—, [Y²¹—C(═O)—O]_{m′}—Y²²— or —Y²¹—O—C(═O)—Y²²— is more preferred, and a group represented by the formula —[Y²¹—C(═O)—]_{m′}—Y²²— or the formula —Y²¹—O—C(═O)—Y²²— is particularly desirable.

Among the above possibilities, Y² is preferably a linear or branched alkylene group, or a divalent linking group containing a hetero atom, and is more preferably a linear or branched alkylene group, a group represented by the above formula —Y²¹—Y²²—, a group represented by the above formula —[Y²¹—C(═O)—]_{m′}—Y²²— or a group represented by the above formula —Y²¹—O—C(═O)—Y²²—.

Specific examples of the structural unit (a11) include structural units represented by general formulas (a1-1) to (a1-4) shown below.

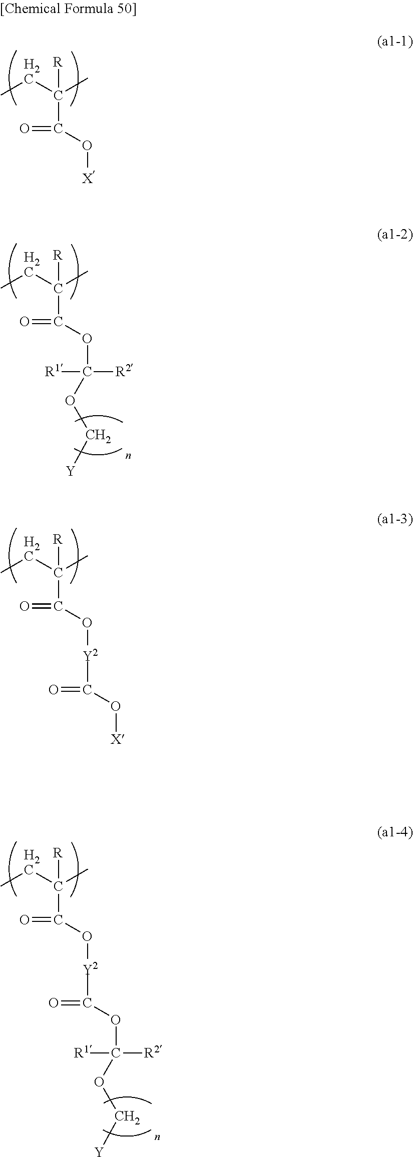

In the formulas, R, R¹′, R²′, n, Y and Y² are each the same as defined above, and X′ represents a tertiary alkyl ester-type acid dissociable group.

In the above formulas, examples of X′ include the same tertiary alkyl ester-type acid dissociable groups as those described above.

R¹′, R²′, n and Y are the same as defined above for R¹′, R²′, n and Y respectively in general formula (p1) within the description relating to the “acetal-type acid dissociable group”.

Examples of Y² include the same groups as those described above for Y² in general formula (a1-0-2).

Specific examples of structural units represented by general formulas (a1-1) to (a1-4) are shown below.

In the formulas shown below, R^{α} represents a hydrogen atom, a methyl group or a trifluoromethyl group.

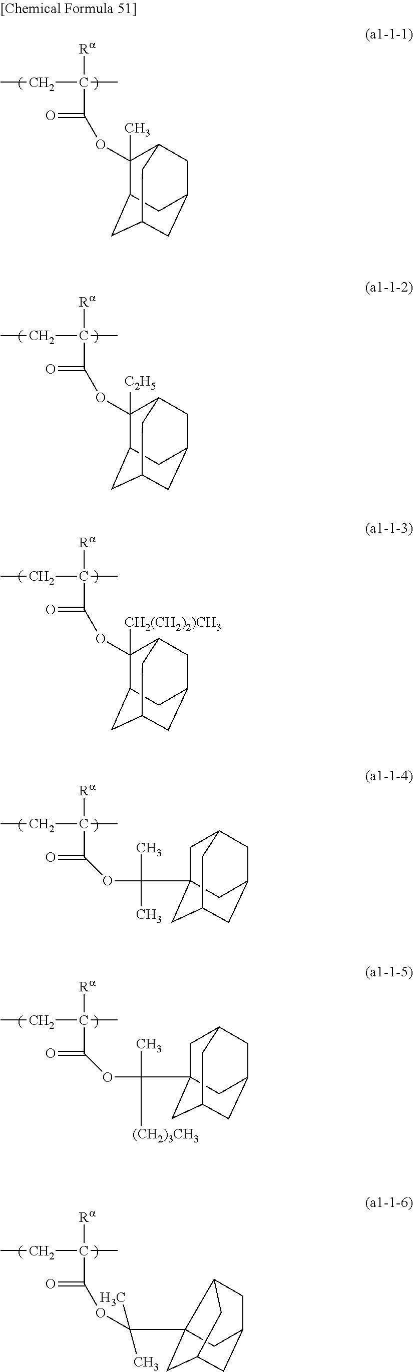

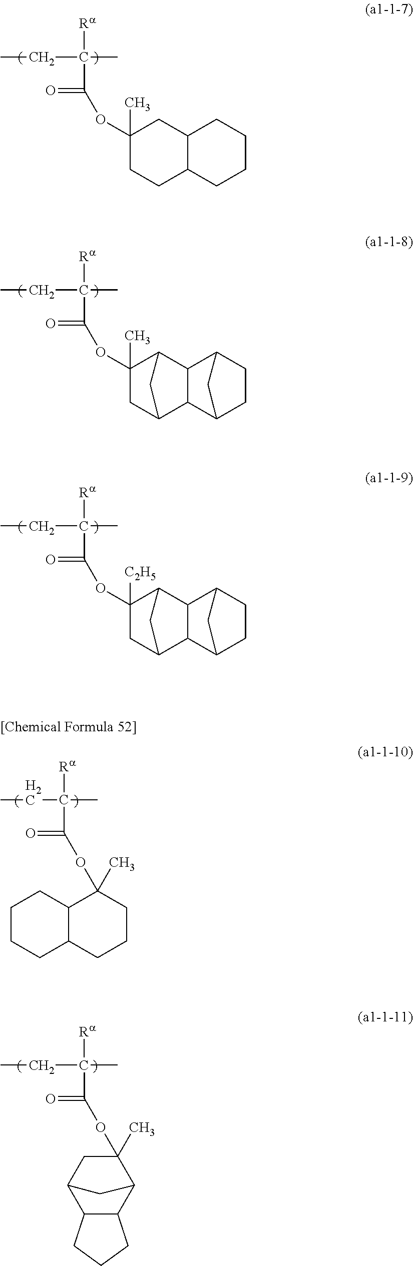

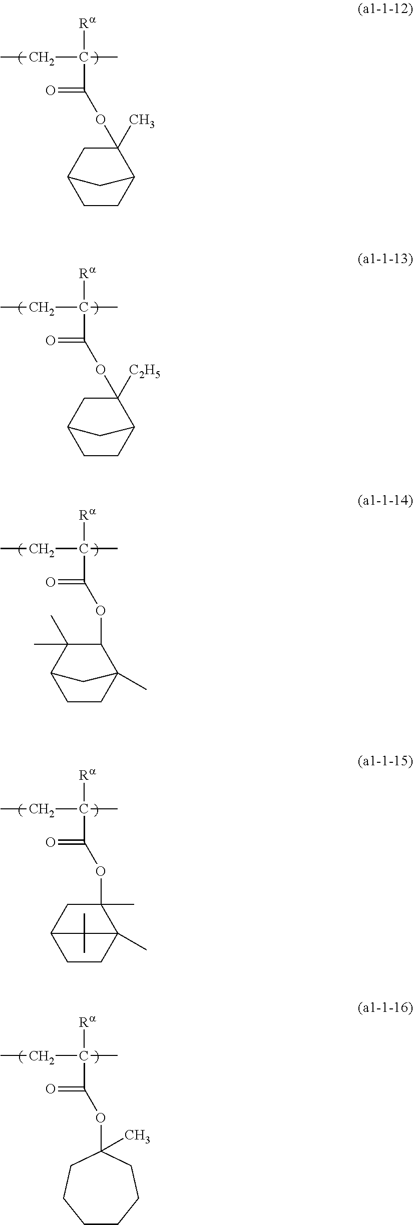

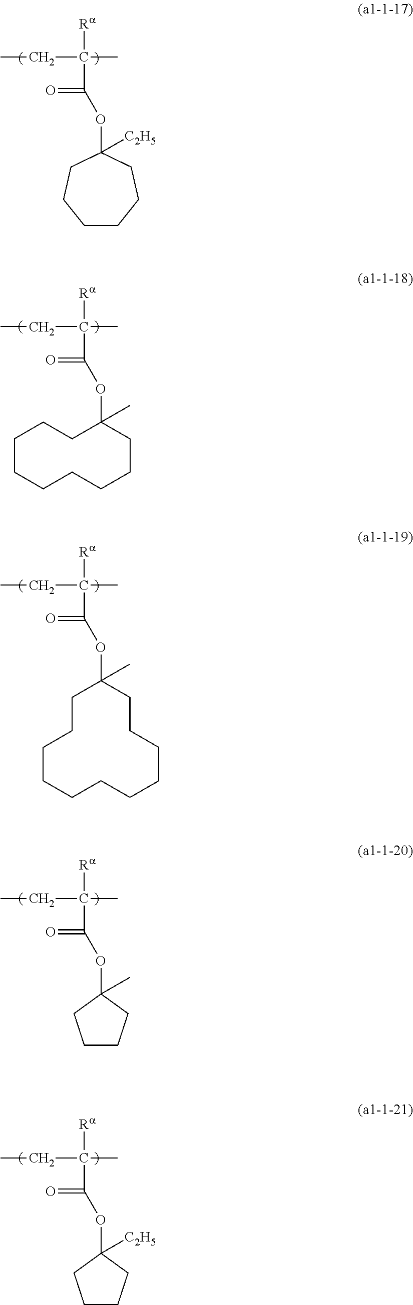

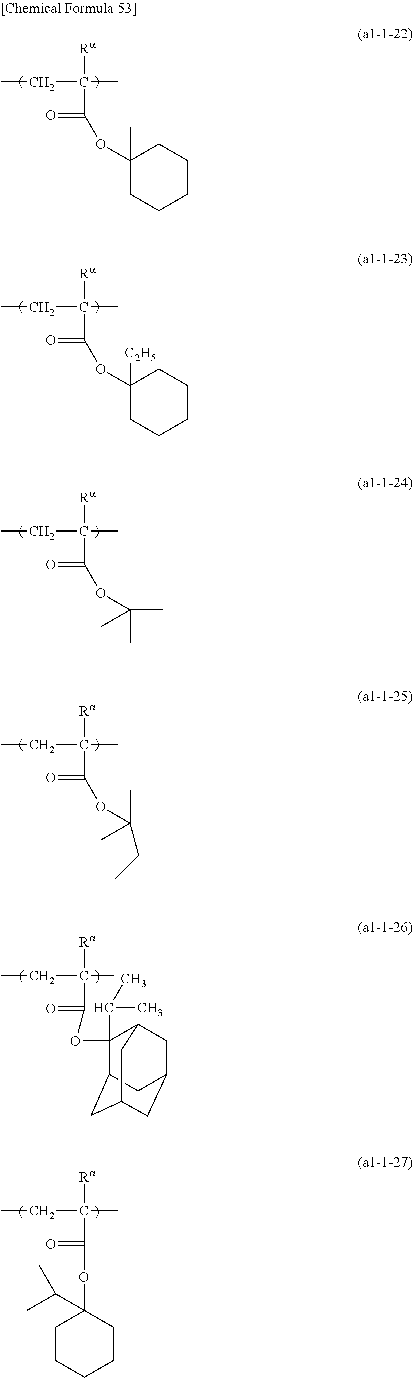

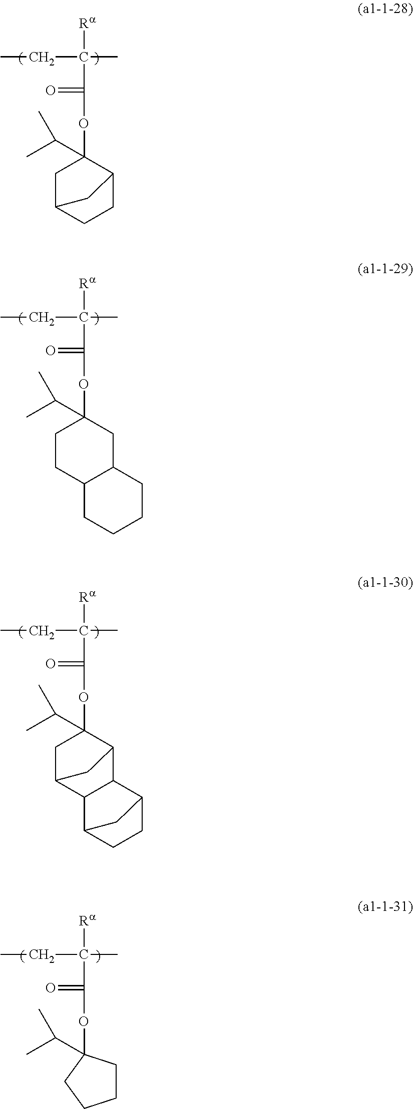

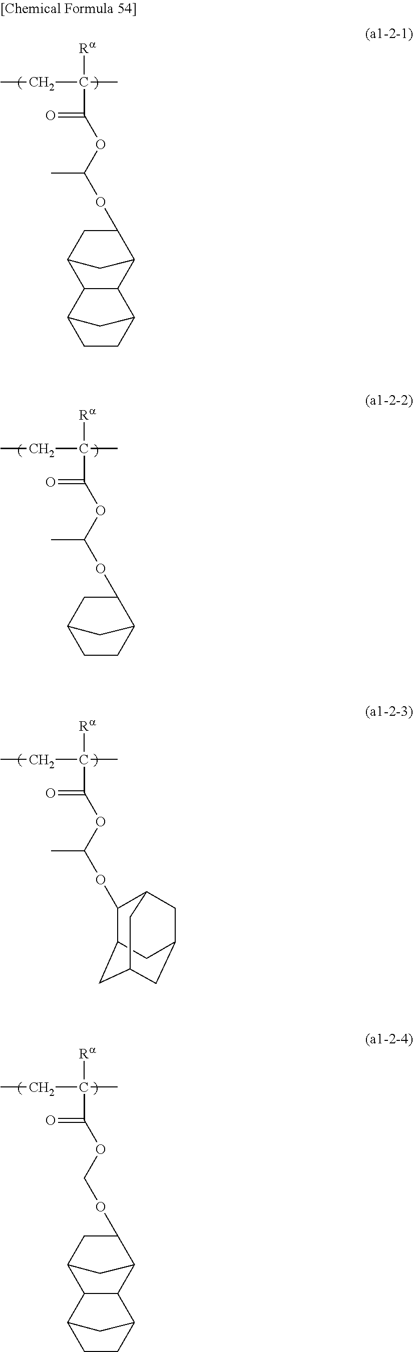

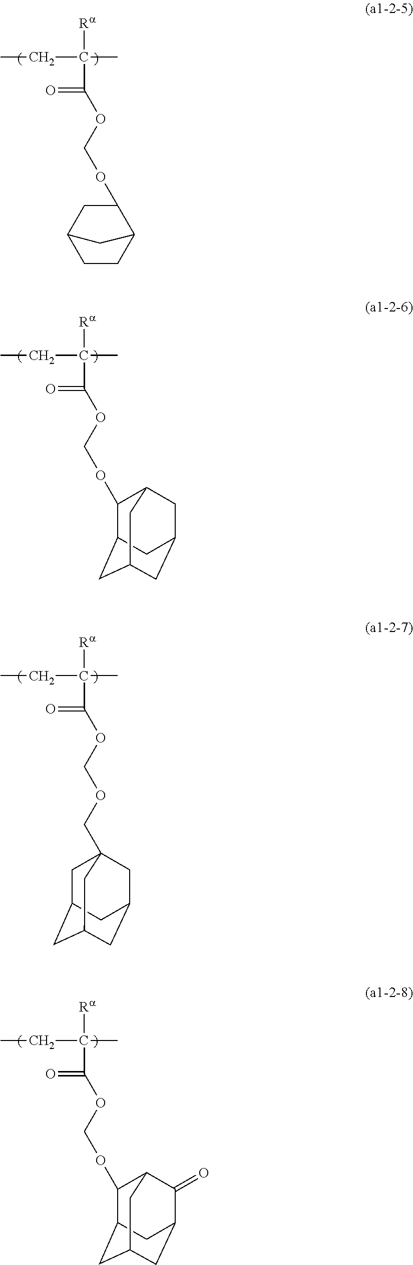

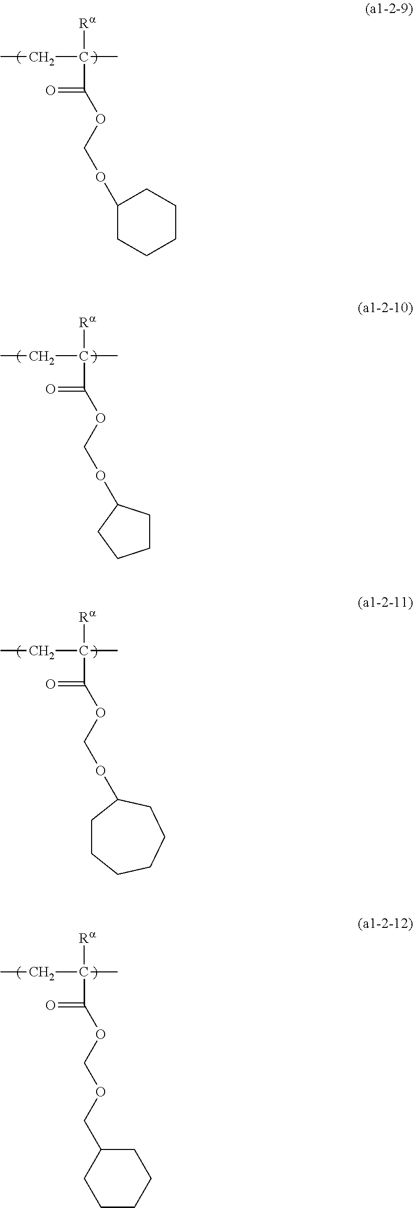

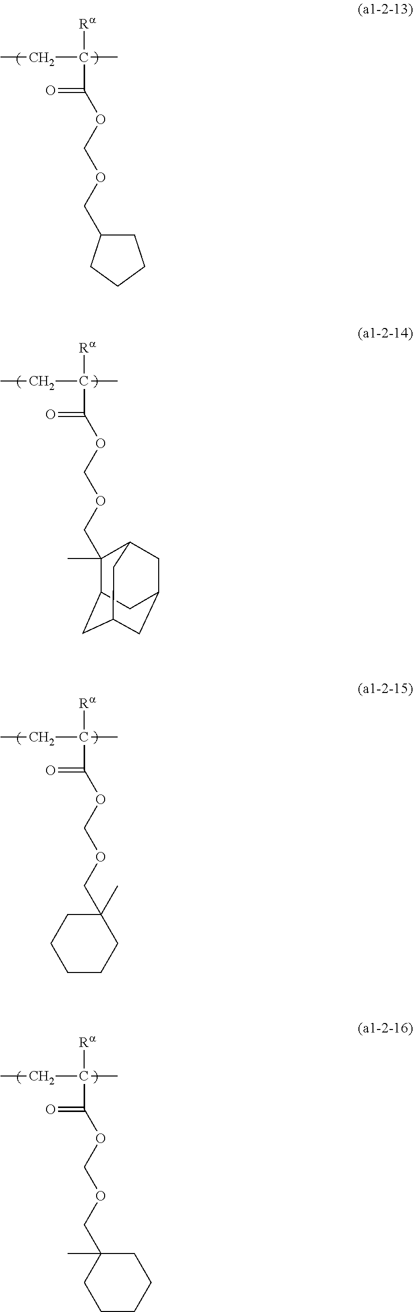

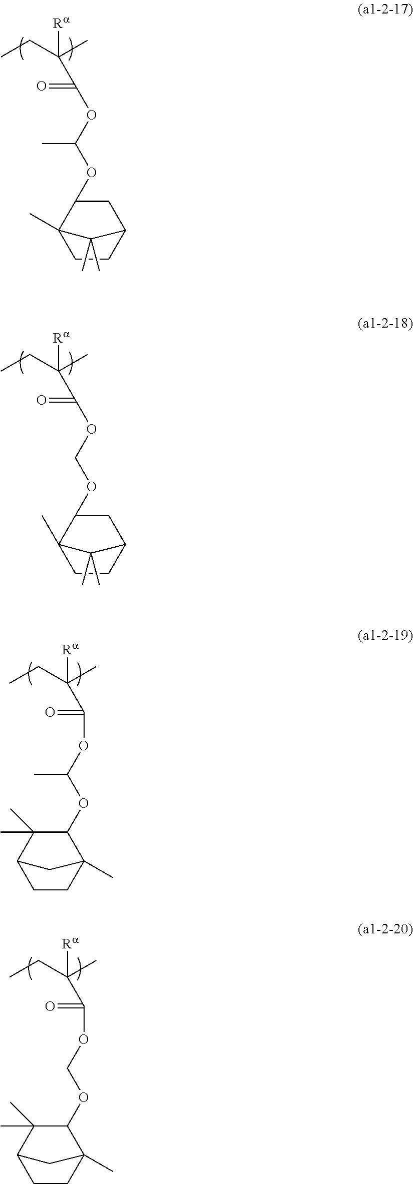

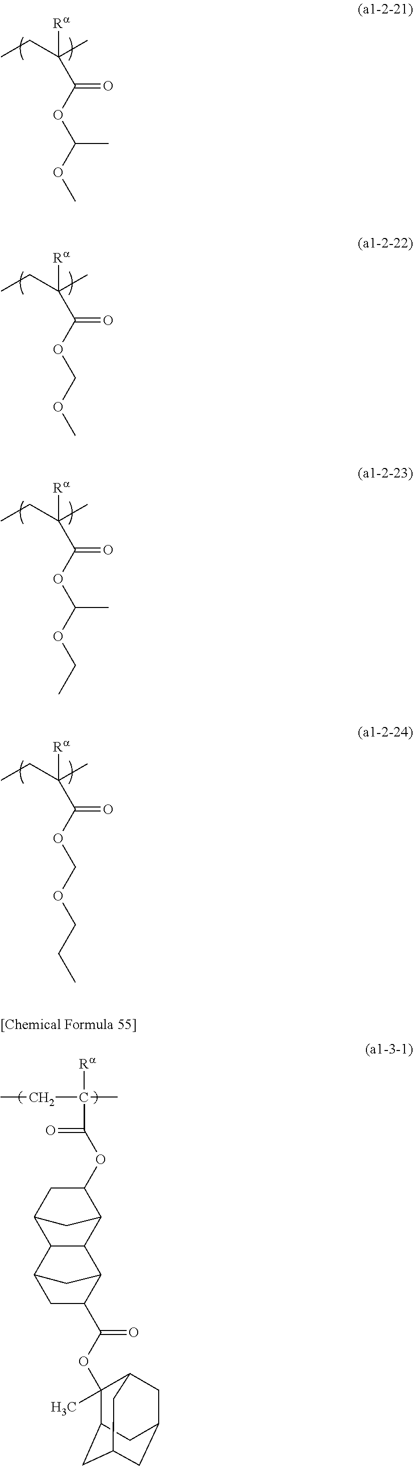

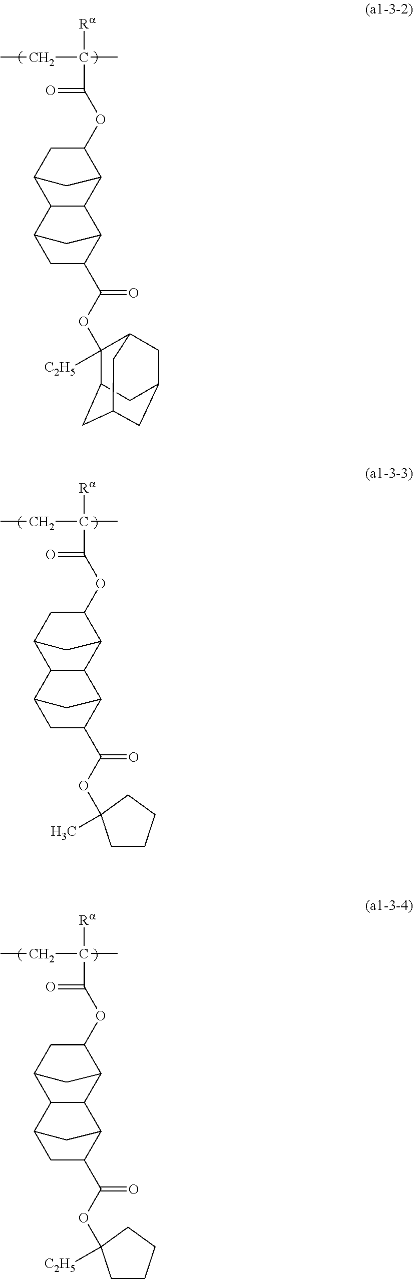

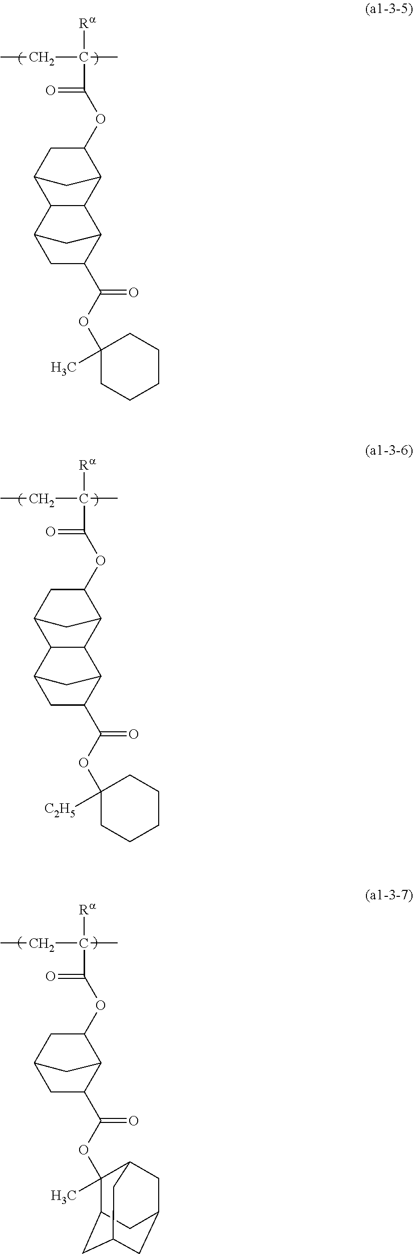

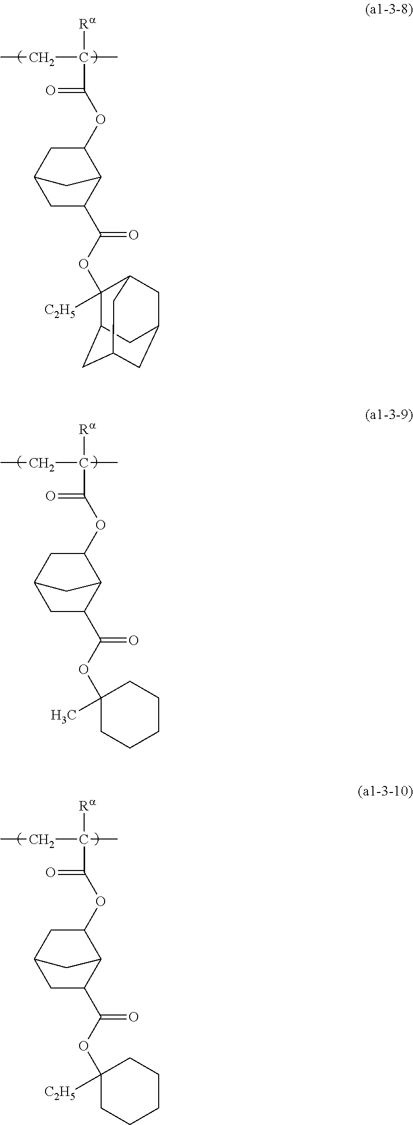

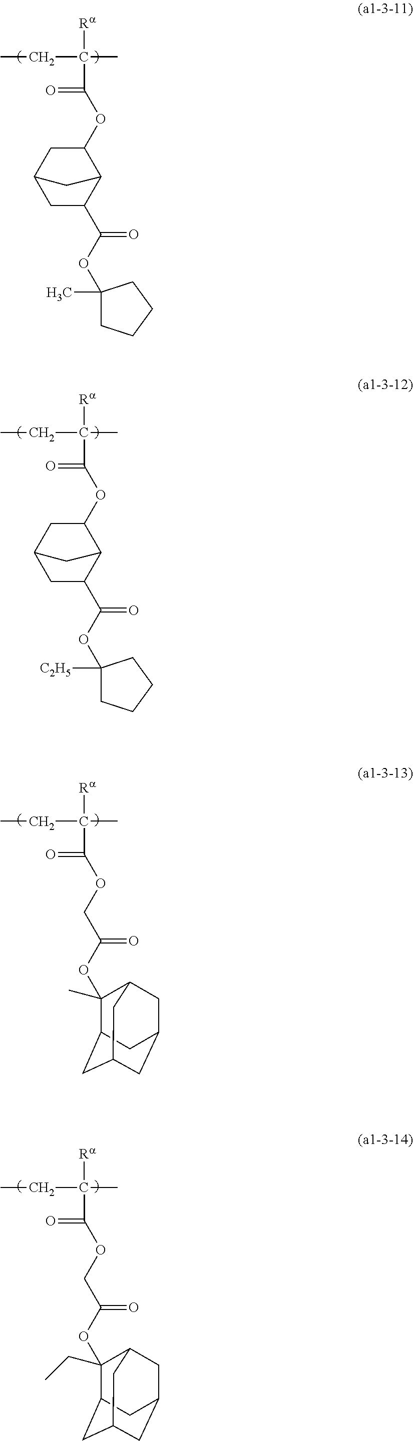

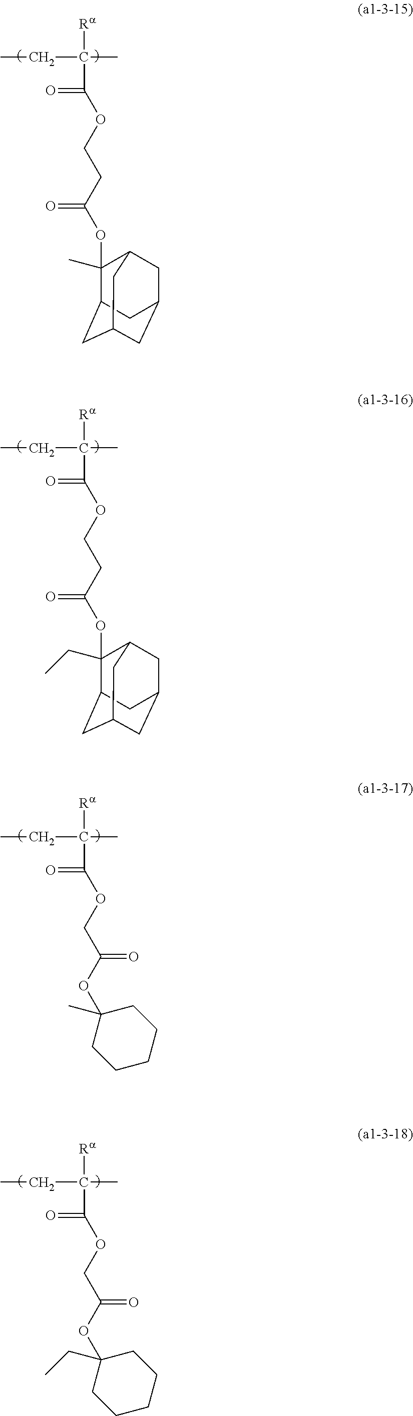

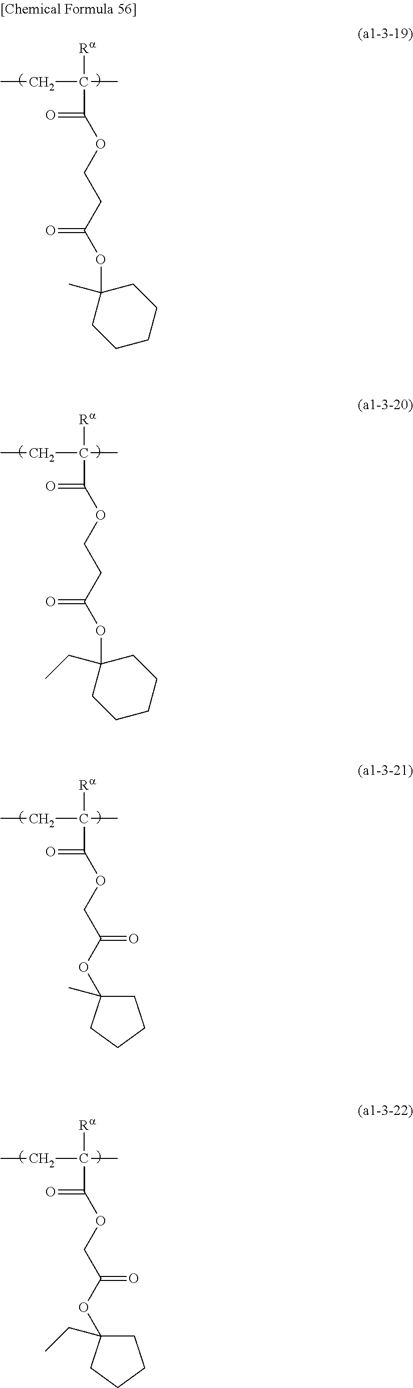

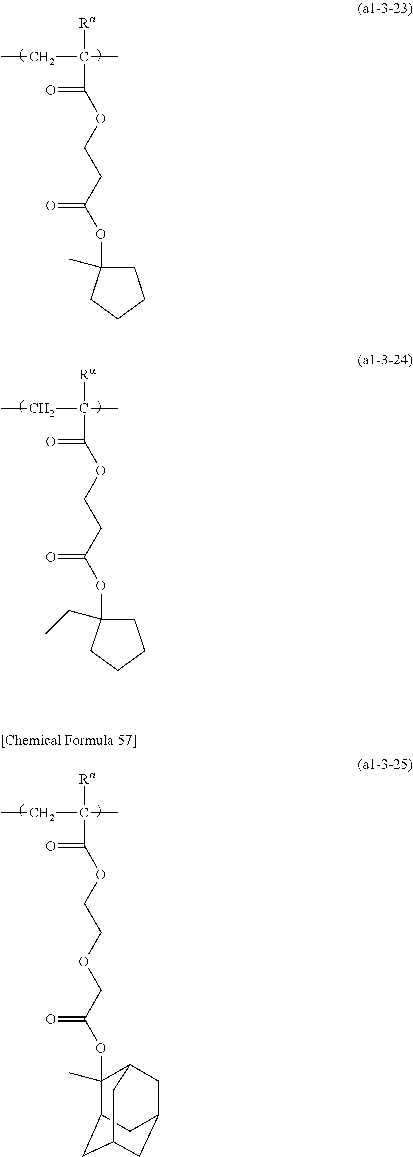

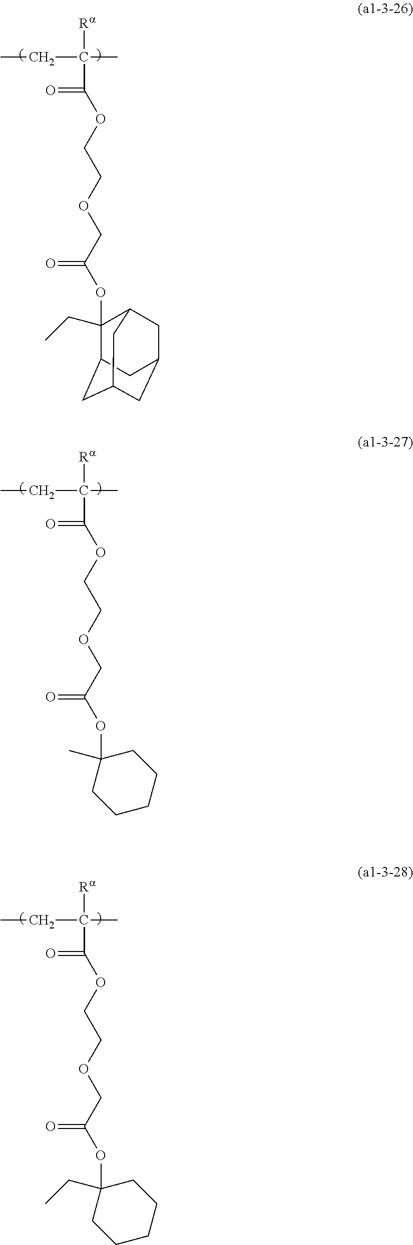

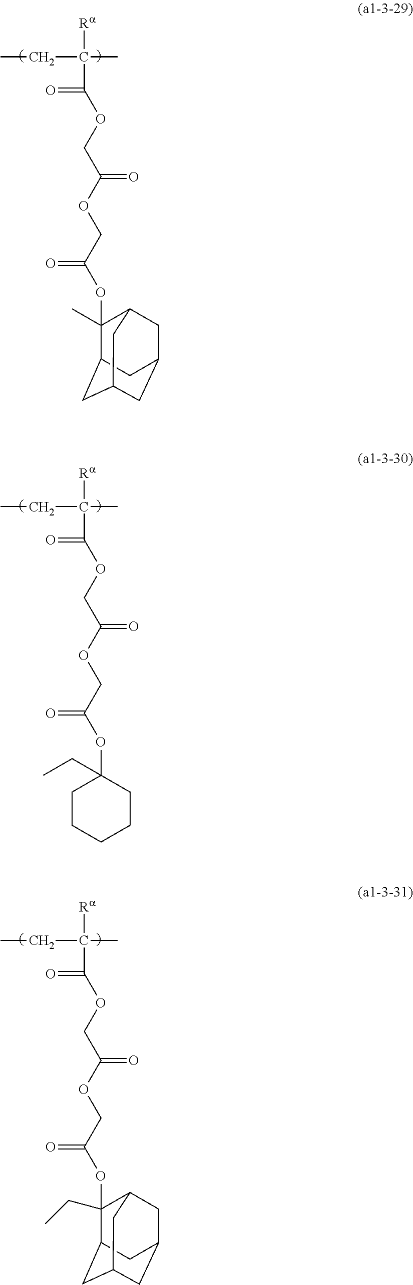

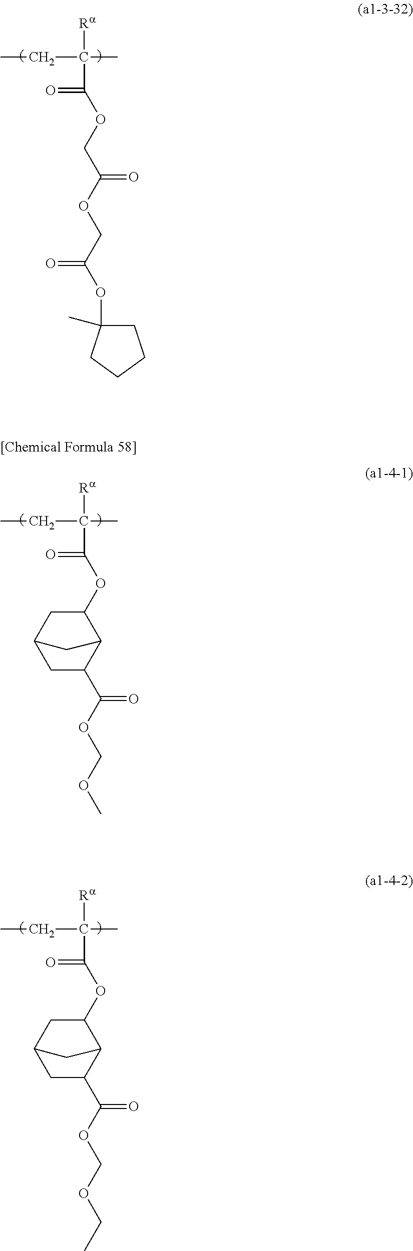

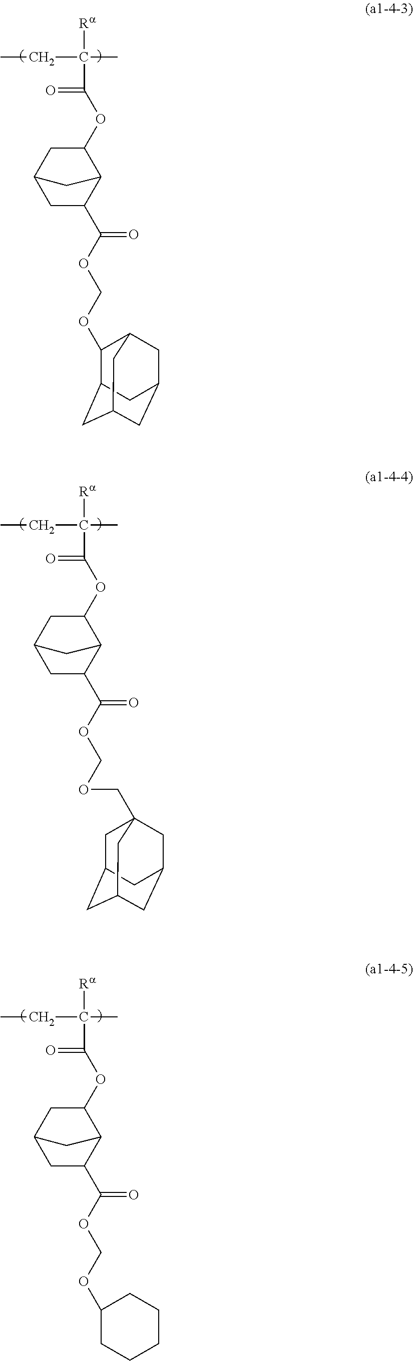

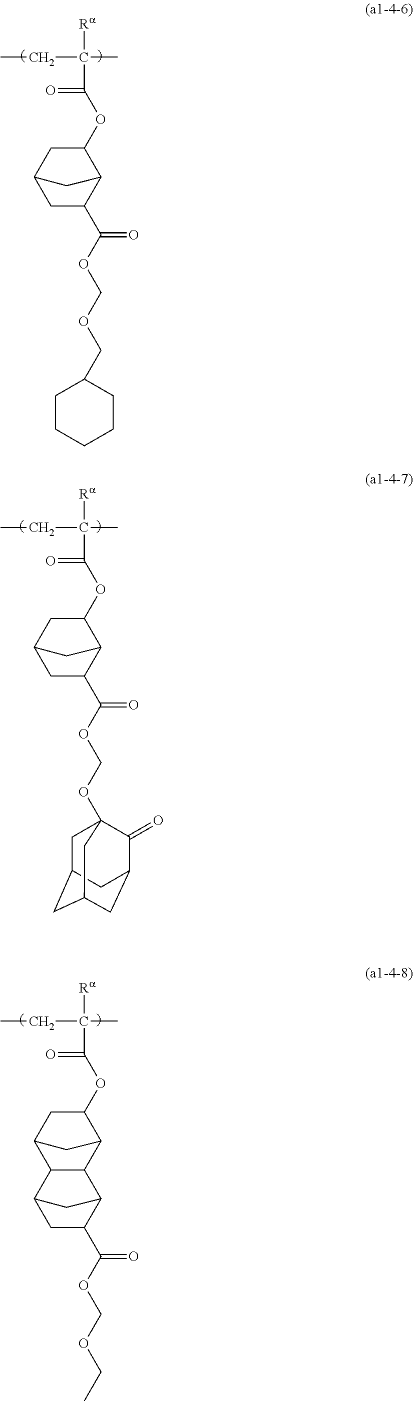

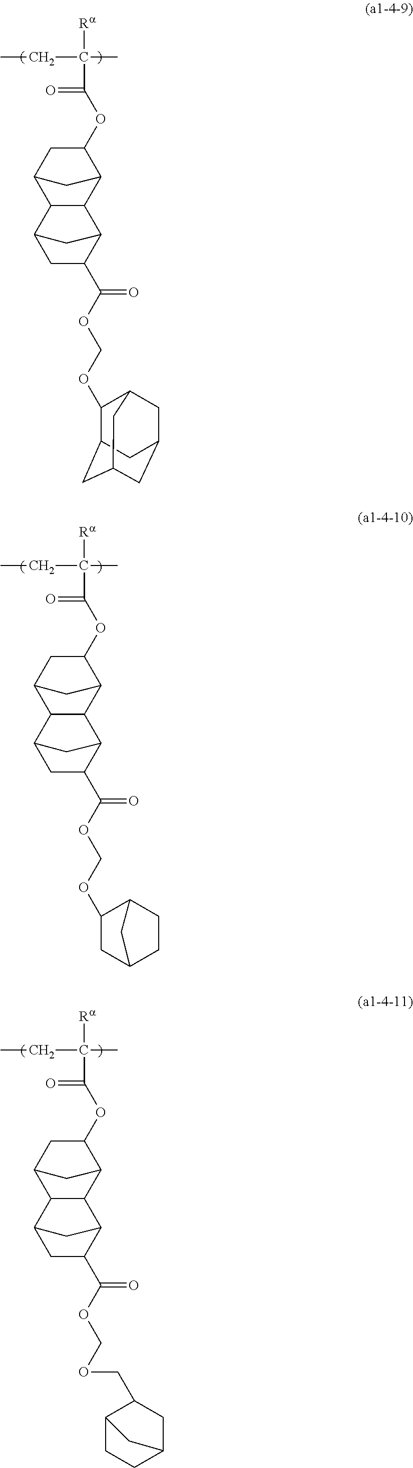

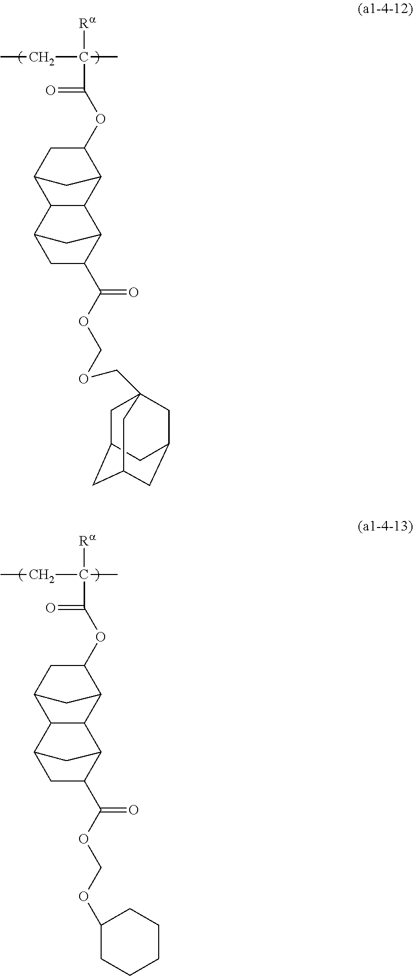

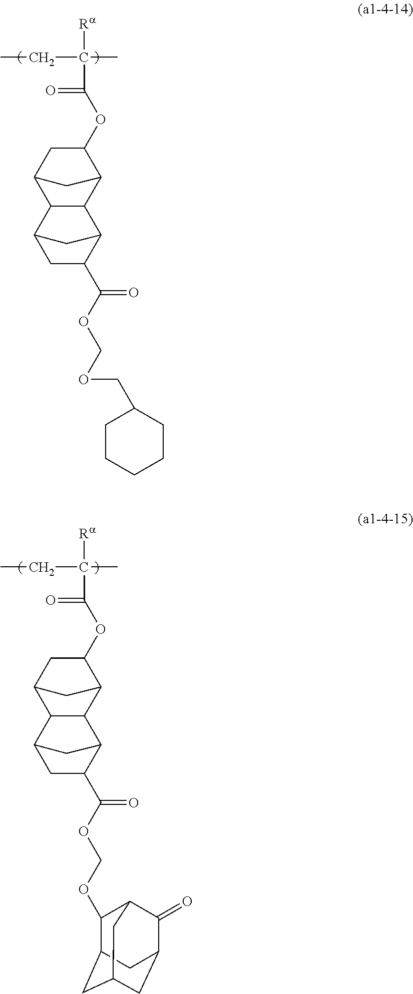

The present invention preferably includes, as the structural unit (a11), at least one structural unit selected from the group consisting of structural units represented by general formula (a1-0-11) shown below, structural units represented by general formula (a1-0-12) shown below, structural units represented by general formula (a1-0-13) shown below, and structural units represented by general formula (a1-0-2) shown below. Among these structural units, at least one structural unit selected from the group consisting of structural units represented by general formula (a1-0-11) shown below, structural units represented by general formula (a1-0-12) shown below and structural units represented by general formula (a1-0-2) shown below is particularly desirable.

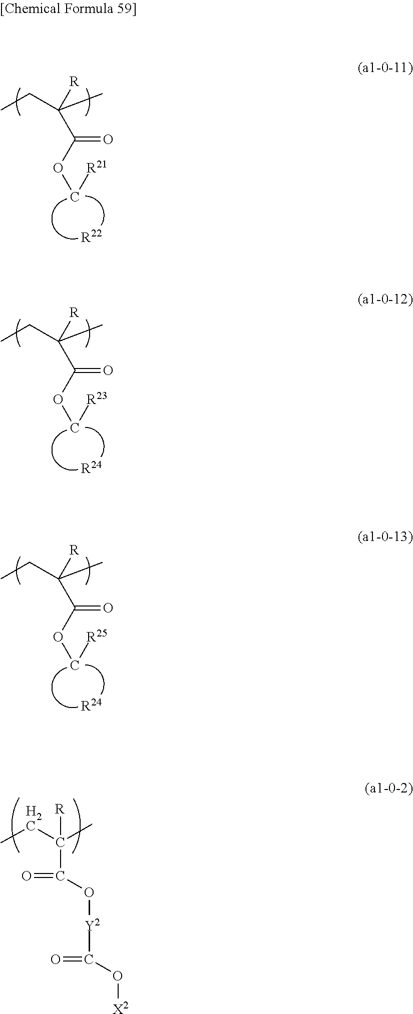

In the formulas, R represents a hydrogen atom, an alkyl group of 1 to 5 carbon atoms or a halogenated alkyl group of 1 to 5 carbon atoms, R²¹ represents an alkyl group, R²² represents a group that forms an aliphatic monocyclic group together with the carbon atom to which R²² is bonded, R²³ represents a branched alkyl group, R²⁴ represents a group that forms an aliphatic polycyclic group together with the carbon atom to which R²⁴ is bonded, R²⁵ represents a linear alkyl group of 1 to 5 carbon atoms, Y² represents a divalent linking group, and X² represents an acid dissociable group.

In each of the above formulas, R, Y² and X² are the same as defined above.

In formula (a1-0-11), examples of the alkyl group for R²¹ include the same alkyl groups as those described above for R¹⁴ in the formulas (1-1) to (1-9), and a methyl group, an ethyl group or an isopropyl group is preferred.

In terms of R²², examples of the aliphatic monocyclic group that is formed together with the carbon atom to which R²² is bonded include the same groups as the monocyclic groups among the aliphatic cyclic groups described above in connection with the tertiary alkyl ester-type acid dissociable groups. Specific examples include groups in which one or more hydrogen atoms have been removed from a monocycloalkane. The monocycloalkane is preferably a 3- to 11-membered ring, more preferably a 3- to 8-membered ring, still more preferably a 4- to 6-membered ring, and most preferably a 5- or 6-membered ring.

A portion of the carbon atoms that constitute the ring of the monocycloalkane may or may not be substituted with an ether group (—O—).

Further, the monocycloalkane may include an alkyl group of 1 to 5 carbon atoms, a fluorine atom, or a fluorinated alkyl group of 1 to 5 carbon atoms as a substituent.

Examples of the R²² group that constitutes the aliphatic monocyclic group include linear alkylene groups which may have an ether group (—O—) interposed between the carbon atoms of the alkylene chain.

Specific examples of the structural units represented by formula (a1-0-11) include structural units represented by the above formulas (a1-1-16) to (a1-1-23), (a1-1-27) and (a1-1-31). Among these, structural units represented by general formula (a1-1-02) shown below, which includes the structural units represented by formulas (a1-1-16) and (a1-1-17), formulas (a1-1-20) to (a1-1-23), and formulas (a1-1-27) and (a1-1-31) are preferred. Further, a structural unit represented by general formula (a1-1-02′) shown below is also preferable.

In each of the formulas below, h is preferably 1 or 2.

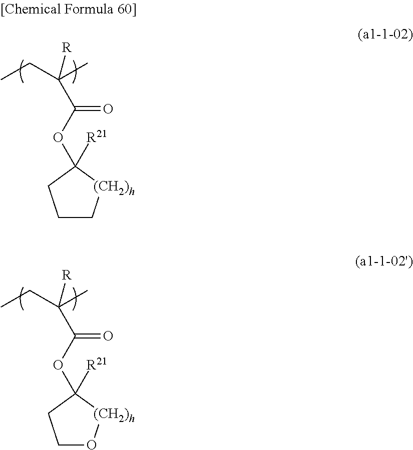

In the formulas, R and R²¹ are each the same as defined above, and h represents an integer of 1 to 4

In formula (a1-0-12), examples of the branched alkyl group for R²³ include the same branched alkyl groups as those described above for the alkyl group for R¹⁴ in the formulas (1-1) to (1-9), and an isopropyl group is particularly desirable.

Examples of the aliphatic polycyclic group formed by R²⁴ together with the carbon atom to which R²⁴ is bonded include the same groups as the polycyclic groups among the aliphatic cyclic groups described above in connection with the tertiary alkyl ester-type acid dissociable groups.

Specific examples of structural units represented by general formula (a1-0-12) include the structural units represented by the above formula (a1-1-26) and formulas (a1-1-28) to (a1-1-30).

The structural unit represented by formula (a1-1-12) is preferably a structural unit in which the aliphatic polycyclic group formed by R²⁴ together with the carbon atom to which R²⁴ is bonded is a 2-adamantyl group, and a structural unit represented by the above formula (a1-1-26) is particularly desirable.

In formula (a1-0-13), R and R²⁴ are each the same as defined above.

Examples of the linear alkyl group for R²⁵ include the same linear alkyl groups as those described above for the alkyl group for R¹⁴ in the formulas (1-1) to (1-9), and a methyl group or ethyl group is the most desirable.

Specific examples of the structural units represented by formula (a1-0-13) include the structural units represented by formulas (a1-1-1) to (a1-1-3) and formulas (a1-1-7) to (a1-1-15), which were listed above as specific examples of the general formula (a1-1).

The structural unit represented by formula (a1-0-13) is preferably a structural unit in which the aliphatic polycyclic group formed by R²⁴ together with the carbon atom to which R²⁴ is bonded is a 2-adamantyl group, and a structural unit represented by the above formula (a1-1-1) or (a1-1-2) is particularly desirable.

Examples of the structural units represented by formula (a1-0-2) include structural units represented by the above formulas (a1-3) and (a1-4), and of these, a structural unit represented by formula (a1-3) is particularly desirable.

In particular, the structural unit represented by general formula (a1-0-2) is preferably a structural unit in which Y² in the formula is a group represented by the above formula —Y²¹—O—Y²²—, a group represented by the above formula —Y²¹—O—C(═O)—Y²²— or a group represented by the above formula —Y²¹—O—C(═O)—.

Preferred examples of such structural units include structural units represented by general formula (a1-3-01) shown below, structural units represented by general formula (a1-3-02) shown below, and structural units represented by general formula (a1-3-03) shown below.

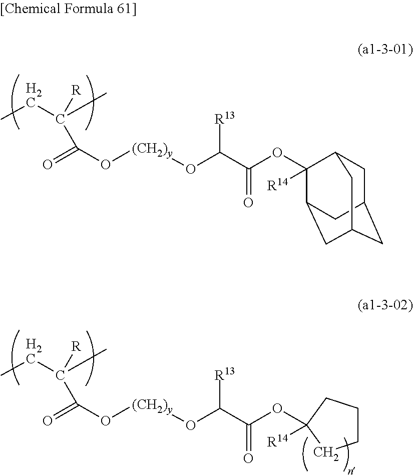

In the formulas, R is the same as defined above; R¹³ represents a hydrogen atom or a methyl group; R¹⁴ represents an alkyl group; y represents an integer of 1 to 10; and n′ represents an integer of 0 to 3.

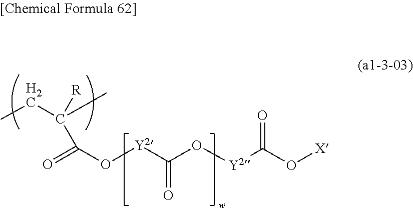

In the formula, R is the same as defined above; each of Y²′ and Y²″ independently represents a divalent linking group; X′ represents an acid dissociable group; and w represents an integer of 0 to 3.

In formulas (a1-3-01) to (a1-3-02), R¹³ is preferably a hydrogen atom.

R¹⁴ is the same as defined above for R¹⁴ in formulas (1-1) to (1-9).

y is preferably an integer of 1 to 8, more preferably an integer of 1 to 5, and most preferably 1 or 2.

n′ is preferably 1 or 2, and most preferably 2.

Specific examples of the structural units represented by formula (a1-3-01) include the structural units represented by the above formulas (a1-3-25) and (a1-3-26).

Specific examples of the structural units represented by general formula (a1-3-02) include structural units represented by the aforementioned formulas (a1-3-27) and (a1-3-28).

Examples of the divalent linking groups for Y²′ and Y²″ in formula (a1-3-03) include the same groups as those described above for Y² in the general formula (a1-3).

Y²′ is preferably a divalent hydrocarbon group which may have a substituent, is more preferably a linear aliphatic hydrocarbon group, and is still more preferably a linear alkylene group. Among such groups, a linear alkylene group of 1 to 5 carbon atoms is preferable, and a methylene group or an ethylene group is the most desirable.

Y²″ is preferably a divalent hydrocarbon group which may have a substituent, is more preferably a linear aliphatic hydrocarbon group, and is still more preferably a linear alkylene group. Among such groups, a linear alkylene group of 1 to 5 carbon atoms is preferable, and a methylene group or an ethylene group is the most desirable.

The acid dissociable group for X′ is the same as defined above, is preferably a tertiary alkyl ester-type acid dissociable group, is more preferably a group of type (i) described above, in which a substituent is bonded to a carbon atom that is bonded to the atom adjacent to the acid-dissociable group, thereby forming a tertiary carbon atom on the ring structure of a monovalent aliphatic cyclic group, and is most preferably a group represented by the above general formula (1-1).

w represents an integer of 0 to 3, and is preferably an integer of 0 to 2, more preferably 0 or 1, and most preferably 1.

The structural unit represented by general formula (a1-3-03) is preferably a structural unit represented by general formula (a1-3-03-1) or (a1-3-03-2) shown below, and among these, is most preferably a structural unit represented by formula (a1-3-03-1).

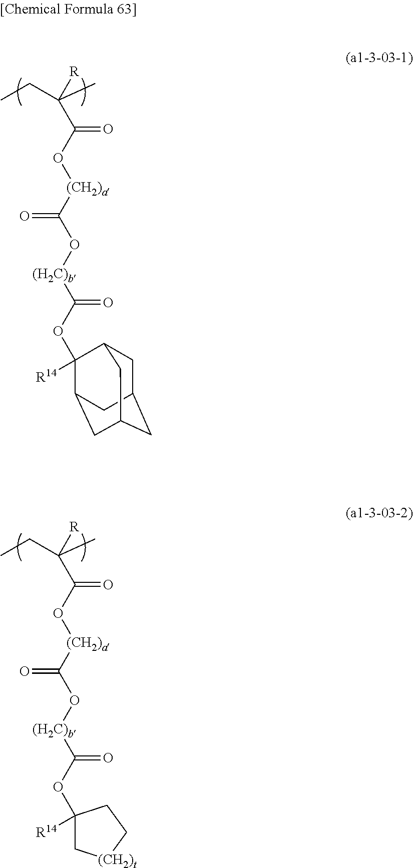

In the formulas, R and R¹⁴ are the same as defined above, a′ represents an integer of 1 to 10, b′ represents an integer of 1 to 10, and t represents an integer of 0 to 3.

In formulas (a1-3-03-1) and (a1-3-03-2), a′ is preferably an integer of 1 to 8, more preferably an integer of 1 to 5, and most preferably 1 or 2.

b′ is preferably an integer of 1 to 8, more preferably an integer of 1 to 5, and most preferably 1 or 2.

t is preferably an integer of 1 to 3, and most preferably 1 or 2.

Specific examples of the structural units represented by formulas (a1-3-03-1) and (a1-3-03-2) include the structural units represented by the above formulas (a1-3-29) to (a1-3-32).

{Structural Unit (a12)}

The structural unit (a12) is a structural unit derived from a hydroxystyrene in which the hydrogen atom bonded to the carbon atom on the α-position may be substituted with a substituent and a hydrogen atom bonded to the benzene ring may be substituted with a substituent other than a hydroxyl group, and in which the hydrogen atom of the hydroxyl group is substituted with an acid dissociable group or a substituent containing an acid dissociable group.

Examples of the acid dissociable group that substitutes the hydrogen atom of the hydroxyl group include the same acid dissociable groups as those described above. Of these, a tertiary alkyl ester-type acid dissociable group or an acetal-type acid dissociable group is preferred, and an acetal-type acid dissociable group is particularly desirable.

Examples of the aforementioned substituent containing an acid dissociable group include groups composed of an acid dissociable group and a divalent linking group. Examples of the divalent linking group include the same divalent linking groups as those described above for L⁰¹ in the general formula (I-1) within the description relating to the component (C), and a group in which the terminal structure on the acid dissociable group-side of the group is a carbonyloxy group is particularly desirable. In such a case, the acid dissociable group is preferably bonded to the oxygen atom (—O—) of the carbonyloxy group.

As the substituent containing an acid dissociable group, groups represented by a formula R¹¹′—O—C(═O)— and groups represented by a formula R¹′—O—C(═O)—R¹²′— are preferred. In these formulas, R¹¹ represents an acid dissociable group, and R¹²′ represents a linear or branched alkylene group.

The acid dissociable group for R¹¹′ is preferably a tertiary alkyl ester-type acid dissociable group or an acetal-type acid dissociable group, and is more preferably a tertiary alkyl ester-type acid dissociable group. Preferred examples of the tertiary alkyl ester-type acid dissociable group include the aforementioned aliphatic branched, acid dissociable groups represented by the formula —C(R⁷¹)(R⁷²)(R⁷³), groups represented by the above formulas (1-1) to (1-9), and groups represented by the above formulas (2-1) to (2-6).

Examples of the alkylene group for R¹²′ include a methylene group, an ethylene group, a trimethylene group, a tetramethylene group and a 1,1-dimethylethylene group. A linear alkylene group is preferred as R¹²′.

Specific examples of the structural unit (a12) include the structural units represented by general formula (U-3) described above within the description of the component (C) in which px of —(OX^{c})ₚₓ bonded to a benzene ring is an integer of 1 to 3, and at least one of X^{c} is an acid dissociable group or a substituent containing an acid dissociable group. If px is 2 or 3, the plurality of groups may be the same or different from each other. For example, one of them may represent an acid dissociable group or a substituent containing an acid dissociable group, while the other one or two represent a hydrogen atom.

{Structural Unit (a13)}

The structural unit (a13) is a structural unit derived from a vinyl(hydroxynaphthalene) in which the hydrogen atom bonded to the carbon atom on the α-position may be substituted with a substituent and a hydrogen atom bonded to the naphthalene ring may be substituted with a substituent other than a hydroxyl group, and in which the hydrogen atom of the hydroxyl group is substituted with an acid dissociable group or a substituent containing an acid dissociable group.

In the structural unit (a13), examples of the acid dissociable group or the substituent containing an acid dissociable group that substitute the hydrogen atom of the hydroxyl group include the same groups as those mentioned above within the description of the structural unit (a12).

Specific examples of the structural unit (a13) include the structural units represented by general formula (U-4) described above within the description of the component (C) in which x of —(OX^{d})ₓ bonded to a benzene ring is an integer of 1 to 3, and at least one of X^{d} is an acid dissociable group or a substituent containing an acid dissociable group.

If x is 2 or 3, the plurality of X^{d} groups may be the same or different from each other. For example, one of them may represent an acid dissociable group or a substituent containing an acid dissociable group, while the other one or two represent a hydrogen atom.

The structural unit (a1) contained within the component (A1) may be either a single type of structural unit or a combination of two or more types of structural units.

The amount of the structural unit (a1)) within the component (A1), based on the combined total of all the structural units that constitute the component (A1), is preferably within a range from 15 to 70 mol %, more preferably from 15 to 60 mol %, and still more preferably from 20 to 55 mol %. When the amount of the structural unit (a1) is at least as large as the lower limit of the above range, a pattern can be formed easily using a resist composition prepared from the component (A1), and the lithography properties such as the sensitivity, the resolution and the pattern shape also improve. On the other hand, when the amount of the structural unit (a1) is not more than the upper limit of the above range, a good balance can be achieved with the other structural units.

(Structural Unit (a2))

It is preferable that the component (A1) also have a structural unit (a2) containing a —SO₂— containing cyclic group or a lactone-containing cyclic group, as well as the structural units (a0) and (a1).

When the component (A1) is used in forming a resist film, the —SO₂— containing cyclic group or a lactone-containing cyclic group of the structural unit (a2) is effective in improving the adhesion between the resist film and the substrate. Further, the —SO₂— containing cyclic group or lactone-containing cyclic group is also effective in an alkali developing process in terms of improving the compatibility of the resist with developing solutions containing water, such as an alkali developing solution.

In the case of an aforementioned structural unit (a0) or (a1) that also includes an —SO₂-containing cyclic group or lactone-containing cyclic group within the structure, although such a structural unit also corresponds with the structural unit (a2), it is deemed to be a structural unit (a0) or (a1) and is excluded from the definition of the structural unit (a2).

Here, an “—SO₂— containing cyclic group” refers to a cyclic group having a ring containing —SO₂— within the ring skeleton thereof, and more specifically, a cyclic group in which the sulfur atom (S) within —SO₂— forms part of the ring skeleton of the cyclic group. In the —SO₂— containing cyclic group, the ring containing the —SO₂— group within the ring structure is counted as the first ring, so that groups containing only the first ring are referred to as monocyclic groups, and groups containing other ring structures are described as polycyclic groups regardless of the structure of the other rings. The —SO₂— containing cyclic group may be either a monocyclic group or a polycyclic group.

As the —SO₂— containing cyclic group, a cyclic group containing —O—SO₂— within the ring skeleton thereof, i.e., a cyclic group containing a sultone ring in which —O—S— within the —O—SO₂— group forms part of the ring skeleton thereof is particularly desirable.

The —SO₂— containing cyclic group preferably contains 3 to 30 carbon atoms, more preferably 4 to 20 carbon atoms, still more preferably 4 to 15 carbon atoms, and most preferably 4 to 12 carbon atoms. Here, the number of carbon atoms refers to the number of carbon atoms that constitute the ring skeleton, and does not include carbon atoms contained within substituents.

The —SO₂— containing cyclic group may be either a —SO₂— containing aliphatic cyclic group or a —SO₂— containing aromatic cyclic group. A —SO₂— containing aliphatic cyclic group is preferable.

Examples of the —SO₂— containing aliphatic cyclic group include aliphatic cyclic groups in which part of the carbon atoms constituting the ring skeleton thereof has been substituted with a —SO₂— group or a —O—SO₂— group and has at least one hydrogen atom removed from the aliphatic hydrocarbon ring. More specific examples include groups in which at least one hydrogen atom has been removed from an aliphatic hydrocarbon ring in which a —CH₂— group that constitutes part of the ring structure has been substituted with an —SO₂— group, and groups in which at least one hydrogen atom has been removed from an aliphatic hydrocarbon ring in which a —CH₂—CH₂— group that constitutes part of the ring structure has been substituted with an —O—SO₂— group.

The aliphatic hydrocarbon ring preferably has 3 to 20 carbon atoms, and more preferably 3 to 12 carbon atoms.

The aliphatic hydrocarbon ring may be either a polycyclic group or a monocyclic group. As the monocyclic alicyclic hydrocarbon group, a group in which two hydrogen atoms have been removed from a monocycloalkane of 3 to 6 carbon atoms is preferable. Examples of the monocycloalkane include cyclopentane and cyclohexane. As the polycyclic alicyclic hydrocarbon group, a group in which two hydrogen atoms have been removed from a polycycloalkane of 7 to 12 carbon atoms is preferable. Examples of the polycycloalkane include adamantane, norbornane, isobornane, tricyclodecane and tetracyclododecane.

The —SO₂— containing cyclic group may have a substituent. Examples of the substituent include an alkyl group, an alkoxy group, a halogen atom, a halogenated alkyl group, a hydroxyl group, an oxygen atom (═O), —COOR″, —OC(═O)R″, a hydroxyalkyl group and a cyano group.

The alkyl group for the substituent is preferably an alkyl group of 1 to 6 carbon atoms. The alkyl group is preferably a linear alkyl group or a branched alkyl group. Specific examples include a methyl group, an ethyl group, a propyl group, an isopropyl group, an n-butyl group, an isobutyl group, a tert-butyl group, a pentyl group, an isopentyl group, a neopentyl group and a hexyl group. Among these, a methyl group or ethyl group is preferable, and a methyl group is particularly desirable.

As the alkoxy group for the substituent, an alkoxy group of 1 to 6 carbon atoms is preferable. Further, the alkoxy group is preferably a linear alkoxy group or a branched alkyl group. Specific examples of the alkoxy group include the aforementioned alkyl groups for the substituent having an oxygen atom (—O—) bonded thereto.

Examples of the halogen atom for the substituent include a fluorine atom, a chlorine atom, a bromine atom and an iodine atom, and a fluorine atom is preferable.

As examples of the halogenated alkyl group for the substituent, groups in which part or all of the hydrogen atoms of the aforementioned alkyl groups for the substituent have been substituted with the aforementioned halogen atoms can be given. A fluorinated alkyl group is preferred as the halogenated alkyl group, and a perfluoroalkyl group is particularly desirable.

In the —COOR″ group and the —OC(═O)R″ group, R″ represents a hydrogen atom or a linear, branched or cyclic alkyl group of 1 to 15 carbon atoms.

When R″ represents a linear or branched alkyl group, it is preferably an alkyl group of 1 to 10 carbon atoms, more preferably an alkyl group of 1 to 5 carbon atoms, and most preferably a methyl group or an ethyl group.

When R″ is a cyclic alkyl group (cycloalkyl group), it preferably contains 3 to 15 carbon atoms, more preferably 4 to 12 carbon atoms, and most preferably 5 to 10 carbon atoms. As examples of the cyclic alkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane and cyclohexane; and groups in which one or more hydrogen atoms have been removed from a polycycloalkane such as adamantane, norbornane, isobornane, tricyclodecane or tetracyclododecane.

The hydroxyalkyl group for the substituent preferably has 1 to 6 carbon atoms, and specific examples thereof include the aforementioned alkyl groups for the substituent in which at least one hydrogen atom has been substituted with a hydroxyl group.

More specific examples of the —SO₂— containing cyclic group include groups represented by general formulas (3-1) to (3-4) shown below.

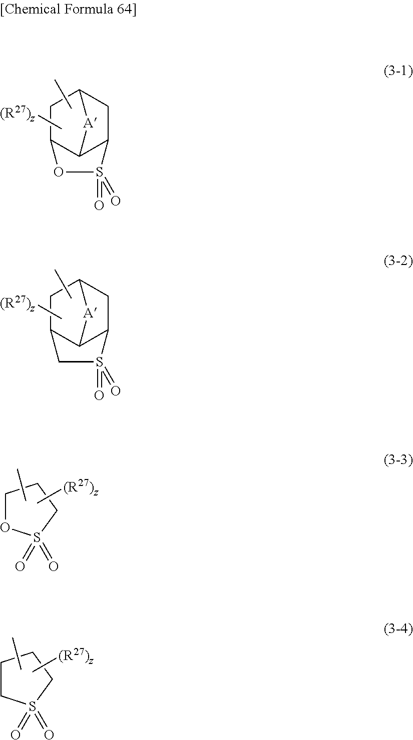

In the formulas, A′ represents an oxygen atom, a sulfur atom or an alkylene group of 1 to 5 carbon atoms which may contain an oxygen atom or a sulfur atom; z represents an integer of 0 to 2; and R²⁷ represents an alkyl group, an alkoxy group, a halogenated alkyl group, a hydroxyl group, —COOR″, —OC(═O)R″, a hydroxyalkyl group or a cyano group, wherein R″ represents a hydrogen atom or an alkyl group.

In the general formulas (3-1) to (3-4) above, A′ represents an oxygen atom (—O—), a sulfur atom (—S—), or an alkylene group of 1 to 5 carbon atoms which may contain an oxygen atom or a sulfur atom.

As the alkylene group of 1 to 5 carbon atoms represented by A′, a linear or branched alkylene group is preferable, and examples thereof include a methylene group, an ethylene group, an n-propylene group and an isopropylene group.

Examples of the alkylene groups that contain an oxygen atom or a sulfur atom include the aforementioned alkylene groups in which —O— or —S— is bonded to the terminal of the alkylene group or present between the carbon atoms of the alkylene group. Specific examples of such alkylene groups include —O—CH₂—, —S—CH₂— and —CH₂—S—CH₂—.

As A′, an alkylene group of 1 to 5 carbon atoms or —O— is preferable, more preferably an alkylene group of 1 to 5 carbon atoms, and most preferably a methylene group.

z represents an integer of 0 to 2, and is most preferably 0.

When z is 2, the plurality of R²⁷ may be the same or different from each other.

As the alkyl group, alkoxy group, halogenated alkyl group, —COOR″, —OC(═O)R″ and hydroxyalkyl group for R²⁷, the same alkyl groups, alkoxy groups, halogenated alkyl groups, —COOR″, —OC(═O)R″ and hydroxyalkyl groups as those described above as the substituent which the —SO₂— containing cyclic group may have can be used.

Specific examples of the cyclic groups represented by general formulas (3-1) to (3-4) are shown below. In the formulas shown below, “Ac” represents an acetyl group.

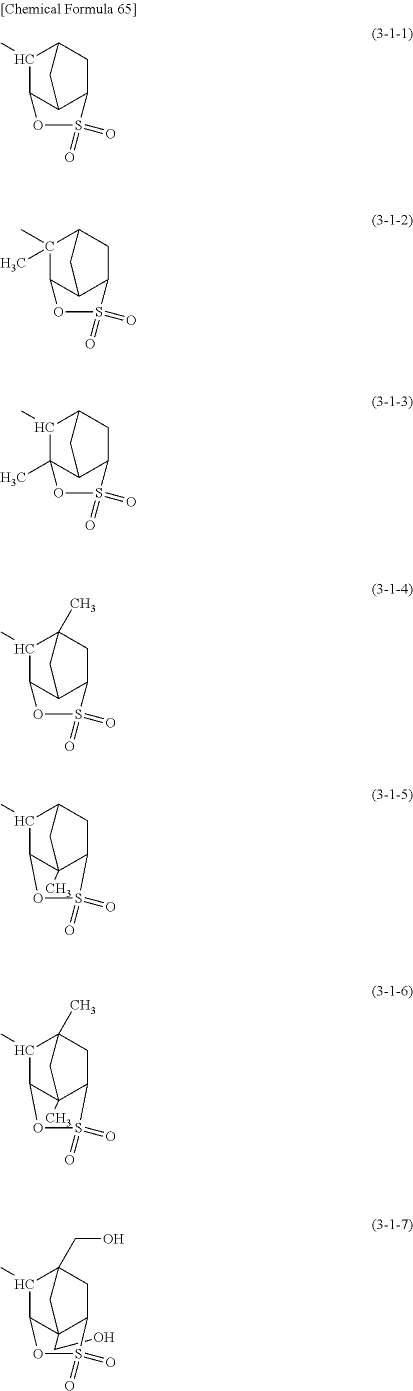

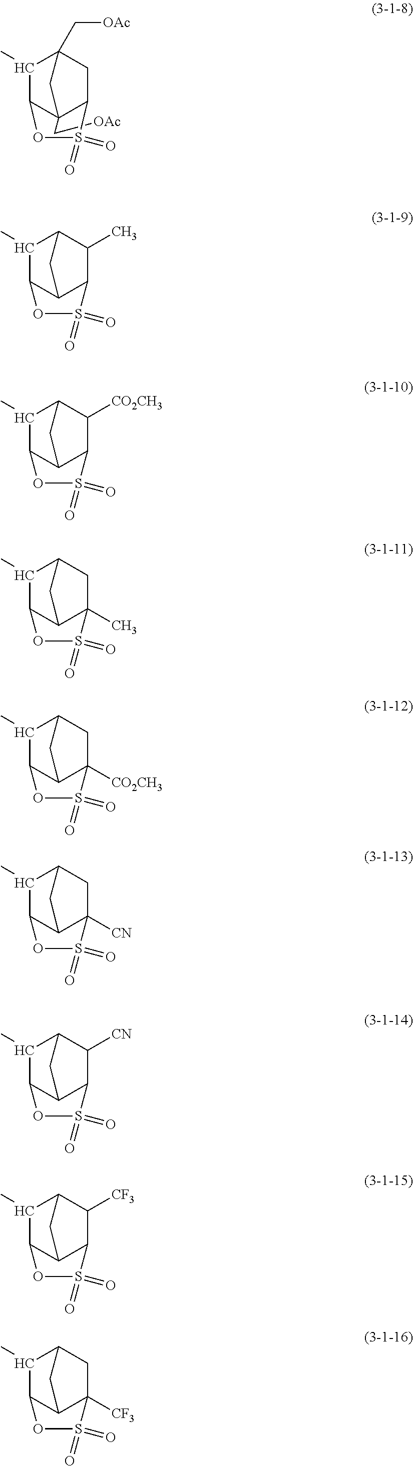

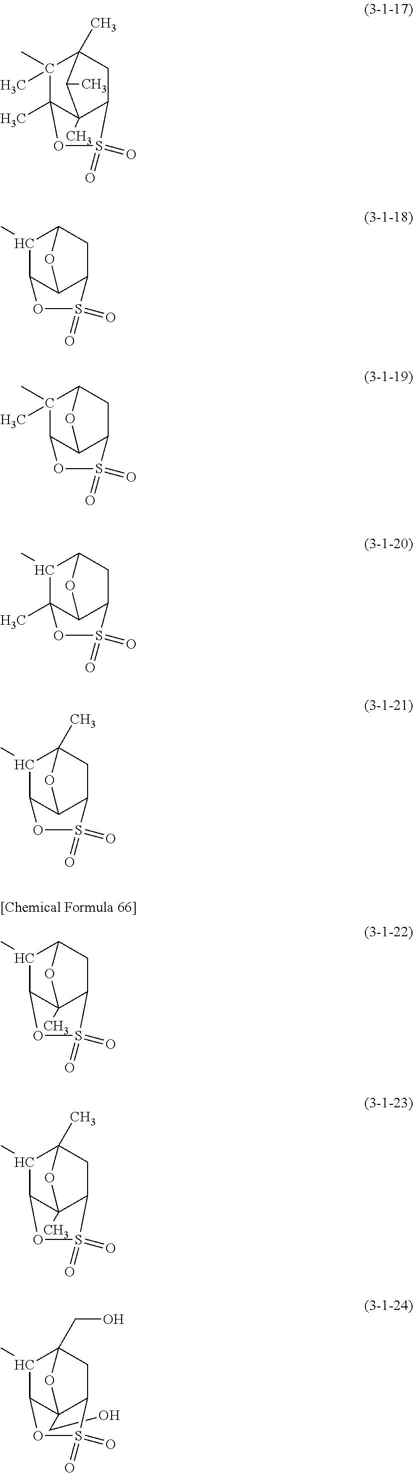

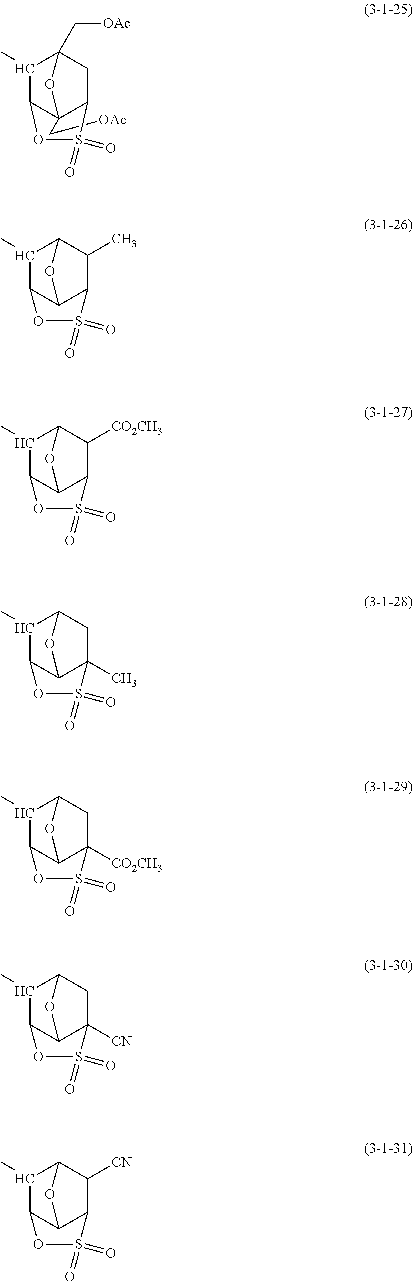

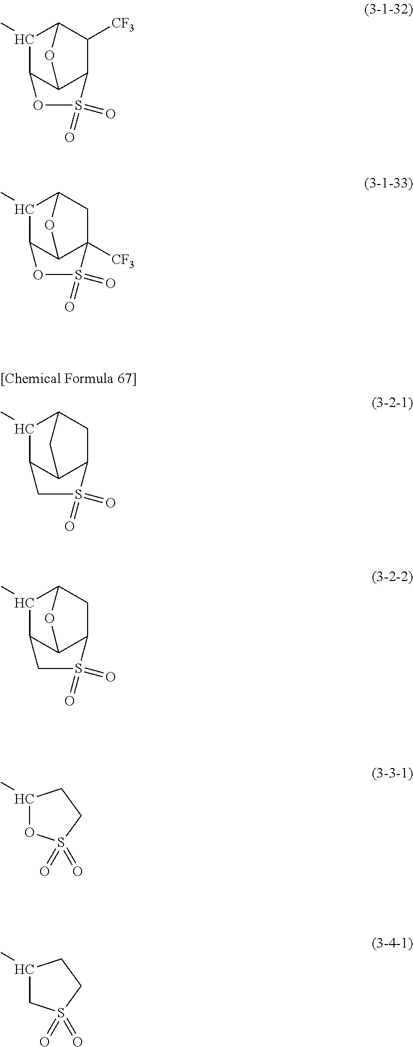

Of the various possibilities described above, as the —SO₂— containing cyclic group, a group represented by the aforementioned general formula (3-1) is preferable, at least one member selected from the group consisting of groups represented by any one of the aforementioned chemical formulas (3-1-1), (3-1-18), (3-3-1) and (3-4-1) is more preferable, and a group represented by the aforementioned chemical formula (3-1-1) is most preferable.

The term “lactone-containing cyclic group” refers to a cyclic group including a ring containing a —O—C(═O)— group within the ring structure thereof (lactone ring). The lactone ring is counted as the first ring, and a lactone-containing cyclic group in which the only ring structure is the lactone ring is referred to as a monocyclic group, and groups containing other ring structures are described as polycyclic groups regardless of the structure of the other rings. The lactone-containing cyclic group may be either a monocyclic group or a polycyclic group.

There are no particular limitations on the lactone-containing cyclic group within the structural unit (a2), and an arbitrary lactone-containing cyclic group may be used. Specific examples of lactone-containing monocyclic groups include a group in which one hydrogen atom has been removed from a 4- to 6-membered lactone ring, such as a group in which one hydrogen atom has been removed from β-propiolactone, a group in which one hydrogen atom has been removed from γ-butyrolactone, and a group in which one hydrogen atom has been removed from δ-valerolactone. Further, specific examples of lactone-containing polycyclic groups include groups in which one hydrogen atom has been removed from a lactone ring-containing bicycloalkane, tricycloalkane or tetracycloalkane.

As the structural unit (a2), as long as it contains an —SO₂— containing cyclic group and a lactone-containing cyclic group, there are no particular limitations on the structure of other sites, although it is preferably at least one type of structural unit selected from the group consisting of structural units (a2^{S}) derived from an acrylate ester in which the hydrogen atom bonded to the carbon atom on the α-position may be substituted with a substituent and containing an —SO₂-containing cyclic group, and structural units (a2^{L}) derived from an acrylate ester in which the hydrogen atom bonded to the carbon atom on the α-position may be substituted with a substituent and containing a lactone-containing cyclic group.

Structural Unit (a2^{S}):

More specific examples of the structural unit a2^{S}) include structural units represented by general formula (a2-0) shown below.

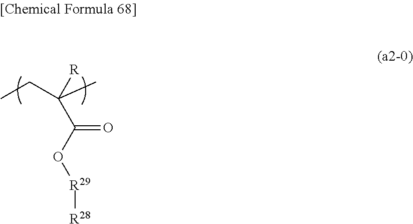

In the formula, R represents a hydrogen atom, an alkyl group of 1 to 5 carbon atoms or a halogenated alkyl group of 1 to 5 carbon atoms; R²⁸ represents a —SO₂— containing cyclic group; and R²⁹ represents a single bond or a divalent linking group.

In genera formula (a2-0), R is the same as defined above.

R²⁸ is the same as defined for the aforementioned —SO₂— containing cyclic group.

R²⁹ may be either a single bond or a divalent linking group. A divalent linking group is preferable in terms of achieving superior effects for the present invention.

The divalent linking group for R²⁹ is not particularly limited, and examples thereof include the same divalent linking groups as those described above for L⁰¹ in the general formula (I-1) within the description relating to the component (C). Among these, an alkylene group or a divalent linking group containing an ester bond (—C(═O)—O—) is preferable.

The alkylene group is preferably a linear or branched alkylene group. Specific examples include the same groups as the linear alkylene groups and branched alkylene groups described above as the aliphatic hydrocarbon group for Y².

As the divalent linking group containing an ester bond, a group represented by general formula: —R³⁰—C(═O)—O— (in the formula, R³⁰ represents a divalent linking group) is particularly desirable. That is, the structural unit (a2^{S}) is preferably a structural unit represented by general formula (a2-0-1) shown below.

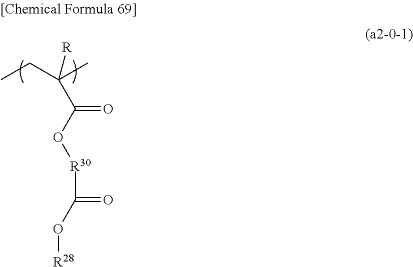

In the formula, R and R²⁸ are the same as defined above; and R³⁰ represents a divalent linking group.

R³⁰ is not particularly limited, and examples thereof include the same divalent linking groups as those described above for L⁰¹ in the general formula (I-1) within the description relating to the component (C).

As the divalent linking group for R³⁰, a linear or branched alkylene group, an aliphatic hydrocarbon group containing a ring within the structure thereof, or a divalent linking group containing a hetero atom is preferred, and a linear or branched alkylene group or a divalent linking group containing an oxygen atom as a hetero atom is more preferred.

As the linear alkylene group, a methylene group or an ethylene group is preferred, and a methylene group is particularly desirable.

As the branched alkylene group, an alkylmethylene group or an alkylethylene group is preferred, and —CH(CH₃)—, —C(CH₃)₂— or —C(CH₃)₂CH₂— is particularly desirable.

As the divalent linking group containing an oxygen atom, divalent linking groups containing an ether bond or an ester bond are preferred, and groups represented by the aforementioned formulas —Y²¹—O—Y²²—, —[Y²¹—C(═O)—O]_{m′}—Y²²— and —Y²¹—O—C(═O)—Y²²— are more preferred. Each of Y²¹ and Y²² independently represents a divalent hydrocarbon group which may have a substituent, and m′ represents an integer of 0 to 3. Among these, a group represented by the formula —Y²¹—O—C(═O)—Y²²— is preferred, and a group represented by the formula —(CH₂)_{c}—O—C(═O)—(CH₂)_{d}— is particularly desirable. c represents an integer of 1 to 5, and is preferably 1 or 2. d represents an integer of 1 to 5, and is preferably 1 or 2.

In particular, as the structural unit (a2^{S}), a structural unit represented by general formula (a2-0-11) or (a2-0-12) shown below is preferred, and a structural unit represented by general formula (a2-0-12) shown below is more preferred.

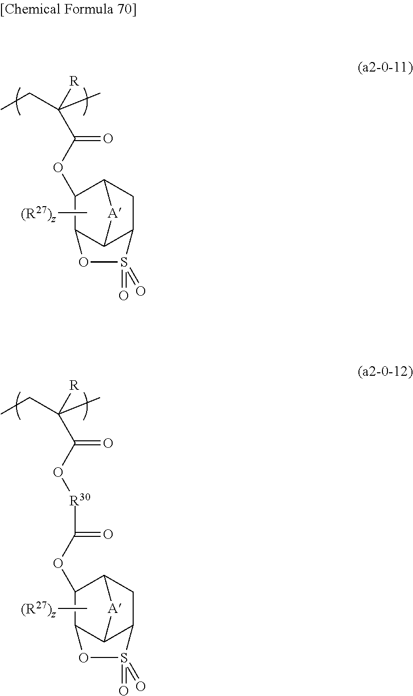

In the formulas, R, A′, R²⁷, z and R³⁰ are the same as defined above.

In formula (a2-0-11), A′ is preferably a methylene group, an oxygen atom (—O—) or a sulfur atom (—S—).

As R³⁰, a linear or branched alkylene group or a divalent linking group containing an oxygen atom is preferable. As the linear or branched alkylene group and the divalent linking group containing an oxygen atom represented by R³⁰, the same linear or branched alkylene groups and the divalent linking groups containing an oxygen atom as those described above can be mentioned.

As the structural unit represented by the formula (a2-0-12), a structural unit represented by a general formula (a2-0-12a) or (a2-0-12b) shown below is particularly desirable.

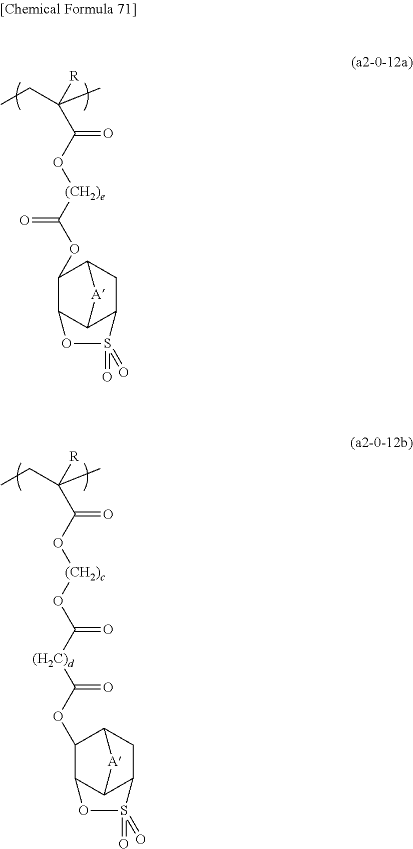

In the formulas, R and A′ are each the same as defined above, and each of c to e independently represents an integer of 1 to 3.

Structural Unit (a2^{L}):

Examples of the structural unit (a2^{L}) include structural units represented by the aforementioned general formula (a2-0) in which the R²⁸ group has been substituted with a lactone-containing cyclic group. Specific examples thereof include structural units represented by general formulas (a2-1) to (a2-5) shown below.

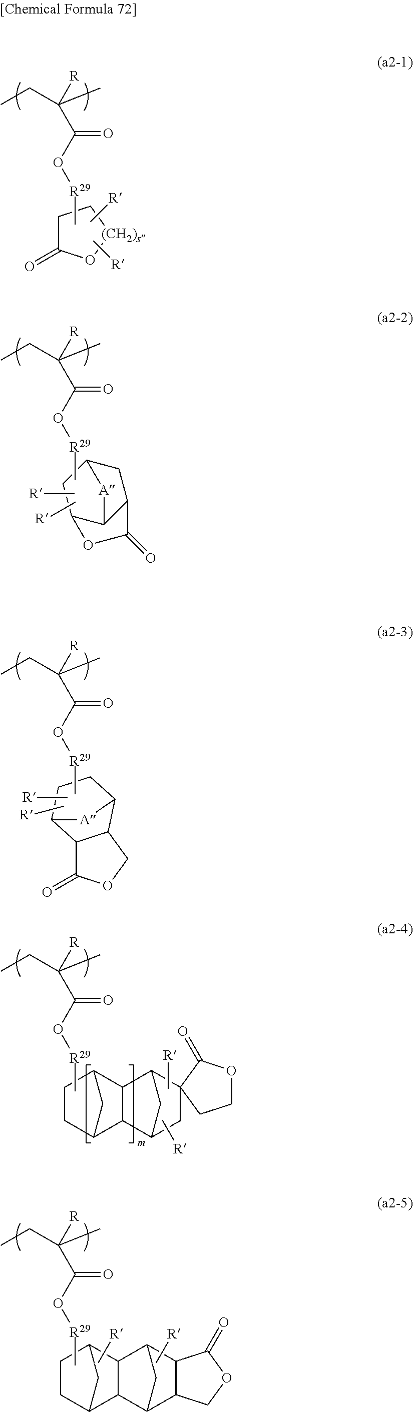

In the formulas, R represents a hydrogen atom, an alkyl group of 1 to 5 carbon atoms or a halogenated alkyl group of 1 to 5 carbon atoms; each R′ independently represents a hydrogen atom, an alkyl group, an alkoxy group, a halogenated alkyl group, a hydroxyl group, —COOR″, —OC(═O)R″, a hydroxyalkyl group or a cyano group, wherein R″ represents a hydrogen atom or an alkyl group; R²⁹ represents a single bond or a divalent linking group; s″ represents an integer of 0 to 2; A″ represents an oxygen atom, a sulfur atom or an alkylene group of 1 to 5 carbon atoms which may contain an oxygen atom or a sulfur atom; and m represents 0 or 1.

In general formulas (a2-1) to (a2-5), R is the same as defined above.

As the alkyl group, alkoxy group, halogenated alkyl group, —COOR″, —OC(═O)R″ and hydroxyalkyl group for R′, the same alkyl groups, alkoxy groups, halogenated alkyl groups, —COOR″, —OC(═O)R″ and hydroxyalkyl groups as those described above as the substituent which the —SO₂— containing cyclic group may have can be used.

In terms of industrial availability, R∝ is preferably a hydrogen atom.

The alkyl group for R″ may be any of linear, branched or cyclic.

When R″ is a linear or branched alkyl group, the alkyl group preferably contains 1 to 10 carbon atoms, and more preferably 1 to 5 carbon atoms.

When R″ is a cyclic alkyl group (cycloalkyl group), it preferably contains 3 to 15 carbon atoms, more preferably 4 to 12 carbon atoms, and most preferably 5 to 10 carbon atoms. As examples of the cycloalkyl group, groups in which one or more hydrogen atoms have been removed from a monocycloalkane or a polycycloalkane such as a bicycloalkane, tricycloalkane or tetracycloalkane, which may or may not be substituted with a fluorine atom or a fluorinated alkyl group, may be used. Specific examples include groups in which one or more hydrogen atoms have been removed from a monocycloalkane such as cyclopentane or cyclohexane, and groups in which one or more hydrogen atoms have been removed from a polycycloalkane such as adamantane, norbornane, isobornane, tricyclodecane or tetracyclododecane.

As examples of A″, the same groups as those described above for A′ in general formula (3-1) can be given. A″ is preferably an alkylene group of 1 to 5 carbon atoms, an oxygen atom (—O—) or a sulfur atom (—S—), and is more preferably an alkylene group of 1 to 5 carbon atoms or —O—. As the alkylene group of 1 to 5 carbon atoms, a methylene group or a dimethylmethylene group is preferable, and a methylene group is particularly desirable.

R²⁹ is the same as defined for R²⁹ in the aforementioned general formula (a2-0).

In formula (a2-1), s″ is preferably 1 or 2.

Specific examples of the structural units represented by general formulas (a2-1) to (a2-5) are shown below. In the formulas shown below, R^{α} represents a hydrogen atom, a methyl group or a trifluoromethyl group.

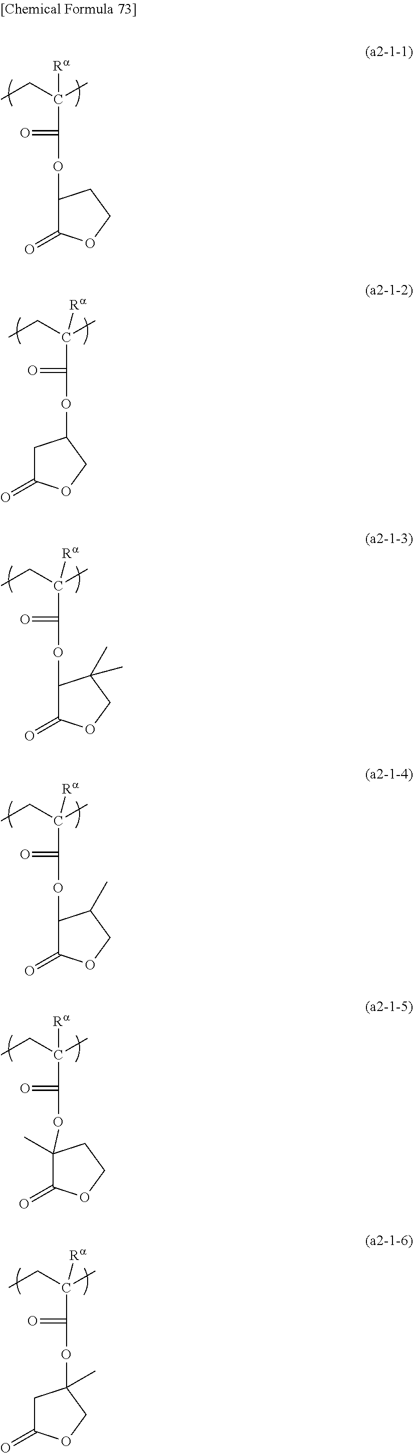

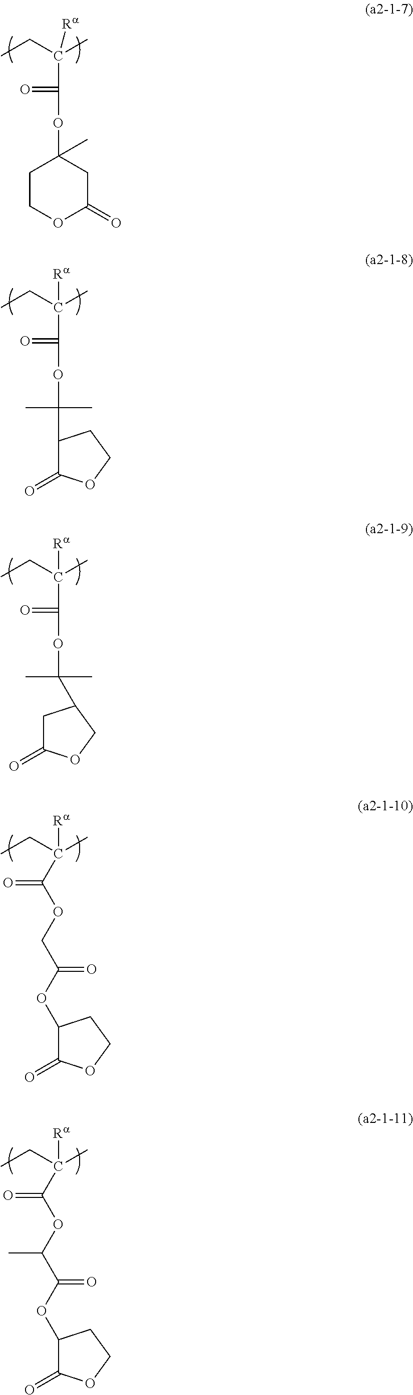

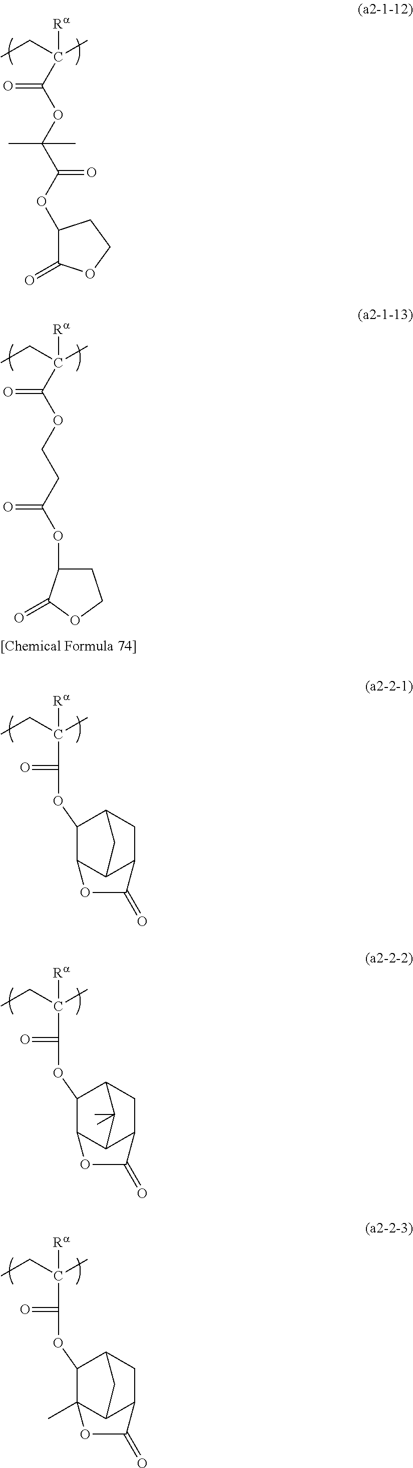

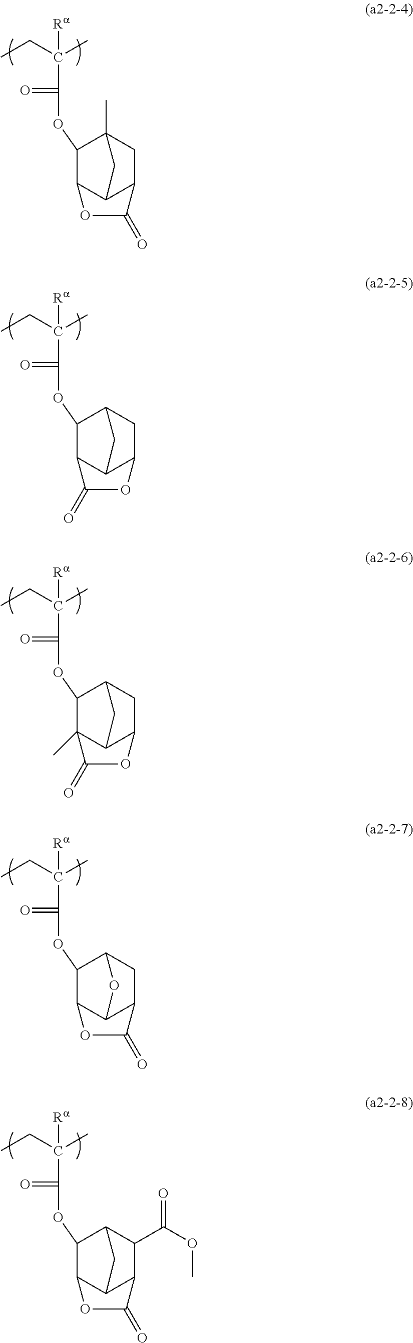

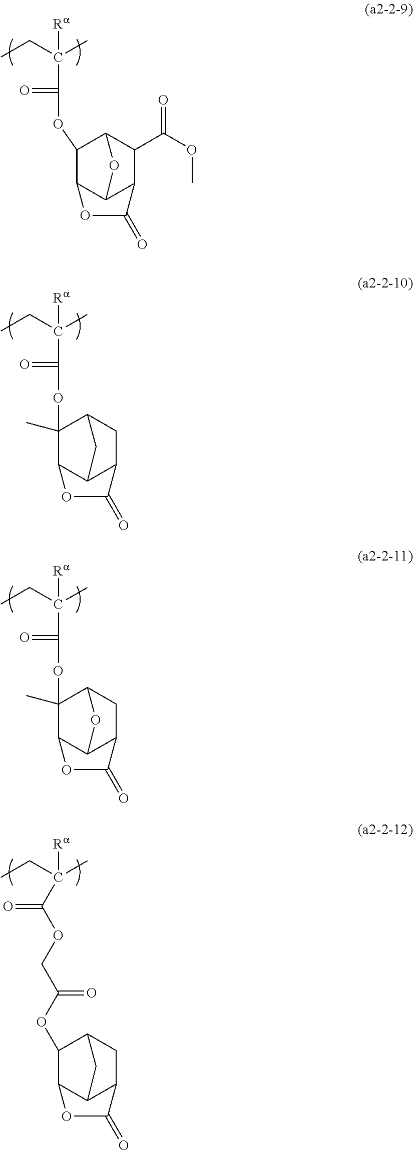

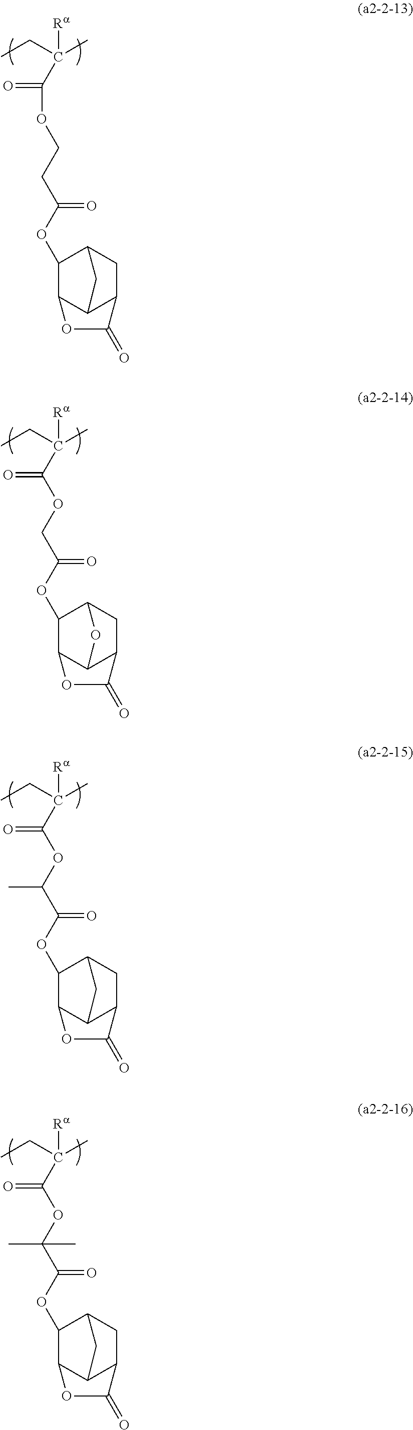

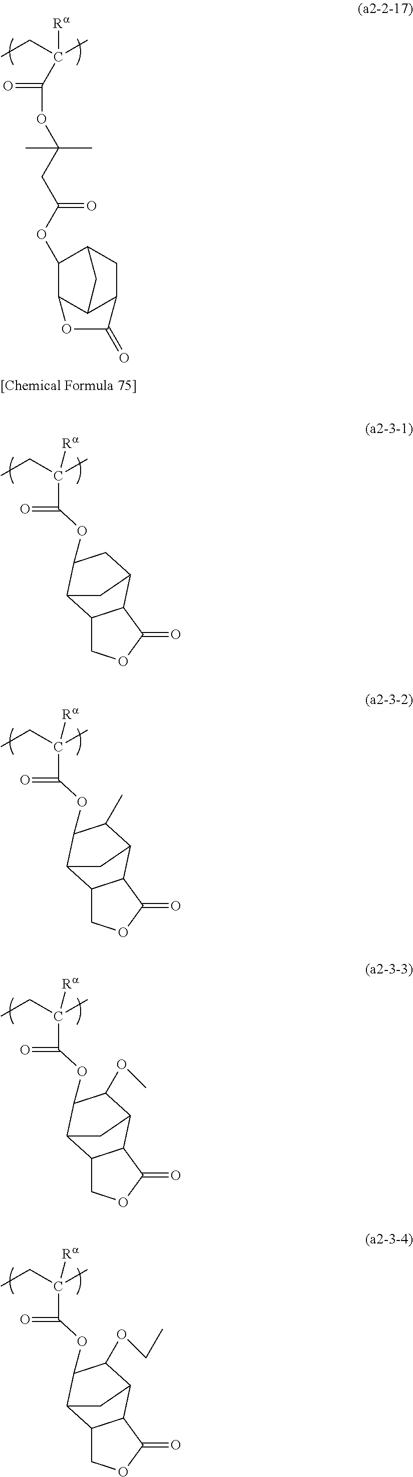

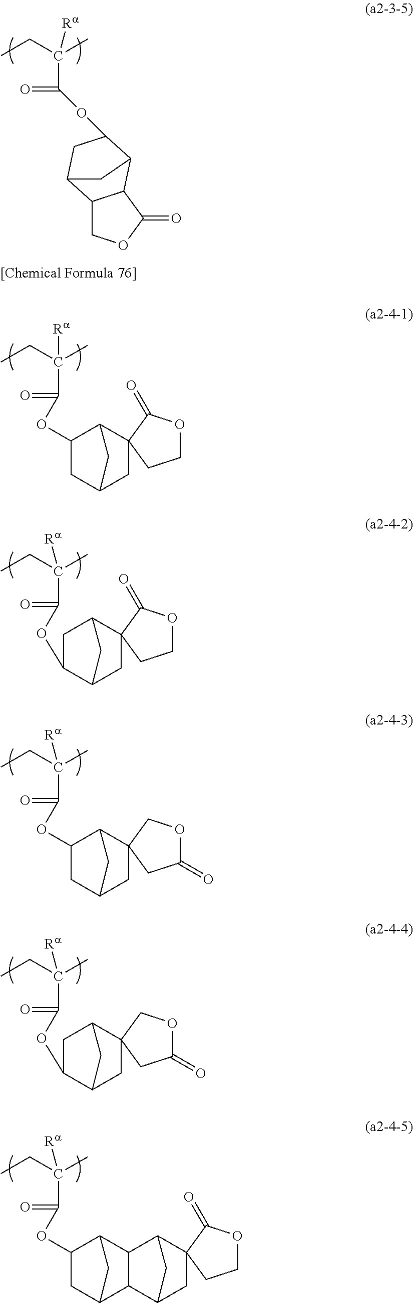

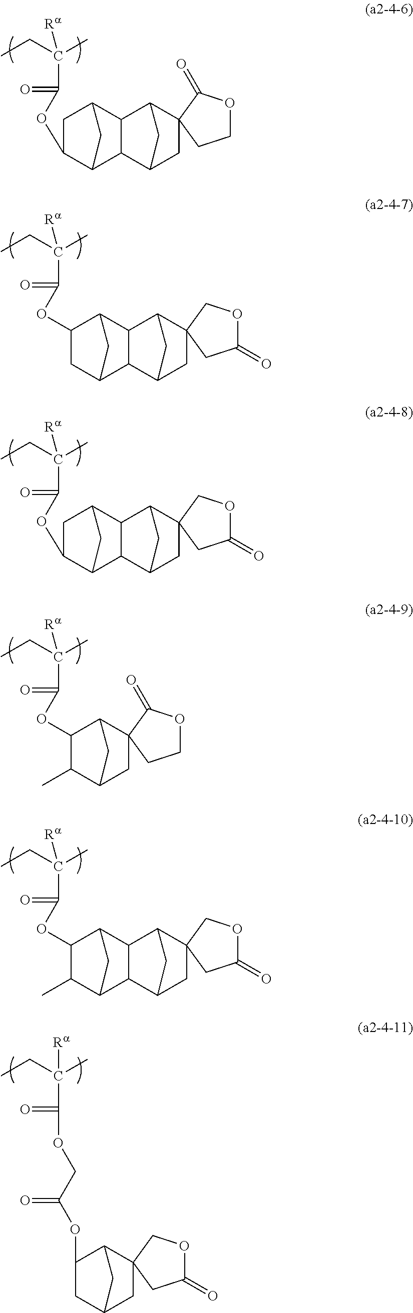

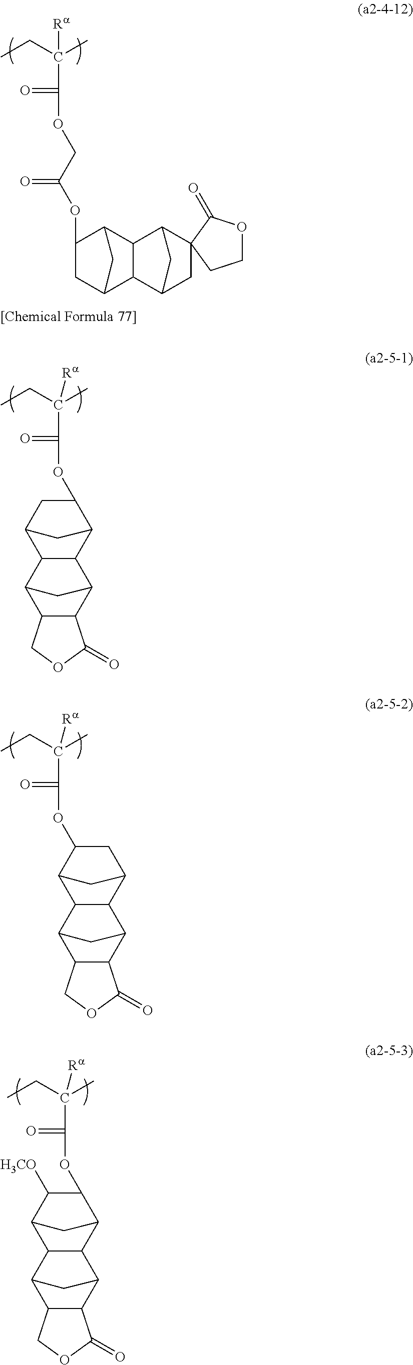

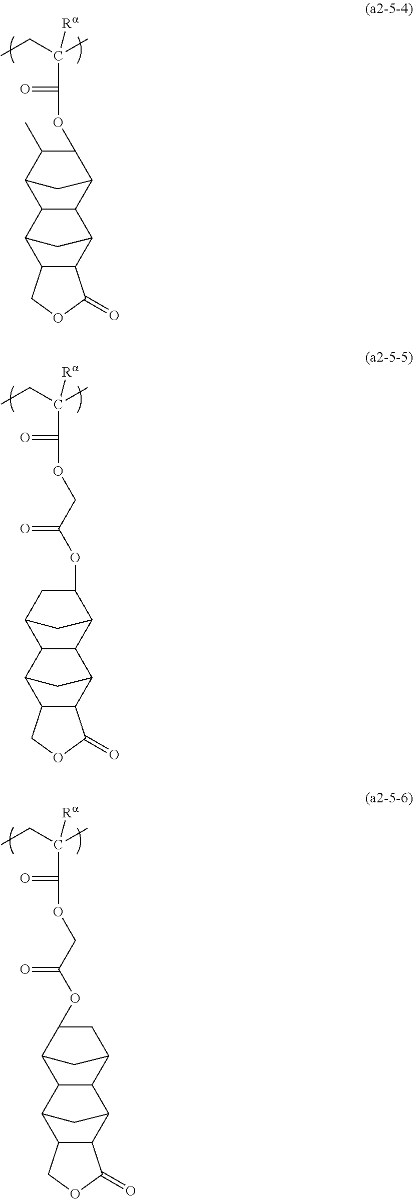

As the structural unit (a2^{L}), it is preferable to include at least one structural unit selected from the group consisting of structural units represented by the aforementioned general formulas (a2-1) to (a2-5), more preferably at least one structural unit selected from the group consisting of structural units represented by the aforementioned general formulas (a2-1) to (a2-3), and most preferably at least one structural unit selected from the group consisting of structural units represented by the aforementioned general formulas (a2-1) and (a2-3).

Of these, it is particularly preferable to use at least one structural unit selected from the group consisting of structural units represented by the aforementioned formulas (a2-1-1), (a2-1-2), (a2-2-1), (a2-2-7), (a2-2-12), (a2-2-14), (a2-3-1) and (a2-3-5).

Further, as the structural unit (a2^{L}), structural units represented by formulas (a2-6) and (a2-7) shown below are also preferred.

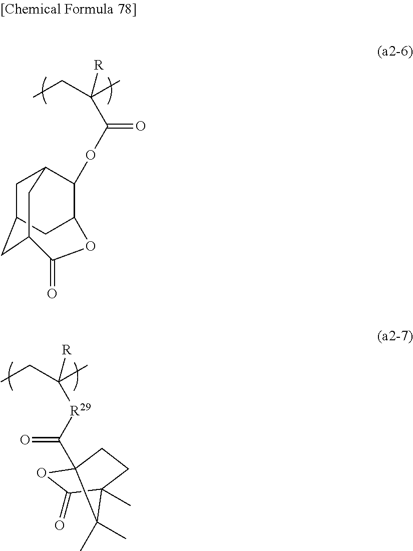

In the formulas, R and R²⁹ are the same as defined above.

The structural unit (a2) of the component (A1) may be either a single type of structural unit or a combination of two or more types of structural units. For example, as the structural unit (a2), the structural unit (a2^{S}) may be used alone, the structural unit (a2^{L}) may be used alone, or the structural units (a2^{S}) and (a2^{L}) may be used in combination. Further, as the structural unit (a2^{S}) or the structural unit (a2^{L}), one type of structural unit may be used alone, or two or more types of structural units may be used in combination.

In the component (A1), the amount of the structural unit (a2) based on the combined total of all structural units constituting the component (A1) is preferably 1 to 80 mol %, more preferably 10 to 70 mol %, still more preferably 10 to 65 mol %, and most preferably 10 to 60 mol %. When the amount of the structural unit (a2) is at least as large as the lower limit of the above-mentioned range, the effect of using the structural unit (a2) can be satisfactorily achieved. On the other hand, when the amount of the structural unit (a2) is no more than the upper limit of the above-mentioned range, a good balance can be achieved with the other structural units, and various lithography properties, such as DOF and CDU, and pattern shape can be improved.

(Structural Unit (a3))

The component (A1) may also include a structural unit (a3) containing a polar group, either in addition to the structural units (a0) and (a1), or in addition to the structural units (a0), (a1) and (a2).

Including the structural unit (a3) within the component (A1) further increases the polarity of the component (A1) following exposure. This increase in polarity contributes to improved resolution and the like, particularly in the case of an alkali developing process.

Examples of polar groups include —OH, —COOH, —CN, —SO₂NH₂ and —CONH₂. Structural units containing —COOH also include structural units composed of (α-substituted) acrylic acid.

The structural unit (a3) is preferably a structural unit containing a hydrocarbon group in which some of the hydrogen atoms have been substituted with a polar group. The hydrocarbon group may be either an aliphatic hydrocarbon group or an aromatic hydrocarbon group. Among these, the hydrocarbon group is more preferably an aliphatic hydrocarbon group.

Examples of the aliphatic hydrocarbon group for the hydrocarbon group include linear or branched hydrocarbon groups (and preferably alkylene groups) of 1 to 10 carbon atoms and aliphatic cyclic groups (monocyclic groups and polycyclic groups).

These aliphatic cyclic groups (monocyclic groups and polycyclic groups) can be selected appropriately from the multitude of groups that have been proposed for the resins of resist compositions designed for use with ArF excimer lasers. The aliphatic cyclic group preferably contains 3 to 30 carbon atoms, more preferably 5 to 30 carbon atoms, still more preferably 5 to 20 carbon atoms, still more preferably 6 to 15 carbon atoms, and most preferably 6 to 12 carbon atoms. Examples of the aliphatic cyclic group include groups in which two or more hydrogen atoms have been removed from a monocycloalkane, or a polycycloalkane such as a bicycloalkane, tricycloalkane or tetracycloalkane. Specific examples include groups in which two or more hydrogen atoms have been removed from a monocycloalkane such as cyclopentane or cyclohexane; and groups in which two or more hydrogen atoms have been removed from a polycycloalkane such as adamantane, norbornane, isobornane, tricyclodecane or tetracyclododecane. The aliphatic cyclic group may or may not have a substituent. Examples of the substituent include an alkyl group of 1 to 5 carbon atoms, a fluorine atom and a fluorinated alkyl group of 1 to 5 carbon atoms.

The aromatic hydrocarbon group for the hydrocarbon group is a hydrocarbon group having an aromatic ring, and preferably has 5 to 30 carbon atoms, more preferably 6 to 20 carbon atoms, still more preferably 6 to 15 carbon atoms, and most preferably 6 to 10 carbon atoms. Here, the number of carbon atoms does not include any carbon atoms within any substituent(s). Specific examples of the aromatic ring within the aromatic hydrocarbon group include aromatic hydrocarbon rings such as benzene, biphenyl, fluorene, naphthalene, anthracene and phenanthrene.

Specific examples of the aromatic hydrocarbon group include groups in which two or more hydrogen atoms have been removed from an aforementioned aromatic hydrocarbon ring (namely, arylene groups), and groups in which one hydrogen atom from a group having one hydrogen atom removed from an aforementioned aromatic hydrocarbon ring (namely, an aryl group) has been substituted with an alkylene group (for example, groups in which one hydrogen atom has been further removed from the aryl group of an arylalkyl group such as a benzyl group, a phenethyl group, a 1-naphthylmethyl group, a 2-naphthylmethyl group, a 1-naphthylethyl group or a 2-naphthylethyl group). The alkylene group (the alkyl chain within the arylalkyl group) preferably contains 1 to 4 carbon atoms, more preferably 1 or 2 carbon atoms, and most preferably 1 carbon atom.

The aromatic hydrocarbon group may or may not have a substituent. For example, a hydrogen atom bonded to the aromatic hydrocarbon ring within the aromatic hydrocarbon group may be substituted with a substituent. Examples of the substituent include an alkyl group, a halogen atom and a halogenated alkyl group.

The alkyl group for the substituent is preferably an alkyl group of 1 to 5 carbon atoms, and is most preferably a methyl group, an ethyl group, a propyl group, an n-butyl group or a tert-butyl group.

Examples of the halogen atom as the substituent for the aromatic hydrocarbon group include a fluorine atom, a chlorine atom, a bromine atom and an iodine atom, and a fluorine atom is preferable.

Examples of the halogenated alkyl group for the substituent include groups in which part or all of the hydrogen atoms of an aforementioned alkyl group have each been substituted with an aforementioned halogen atom.

As the structural unit (a3), structural units represented by general formula (a3-1) shown below are preferred.

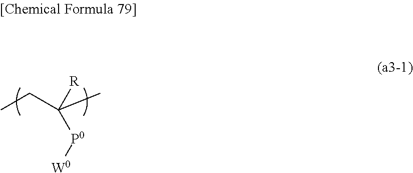

In the formula, R represents a hydrogen atom, an alkyl group of 1 to 5 carbon atoms or a halogenated alkyl group of 1 to 5 carbon atoms; P⁰ represents —C(═O)—O—, —C(═O)—NR⁰— (R⁰ represents a hydrogen atom or an alkyl group of 1 to 5 carbon atoms) or a single bond; and W⁰ represents —COOH or a hydrocarbon group having at least one type of group selected from the group consisting of —OH, —COOH, —CN, —SO₂NH₂ and —CONH₂ as a substituent, and may have an oxygen atom or a sulfur atom at an arbitrary position.

In the above formula (a3-1), the alkyl group for R is preferably a linear or branched alkyl group, and specific examples thereof include a methyl group, an ethyl group, a propyl group, an isopropyl group, an n-butyl group, an isobutyl group, a tert-butyl group, a pentyl group, an isopentyl group and a neopentyl group.

Examples of the halogenated alkyl group for R include groups in which part or all of the hydrogen atoms within the aforementioned alkyl group for R has been substituted with a halogen atom. Examples of the halogen atom include a fluorine atom, a chlorine atom, a bromine atom and an iodine atom, and a fluorine atom is particularly desirable.

As R, a hydrogen atom, an alkyl group of 1 to 5 carbon atoms or a fluorinated alkyl group of 1 to 5 carbon atoms is preferable, and a hydrogen atom or a methyl group is particularly desirable.

In the above formula (a3-1), P⁰ represents —C(═O)—O—, —C(═O)—NR⁰— (R⁰ represents a hydrogen atom or an alkyl group of 1 to 5 carbon atoms) or a single bond. As the alkyl group for R⁰, the same alkyl groups as those for R can be used.

In the above formula (a3-1), W⁰ represent a hydrocarbon group having at least one type of group selected from the group consisting of —OH, —COOH, —CN, —SO₂NH₂ and —CONH₂ as a substituent, and may have an oxygen atom or a sulfur atom at an arbitrary position.

A “hydrocarbon group having a substituent” means that at least some of the hydrogen atoms bonded to the hydrocarbon group is substituted with a substituent.

The hydrocarbon group for W⁰ may be either an aliphatic hydrocarbon group, or an aromatic hydrocarbon group.

Preferred examples of the aliphatic hydrocarbon group for W⁰ include linear or branched hydrocarbon groups (and preferably alkylene groups) of 1 to 10 carbon atoms and aliphatic cyclic groups (monocyclic groups and polycyclic groups), and explanations therefor are the same as those provided above.

The aromatic hydrocarbon group for W⁰ is a hydrocarbon group having an aromatic ring, and explanations therefor are the same as those provided above.

Further, W⁰ may have an oxygen atom or a sulfur atom at an arbitrary position. The description that W⁰ “may have an oxygen atom or a sulfur atom at an arbitrary position” means either that some of the carbon atoms constituting the hydrocarbon group or a hydrocarbon group having a substituent (including the carbon atoms constituting a substituent moiety) may be substituted with an oxygen atom or a sulfur atom, or that the hydrogen atom bonded to a hydrocarbon group may be substituted with an oxygen atom or a sulfur atom.

The following is an example of W⁰ having an oxygen atom (O) at an arbitrary position.

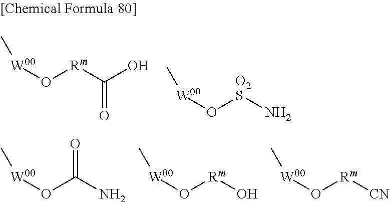

In the formulas, W⁰⁰ represents a hydrocarbon group, and R^{m} represents an alkylene group of 1 to 5 carbon atoms.

In the above formulas, W⁰⁰ represents a hydrocarbon group, and examples thereof include the same groups as those described above for W⁰ in the formula (a3-1). W⁰⁰ is preferably an aliphatic hydrocarbon group, and more preferably an aliphatic cyclic group (a monocyclic group or a polycyclic group).

R^{m} is preferably linear or branched alkylene group and is also preferably an alkylene group of 1 to 3 carbon atoms, and more preferably a methylene group or an ethylene group.

More specifically, preferred examples of the structural unit (a3) include structural units derived from (α-substituted) acrylate esters, and structural units represented by any one of general formulas (a3-11) to (a3-13) shown below. Examples of the structural units derived from (α-substituted) acrylate esters include structural units represented by the formula (a3-1) in which P⁰ represents a single bond and W⁰ represents —COOH.

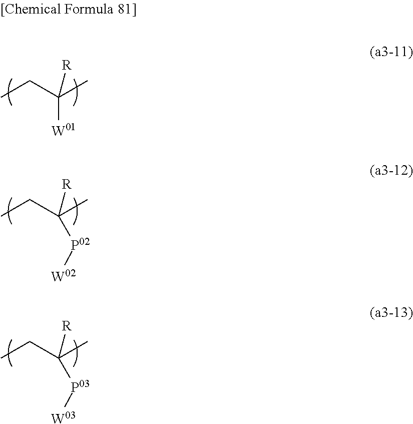

In the formulas, R represents a hydrogen atom, an alkyl group of 1 to 5 carbon atoms or a halogenated alkyl group of 1 to 5 carbon atoms; W⁰¹ represents an aromatic hydrocarbon group having at least one type of group selected from the group consisting of —OH, —COOH, —CN, —SO₂NH₂ and —CONH₂ as a substituent; each of P⁰² and P⁰³ represents —C(═O)—O— or —C(═O)—NR⁰— (R⁰ represents a hydrogen atom or an alkyl group of 1 to 5 carbon atoms); W⁰² represents a cyclic hydrocarbon group having at least one type of group selected from the group consisting of —OH, —COOH, —CN, —SO₂NH₂ and —CONH₂ as a substituent, and may have an oxygen atom or a sulfur atom at an arbitrary position; and W⁰³ represents a linear hydrocarbon group having at least one type of group selected from the group consisting of —OH, —COOH, —CN, —SO₂NH₂ and —CONH₂ as a substituent.
[Structural Unit Represented by General Formula (a3-11)]

In the above formula (a3-11), R is the same as described above for R in the formula (a3-1).

The aromatic hydrocarbon group for W⁰¹ is the same as the aromatic hydrocarbon groups as those described above for W⁰ in the formula (a3-1).

Specific examples of preferred structural units represented by general formula (a3-11) are shown below. In the formulas shown below, R^{α} represents a hydrogen atom, a methyl group or a trifluoromethyl group.

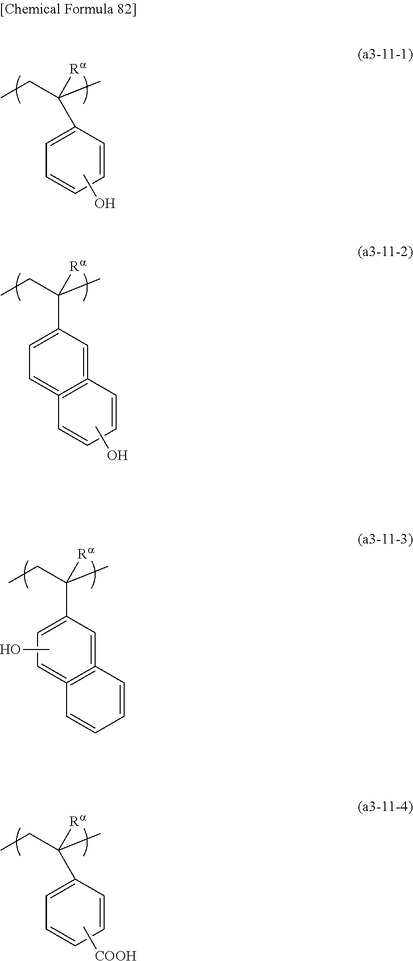

[Structural Unit Represented by General Formula (a3-12)]

In the above formula (a3-12), R is the same as described above for R in the formula (a3-1)

P⁰² represents —C(═O)—O— or —C(═O)—NR⁰— (R⁰ represents a hydrogen atom or an alkyl group of 1 to 5 carbon atoms), and is preferably —C(═O)—O—. As the alkyl group for R⁰, the same alkyl groups as those for R can be used.

Examples of the cyclic hydrocarbon group for W⁰² include the same aliphatic cyclic groups (monocyclic groups and polycyclic groups) and aromatic hydrocarbon groups as those described above within the description of W⁰ in the formula (a3-1).

W⁰² may have an oxygen atom or a sulfur atom at an arbitrary position, as described above for W⁰ in the formula (a3-1).

Specific examples of preferred structural units represented by general formula (a3-12) are shown below. In the formulas shown below, R^{α} represents a hydrogen atom, a methyl group or a trifluoromethyl group.

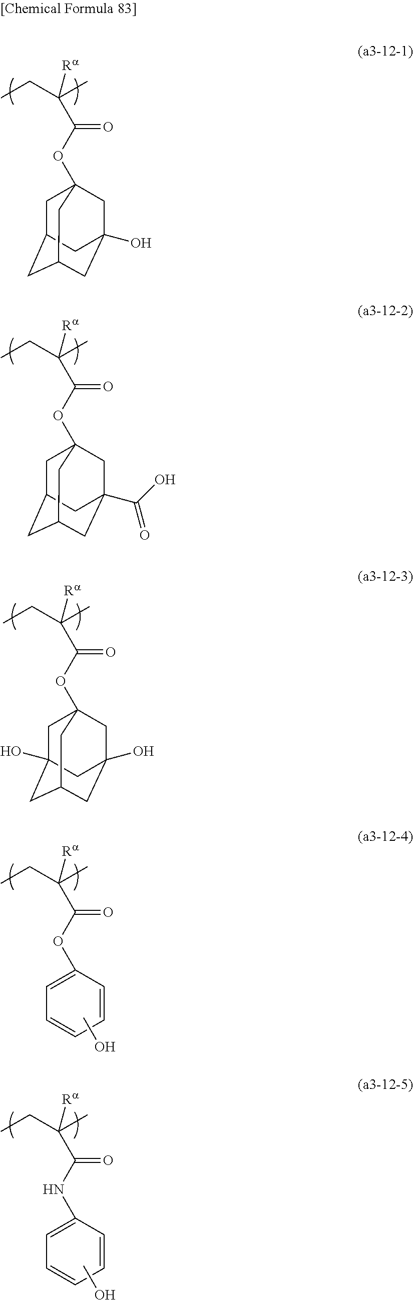

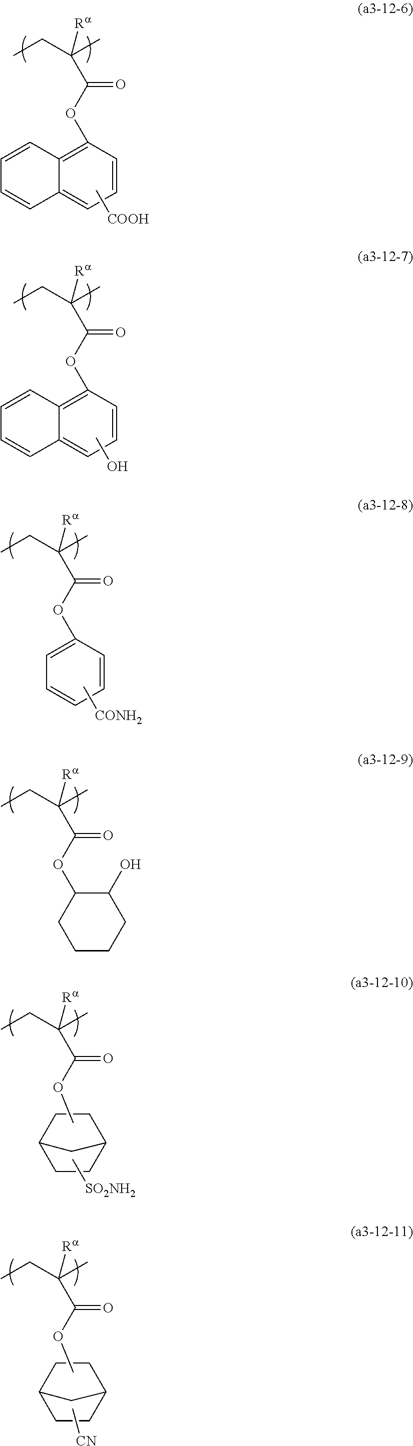

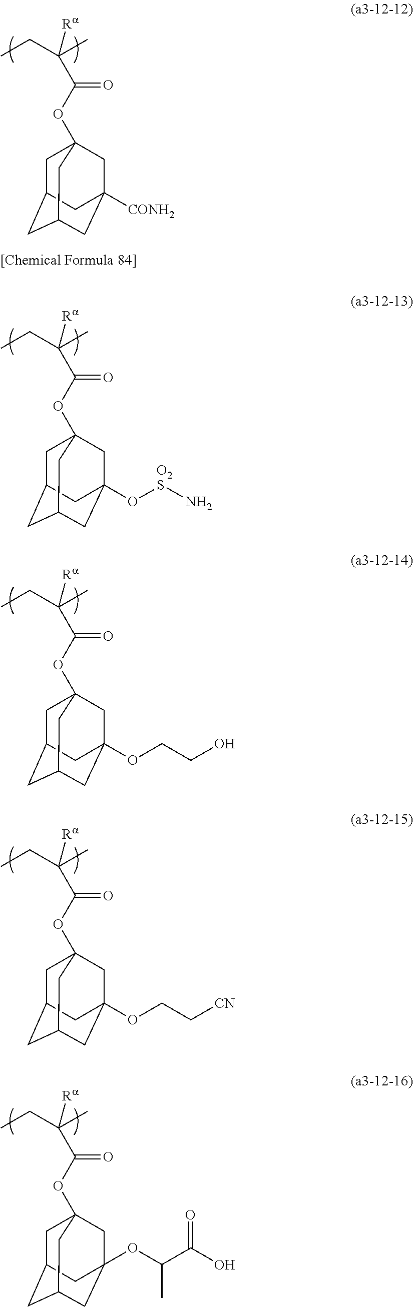

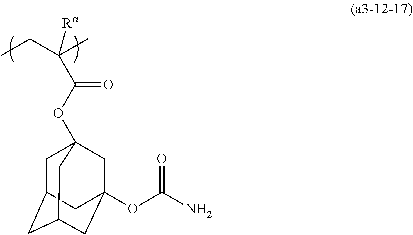

[Structural Unit Represented by General Formula (a3-13)]

In the above formula (a3-13), R is the same as described above for R in the formula (a3-1).

P⁰³ represents —C(═O)—O— or —C(═O)—NR⁰— (R⁰ represents a hydrogen atom or an alkyl group of 1 to 5 carbon atoms), and is preferably —C(═O)—O—. As the alkyl group for R⁰, the same alkyl groups as those for R can be used.

The linear hydrocarbon group for W⁰³ preferably contains 1 to 10 carbon atoms, more preferably 1 to 5 carbon atoms, and still more preferably 1 to 3 carbon atoms.

The linear hydrocarbon group for W⁰³ may further include a substituent (a) other than the aforementioned —OH, —COOH, —CN, —SO₂NH₂ and —CONH₂. Examples of the substituent (a) include an alkyl group of 1 to 5 carbon atoms, an aliphatic cyclic group (a monocyclic group or a polycyclic group), a fluorine atom and a fluorinated alkyl group of 1 to 5 carbon atoms. The aliphatic cyclic group for the substituent (a) (a monocyclic group or a polycyclic group) preferably contains 3 to 30 carbon atoms, more preferably 5 to 30 carbon atoms, still more preferably 5 to 20 carbon atoms, still more preferably 6 to 15 carbon atoms, and most preferably 6 to 12 carbon atoms. Examples of the aliphatic cyclic group include groups in which two or more hydrogen atoms have been removed from a monocycloalkane; or groups in which one or more hydrogen atoms have been removed from a polycycloalkane such as a bicycloalkane, tricycloalkane or tetracycloalkane. Specific examples include groups in which two or more hydrogen atoms have been removed from a monocycloalkane such as cyclopentane or cyclohexane; and groups in which one or more hydrogen atoms have been removed from a polycycloalkane such as adamantane, norbornane, isobornane, tricyclodecane or tetracyclododecane.

Further, the linear hydrocarbon group for W⁰³ may include a plurality of substituents (a), and the plurality of substituents (a) may be bonded to each other to form a ring, as the structural units represented by general formula (a3-13-a) shown below as an example.

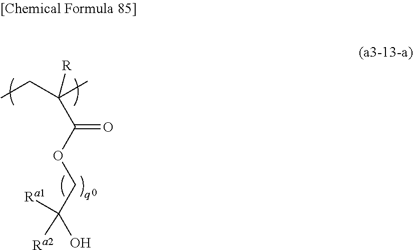

In the formula, R represents a hydrogen atom, an alkyl group of 1 to 5 carbon atoms or a halogenated alkyl group of 1 to 5 carbon atoms; each of R^{a1} and R^{a2} independently represents an alkyl group of 1 to 5 carbon atoms, an aliphatic cyclic group (a monocyclic group or a polycyclic group), a fluorine atom or a fluorinated alkyl group of 1 to 5 carbon atoms, wherein R^{a1} and R^{a2} may be bonded to each other to form a ring; and q⁰ represents an integer of 1 to 4.

In the above formula (a3-13-a), R is the same as described above for R in the formula (a3-1).

The aliphatic cyclic groups (monocyclic groups and polycyclic groups) for R^{a1} and R^{a2} are the same as defined above for the aliphatic cyclic groups (monocyclic groups and polycyclic groups) for the substituent (a).

Further, R^{a1} and R^{a2} may be bonded to each other to form a ring. In such a case, a cyclic group is formed by R^{a1}, R^{a2}, and the carbon atom to which both of R^{a1} and R^{a2} are bonded. The cyclic group may be a monocyclic group or a polycyclic group, and specific examples thereof include groups in which one or more hydrogen atoms have been removed from a monocycloalkane or polycycloalkane mentioned above within the description of the aliphatic cyclic groups (monocyclic groups and polycyclic groups) for the substituent (a).

q⁰ is preferably 1 or 2, and more preferably 1.

Specific examples of preferred structural units represented by general formula (a3-13) are shown below. In the formulas shown below, R^{α} represents a hydrogen atom, a methyl group or a trifluoromethyl group.

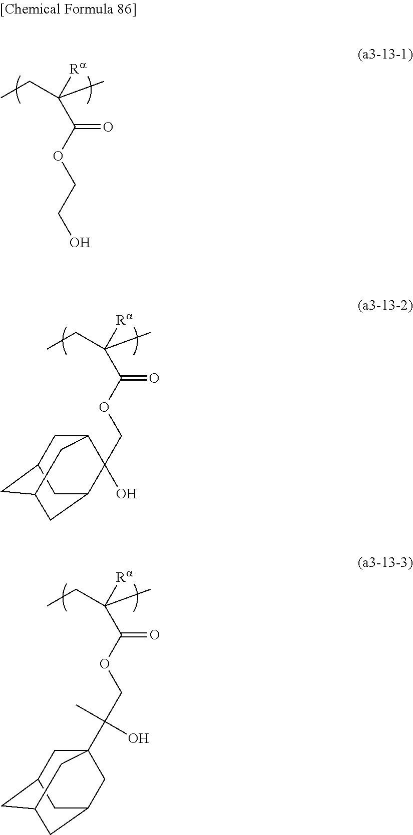

The structural unit (a3) of the component (A1) may be either a single type of structural unit or a combination of two or more types of structural units.

In the component (A1), the amount of the structural unit (a3) based on the combined total of all structural units constituting the component (A1) is preferably 0 to 85 mol %, and more preferably 0 to 80 mol %. When the amount of the structural unit (a3) is at least as large as the lower limit of the above-mentioned range, the effects of using the structural unit (a3) (namely, the effect of improving various lithography properties such as the resolution and the pattern shape) can be satisfactorily achieved. On the other hand, when the amount of the structural unit (a3) is no more than the upper limit of the above-mentioned range, a good balance can be achieved with the other structural units.

(Structural Unit (a4))

The component (A1) may also include a structural unit (a4) that contains a non-acid-dissociable cyclic group, if necessary. Including the structural unit (a4) in the component (A1) improves the dry etching resistance of the formed resist pattern. Further, the hydrophobicity of the component (A1) is also enhanced.

An improvement in the hydrophobicity contributes to improvements in the resolution and the resist pattern shape and the like, particularly in the case of an organic solvent developing process.

The “non-acid-dissociable cyclic group” in the structural unit (a4) is a cyclic group which, even when acid is generated from the aforementioned structural unit (a0) or an optional acid generator component (B) described below upon exposure, does not dissociate under the action of this acid, and is retained as it is within the structural unit.

Examples of the structural unit (a4) include structural units in which the acid dissociable group in an aforementioned structural unit (a1) has been substituted with a non-acid-dissociable cyclic group. Among these, a structural unit (a41) derived from an acrylate ester in which the hydrogen atom bonded to the carbon atom on the α-position may be substituted with a substituent and containing a non-acid-dissociable aliphatic cyclic group, a structural unit (a42) derived from a styrene in which the hydrogen atom bonded to the carbon atom on the α-position may be substituted with a substituent, and a structural unit (a43) derived from a vinylnaphthalene in which the hydrogen atom bonded to the carbon atom on the α-position may be substituted with a substituent, or the like is preferred.

Examples of the non-acid-dissociable aliphatic cyclic group in the structural unit (a41) include monovalent aliphatic cyclic groups in which there is no substituent (atom other than a hydrogen atom or group) bonded to the carbon atom that is bonded to the atom adjacent to the aliphatic cyclic group (for example, the —O— in —C(═O)—O—), and groups in which one of the hydrogen atoms of a primary or secondary alkyl group has been substituted with a monovalent aliphatic cyclic group.

There are no particular limitations on the monovalent aliphatic cyclic group provided it is non-acid-dissociable, and any of the multitude of conventional groups used within the resin components of resist compositions designed for use with an ArF excimer laser or KrF excimer laser (and particularly an ArF excimer laser) may be used. The aliphatic cyclic group may be saturated or unsaturated, but is preferably saturated.

The aliphatic cyclic group may or may not have a substituent. Examples of the substituent include an alkyl group of 1 to 5 carbon atoms, an alkoxy group of 1 to 5 carbon atoms, a fluorine atom, a fluorinated alkyl group of 1 to 5 carbon atoms, and an oxygen atom (═O).

The basic ring structure of the “aliphatic cyclic group” excluding substituents is not limited to structures constituted of only carbon and hydrogen (not limited to hydrocarbon groups), but is preferably a hydrocarbon group. Further, the hydrocarbon group may be either saturated or unsaturated, but in most cases, is preferably saturated.

The aliphatic cyclic group preferably contains 3 to 30 carbon atoms, more preferably 5 to 30 carbon atoms, still more preferably 5 to 20 carbon atoms, still more preferably 6 to 15 carbon atoms, and most preferably 6 to 12 carbon atoms.

The aliphatic cyclic group may be either a monocyclic group or a polycyclic group. As the monocyclic aliphatic cyclic group, a group in which one or more hydrogen atoms have been removed from a monocycloalkane is preferred. The monocycloalkane preferably contains 3 to 6 carbon atoms, and specific examples thereof include cyclobutane, cyclopentane and cyclohexane. As the polycyclic aliphatic cyclic group, a group in which one or more hydrogen atoms have been removed from a polycycloalkane is preferable, and the polycycloalkane preferably contains 7 to 12 carbon atoms. Specific examples of the polycycloalkane include adamantane, norbornane, isobornane, tricyclodecane and tetracyclododecane. Further, in these aliphatic cyclic groups, part of the carbon atoms constituting the ring may be replaced with an ether group (—O—).

The aliphatic cyclic group is preferably a polycyclic group in terms of achieving superior effects. Two- to four-ring groups are particularly desirable, and from the viewpoint of industrial availability, at least one group selected from among a tricyclodecyl group, adamantyl group, tetracyclododecyl group, isobornyl group and norbornyl group is particularly desirable.

Examples of the monovalent aliphatic cyclic groups for the non-acid-dissociable aliphatic cyclic group include monovalent aliphatic cyclic groups in which there is no substituent (atom other than a hydrogen atom or group) bonded to the carbon atom that is bonded to the atom adjacent to the aliphatic cyclic group (for example, the —O— in —C(═O)—O—). Specific examples include groups in which R¹⁴ has been substituted with a hydrogen atom in the groups represented by the formulas (1-1) to (1-9) that were mentioned above within the description of the acid dissociable group, and groups in which a hydrogen atom has been removed from the tertiary carbon atom of a cycloalkane formed solely of the carbon atoms constituting the ring skeleton.

Examples of the groups in which one of the hydrogen atoms of a primary or secondary alkyl group has been substituted with a monovalent aliphatic cyclic group include groups represented by the formulas (2-1) to (2-6) mentioned above within the description of the acid dissociable group in which at least one of R¹⁵ or R¹⁶ is a hydrogen atom.

Examples of the structural unit (a41) include structural units in which the acid dissociable group in an aforementioned structural unit (a11) has been substituted with a non-acid-dissociable aliphatic cyclic group, and structural units in which X¹ in the above general formula (a1-0-1) has been substituted with a non-acid-dissociable aliphatic polycyclic group, namely structural units represented by a general formula (a4-0) shown below, are preferred, and structural units represented by general formulas (a4-1) to (a4-5) shown below are particularly desirable.

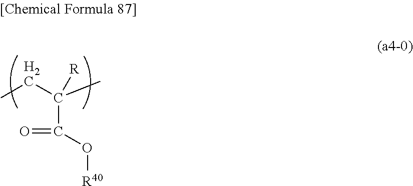

In the formula, R is the same as defined above, and R⁴⁰ represents a non-acid-dissociable aliphatic polycyclic group.

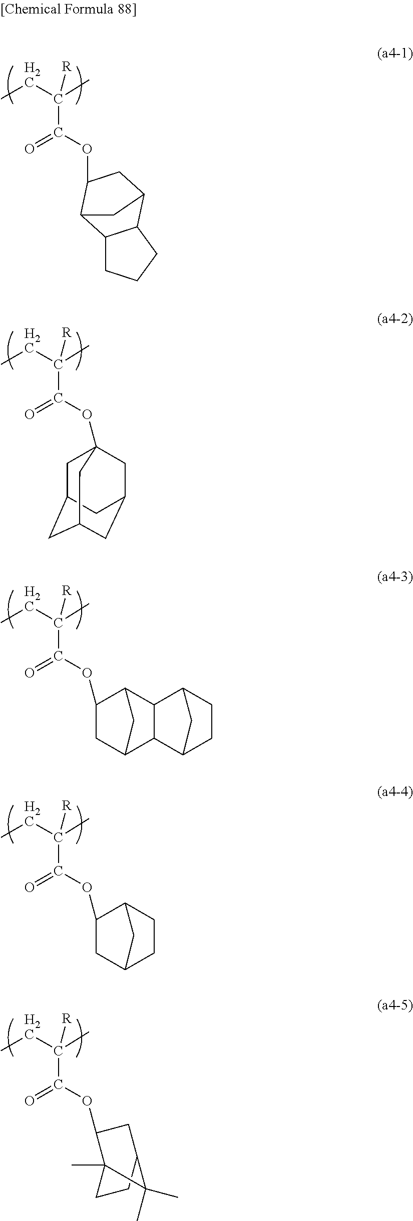

In the formulas, R is the same as defined above.

Specific examples of the structural unit (a42) include the structural units represented by general formula (U-3) described above within the description of the component (C) in which px of —(OX^{c})ₚₓ bonded to a benzene ring is 0.

Specific examples of the structural unit (a43) include the structural units represented by general formula (U-4) described above within the description of the component (C) in which x of —(OX^{d})ₓ bonded to a benzene ring is 0.

The structural unit (a4) of the component (A1) may be either a single type of structural unit or a combination of two or more types of structural units.

When the component (A1) includes the structural unit (a4), the amount of the structural unit (a4) within the component (A1), based on the combined total of all the structural units that constitute the component (A1), is preferably within a range from 1 to 30 mol %, more preferably from 1 to 20 mol %, and still more preferably from 5 to 20 mol %. When the amount of the structural unit (a4) is at least as large as the lower limit of the above range, the effect of using the structural unit (a4) can be satisfactorily achieved. On the other hand, when the amount of the structural unit (a4) is no more than the upper limit of the above range, a good balance can be achieved with the other structural units.

The component (A1) may also include structural units other than the aforementioned structural units (a0) to (a4), as long as the effects of the present invention are not impaired.

As these other structural units, any other structural unit which cannot be classified as one of the above structural units (a0) to (a4) can be used without any particular limitations, and any of the multitude of conventional structural units used within resist resins designed for use with ArF excimer lasers, KrF excimer lasers, EB and EUV can be used.

In the present invention, the component (A1) is preferably a copolymer containing the structural units (a0) and (a1), is more preferably a copolymer containing the structural units (a0), (a1) and (a2), and is still more preferably a copolymer containing the structural units (a0), (a1), (a2) and (a3).

Examples of the copolymer containing the structural units (a0) and (a1) include copolymers consisting of the structural units (a0) and (a1), copolymers consisting of the structural units (a0), (a1) and (a2), copolymers consisting of the structural units (a0), (a1) and (a3), copolymers consisting of the structural units (a0), (a1), (a2) and (a3), and copolymers consisting of the structural units (a0), (a1), (a2), (a3) and (a4).

The weight average molecular weight (Mw) (the polystyrene equivalent value determined by gel permeation chromatography (GPC)) of the component (A) is not particularly limited, but is preferably within a range from 1,000 to 50,000, more preferably from 1,500 to 30,000, and most preferably from 2,000 to 20,000. When the weight average molecular weight is no more than the upper limit of the above-mentioned range, the resist composition exhibits a satisfactory solubility in a resist solvent when used as a resist. On the other hand, when the weight average molecular weight is at least as large as the lower limit of the above-mentioned range, dry etching resistance and the cross-sectional shape of the resist pattern becomes satisfactory.

Further, although there are no particular limitations on the dispersity (Mw/Mn), the dispersity is preferably from 1.0 to 5.0, more preferably from 1.0 to 3.0, and most preferably from 1.0 to 2.5. Here, Mn is the number average molecular weight.

The component (A) can be obtained, for example, by a conventional radical polymerization or the like of the monomers corresponding with each of the structural units, using a radical polymerization initiator such as azobisisobutyronitrile (ATBN).

Furthermore, in the component (A), by using a chain transfer agent such as HS—CH₂—CH₂—CH₂—C(CF₃)₂—OH during the above polymerization, a —C(CF₃)₂—OH group can be introduced at the terminals of the component (A). Such a copolymer having introduced a hydroxyalkyl group in which some of the hydrogen atoms of the alkyl group have been substituted with fluorine atoms is effective in reducing developing defects and LER (line edge roughness: unevenness of the side walls of a line pattern).

As the monomers for deriving the corresponding structural units, commercially available monomers may be used, or the monomers synthesized by a conventional method may be used.

As the component (A), one type of component may be used alone, or two or more types may be used in combination.

In the resist composition of the present aspect, the amount of the component (A) can be appropriately adjusted depending on the thickness of the resist film to be formed, and the like.

### <Acid Generator Component (B)>

The resist composition of the present aspect may also include an acid generator component (B), which does not correspond with the component (A), and which generates acid upon exposure (hereinafter referred to as “component (B)”), provided the inclusion of this component (B) does not impair the effects of the present invention.

As the component (B), there is no particular limitation, and any of the known acid generators proposed for use in conventional chemically amplified resist compositions can be used. Examples of these acid generators are numerous, and include onium salt-based acid generators such as iodonium salts and sulfonium salts; oxime sulfonate-based acid generators;

diazomethane-based acid generators such as bisalkyl or bisaryl sulfonyl diazomethanes and poly(bis-sulfonyl)diazomethanes; nitrobenzylsulfonate-based acid generators; iminosulfonate-based acid generators; and disulfone-based acid generators.

As an onium salt-based acid generator, a compound represented by general formula (b-1) or (b-2) shown below can be used.

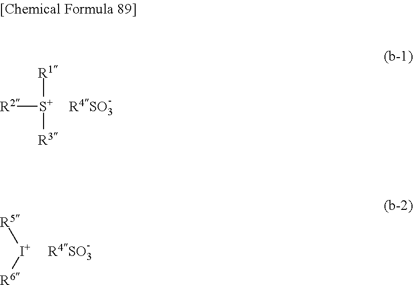

In the formulas, each of R¹″ to R³″ independently represents an aryl group, alkyl group or alkenyl group which may have a substituent, wherein two of R¹″ to R³″ may be bonded to each other to form a ring together with the sulfur atom in the formula; each of R⁵″ and R⁶″ independently represents an aryl group, alkyl group or alkenyl group which may have a substituent; and R⁴″ represents an alkyl group, halogenated alkyl group, aryl group or alkenyl group which may have a substituent.

R¹″ to R³″ in formula (b-1) and R⁵″ and R⁶″ in formula (b-2) are each the same as defined above for R¹″ to R³″ in formula (m-1) and R⁵″ and R⁶″ in formula (m-2) mentioned within the description of the structural unit (a0).

R⁴″SO₃⁻ in formulas (b-1) and (b-2) is the same as defined above for R⁴″SO₃⁻ mentioned within the description of V⁻ in general formula (a0-1) in connection with the structural unit (a0).

Further, onium salt-based acid generators in which the anion moiety in the above general formula (b-1) or (b-2) is replaced by an anion moiety represented by general formula (b-3) or (b-4) shown above (the cation moiety is the same as that of (b-1) or (b-2)) may also be used.

In the present description, an oxime sulfonate-based acid generator is a compound having at least one group represented by general formula (B-1) shown below, and has a feature of generating acid by irradiation. Such oxime sulfonate-based acid generators are widely used for a chemically amplified resist composition, and can be selected as appropriate.

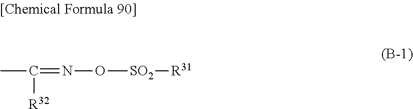

In formula (B-1), each of R³¹ and R³² independently represents an organic group.

The organic group for R³¹ and R³² refers to a group containing a carbon atom, and may include atoms other than carbon atoms (such as a hydrogen atom, an oxygen atom, a nitrogen atom, a sulfur atom, or a halogen atom (such as a fluorine atom and a chlorine atom) and the like).

As the organic group for R³¹, a linear, branched, or cyclic alkyl group or aryl group is preferable. The alkyl group or the aryl group may have a substituent. The substituent is not particularly limited, and examples thereof include a fluorine atom and a linear, branched, or cyclic alkyl group having 1 to 6 carbon atoms. The expression “have a substituent” means that some or all of the hydrogen atoms of the alkyl group or the aryl group are substituted with substituents.

The alkyl group preferably has 1 to 20 carbon atoms, more preferably 1 to 10 carbon atoms, still more preferably 1 to 8 carbon atoms, still more preferably 1 to 6 carbon atoms, and most preferably 1 to 4 carbon atoms. As the alkyl group, a partially or completely halogenated alkyl group (hereinafter, sometimes referred to as a “halogenated alkyl group”) is particularly desirable. The “partially halogenated alkyl group” refers to an alkyl group in which some of the hydrogen atoms are substituted with halogen atoms, and the “completely halogenated alkyl group” refers to an alkyl group in which all of the hydrogen atoms are substituted with halogen atoms. Examples of the halogen atom include a fluorine atom, a chlorine atom, a bromine atom and an iodine atom, and a fluorine atom is particularly desirable. In other words, the halogenated alkyl group is preferably a fluorinated alkyl group.

The aryl group preferably has 4 to 20 carbon atoms, more preferably 4 to 10 carbon atoms, and most preferably 6 to 10 carbon atoms. As the aryl group, partially or completely halogenated aryl group is particularly desirable. The “partially halogenated aryl group” refers to an aryl group in which some of the hydrogen atoms are substituted with halogen atoms, and the “completely halogenated aryl group” refers to an aryl group in which all of hydrogen atoms are substituted with halogen atoms.

As R³¹, an alkyl group of 1 to 4 carbon atoms which has no substituent or a fluorinated alkyl group of 1 to 4 carbon atoms is particularly desirable.

As the organic group for R³², a linear, branched, or cyclic alkyl group, aryl group, or cyano group is preferable. Examples of the alkyl group and the aryl group for R³² include the same alkyl groups and aryl groups as those described above for R³′.

As R³², a cyano group, an alkyl group of 1 to 8 carbon atoms having no substituent or a fluorinated alkyl group of 1 to 8 carbon atoms is particularly desirable.

Preferred examples of the oxime sulfonate-based acid generator include compounds represented by general formula (B-2) or (B-3) shown below.

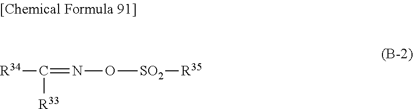

In formula (B-2), R³³ represents a cyano group, an alkyl group having no substituent or a halogenated alkyl group; R³⁴ represents an aryl group; and R³⁵ represents an alkyl group having no substituent or a halogenated alkyl group.

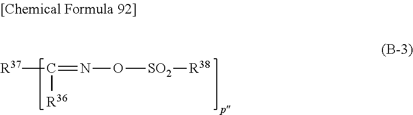

In formula (B-3), R³⁶ represents a cyano group, an alkyl group having no substituent or a halogenated alkyl group; R³⁷ represents a divalent or trivalent aromatic hydrocarbon group; R³⁸ represents an alkyl group having no substituent or a halogenated alkyl group; and p″ represents 2 or 3.

In general formula (B-2), the alkyl group having no substituent or the halogenated alkyl group for R³³ preferably has 1 to 10 carbon atoms, more preferably 1 to 8 carbon atoms, and most preferably 1 to 6 carbon atoms.

As R³³, a halogenated alkyl group is preferable, and a fluorinated alkyl group is more preferable.

The fluorinated alkyl group for R³³ preferably has 50% or more of the hydrogen atoms thereof fluorinated, more preferably 70% or more, and most preferably 90% or more.

Examples of the aryl group for R³⁴ include groups in which one hydrogen atom has been removed from an aromatic hydrocarbon ring, such as a phenyl group, a biphenyl group, a fluorenyl group, a naphthyl group, an anthryl group, and a phenanthryl group, and heteroaryl groups in which some of the carbon atoms constituting the ring(s) of these groups are substituted with hetero atoms such as an oxygen atom, a sulfur atom, and a nitrogen atom. Of these, a fluorenyl group is preferable.

The aryl group for R³⁴ may have a substituent such as an alkyl group of 1 to 10 carbon atoms, a halogenated alkyl group, or an alkoxy group. The alkyl group and halogenated alkyl group as the substituent preferably has 1 to 8 carbon atoms, and more preferably 1 to 4 carbon atoms. Further, the halogenated alkyl group is preferably a fluorinated alkyl group.

The alkyl group having no substituent or the halogenated alkyl group for R³⁵ preferably has 1 to 10 carbon atoms, more preferably 1 to 8 carbon atoms, and most preferably 1 to 6 carbon atoms.

As R³⁵, a halogenated alkyl group is preferable, and a fluorinated alkyl group is more preferable.

In terms of enhancing the strength of the acid generated, the fluorinated alkyl group for R³⁵ preferably has 50% or more of the hydrogen atoms within the alkyl group fluorinated, more preferably 70% or more fluorinated, and still more preferably 90% or more fluorinated. A completely fluorinated alkyl group in which 100% of the hydrogen atoms are substituted with fluorine atoms is particularly desirable.

In the above general formula (B-3), as the alkyl group having no substituent and the halogenated alkyl group for R³⁶, the same alkyl group having no substituent and the halogenated alkyl group described above for R³³ can be used.

Examples of the divalent or trivalent aromatic hydrocarbon group for R³⁷ include groups in which one or two hydrogen atoms have been removed from the aryl group described above for R³⁴.

As the alkyl group having no substituent or the halogenated alkyl group for R³⁸, the same one as the alkyl group having no substituent or the halogenated alkyl group described above for R³⁵ can be used.

p″ is preferably 2.

Specific examples of suitable oxime sulfonate-based acid generators include α-(p-toluenesulfonyloxyimino)-benzyl cyanide, α-(p-chlorobenzenesulfonyloxyimino)-benzyl cyanide, α-(4-nitrobenzenesulfonyloxyimino)-benzyl cyanide, α-(4-nitro-2-trifluoromethylbenzenesulthnyloxyimino)-benzyl cyanide, α-(benzenesulfonyloxyimino)-4-chlorobenzyl cyanide, α-(benzenesulfonyloxyimino)-2,4-dichlorobenzyl cyanide, α-(benzenesulfonyloxyimino)-2,6-dichlorobenzyl cyanide, α-(benzenesulthnyloxyimino)-4-methoxybenzyl cyanide, α-(2-chlorobenzenesulfonyloxyimino)-4-methoxybenzyl cyanide, α-(benzenesulfonyloxyimino)-thien-2-yl acetonitrile, α-(4-dodecylbenzenesulfonyloxyimino)benzyl cyanide, α-[(p-toluenesulfonyloxyimino)-4-methoxyphenyl]acetonitrile, α-[(dodecylbenzenesulfonyloxyimino)-4-methoxyphenyl]acetonitrile, α-(tosyloxyimino)-4-thienyl cyanide, α-(methylsulfonyloxyimino)-1-cyclopentenyl acetonitrile, α-(methylsulfonyloxyimino)-1-cyclohexenyl acetonitrile, α-(methylsulfonyloxyimino)-1-cycloheptenyl acetonitrile, α-(methylsulfonyloxyimino)-1-cyclooctenyl acetonitrile, α-(trifluoromethylsulfonyloxyimino)-1-cyclopentenyl acetonitrile, α-(trifluoromethylsulfonyloxyimino)-cyclohexyl acetonitrile, α-(ethylsulfonyloxyimino)-ethyl acetonitrile, α-(propylsulfonyloxyimino)-propyl acetonitrile, α-(cyclohexylsulfonyloxyimino)-cyclopentyl acetonitrile, α-(cyclohexylsulfonyloxyimino)-cyclohexyl acetonitrile, α-(cyclohexylsulfonyloxyimino)-1-cyclopentenyl acetonitrile, α-(ethylsulfonyloxyimino)-1-cyclopentenyl acetonitrile, α-(isopropylsulfonyloxyimino)-1-cyclopentenyl acetonitrile, α-(n-butylsulfonyloxyimino)-1-cyclopentenyl acetonitrile, α-(ethylsulfonyloxyimino)-1-cyclohexenyl acetonitrile, α-(isopropylsulfonyloxyimino)-1-cyclohexenyl acetonitrile, α-(n-butylsulfonyloxyimino)-1-cyclohexenyl acetonitrile, α-(methylsulfonyloxyimino)-phenyl acetonitrile, α-(methylsulfonyloxyimino)-p-methoxyphenyl acetonitrile, α-(trifluoromethylsulfonyloxyimino)-phenyl acetonitrile, α-(trifluoromethylsulfonyloxyimino)-p-methoxyphenyl acetonitrile, α-(ethylsulfonyloxyimino)-p-methoxyphenyl acetonitrile, α-(propylsulfonyloxyimino)-p-methylphenyl acetonitrile, and α-(methylsulfonyloxyimino)-p-bromophenyl acetonitrile.

Further, oxime sulfonate-based acid generators disclosed in Japanese Unexamined Patent Application, First Publication No. Hei 9-208554 (Chemical Formulas 18 and 19 shown in paragraphs [0012] to [0014]) and oxime sulfonate-based acid generators disclosed in WO 2004/074242A2 (Examples 1 to 40 described at pages 65 to 86) may be preferably used.

Furthermore, as preferable examples, the following can be used.

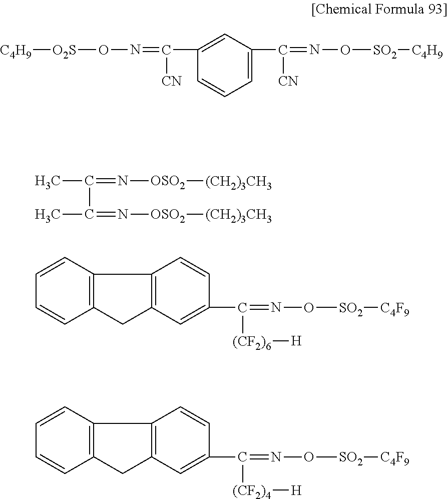

Of the aforementioned diazomethane-based acid generators, specific examples of suitable bisalkyl or bisaryl sulfonyl diazomethanes include bis(isopropylsulfonyl)diazomethane, bis(p-toluenesulfonyl)diazomethane, bis(1,1-dimethylethylsulfonyl)diazomethane, bis(cyclohexylsulfonyl)diazomethane, and bis(2,4-dimethylphenylsulfonyl)diazomethane.

Further, diazomethane-based acid generators disclosed in Japanese Unexamined Patent Application, First Publication No. Hei 11-035551, Japanese Unexamined Patent Application, First Publication No. Hei 11-035552 and Japanese Unexamined Patent Application, First Publication No. Hei 11-035573 may also be used favorably.

Furthermore, as examples of poly(bis-sulfonyl)diazomethanes, those disclosed in Japanese Unexamined Patent Application, First Publication No. Hei 11-322707, including 1,3-bis(phenylsulfonyldiazomethylsulfonyl)propane, 1,4-bis(phenylsulfonyldiazomethylsulfonyl)butane, 1,6-bis(phenylsulfonyldiazomethylsulfonyl)hexane, 1,10-bis(phenylsulfonyldiazomethylsulfonyl)decane, 1,2-bis(cyclohexylsulfonyldiazomethylsulfonyl)ethane, 1,3-bis(cyclohexylsulfonyldiazomethylsulfonyl)propane, 1,6-bis(cyclohexylsulfonyldiazomethylsulfonyl)hexane, and 1,10-bis(cyclohexylsulfonyldiazomethylsulfonyl)decane, may be given.

As the component (B), one type of these acid generators may be used alone, or two or more types may be used in combination.

The amount of the component (B) within the resist composition of the present aspect is preferably within a range from 0 to 60 parts by weight, more preferably from 0 to 40 parts by weight, and still more preferably from 0 to 10 parts by weight, relative to 100 parts by weight of the component (A). When the amount of the component (B) is not more than 40 parts by weight, a uniform solution can be obtained when each of the components of the resist composition are dissolved in an organic solvent, and the storage stability of the composition tends to improve. In particular, when the amount of the component (B) is 10 parts by weight or less, a good balance can be achieved between suppressing any deterioration in the lithography properties caused by OoB light, and increasing the sensitivity.

### <Other Optional Components>

The resist composition of the present aspect may also contain a basic compound (D) (hereafter referred to as the component (D)) as an optional component. In the present invention, the component (D) functions as an acid diffusion control agent, i.e., a quencher which traps the acid generated from the aforementioned component (A), the component (B) or the like upon exposure. Further, in the present invention, a “basic compound” refers to a compound which is basic relative to the aforementioned component (A) or the component (B).

In the present invention, the component (D) may be a basic compound (D1) (hereafter, referred to as “component (D1)”) which has a cation moiety and an anion moiety, or a basic compound (D2) (hereafter, referred to as “component (D2)”) which does not fall under the definition of the component (D1).

### [Component (D1)]

As the component (D1), at least one type of compound selected from the group consisting of a compound (d1-1) represented by general formula (d1-1) shown below (hereafter, referred to as “component (d1-1)”), a compound (d1-2) represented by general formula (d1-2) shown below (hereafter, referred to as “component (d1-2)”) and a compound (d1-3) represented by general formula (d1-3) shown below (hereafter, referred to as “component (d1-3)”) is preferred.

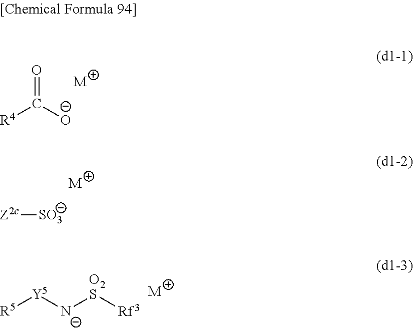

In the formulas, R⁴ represents a hydrocarbon group which may have a substituent; Z^{2c} represents a hydrocarbon group of 1 to 30 carbon atoms which may have a substituent (provided that the carbon adjacent to sulfur (S) does not contain a fluorine atom as a substituent); R⁵ represents an organic group; Y⁵ represents a linear, branched or cyclic alkylene group or an arylene group; R^{f3} represents a hydrocarbon group containing a fluorine atom; and each M⁺ independently represents a sulfonium or iodonium cation.
[Component (d1-1)]

Anion Moiety

In formula (d1-1), R⁴ represents a hydrocarbon group which may have a substituent.

The hydrocarbon group for R⁴ which may have a substituent may be either an aliphatic hydrocarbon group or an aromatic hydrocarbon group, and the same groups as those described for X³ in the formula: X³-Q′- mentioned as a substituent which R⁴″ may have in connection with the general formula: R⁴″SO₃⁻ within the description of the structural unit (a0) can be used.

Among these, as the hydrocarbon group for R⁴ which may have a substituent, an aromatic hydrocarbon group which may have a substituent or an aliphatic cyclic group which may have a substituent is preferable, and a phenyl group or a naphthyl group which may have a substituent, or a group in which one or more hydrogen atoms have been removed from a polycycloalkane such as adamantane, norbornane, isobornane, tricyclodecane or tetracyclododecane is more preferable.

Further, as the hydrocarbon group for R⁴ which may have a substituent, a linear or branched alkyl group or a fluorinated alkyl group is also preferable.

The linear or branched alkyl group for R⁴ preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl group or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group or a 4-methylpentyl group.

The fluorinated alkyl group for R⁴ may be either chain-like or cyclic, but is preferably linear or branched.

The fluorinated alkyl group preferably has 1 to 11 carbon atoms, more preferably 1 to 8 carbon atoms, and still more preferably 1 to 4 carbon atoms. Specific examples include a group in which part or all of the hydrogen atoms constituting a linear alkyl group (such as a methyl group, an ethyl group, a propyl group, a butyl group, a pentyl group, a hexyl group, a heptyl group, an octyl group, a nonyl group or a decyl group) have been substituted with fluorine atom(s), and a group in which part or all of the hydrogen atoms constituting a branched alkyl group (such as a 1-methylethyl group, a 1-methylpropyl group, a 2-methylpropyl group, a 1-methylbutyl group, a 2-methylbutyl group or a 3-methylbutyl group) have been substituted with fluorine atom(s).

Further, the fluorinated alkyl group for R⁴ may contain an atom other than a fluorine atom. Examples of the atom other than a fluorine atom include an oxygen atom, a carbon atom, a hydrogen atom, a sulfur atom and a nitrogen atom.

Among these, as the fluorinated alkyl group for R⁴, a group in which part or all of the hydrogen atoms constituting a linear alkyl group have been substituted with fluorine atom(s) is preferable, and a group in which all of the hydrogen atoms constituting a linear alkyl group have been substituted with fluorine atoms (i.e., a perfluoroalkyl group) is more preferable.

Specific examples of preferable anion moieties for the component (d1-1) are shown below.

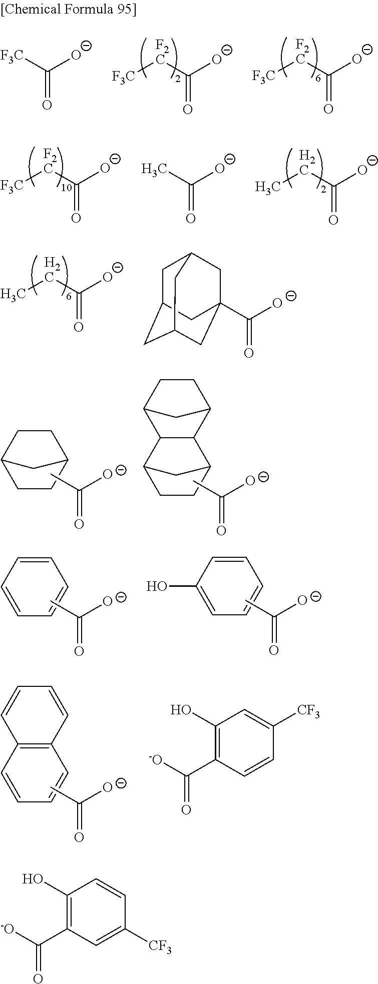

Cation Moiety

In formula (d1-1), M⁺ represents an organic cation.

The organic cation for M⁺ is not particularly limited, and examples thereof include the same cation moieties as those of compounds represented by the aforementioned formula (b-1) or (b-2).

As the component (d1-1), one type of compound may be used alone, or two or more types of compounds may be used in combination.

[Component (d1-2)]

Anion Moiety

In formula (d1-2), Z^{2c} represents a hydrocarbon group of 1 to 30 carbon atoms which may have a substituent.

The hydrocarbon group of 1 to 30 carbon atoms for Z^{2c} which may have a substituent may be either an aliphatic hydrocarbon group or an aromatic hydrocarbon group, and the same groups as those described above for R⁴ in the aforementioned formula (d1-1) can be used.

Among these, as the hydrocarbon group for Z^{2c} which may have a substituent, an aliphatic cyclic group which may have a substituent is preferable, and a group in which one or more hydrogen atoms have been removed from adamantane, norbornane, isobornane, tricyclodecane, tetracyclododecane or camphor (which may have a substituent) is more preferable.

The hydrocarbon group for Z^{2c} may have a substituent, and the same substituents as those described above for X in the component (B) can be used. However, in Z^{2c}, the carbon adjacent to the sulfur (S) atom within SO₃⁻ has no fluorine atom as a substituent. By virtue of SO₃⁻ having no fluorine atom adjacent thereto, the anion of the component (d1-2) becomes an appropriately weak acid anion, thereby improving the quenching ability of the component (D).

Specific examples of preferable anion moieties for the component (d1-2) are shown below.

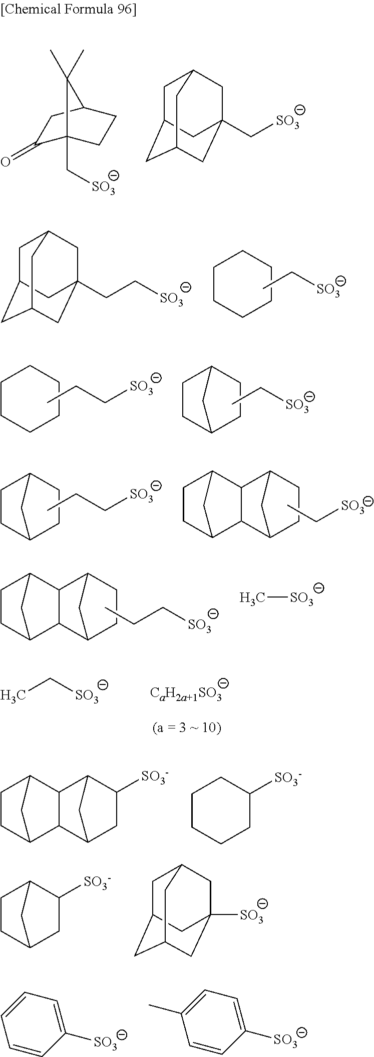

Cation Moiety

In formula (d1-2), M⁺ is the same as defined for M⁺ in the aforementioned formula (d1-1)

As the component (d1-2), one type of compound may be used alone, or two or more types of compounds may be used in combination.

[Component (d1-3)]

Anion Moiety

In formula (d1-3), R⁵ represents an organic group.

The organic group for R⁵ is not particularly limited, and examples thereof include an alkyl group, an alkoxy group, —O—C(═O)—C(R^{C2})═CH₂ (R^{C2} represents a hydrogen atom, an alkyl group of 1 to 5 carbon atoms or a halogenated alkyl group of 1 to 5 carbon atoms) and —O—C(═O)—R^{C3} (R^{C3} represents a hydrocarbon group).

The alkyl group for R⁵ is preferably a linear or branched alkyl group of 1 to 5 carbon atoms, and specific examples thereof include a methyl group, an ethyl group, a propyl group, an isopropyl group, an n-butyl group, an isobutyl group, a tert-butyl group, a pentyl group, an isopentyl group and a neopentyl group. Part of the hydrogen atoms within the alkyl group for R⁵ may be substituted with a hydroxyl group, a cyano group or the like.

The alkoxy group for R⁵ is preferably an alkoxy group of 1 to 5 carbon atoms, and specific examples thereof include a methoxy group, an ethoxy group, an n-propoxy group, an iso-propoxy group, an n-butoxy group and a tert-butoxy group. Among these, a methoxy group and an ethoxy group are particularly desirable.

When R⁵ is —O—C(═O)—C(R^{C2})═CH₂, R^{C2} represents a hydrogen atom, an alkyl group of 1 to 5 carbon atoms or a halogenated alkyl group of 1 to 5 carbon atoms.

The alkyl group of 1 to 5 carbon atoms for R^{C2} is preferably a linear or branched alkyl group of 1 to 5 carbon atoms, and specific examples thereof include a methyl group, an ethyl group, a propyl group, an isopropyl group, an n-butyl group, an isobutyl group, a tert-butyl group, a pentyl group, an isopentyl group and a neopentyl group.

The halogenated alkyl group for R^{C2} is a group in which part or all of the hydrogen atoms of the aforementioned alkyl group of 1 to 5 carbon atoms has been substituted with halogen atoms. Examples of the halogen atom include a fluorine atom, a chlorine atom, a bromine atom and an iodine atom, and a fluorine atom is particularly desirable.

As R^{C2}, a hydrogen atom, an alkyl group of 1 to 3 carbon atoms or a fluorinated alkyl group of 1 to 3 carbon atoms is preferable, and a hydrogen atom or a methyl group is particularly desirable in terms of industrial availability.

When R⁵ is —O—C(═O)—R^{C3}, R^{C3} represents a hydrocarbon group.

The hydrocarbon group for R^{C3} may be either an aromatic hydrocarbon group or an aliphatic hydrocarbon group. Specific examples of the hydrocarbon group for R^{C3} include the same groups as those described above for R⁴ in the above formula (d1-1).

Among these, as the hydrocarbon group for R^{C3}, an alicyclic group (e.g., a group in which one or more hydrogen atoms have been removed from a cycloalkane such as cyclopentane, cyclohexane, adamantane, norbornane, isobornane, tricyclodecane or tetracyclododecane) or an aromatic group (e.g., a phenyl group or a naphthyl group) is preferable. When R^{C3} is an alicyclic group, the resist composition can be satisfactorily dissolved in an organic solvent, thereby improving the lithography properties. Alternatively, when R^{C3} is an aromatic group, the resist composition exhibits an excellent photoabsorption efficiency in a lithography process using EUV or the like as the exposure light source, thereby resulting in the improvement of the sensitivity and the lithography properties.

Among these, as R⁵, —O—C(═O)—C(R^{C2}′)═CH₂ (R^{C2}′ represents a hydrogen atom or a methyl group) or —O—C(═O)—R^{C3}′ (R^{C3}′ represents an aliphatic cyclic group) is preferable.

In formula (d1-3), Y⁵ represents a linear, branched or cyclic alkylene group or an arylene group.

Examples of the linear, branched or cyclic alkylene group or the arylene group for Y⁵ include the same “linear or branched aliphatic hydrocarbon groups”, “cyclic aliphatic hydrocarbon groups” and “aromatic hydrocarbon groups” as those described above as the divalent linking group for L⁰¹ in the aforementioned formula (I-1).

Among these, as Y⁵, an alkylene group is preferable, a linear or branched alkylene group is more preferable, and a methylene group or an ethylene group is still more preferable.

In formula (d1-3), R^{f3} represents a hydrocarbon group containing a fluorine atom.

The hydrocarbon group containing a fluorine atom for R^{f3} is preferably a fluorinated alkyl group, and more preferably the same fluorinated alkyl groups as those described above for R⁴.

Specific examples of preferable anion moieties for the component (d1-3) are shown below.

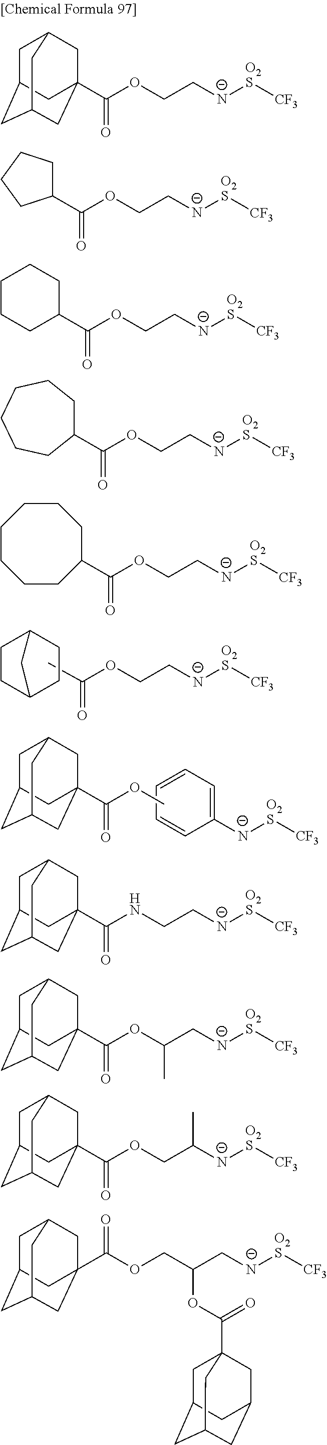

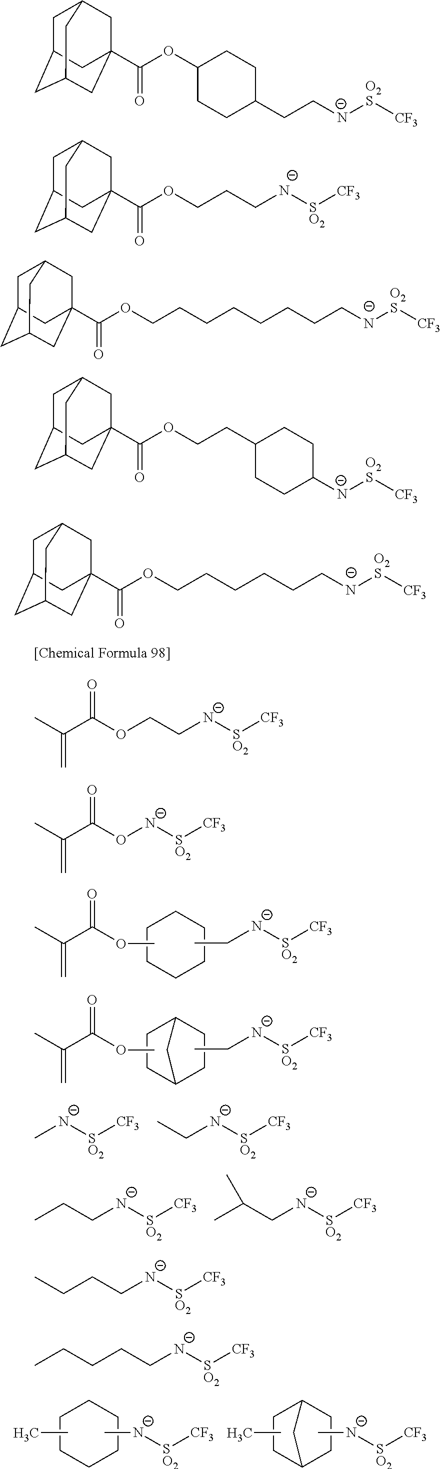

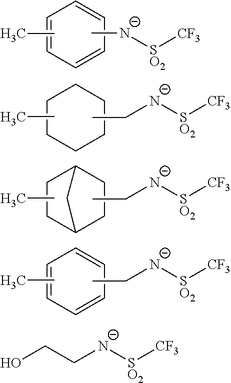

Cation Moiety

In formula (d1-3), M⁺ is the same as defined for M⁺ in the aforementioned formula (d1-1)

As the component (d1-3), one type of compound may be used alone, or two or more types of compounds may be used in combination.

The component (D1) may contain any one of the aforementioned components (d1-1) to (d1-3), or a combination of two or more types thereof. Of these, it is particularly desirable to contain the component (d1-2).

The amount of the component (D1) is preferably from 0.5 to 10.0 parts by weight, more preferably from 0.5 to 8.0 parts by weight, still more preferably from 1.0 to 8.0 parts by weight, and most preferably 2.5 to 5.5 parts by weight, relative to 100 parts by weight of the component (A). When the amount of the component (D1) is at least as large as the lower limit of the above-mentioned range, excellent lithography properties and excellent resist pattern shape can be obtained. On the other hand, when the amount of the component (D1) is no more than the upper limit of the above-mentioned range, sensitivity can be maintained at a satisfactory level, and throughput becomes excellent.

(Production Method of Components (d1-1) to (d1-3))

The production methods of the components (d1-1) and (d1-2) are not particularly limited, and the components (d1-1) and (d1-2) can be produced by conventional methods.

The production method of the component (d1-3) is not particularly limited. For example, in the case where R⁵ in the aforementioned formula (d1-3) is a group having an oxygen atom on the terminal thereof which is bonded to Y⁵, a compound (i-1) represented by general formula (i-1) shown below can be reacted with a compound (i-2) represented by general formula (i-2) shown below to obtain a compound (i-3) represented by general formula (i-3) shown below, and the compound (i-3) can be reacted with a compound (i-4) having a desired cation M⁺ (Z⁻M⁺), thereby producing a compound (d1-3) represented by general formula (d1-3).

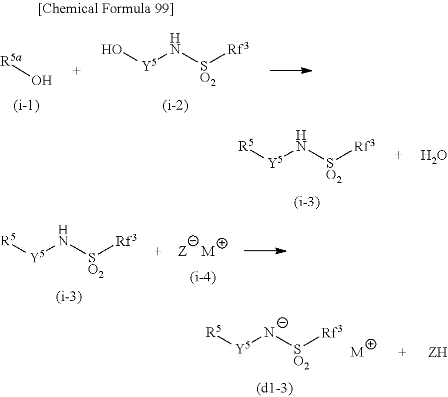

In the formulas, R⁵, Y⁵, R^{f3} and M⁺ are respectively the same as defined above for R⁵, Y⁵, R^{f3} and M⁺ in general formula (d1-3); R^{5a} represents a group in which the terminal oxygen atom has been removed from R⁵; and Z⁻ represents a counter anion.

Firstly, the compound (i-1) is reacted with the compound (i-2), to thereby obtain the compound (i-3).

In formula (i-1), R^{5a} represents a group in which the terminal oxygen atom has been removed from R⁵. In formula (i-2), Y⁵ and R^{f3} are the same as defined above.

As the compound (i-1) and the compound (i-2), commercially available compounds may be used, or the compounds may be synthesized.

The method for reacting the compound (i-1) with the compound (i-2) to obtain the compound (i-3) is not particularly limited, but can be performed, for example, by reacting the compound (i-1) with the compound (i-2) in an organic solvent in the presence of an appropriate acid catalyst, followed by washing and recovering the reaction mixture.

The acid catalyst used in the above reaction is not particularly limited, and examples thereof include toluene sulfonic acid and the like. The amount of the acid catalyst is preferably about 0.05 to about 5 moles, per 1 mole of the compound (i-2).

As the organic solvent used in the above reaction, any organic solvent which is capable of dissolving the raw materials, i.e., the compound (i-1) and the compound (i-2) can be used, and specific examples thereof include toluene and the like. The amount of the organic solvent is preferably 0.5 to 100 parts by weight, more preferably 0.5 to 20 parts by weight, relative to the amount of the compound (i-1). As a solvent, one type of solvent may be used alone, or two or more types of solvents may be used in combination.

In general, the amount of the compound (i-2) used in the above reaction is preferably about 0.5 to about 5 moles per 1 mole of the compound (i-1), and more preferably about 0.8 to about 4 moles per 1 mole of the compound (i-1).

The reaction time depends on the reactivity of the compounds (i-1) and (i-2), the reaction temperature or the like. However, in general, the reaction time is preferably 1 to 80 hours, and more preferably 3 to 60 hours.

The reaction temperature in the above reaction is preferably 20° C. to 200° C., and more preferably about 20° C. to about 150° C.

Next, the obtained compound (i-3) is reacted with the compound (i-4), thereby obtaining the compound (d1-3).

In formula (i-4), M⁺ is the same as defined above, and Z⁻ represents a counter anion.

The method for reacting the compound (i-3) with the compound (i-4) to obtain the compound (d1-3) is not particularly limited, but can be performed, for example, by dissolving the compound (i-3) in an appropriate organic solvent and water in the presence of an appropriate alkali metal hydroxide, followed by addition of the compound (i-4) and stifling to effect the reaction.

The alkali metal hydroxide used in the above reaction is not particularly limited, and examples thereof include sodium hydroxide, potassium hydroxide and the like. The amount of the alkali metal hydroxide is preferably about 0.3 to 3 moles, per 1 mole of the compound (i-3).

Examples of the organic solvent used in the above reaction include dichloromethane, chloroform, ethyl acetate and the like. The amount of the organic solvent is preferably 0.5 to 100 parts by weight, and more preferably 0.5 to 20 parts by weight, relative to the weight of the compound (i-3). As a solvent, one type of solvent may be used alone, or two or more types of solvents may be used in combination.

In general, the amount of the compound (i-4) used in the above reaction is preferably about 0.5 to about 5 moles per 1 mole of the compound (i-3), and more preferably about 0.8 to about 4 moles per 1 mole of the compound (i-3).

The reaction time depends on the reactivity of the compounds (i-3) and (i-4), the reaction temperature or the like. However, in general, the reaction time is preferably 1 to 80 hours, and more preferably 3 to 60 hours.

The reaction temperature in the above reaction is preferably 20° C. to 200° C., and more preferably about 20° C. to about 150° C.

After the reaction, the compound (d1-3) contained in the reaction mixture may be separated and purified. The separation and purification can be conducted by a conventional method. For example, any one of concentration, solvent extraction, distillation, crystallization, recrystallization and chromatography can be used alone, or two or more of these methods may be used in combination.

The structure of the compound (d1-3) obtained in the manner described above can be confirmed by a general organic analysis method such as ¹H-nuclear magnetic resonance (NMR) spectrometry, ¹³C-NMR spectrometry, ¹⁹F-NMR spectrometry, infrared absorption (IR) spectrometry, mass spectrometry (MS), elementary analysis and X-ray diffraction analysis.

### [Component (D2)]

The component (D2) is not particularly limited and any of the conventionally known compounds may be used, as long as it is a compound which is basic relative to the component (A) or the component (B); functions as an acid diffusion control agent, namely, a quencher which traps the acid generated from the component (A) and the component (B) upon exposure; and also does not fall under the definition of the component (D1). Examples of these conventional compounds include amines such as aliphatic amines and aromatic amines, and of these, an aliphatic amine, and particularly a secondary aliphatic amine or tertiary aliphatic amine, is preferable.

An aliphatic amine is an amine having one or more aliphatic groups, and the aliphatic groups preferably have 1 to 12 carbon atoms.

Examples of these aliphatic amines include amines in which at least one hydrogen atom of ammonia (NH₃) has been substituted with an alkyl group or hydroxyalkyl group of not more than 20 carbon atoms (namely, alkylamines or alkyl alcohol amines), cyclic amines, and other aliphatic amines.

The alkyl group within the alkylamine may be linear, branched or cyclic.

When the alkyl group is a linear or branched group, the group preferably contains 2 to 20 carbon atoms, and more preferably 2 to 8 carbon atoms.

When the alkyl group is a cyclic group (namely, a cycloalkyl group), the cycloalkyl group preferably contains 3 to 30 carbon atoms, more preferably 3 to 20 carbon atoms, still more preferably 3 to 15 carbon atoms, still more preferably 4 to 12 carbon atoms, and most preferably 5 to 10 carbon atoms. The cycloalkyl group may be either monocyclic or polycyclic. Examples thereof include groups in which one or more of the hydrogen atoms have been removed from a monocycloalkane; and groups in which one or more of the hydrogen atoms have been removed from a polycycloalkane such as a bicycloalkane, a tricycloalkane, or a tetracycloalkane. Specific examples of the monocycloalkane include cyclopentane and cyclohexane. Further, specific examples of the polycycloalkane include adamantane, norbornane, isobornane, tricyclodecane and tetracyclododecane.

Examples of the alkyl group of the hydroxyalkyl group within the aforementioned alkyl alcohol amine include the same groups as those mentioned above for the alkyl group within the alkylamine.

Specific examples of the alkylamine include monoalkylamines such as n-hexylamine, n-heptylamine, n-octylamine, n-nonylamine and n-decylamine; dialkylamines such as diethylamine, di-n-propylamine, di-n-heptylamine, di-n-octylamine and dicyclohexylamine; and trialkylamines such as trimethylamine, triethylamine, tri-n-propylamine, tri-n-butylamine, tri-n-hexylamine, tri-n-pentylamine, tri-n-heptylamine, tri-n-octylamine, tri-n-nonylamine, tri-n-decanylamine and tri-n-dodecylamine.

Specific examples of the alkyl alcohol amines include diethanolamine, triethanolamine, diisopropanolamine, tri isopropanolamine, di-n-octanolamine, tri-n-octanolamine, stearyldiethanolamine and lauryldiethanolamine.

Among these, trialkylamines of 5 to 10 carbon atoms are more preferable, and tri-n-pentylamine or tri-n-octylamine is particularly desirable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples thereof include 1,5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanolamine triacetate.

Examples of aromatic amines include aniline, pyridine, 4-dimethylaminopyridine, pyrrole, indole, pyrazole, imidazole and derivatives thereof, as well as diphenylamine, triphenylamine, tribenzylamine, 2,6-diisopropylaniline and N-tert-butoxycarbonyl pyrrolidine.

As the component (D2), any of the above compounds may be used alone, or two or more different compounds may be used in combination.

The component (D2) is typically used in an amount within a range from 0.01 to 5.0 parts by weight, relative to 100 parts by weight of the component (A). By ensuring that the amount of the component (D2) is within the aforementioned range, the shape of the resist pattern and the post exposure stability of the latent image formed by the pattern-wise exposure of the resist layer are improved.

As the component (D), one type of compound may be used alone, or two or more types of compounds may be used in combination.

When the resist composition of the present aspect contains the component (D), the amount of the component (D) relative to 100 parts by weight of the component (A) is preferably within a range from 0.1 to 15 parts by weight, more preferably from 0.3 to 12 parts by weight, and still more preferably from 0.5 to 12 parts by weight. When the amount of the component (D) is at least as large as the lower limit of the above-mentioned range, various lithography properties (such as roughness) are further improved. Further, a resist pattern having an excellent shape can be obtained. On the other hand, when the amount of the component (D) is no more than the upper limit of the above-mentioned range, sensitivity can be maintained at a satisfactory level, and throughput becomes excellent.

Furthermore, in the resist composition of the present aspect, for the purposes of preventing any deterioration in sensitivity, and improving the resist pattern shape and the post exposure stability of the latent image formed by the pattern-wise exposure of the resist layer, at least one compound (E) (hereinafter referred to as “component (E)”) selected from the group consisting of an organic carboxylic acid, a phosphorus oxo acid and derivatives thereof can also be added as an optional component.

Examples of suitable organic carboxylic acids include acetic acid, malonic acid, citric acid, malic acid, succinic acid, benzoic acid, and salicylic acid.

Examples of phosphorus oxo acids include phosphoric acid, phosphonic acid and phosphinic acid, and among these, phosphonic acid is particularly desirable.

Examples of phosphorus oxo acid derivatives include esters in which a hydrogen atom within an above-mentioned oxo acid is substituted with a hydrocarbon group. Examples of the hydrocarbon group include an alkyl group of 1 to 5 carbon atoms and an aryl group of 6 to 15 carbon atoms.

Examples of phosphoric acid derivatives include phosphoric acid esters such as di-n-butyl phosphate and diphenyl phosphate.

Examples of phosphonic acid derivatives include phosphonic acid esters such as dimethyl phosphonate, di-n-butyl phosphonate, phenyl phosphonate, diphenyl phosphonate and dibenzyl phosphonate.

Examples of phosphinic acid derivatives include phosphinic acid esters and phenylphosphinic acid.

As the component (E), one type may be used alone, or two or more types may be used in combination.

The component (E) is typically used in an amount within a range from 0.01 to 5.0 parts by weight, relative to 100 parts by weight of the component (A).

If desired, other miscible additives can also be added to the resist composition of the present aspect. Examples of such miscible additives include additive resins for improving the performance of the resist film, surfactants for improving the applicability, dissolution inhibitors, plasticizers, stabilizers, colorants, halation prevention agents, and dyes.

The resist composition of the present aspect can be prepared by dissolving the materials for the resist composition in an organic solvent (hereafter, frequently referred to as “component (S)”).

The component (S) may be any organic solvent which can dissolve the respective components to give a uniform solution, and one or more kinds of any organic solvent can be appropriately selected from those which have been conventionally known as solvents for a chemically amplified resist.

Examples thereof include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; polyhydric alcohol derivatives including compounds having an ether bond, such as a monoalkylether (e.g., monomethylether, monoethylether, monopropylether or monobutylether) or monophenylether of any of these polyhydric alcohols or compounds having an ester bond (among these, propylene glycol monomethyl ether acetate (PGMEA) and propylene glycol monomethyl ether (PGME) are preferable); cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; and aromatic organic solvents such as anisole, ethylbenzylether, cresylmethylether, diphenylether, dibenzylether, phenetole, butylphenylether, ethylbenzene, diethylbenzene, pentyl benzene, isopropylbenzene, toluene, xylene, cymene and mesitylene.

These organic solvents may be used individually, or as a mixed solvent containing two or more different solvents.

Among these, propylene glycol monomethyl ether acetate (PGMEA), propylene glycol monomethyl ether (PGME) and ethyl lactate (EL) are preferable.

Further, among the mixed solvents, a mixed solvent obtained by mixing PGMEA with a polar solvent is preferable. The mixing ratio (weight ratio) of the mixed solvent can be appropriately determined, taking into consideration the compatibility of the PGMEA with the polar solvent, but is preferably in the range of 1:9 to 9:1, more preferably from 2:8 to 8:2. For example, when EL is mixed as the polar solvent, the PGMEA:EL weight ratio is preferably from 1:9 to 9:1, and more preferably from 2:8 to 8:2. Alternatively, when PGME is mixed as the polar solvent, the PGMEA:PGME weight ratio is preferably from 1:9 to 9:1, more preferably from 2:8 to 8:2, and still more preferably from 3:7 to 7:3. Alternatively, when PGME and cyclohexanone are mixed in combination as the polar solvent, the PGMEA:(PGME+cyclohexanone) weight ratio is preferably from 1:9 to 9:1, more preferably from 2:8 to 8:2, and still more preferably from 3:7 to 7:3.

Further, as the component (S), a mixed solvent of PGMEA, EL or an aforementioned mixed solvent of PGMEA and a polar solvent, with γ-butyrolactone is also preferable. The mixing ratio (former:latter) of such a mixed solvent is preferably from 70:30 to 95:5.

There are no particular limitations on the amount used of the component (S), which may be adjusted appropriately to produce a concentration that enables application of a coating solution onto a substrate in accordance with the thickness of the coating film. In general, the organic solvent is used in an amount that yields a solid fraction concentration for the resist composition that is within a range from 1 to 20% by weight, and preferably from 2 to 15% by weight.

### <<Resist Composition According to Second Aspect>>

A resist composition according to a second aspect of the present invention is a resist composition for use with EUV or EB which is characterized by including a resin component (C) containing at least one type of atom selected from the group consisting of a fluorine atom and a silicon atom, an aromatic group, and a polarity conversion group that decomposes by the action of a base to increase the polarity (hereafter, referred to as component (C′)); a resin component (A) that exhibits changed solubility in a developing solution under the action of acid (provided that the aforementioned component (C′) is excluded, and hereafter referred to as component (A′)); and an acid generator component (B) that generates acid upon exposure (hereafter, referred to as component (B′)), wherein an amount of a structural unit having the aforementioned aromatic group in the aforementioned resin component (C′) is at least 20 mol %, and the amount of the aforementioned component (B′) is 15 parts by weight or more, relative to 100 parts by weight of the aforementioned component (A′).

The component (C′) used in the present aspect is the same as the component (C) mentioned within the description of the resist composition according to the first aspect.

As the component (C′), one type of component may be used alone, or two or more types may be used in combination.

In the resist composition of the present aspect, the amount of the component (C′) is preferably from 1 to 15 parts by weight, more preferably from 2 to 14 parts by weight, and still more preferably from 3 to 12 parts by weight, relative to 100 parts by weight of the component (A). Provided the amount is at least 1 part by weight, the pattern shape and resolution limit and the like are improved for a resist pattern formed by EUV exposure or EB exposure. When the amount is not more than 15 parts by weight, a good balance can be achieved with the component (A), and the lithography properties such as the shape and resolution are improved.

### <Component (A′)>

As the component (A′), the same components as those listed above as the component (A) mentioned within the description of the resist composition according to the first aspect may be used, although it is preferable to use a resin component other than the component (A) that exhibits changed solubility in a developing solution under the action of acid. In other words, a resin component that exhibits changed solubility in a developing solution under the action of acid and also does not generate an acid upon exposure is preferably used. There are no particular limitations on the resin component, which may be selected appropriately from those used as the base resins within conventional chemically amplified resist compositions.

For example, in those cases where the resist composition of the present aspect is a resist composition which forms a negative-type resist pattern in an alkali developing process (or forms a positive-type resist pattern in a solvent developing process), a resin component which generates acid upon exposure and is also soluble in an alkali developing solution (hereinafter, sometimes referred to as “component (A2′)”) is preferably used as the component (A′), and a cross-linking agent is further added to the composition. In this resist composition, when acid is generated from the component (B) upon exposure, the action of the acid causes cross-linking between the component (A2′) and the cross-linking agent, and as a result, the solubility in an alkali developing solution decreases (whereas the solubility in an organic developing solution increases). Accordingly, during resist pattern formation, by conducting selective exposure of a resist film formed by applying the resist composition onto a substrate, the exposed portions change to a state that is substantially insoluble in an alkali developing solution (but soluble in an organic developing solution), while the unexposed portions remain soluble in an alkali developing solution (but substantially insoluble in an organic developing solution), meaning developing with an alkali developing solution can be used to form a negative-type resist pattern. Further, if an organic developing solution is used as the developing solution, then a positive-type resist pattern can be formed.

As the component (A2′), conventional resins that are soluble in an alkali developing solution (hereinafter referred to as “alkali-soluble resins”) can be used. Examples of the alkali-soluble resin include a resin having a structural unit derived from at least one of an α-(hydroxyalkyl)acrylic acid and an alkyl ester of α-(hydroxyalkyl)acrylic acid (preferably an alkyl ester having 1 to 5 carbon atoms), as disclosed in Japanese Unexamined Patent Application, First Publication No. 2000-206694; an acrylic resin or polycycloolefin resin having a sulfonamide group, and in which an atom other than a hydrogen atom or a substituent may be bonded to the carbon atom on the α-position, as disclosed in U.S. Pat. No. 6,949,325; an acrylic resin containing a fluorinated alcohol, and in which an atom other than a hydrogen atom or a substituent may be bonded to the carbon atom on the α-position, as disclosed in U.S. Pat. No. 6,949,325, Japanese Unexamined Patent Application, First Publication No. 2005-336452 or Japanese Unexamined Patent Application, First Publication No. 2006-317803; and a polycycloolefin resin having a fluorinated alcohol, as disclosed in Japanese Unexamined Patent Application, First Publication No. 2006-259582. These resins are preferable in that a resist pattern can be formed with minimal swelling.

The term “α-(hydroxyalkyl)acrylic acid” refers to one or both of acrylic acid in which a hydrogen atom is bonded to the carbon atom on the α-position having the carboxyl group bonded thereto, and α-hydroxyalkylacrylic acid in which a hydroxyalkyl group (and preferably a hydroxyalkyl group of 1 to 5 carbon atoms) is bonded to the carbon atom on the α-position.

As the cross-linking agent, usually, an amino-based cross-linking agent such as a glycoluril having a methylol group or alkoxymethyl group, or a melamine-based cross-linking agent is preferable, as it enables formation of a resist pattern with minimal swelling. The amount of the cross-linking agent added is preferably within a range from 1 to 50 parts by weight, relative to 100 parts by weight of the alkali-soluble resin.

In those cases where the resist composition of the present aspect is a resist composition which forms a positive-type resist pattern in an alkali developing process, and forms a negative-type resist pattern in a solvent developing process, a resin component which exhibits increased polarity under the action of acid (hereinafter, sometimes referred to as “component (A1″)”) is preferably used as the component (A′). Because the polarity of the component (A1′) changes upon exposure, by using the component (A1′), favorable developing contrast can be achieved, not only in an alkali developing process, but also in a solvent developing process.

In other words, in those cases where an alkali developing process is employed, the component (A1′) is substantially insoluble in an alkali developing solution prior to exposure, but when acid is generated from the component (B) upon exposure, the action of the acid causes an increase in the polarity that increases the solubility in the alkali developing solution. Accordingly, during resist pattern formation, by conducting selective exposure of a resist film formed by applying the resist composition onto a substrate, the exposed portions change from being substantially insoluble in the alkali developing solution to being soluble, while the unexposed portions remain substantially insoluble in the alkali developing solution, meaning alkali developing can be used to form a positive-type resist pattern. On the other hand, when a solvent developing process is employed, the component (A1′) exhibits high solubility in an organic developing solution prior to exposure, but when acid is generated from the component (B) upon exposure, the action of the acid causes an increase in the polarity that reduces the solubility in the organic developing solution. Accordingly, during resist pattern formation, by conducting selective exposure of a resist film formed by applying the resist composition onto a substrate, the exposed portions change from being soluble in the organic developing solution to being substantially insoluble, while the unexposed portions remain soluble in the organic developing solution, meaning developing with the organic developing solution can be used to achieve contrast between the exposed portions and the unexposed portions, enabling formation of a negative-type resist pattern.

In the present aspect, the component (A′) is preferably the component (A1′). That is, the resist composition of the present aspect is preferably a chemically amplified resist composition which becomes a positive type in the case of an alkali developing process, and a negative type in the case of a solvent developing process.

Examples of the component (A1′) include a resin component containing the aforementioned structural unit (a1).

The structural unit (a1) contained within the component (A1′) may be either a single type of structural unit or a combination of two or more types of structural units.

The amount of the structural unit (a1) within the component (A1′), based on the combined total of all the structural units that constitute the component (A1′), is preferably within a range from 15 to 70 mol %, more preferably from 15 to 60 mol %, and still more preferably from 20 to 55 mol %. When the amount of the structural unit (a1)) is at least as large as the lower limit of the above range, a pattern can be formed easily using a resist composition prepared from the component (A1′), and the lithography properties such as the sensitivity, the resolution and the pattern shape also improve. On the other hand, when the amount of the structural unit (a1)) is not more than the upper limit of the above range, a good balance can be achieved with the other structural units.

It is preferable that the component (A1′) further include the aforementioned structural unit (a2), as well as the structural unit (a1).

The structural unit (a2) of the component (A1′) may be either a single type of structural unit or a combination of two or more types of structural units. For example, as the structural unit (a2), the structural unit (a2^{S}) may be used alone, the structural unit (a2^{L}) may be used alone, or the structural units (a2^{S}) and (a2^{L}) may be used in combination. Further, as the structural unit (a2^{S}) or the structural unit (a2^{L}), one type of structural unit may be used alone, or two or more types of structural units may be used in combination.

In the component (A1′), the amount of the structural unit (a2) based on the combined total of all structural units constituting the component (A1′) is preferably 1 to 80 mol %, more preferably 10 to 70 mol %, still more preferably 10 to 65 mol %, and most preferably 10 to 60 mol %. When the amount of the structural unit (a2) is at least as large as the lower limit of the above-mentioned range, the effect of using the structural unit (a2) can be satisfactorily achieved. On the other hand, when the amount of the structural unit (a2) is no more than the upper limit of the above-mentioned range, a good balance can be achieved with the other structural units, and various lithography properties such as DOF and CDU and pattern shape can be improved.

The component (A1′) may also include the aforementioned structural unit (a3), either in addition to the structural unit (a1), or in addition to the structural units (a1)) and (a2).

The structural unit (a3) of the component (A1′) may be either a single type of structural unit or a combination of two or more types of structural units.

The amount of the structural unit (a3) within the component (A1′) based on the combined total of all structural units constituting the component (A1′) is preferably 1 to 85 mol %, and more preferably 5 to 80 mol %. When the amount of the structural unit (a3) is at least as large as the lower limit of the above-mentioned range, the effects of using the structural unit (a3) (namely, the effect of improving various lithography properties such as the resolution and the pattern shape) can be satisfactorily achieved. On the other hand, when the amount of the structural unit (a3) is no more than the upper limit of the above-mentioned range, a good balance can be achieved with the other structural units.

The component (A1′) may also include the aforementioned structural unit (a4), in addition to the structural unit (a1), in addition to the structural units (a1) and (a2), or in addition to the structural units (a1) to (a3).

In this case, the structural unit (a4) of the component (A1′) may be either a single type of structural unit or a combination of two or more types of structural units.

When the component (A1′) includes the structural unit (a4), the amount of the structural unit (a4) within the component (A1′), based on the combined total of all the structural units that constitute the component (A1′), is preferably within a range from 1 to 30 mol %, more preferably from 1 to 20 mol %, and still more preferably from 5 to 20 mol %. When the amount of the structural unit (a4) is at least as large as the lower limit of the above range, the effect of using the structural unit (a4) can be satisfactorily achieved. On the other hand, when the amount of the structural unit (a4) is no more than the upper limit of the above range, a good balance can be achieved with the other structural units.

The component (A1′) may also include structural units other than the aforementioned structural units (a0) to (a4), as long as the effects of the present invention are not impaired.

As these other structural units, any other structural unit which cannot be classified as one of the above structural units (a0) to (a4) can be used without any particular limitations, and any of the multitude of conventional structural units used within resist resins designed for use with ArF excimer lasers, KrF excimer lasers, EB and EUV can be used.

In the present invention, the component (A1′) is preferably a polymer containing the structural unit (a1), is more preferably a copolymer containing the structural units (a1) and (a2), and is still more preferably a copolymer containing the structural units (a1), (a2) and (a3).

Examples of the polymer containing the structural unit (a1) include a copolymer consisting of the structural unit (a1), a copolymer consisting of the structural units (a1) and (a2), a copolymer consisting of the structural units (a1) and (a3), a copolymer consisting of the structural units (a1), (a2) and (a3), and a copolymer consisting of the structural units (a1), (a2), (a3) and (a4).

The weight average molecular weight (Mw) (the polystyrene equivalent value determined by gel permeation chromatography (GPC)) of the component (A′) is not particularly limited, but is preferably within a range from 1,000 to 50,000, more preferably from 1,500 to 30,000, and most preferably from 2,000 to 20,000. When the weight average molecular weight is no more than the upper limit of the above-mentioned range, the resist composition exhibits a satisfactory solubility in a resist solvent when used as a resist. On the other hand, when the weight average molecular weight is at least as large as the lower limit of the above-mentioned range, dry etching resistance and the cross-sectional shape of the resist pattern becomes satisfactory.

Further, although there are no particular limitations on the dispersity (Mw/Mn), the dispersity is preferably from 1.0 to 5.0, more preferably from 1.0 to 3.0, and most preferably from 1.0 to 2.5. Here, Mn is the number average molecular weight.

The component (A′) can be obtained, for example, by a conventional radical polymerization or the like of the monomers corresponding with each of the structural units, using a radical polymerization initiator such as azobisisobutyronitrile (AIBN).

Furthermore, in the component (A′), by using a chain transfer agent such as HS—CH₂—CH₂—CH₂—C(CF₃)₂—OH during the aforementioned polymerization, a —C(CF₃)₂—OH group can be introduced at the terminals of the component (A′). Such a copolymer having an introduced hydroxyalkyl group in which some of the hydrogen atoms of the alkyl group have been substituted with fluorine atoms is effective in reducing developing defects and LER (line edge roughness: unevenness in the side walls of a line pattern).

As the monomers for deriving the corresponding structural units, commercially available monomers may be used, or the monomers synthesized by a conventional method may be used.

As the component (A′), one type of component may be used alone, or two or more types may be used in combination.

In the resist composition of the present aspect, the amount of the component (A′) can be appropriately adjusted depending on the thickness of the resist film to be formed, and the like.

As the component (B′) used in the present aspect, the same as those described above for the component (B) in connection with the resist composition according to the first aspect can be used.

As the component (B′), one type of component may be used alone, or two or more types may be used in combination.

In the resist composition of the present aspect, the amount of the component (B′) is at least 15 parts by weight, preferably from 20 to 70 parts by weight, more preferably from 30 to 60 parts by weight, and still more preferably from 35 to 55 parts by weight, relative to 100 parts by weight of the component (A). When the amount of the component (B′) is within the above-mentioned range, lithography properties such as the pattern shape, resolution limit, roughness and exposure latitude (EL) are improved for a resist pattern formed by EUV exposure or EB exposure.

The resist composition of the present aspect may also contain a basic compound (hereafter referred to as the component (D′)) as an optional component.

Examples of the component (D′) include the same as those described above for the component (D).

As the component (D′), one type of compound may be used alone, or two or more types of compounds may be used in combination.

When the resist composition of the present aspect contains the component (D′), the amount of the component (D′) relative to 100 parts by weight of the component (A) is preferably within a range from 0.1 to 15 parts by weight, more preferably from 0.3 to 12 parts by weight, and still more preferably from 0.5 to 12 parts by weight. When the amount of the component (D′) is at least as large as the lower limit of the above-mentioned range, various lithography properties (such as roughness) are further improved. Further, a resist pattern having an excellent shape can be obtained. On the other hand, when the amount of the component (D′) is no more than the upper limit of the above-mentioned range, sensitivity can be maintained at a satisfactory level, and throughput becomes excellent.

Furthermore, in the resist composition of the present aspect, for the purposes of preventing any deterioration in sensitivity, and improving the resist pattern shape and the post exposure stability of the latent image formed by the pattern-wise exposure of the resist layer, at least one compound (hereinafter referred to as “component (E′)”) selected from the group consisting of an organic carboxylic acid, a phosphorus oxo acid and derivatives thereof can also be added as an optional component.

Examples of the component (E′) include the same as those described above for the component (E).

As the component (E′), one type may be used alone, or two or more types may be used in combination.

The component (E′) is typically used in an amount within a range from 0.01 to 5.0 parts by weight, relative to 100 parts by weight of the component (A).

If desired, other miscible additives can also be added to the resist composition of the present aspect. Examples of such miscible additives include additive resins for improving the performance of the resist film, surfactants for improving the applicability, dissolution inhibitors, plasticizers, stabilizers, colorants, halation prevention agents, and dyes.

The resist composition of the present aspect can be prepared by dissolving the materials for the resist composition in an organic solvent (hereafter, frequently referred to as “component (S′)”).

The component (S′) may be any organic solvent which can dissolve the respective components to give a uniform solution, and any one or more kinds of organic solvents can be appropriately selected from those which have been conventionally known as solvents for a chemically amplified resist. Examples of the component (S′) include the same as those described above for the component (S).

There are no particular limitations on the amount used of the component (S′), which may be adjusted appropriately to produce a concentration that enables application of a coating solution onto a substrate in accordance with the thickness of the coating film. In general, the organic solvent is used in an amount that yields a solid fraction concentration for the resist composition that is within a range from 1 to 20% by weight, and preferably from 2 to 15% by weight.

The resist composition according to the first aspect or second aspect of the present invention described above exhibits superior lithography properties such as the resolution and exposure latitude when forming a resist pattern by EUV exposure or EB exposure, and moreover, is capable of forming a resist pattern having a favorable shape with minimal roughness and exhibiting a high degree of rectangularity for the cross-sectional shape (namely, superior verticalness of the pattern side walls).

It is thought that this is because there is a synergistic action among the fact that inclusion of the component (C) containing a high proportion of structural units having an aromatic group that absorbs light in the DUV region, particularly light having a wavelength of 150 to 300 nm, enables suppression of the adverse effects resulting from the penetration into the unexposed portions of light from the DUV region incorporated within the OoB light generated from the EUV light source or the diffusion (scattering) of electrons in the surface of the resist film during EB exposure (such as the reduction in the optical contrast and the generation of acid in the unexposed portions and the accompanying change in solubility within the developing solution); the fact that incorporating the component (A) having introduced an acid generating region therein as a base resin or incorporating a high concentration of component (B) results in a more uniform distribution of the acid generating regions throughout the resist film; and the fact that the occurrence of developing defects can be suppressed especially after an alkali developing process by including the component (C).

The term “defects” refers to general abnormalities of a resist pattern, which are detected when observed from right above the developed resist pattern, using a surface defect detection apparatus (product name: “KLA”) manufactured by KLA-TENCOR Corporation. Examples of these abnormalities include abnormalities caused by the deposition of foreign substances and deposits on the resist pattern surface, such as post-developing scum (resist residues), foam and dust; abnormalities with regard to the pattern shape, such as bridges across different portions of the line pattern and the filling of holes in contact hole patterns; and color irregularities in the pattern. High hydrophobicity of the resist materials is one of the causes for these defects. Because the hydrophobicity is high, precipitates are easily redeposited during the alkali developing or the subsequent rinsing with water. The component (C) exhibits hydrophobicity at the time of exposure prior to development, while increasing the polarity to exhibit hydrophilicity following an alkali developing process. In addition, by containing a fluorine atom or a silicon atom, the component (C) is likely to be distributed unevenly near the surface of the resist film. For this reason, the surface of the resist film obtained by using a resist composition containing the component (C) becomes hydrophilic following the alkali development. As described above, the surface of the resist film becomes hydrophilic after an alkali developing process, thereby reducing the defects following the development, especially the defects concerning the redeposition of scum and dust onto the film surface (defects known as blobs).

### <<Method of Forming a Resist Pattern>>

The method of forming a resist pattern according to the present invention includes: forming a resist film on a substrate using the resist composition according to the first or second aspect, conducting exposure of the resist film using EUV or EB, and developing the resist film to form a resist pattern.

More specifically, the method of forming a resist pattern according to the present invention can be performed, for example, as follows.

First, the resist composition according to the first or second aspect of the present invention is applied onto a substrate using a spinner or the like, and a bake treatment (post applied bake (PAB)) is conducted under temperature conditions of 80 to 150° C. for 40 to 120 seconds, and preferably 60 to 90 seconds to form a resist film.

Subsequently, the resist film is selectively exposed using an exposure apparatus such as an EB exposure apparatus or an EUV exposure apparatus, either by irradiation through a mask having a predetermined pattern formed therein (namely, a mask pattern), or by patterning via direct irradiation with an electron beam without using a mask pattern, and the resist film is then subjected to a bake treatment (post exposure bake (PEB)) under temperature conditions of 80 to 150° C. for 40 to 120 seconds, and preferably 60 to 90 seconds.

Next, the resist film is subjected to a developing treatment. In the case of an alkali developing process, an alkali developing solution such as a 0.1 to 10% by weight aqueous solution of tetramethylammonium hydroxide (TMAH) is used to perform an alkali developing treatment. In the case of a solvent developing process, an organic solvent is used to perform a developing treatment. As the organic solvent, any of the conventional organic solvents can be used which are capable of dissolving the component (A) (prior to exposure). More specifically, polar solvents such as ketone-based solvents, ester-based solvents, alcohol-based solvents, amide-based solvents or ether-based solvents; and hydrocarbon-based solvents can be used, and among these, ester-based solvents are particularly desirable. As an ester-based solvent, butyl acetate is preferable.

A rinse treatment is preferably performed following the developing treatment. In the case of an alkali developing process, it is preferable to conduct a water rinse using pure water. In the case of a solvent developing process, it is preferable to use a rinse liquid containing the aforementioned organic solvent.

Thereafter, drying is conducted. Further, in some cases, a bake treatment (post bake) may be performed following the above developing treatment.

In this manner, a resist pattern can be obtained. In particular, the resist composition of the present invention is preferably used in the method of forming a positive-type resist pattern in an alkali developing process.

There are no particular limitations on the substrate, and a conventionally known substrate may be used. For example, substrates for electronic components, and such substrates having wiring patterns formed thereon can be used. Specific examples of the material of the substrate include metals such as silicon wafer, copper, chromium, iron and aluminum, as well as glass. Suitable materials for the wiring pattern include copper, aluminum, nickel, and gold.

Further, as the substrate, any one of the above-mentioned substrates provided with an inorganic and/or organic film on the surface thereof may be used. As the inorganic film, an inorganic antireflection film (inorganic BARC) can be used. As the organic film, an organic antireflection film (organic BARC) or an organic film such as a lower-layer organic film used in a multilayer resist method can be used.

Here, a “multilayer resist method” is a method in which at least one layer of an organic film (a lower-layer organic film) and at least one layer of a resist film (an upper-layer resist film) are provided on a substrate, and a resist pattern formed within the upper-layer resist film is used as a mask to conduct patterning of the lower-layer organic film. This method is considered as being capable of forming a pattern with a high aspect ratio. In other words, in the multilayer resist method, a desired thickness can be ensured by the lower-layer organic film, and as a result, the thickness of the resist film can be reduced, and an extremely fine pattern with a high aspect ratio can be formed.

The multilayer resist method can be broadly classified into a method in which a double-layer structure consisting of an upper-layer resist film and a lower-layer organic film is formed (a double-layer resist method), and a method in which a multilayer structure having at least three layers consisting of an upper-layer resist film, a lower-layer organic film and at least one intermediate layer (a thin metal film or the like) provided between the upper-layer resist film and the lower-layer organic film is formed (a triple-layer resist method).

The method of exposing the resist film may employ either a general exposure method (dry exposure) conducted in air or an inert gas such as nitrogen, or an immersion exposure method (a liquid immersion lithography method).

Liquid immersion lithography is a method in which the region between the resist film and the lens at the lowermost portion of the exposure apparatus is pre-filled with a solvent (an immersion medium) that has a larger refractive index than the refractive index of air, and the exposure (immersion exposure) is conducted in this state.

The immersion medium preferably exhibits a refractive index larger than the refractive index of air but smaller than the refractive index of the resist film that is to be exposed. The refractive index of the immersion medium is not particularly limited as long as it satisfies the above-mentioned requirements.

Examples of this immersion medium which exhibits a refractive index that is larger than the refractive index of air but smaller than the refractive index of the resist film include water, fluorine-based inert liquids, silicon-based solvents and hydrocarbon-based solvents.

Specific examples of the fluorine-based inert liquids include liquids containing a fluorine-based compound such as C₃HCl₂F₅, C₄F₉OCH₃, C₄F₉OC₂H₅ or C₅H₃F₇ as the main component, which have a boiling point that is preferably within a range from 70 to 180° C., and more preferably from 80 to 160° C. A fluorine-based inert liquid having a boiling point within the above-mentioned range is advantageous in that the removal of the immersion medium after the exposure can be conducted by a simple method.

As a fluorine-based inert liquid, a perfluoroalkyl compound in which all of the hydrogen atoms of the alkyl group are substituted with fluorine atoms is particularly desirable. Examples of these perfluoroalkyl compounds include perfluoroalkylether compounds and perfluoroalkylamine compounds.

Specifically, one example of a suitable perfluoroalkylether compound is perfluoro(2-butyl-tetrahydrofuran) (boiling point: 102° C.), and one example of a suitable perfluoroalkylamine compound is perfluorotributylamine (boiling point: 174° C.).

As the immersion medium, water is preferable in terms of cost, safety, environmental issues and versatility.

Examples of the alkali developing solution used for the developing treatment in an alkali developing process include 0.1 to 10% by weight aqueous solutions of tetramethylammonium hydroxide (TMAH).

The organic solvent within the organic developing solution that is used for the developing treatment in a solvent developing process may be selected appropriately from among any of the conventional solvents capable of dissolving the component (A) (the component (A) prior to exposure). Specific examples of organic solvents that may be used include polar solvents such as ketone-based solvents, ester-based solvents, alcohol-based solvents, amide-based solvents and ether-based solvents, and hydrocarbon-based solvents.

Conventional additives may be added to the organic developing solution as required. Examples of these additives include surfactants. There are no particular limitations on the surfactants, and ionic and nonionic fluorine-based surfactants and/or silicon-based surfactants can be used.

In those cases where a surfactant is added, the amount of the surfactant is typically within a range from 0.001 to 5% by weight, more preferably from 0.005 to 2% by weight, and still more preferably from 0.01 to 0.5% by weight, relative to the total amount of the organic developing solution.

The developing treatment can be performed by a conventional developing method. Examples of the developing methods include a method in which the substrate is immersed in the developing solution for a certain period of time (a dipping method), a method in which the developing solution is accumulated by surface tension to remain still at the surface of the substrate for a certain period of time (a puddle method), a method in which the developing solution is sprayed onto the surface of the substrate (a spraying method), and a method in which the developing solution is continuously ejected from a developing solution ejecting nozzle while scanning the substrate at a constant rate so as to apply the developing solution onto the substrate which is rotating at a constant rate (a dynamic dispensing method).

Examples of the organic solvent contained within the rinse liquid used for the rinse treatment performed following a solvent developing process include those organic solvents among the solvents described above for the organic solvent of the organic developing solution which exhibit poor dissolution of the resist pattern. Examples of typical solvents that may be used include one or more solvents selected from among hydrocarbon-based solvents, ketone-based solvents, ester-based solvents, alcohol-based solvents, amide-based solvents and ether-based solvents. Among these, at least one solvent selected from among hydrocarbon-based solvents, ketone-based solvents, ester-based solvents, alcohol-based solvents and amide-based solvents is preferred, at least one solvent selected from among alcohol-based solvents and ester-based solvents is more preferred, and an alcohol-based solvent is particularly desirable.

The rinse treatment (washing treatment) using a rinse liquid can be performed using a conventional rinse method. Examples of these methods that may be used include a method in which the rinse liquid is ejected and applied continuously onto the substrate while the substrate is spun at a constant rate (a spin coating method), a method in which the substrate is immersed in the rinse liquid for a certain period of time (a dipping method), and a method in which the rinse liquid is sprayed onto the surface of the substrate (a spraying method).

### EXAMPLES

As follows is a more detailed description of the present invention based on a series of examples, although the scope of the present invention is in no way limited by these examples.

### Examples 1 to 20, Comparative Examples 1 to 5

The components shown in Tables 1 and 2 were mixed together and dissolved to prepare a series of resist compositions.

TABLE 1

| | Component | Component | Component | Component | Component | Component | |
|---|---|---|---|---|---|---|---|
| | (A) | (B) | (C) | (D) | (E) | (S) | |
| Ex. 1 | (A)-1 | (B)-1 | (C)-1 | (D)-1 | (E)-1 | (S)-1 | (S)-2 |
| | [100] | [25.0] | [10] | [1.5] | [0.6] | [100] | [5,000] |
| Ex. 2 | (A)-1 | (B)-1 | (C)-2 | (D)-1 | (E)-1 | (S)-1 | (S)-2 |
| | [100] | [25.0] | [10] | [1.5] | [0.6] | [100] | [5,000] |
| Ex. 3 | (A)-1 | (B)-1 | (C)-3 | (D)-1 | (E)-1 | (S)-1 | (S)-2 |
| | [100] | [25.0] | [10] | [1.5] | [0.6] | [100] | [5,000] |
| Ex. 4 | (A)-1 | (B)-1 | (C)-4 | (D)-1 | (E)-1 | (S)-1 | (S)-2 |
| | [100] | [25.0] | [10] | [1.5] | [0.6] | [100] | [5,000] |
| Ex. 5 | (A)-1 | (B)-1 | (C)-5 | (D)-1 | (E)-1 | (S)-1 | (S)-2 |
| | [100] | [25.0] | [10] | [1.5] | [0.6] | [100] | [5,000] |
| Ex. 6 | (A)-1 | (B)-1 | (C)-6 | (D)-1 | (E)-1 | (S)-1 | (S)-2 |
| | [100] | [25.0] | [10] | [1.5] | [0.6] | [100] | [5,000] |
| Ex. 7 | (A)-1 | (B)-1 | (C)-7 | (D)-1 | (E)-1 | (S)-1 | (S)-2 |
| | [100] | [25.0] | [10] | [1.5] | [0.6] | [100] | [5,000] |
| Ex. 8 | (A)-1 | (B)-1 | (C)-8 | (D)-1 | (E)-1 | (S)-1 | (S)-2 |
| | [100] | [25.0] | [10] | [1.5] | [0.6] | [100] | [5,000] |
| Ex. 9 | (A)-1 | (B)-1 | (C)-9 | (D)-1 | (E)-1 | (S)-1 | (S)-2 |
| | [100] | [25.0] | [10] | [1.5] | [0.6] | [100] | [5,000] |
| Ex. 10 | (A)-1 | (B)-1 | (C)-10 | (D)-1 | (E)-1 | (S)-1 | (S)-2 |
| | [100] | [25.0] | [10] | [1.5] | [0.6] | [100] | [5,000] |
| Comp. | (A)-1 | (B)-1 | (C″)-1 | (D)-1 | (E)-1 | (S)-1 | (S)-2 |
| Ex. 1 | [100] | [25.0] | [10] | [1.5] | [0.6] | [100] | [5,000] |
| Comp. | (A)-1 | (B)-1 | (C″)-2 | (D)-1 | (E)-1 | (S)-1 | (S)-2 |
| Ex. 2 | [100] | [25.0] | [10] | [1.5] | [0.6] | [100] | [5,000] |

TABLE 2

| | Component (A) | Component (C) | Component (D) | Component (S) | |
|---|---|---|---|---|---|
| Ex. 11 | (A)-2 [100] | (C)-1 [10] | (D)-2 [2.1] | (S)-1 [100] | (S)-3 [5,000] |
| Ex. 12 | (A)-2 [100] | (C)-2 [10] | (D)-2 [2.1] | (S)-1 [100] | (S)-3 [5,000] |
| Ex. 13 | (A)-2 [100] | (C)-3 [10] | (D)-2 [2.1] | (S)-1 [100] | (S)-3 [5,000] |
| Ex. 14 | (A)-2 [100] | (C)-4 [10] | (D)-2 [2.1] | (S)-1 [100] | (S)-3 [5,000] |
| Ex. 15 | (A)-2 [100] | (C)-5 [10] | (D)-2 [2.1] | (S)-1 [100] | (S)-3 [5,000] |
| Ex. 16 | (A)-2 [100] | (C)-6 [10] | (D)-2 [2.1] | (S)-1 [100] | (S)-3 [5,000] |
| Ex. 17 | (A)-2 [100] | (C)-7 [10] | (D)-2 [2.1] | (S)-1 [100] | (S)-3 [5,000] |
| Ex. 18 | (A)-2 [100] | (C)-8 [10] | (D)-2 [2.1] | (S)-1 [100] | (S)-3 [5,000] |
| Ex. 19 | (A)-2 [100] | (C)-9 [10] | (D)-2 [2.1] | (S)-1 [100] | (S)-3 [5,000] |
| Ex. 20 | (A)-2 [100] | (C)-10 [10] | (D)-2 [2.1] | (S)-1 [100] | (S)-3 [5,000] |
| Comp. Ex. 3 | (A)-2 [100] | (C″)-3 [10] | (D)-2 [2.1] | (S)-1 [100] | (S)-3 [5,000] |
| Comp. Ex. 4 | (A)-2 [100] | (C″)-4 [10] | (D)-2 [2.1] | (S)-1 [100] | (S)-3 [5,000] |
| Comp. Ex. 5 | (A)-2 [100] | (C″)-5 [10] | (D)-2 [2.1] | (S)-1 [100] | (S)-3 [5,000] |

In Tables 1 and 2, the abbreviations used indicate the following. Further, the numerical values in brackets [ ] indicate the amount (in terms of parts by weight) of the component added.

(A)-1: a copolymer represented by a structural formula (A)-1 shown below.

(A)-2: a copolymer represented by a structural formula (A)-2 shown below.

(C)-1 to (C)-10: copolymers represented by structural formulas (C)-1 to (C)-10 shown below, respectively.

(C″)-1 to (C″)-5: copolymers represented by structural formulas (C″)-1 to (C″)-5 shown below, respectively.

(B)-1: a compound represented by a structural formula (B)-1 shown below.

(D)-1: tri-n-octylamine.

(D)-2: a compound represented by a structural formula (D)-2 shown below.

(E)-1: salicylic acid.

(S)-1: γ-butyrolactone.

(S)-2: a mixed solvent of PGMEA/PGME=3000/2000 (weight ratio)

(S)-3: a mixed solvent of PGMEA/PGME/cyclohexanone=1500/1000/2500 (weight ratio)

The components (A) and (C) were synthesized by known methods. The weight average molecular weight (Mw) and the molecular weight dispersity (Mw/Mn) thereof were measured by gel permeation chromatography (GPC) in terms of the polystyrene equivalent value. The compositional ratio of the copolymer (the proportion (molar ratio) of each of the structural units within the structural formula) was determined by carbon 13 nuclear magnetic resonance spectroscopy (600 MHz, ¹³C-NMR). Tetramethylsilane (TMS) was used as an internal standard for the ¹³C-NMR measurements.

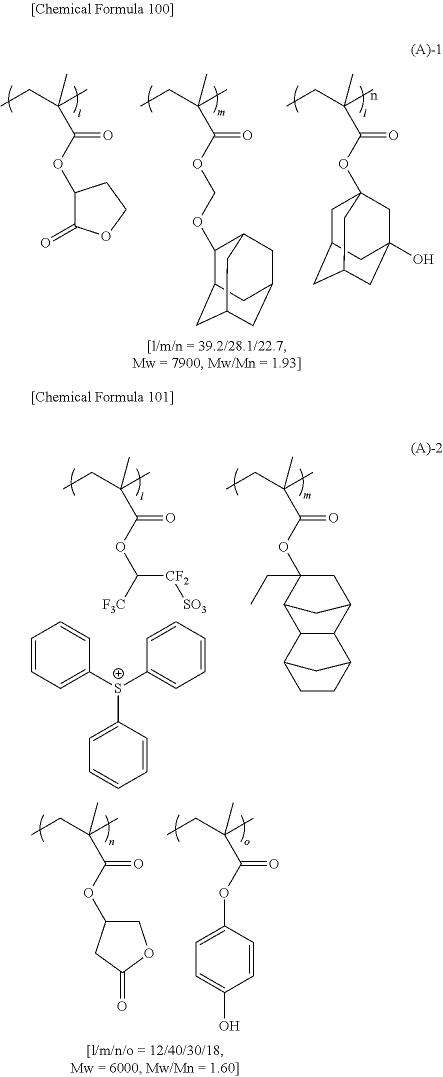

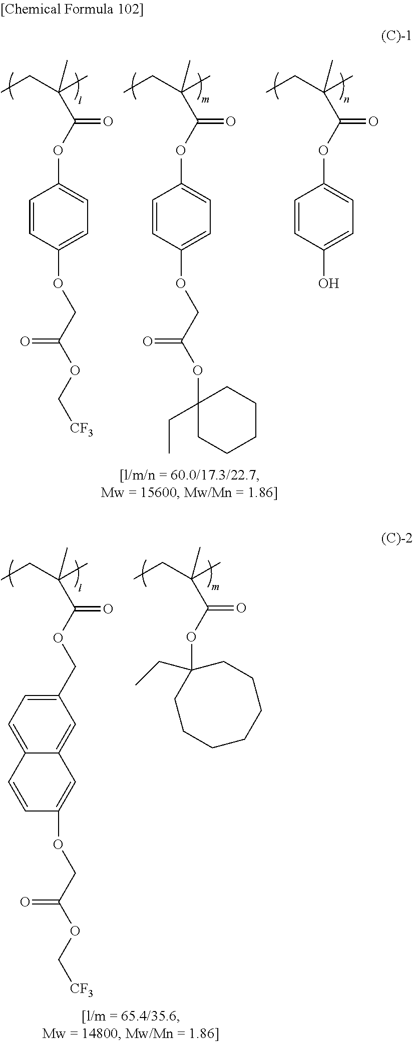

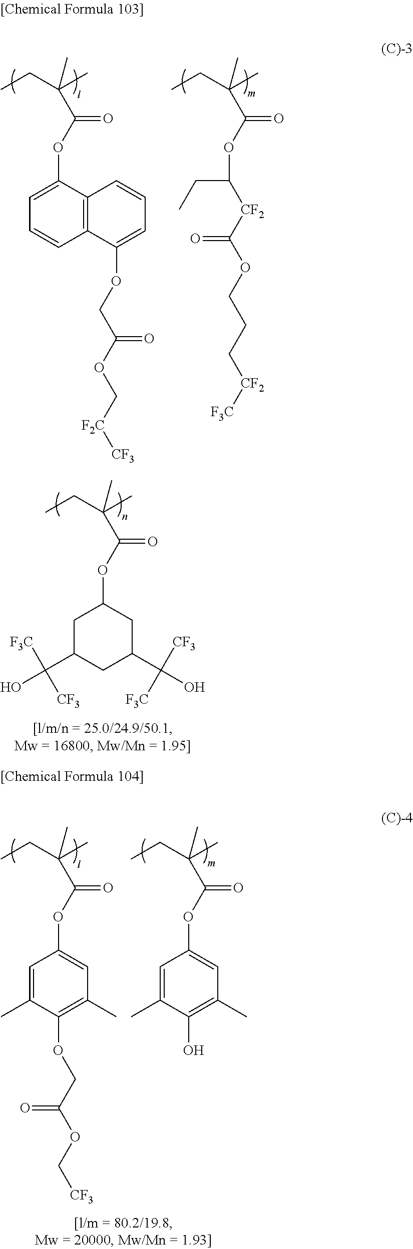

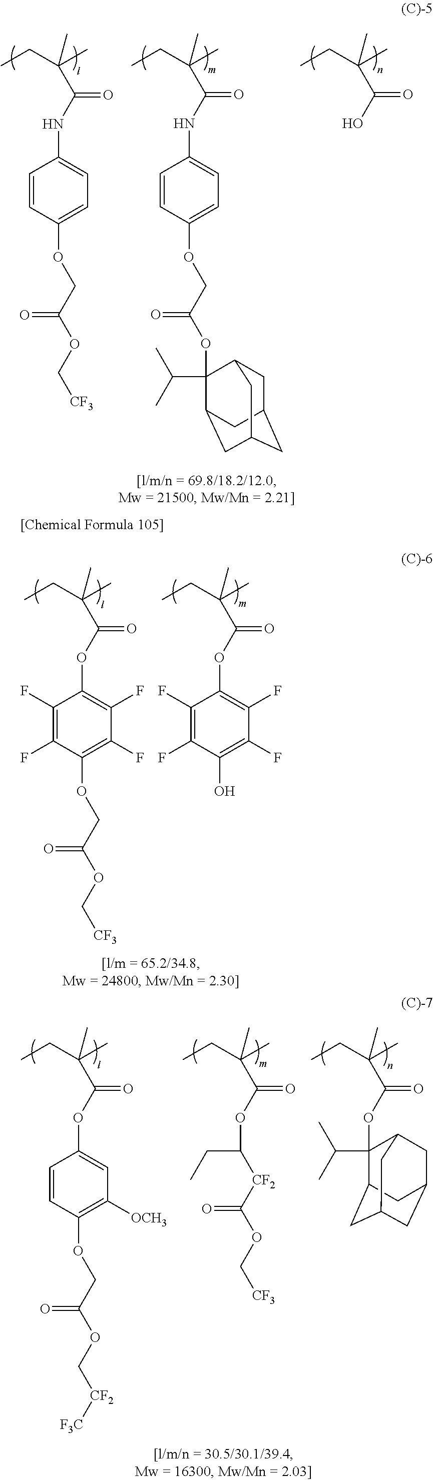

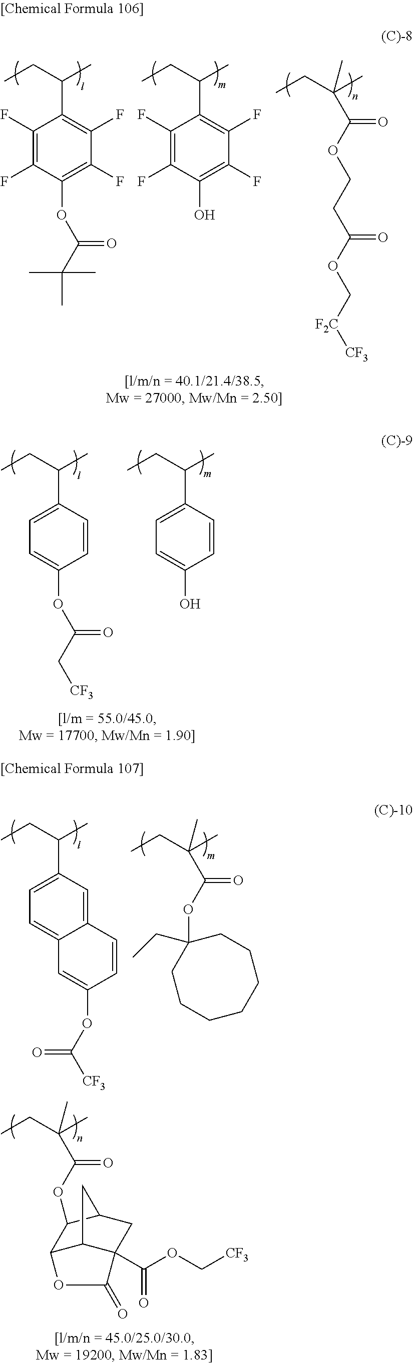

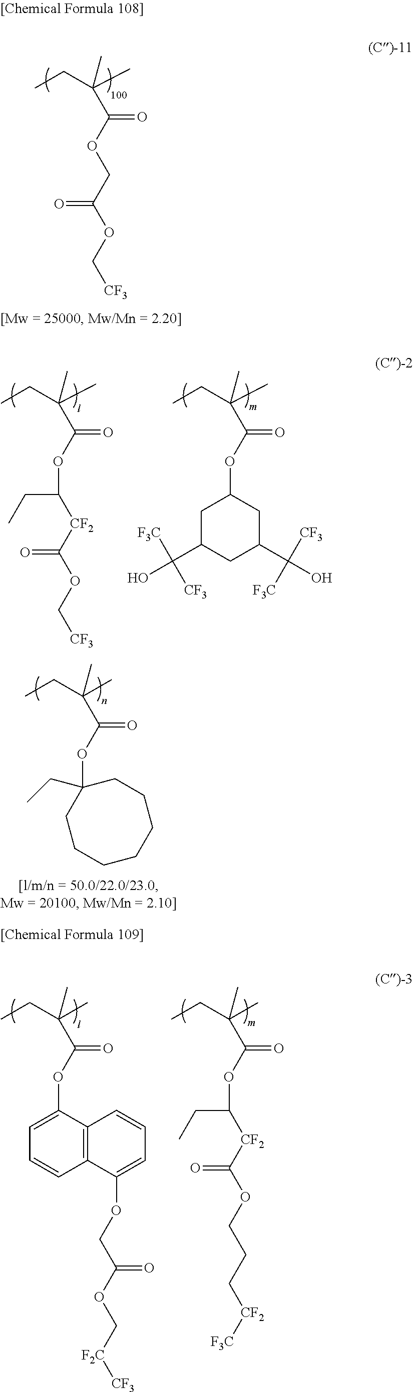

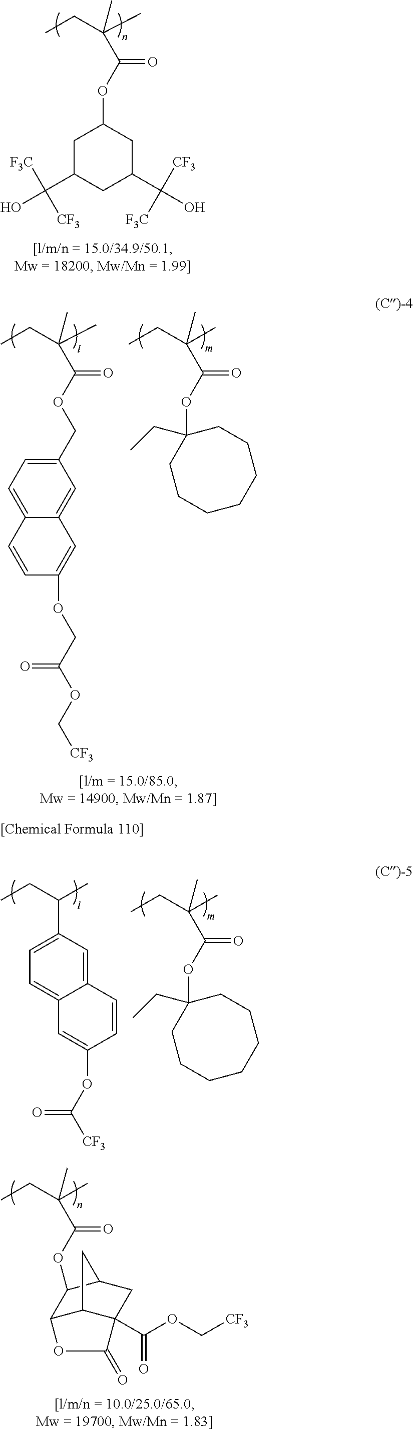

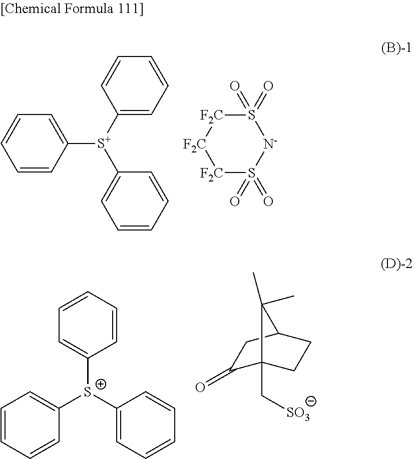

Using each of the obtained resist compositions, the following evaluations were performed.

### [Formation of Resist Pattern]

Using a spinner, the resist composition of each example was applied uniformly onto an 8-inch silicon substrate that had been surface-treated with hexamethyldisilazane (HMDS) for 36 seconds at 90° C., and a bake treatment (PAB) was then conducted for 60 seconds at a PAB temperature shown in Tables 3 and 4, thereby forming a resist film (thickness: 60 nm). This resist film was subjected to patterning (exposure) with an electron beam exposure apparatus HL800D (VSB) (manufactured by Hitachi Ltd.) using an accelerating voltage of 50 keV, and was then subjected to a bake treatment (PEB) for 60 seconds at a PEB temperature shown in Tables 3 and 4, followed by development for 60 seconds at 23° C. in a 2.38% by weight aqueous solution of tetramethylammonium hydroxide (TMAH) (product name: NMD-3, manufactured by Tokyo Ohka Kogyo Co., Ltd.).

As a result, in each example, a line and space resist pattern (hereafter referred to as an “L/pattern”) having a line width of 100 nm and a pitch of 200 nm was formed.

The optimum exposure dose Eop (μC/cm²) at which the LS pattern was formed was determined. The results are shown in Tables 3 and 4.

It is thought that a higher accelerating voltage is advantageous in forming a fine resist pattern, but in the present evaluation, in order to reproduce a state that simulates the state in which OoB light is generated, a comparatively low accelerating voltage of 50 keV was employed for the exposure conditions.

### [Evaluation of Resolution]

The critical resolution (nm) at the above Eop was determined using a scanning electron microscope (product name: S-9380, manufactured by Hitachi High-Technologies Corporation). The results are shown in Tables 3 and 4 as “resolution”.

### [Evaluation of Line Width Roughness (LWR)]

For the LS pattern formed in the aforementioned “Formation of resist pattern” having a line width of 100 nm and a pitch of 200 nm, the value of 3σ was determined as a measure of the LWR. This value of 3σ (units: nm) represents the value of three times the standard deviation (σ) for line width values measured at 400 points along the lengthwise direction of the line using a scanning electron microscope (product name: S-9220, manufactured by Hitachi High-Technologies Corporation, accelerating voltage: 800 V). The smaller the value of 3σ, the lower the level of roughness in the line side walls, meaning an LS pattern of more uniform width has been obtained. The results are shown in Tables 3 and 4.

### [Evaluation of Exposure Margin (10% EL)]

With respect to the aforementioned “Formation of resist pattern”, the exposure dose with which lines of an LS pattern having a dimension of the target dimension (line width: 100 nm)±10% (i.e., 90 nm to 110 nm) were formed was determined, and the exposure latitude (unit: %) was determined by the following formula. The larger the value of exposure latitude, the smaller the fluctuation in the pattern size accompanied by the variation in the exposure dose. The results are shown in Tables 3 and 4 as “10% EL”.

Exposure latitude (%)=(|E1−E2|/Eop)×100

In the formula, E1 indicates an exposure dose (μC/cm²) with which an LS pattern having a line width of 90 nm was formed, and E2 indicates an exposure dose (μC/cm²) with which an LS pattern having a line width of 110 nm was formed.

TABLE 3

| | PAB/PEB | Eop | LWR | 10% EL | Resolution |
|---|---|---|---|---|---|
| | [° C.] | [μC/cm²] | [nm] | [%] | [nm] |
| Ex. 1 | 100/90 | 50 | 7.6 | 20.0 | 50 |
| Ex. 2 | 100/90 | 54 | 6.6 | 21.0 | 50 |
| Ex. 3 | 100/90 | 48 | 6.0 | 22.5 | 50 |
| Ex. 4 | 100/90 | 52 | 5.0 | 26.4 | 50 |
| Ex. 5 | 100/90 | 52 | 7.0 | 21.1 | 50 |
| Ex. 6 | 100/90 | 46 | 7.5 | 24.0 | 50 |
| Ex. 7 | 100/90 | 50 | 8.2 | 20.8 | 50 |
| Ex. 8 | 100/90 | 54 | 7.6 | 23.2 | 50 |
| Ex. 9 | 100/90 | 45 | 7.3 | 19.8 | 50 |
| Ex. 10 | 100/90 | 44 | 7.5 | 19.6 | 50 |
| Comp. Ex. 1 | 100/90 | 50 | 12.2 | 16.0 | 70 |
| Comp. Ex. 2 | 100/90 | 60 | 10.1 | 15.6 | 70 |

TABLE 4

| | PAB/PEB | Eop | LWR | 10% EL | Resolution |
|---|---|---|---|---|---|
| | [° C.] | [μC/cm²] | [nm] | [%] | [nm] |
| Ex. 11 | 120/95 | 54 | 7.2 | 23.4 | 50 |
| Ex. 12 | 120/95 | 56 | 6.5 | 23.8 | 50 |
| Ex. 13 | 120/95 | 48 | 6 | 22.2 | 50 |
| Ex. 14 | 120/95 | 58 | 7.2 | 24.5 | 50 |
| Ex. 15 | 120/95 | 50 | 5.6 | 20.2 | 50 |
| Ex. 16 | 120/95 | 50 | 6.8 | 23.1 | 50 |
| Ex. 17 | 120/95 | 56 | 7 | 20.6 | 50 |
| Ex. 18 | 120/95 | 50 | 7.3 | 20.0 | 50 |
| Ex. 19 | 120/95 | 52 | 6.5 | 24.5 | 50 |
| Ex. 20 | 120/95 | 50 | 7.2 | 23.0 | 50 |
| Comp. Ex. 3 | 120/95 | 52 | 10 | 16.8 | 60 |
| Comp. Ex. 4 | 120/95 | 54 | 9.8 | 15.6 | 60 |
| Comp. Ex. 5 | 120/95 | 54 | 9.8 | 16.5 | 60 |

As is evident from the results shown above, the resist compositions of Examples 1 to 10 exhibited favorable sensitivity to EB, and also exhibited excellent resolution and greater exposure latitude, as compared to Comparative Examples 1 and 2 which were using the component (C″)-1 or (C″)-2 with no structural unit having an aromatic group as the component (C), although other compositions were the same. Further, the shape of the formed resist pattern was also favorable with a smaller LWR value.

Similarly, the resist composition of Examples 11 to 20 exhibited favorable sensitivity to EB, and also exhibited excellent resolution and greater exposure latitude, as compared to Comparative Examples 3 to 5 which were using the components (C″)-3 to (C″)-5 containing no more than 15.0 mol % of structural unit having an aromatic group as the component (C), although other compositions were the same. Further, the shape of the formed resist pattern was also favorable with a smaller LWR value.

What is claimed is:

1. A resist composition for use with EUV or EB comprising:
a resin component (C) containing at least one type of atom selected from the group consisting of a fluorine atom and a silicon atom, an aromatic group, and a polarity conversion group that decomposes by action of base to increase the polarity; and
a resin component (A) that generates acid upon exposure and exhibits changed solubility in a developing solution under action of acid (excluding the resin component (C)),
wherein an amount of a structural unit having the aromatic group in the resin component (C) is at least 20 mol %.

2. The resist composition for use with EUV or EB according to claim 1, which contains 1 to 15 parts by weight of the resin component (C), relative to 100 parts by weight of the resin component (A).

3. The resist composition for use with EUV or EB according to claim 1,
wherein the resin component (A) comprises a structural unit (a0) including a structure that generates an acid upon exposure, and
an amount of the structural unit (a0) in the resin component (A) is at least 5 mol %.

4. A resist composition for use with EUV or EB comprising:
a resin component (C) containing at least one type of atom selected from the group consisting of a fluorine atom and a silicon atom, an aromatic group, and a polarity conversion group that decomposes by action of base to increase the polarity;
a resin component (A) that exhibits changed solubility in a developing solution under action of acid (excluding the component (C)); and
an acid generator component (B) that generates acid upon exposure,
wherein an amount of a structural unit having the aromatic group in the resin component (C) is at least 20 mol %, and
the amount of the acid generator component (B) is 15 parts by weight or more, relative to 100 parts by weight of the resin component (A).

5. The resist composition for use with EUV or EB according to claim 1,
wherein the resin component (A) further comprises a structural unit (a1) containing an acid decomposable group that decomposes by action of an acid to increase the polarity.

6. The resist composition for use with EUV or EB according to claim 4,
wherein the resin component (A) further comprises a structural unit (a1) containing an acid decomposable group that decomposes by action of an acid to increase the polarity.

7. A method of forming a resist pattern, the method comprising:
forming a resist film on a substrate using the resist composition for use with EUV or EB according to any one of claims 1 to 6;
exposing the resist film with EUV or EB; and
developing the resist film to form a resist pattern.
